(19) United States
(12) Patent Application Publication
(10) Pub. No.: US 2008/0233429 A1
(43) Pub. Date: Sep. 25, 2008

(54) Polymer Compound and Polymer Light-Emitting Device Using the Same

(75) Inventors: Jun Oguma, Ibaraki (JP); Kazuei Ohuchi, Ibaraki (JP); Takahiro Ueoka, Ibaraki (JP); Akiko Nakazono, Ibaraki (JP); Kiyotoshi Iimura, Ibaraki (JP); Katsumi Agata, Chiba (JP); Takeshi Yamada, Ibaraki (JP); Osamu Goto, Ibaraki (JP); Satoshi Kobayashi, Ibaraki (JP); Akihiko Okada, Ibaraki (JP)

Correspondence Address: SUGHRUE MION, PLLC, 2100 PENNSYLVANIA AVENUE, N.W., SUITE 800, WASHINGTON, DC, 20037, US

(73) Assignee: SUMITOMO CHEMICAL COMPANY, LIMITED, Tokyo (JP)

(21) Appl. No.: 10/582,394

(22) PCT Filed: Dec. 10, 2004
(86) PCT No.: PCT/JP2004/018865

§ 371 Date: Apr. 18, 2008

(30) Foreign Application Priority Data
Dec. 12, 2003 (JP) 2003-414402
Feb. 26, 2004 (JP) 2004-051173
Apr. 30, 2004 (JP) 2004-135499
Oct. 15, 2004 (JP) 2004-301416
Nov. 5, 2004 (JP) 2004-321803
Nov. 16, 2004 (JP) 2004-331704

(51) Int. Cl. C09K 11/06; C08G 79/08; C08G 79/00; C08G 75/00; C08G 69/08; C08G 73/10; C08G 77/12

(52) U.S. Cl. 428/690; 528/392; 528/8; 528/9; 528/391; 524/1; 528/310; 528/322; 528/31

(57) ABSTRACT

A polymer compound comprising a repeating unit of the following formula (1) and which is useful as a light emitting material or charge transporting material and excellent in heat resistance, fluorescent intensity and the like:

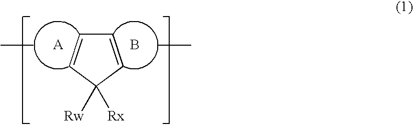

(wherein, ring A and ring B represent each independently an aromatic hydrocarbon ring optionally having a substituent, at least one of ring A and ring B is an aromatic hydrocarbon ring composed of a plurality of condensed benzene rings, R_{w} and Rₓ represent each independently a hydrogen atom, alkyl group, alkoxy group or the like, and R_{w} and Rₓ may mutually bond to form a ring).

### TECHNICAL FIELD

The present invention relates to a polymer compound and a polymer light emitting device using the same.

### BACKGROUND ART

Light emitting materials and charge transporting material of higher molecular weight are soluble in a solvent and can form an organic layer in a light emitting device by an application method, unlike those of lower molecular weight, thus, are investigated variously. As an example, a polymer compound is known having the following structure containing two benzene rings condensed to a cyclopentadiene ring as a repeating unit (for example, Advanced Materials 1999, vol. 9, No. 10, p. 798, International Publication No. 99/54385 pamphlet).

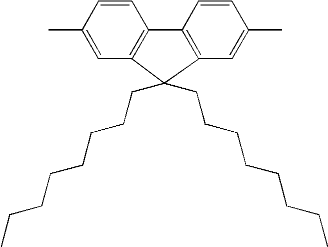

However, the above-mentioned polymer compound has a problem that its heat resistance, fluorescent intensity and the like are not necessarily sufficient.

### DISCLOSURE OF THE INVENTION

The present invention has an object of providing a polymer compound which is useful as a light emitting material and an charge transporting material and excellent in heat resistance, fluorescent intensity and the like.

The present inventors have intensively studied to solve the above-mentioned problem and resultantly found that a polymer compound having a structure containing two aromatic hydrocarbon rings condensed to a cyclopentadiene ring as a repeating unit wherein at least one of the aromatic hydrocarbon rings is an aromatic hydrocarbon ring containing a plurality of condensed benzene rings is useful as a light emitting material and an charge transporting material and excellent in heat resistance, fluorescent intensity and the like, leading to completion of the present invention.

That is, the present invention provides a polymer compound containing a repeating unit of the following formula (1):

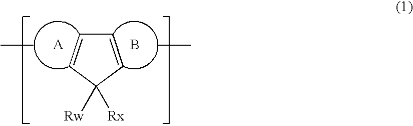

(wherein, ring A and ring B represent each independently an aromatic hydrocarbon ring optionally having a substituent, at least one of ring A and ring B is an aromatic hydrocarbon ring composed of a plurality of condensed benzene rings, two connecting bonds are present on ring A and/or ring B, R_{w} and Rₓ represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, and R_{w} and Rₓ may mutually bond to form a ring).

### BRIEF EXPLANATION OF DRAWINGS

FIG. 1 is a schematic sectional view of a forward stagger type organic film transistor of the present invention.

FIG. 2 is a schematic sectional view of a forward stagger inclined type organic film transistor of the present invention.

FIG. 3 is a schematic sectional view of a reverse stagger type organic film transistor of the present invention.

FIG. 4 is a schematic sectional view of a reverse stagger inclined type organic film transistor of the present invention.

FIG. 5 shows a structure of an organic film transistor used in Example 125 of the present invention.

FIG. 6 shows I_{D}-V_{DS} property of an organic film transistor used in Example 125 of the present invention.

### BEST MODES FOR CARRYING OUT THE INVENTION

The polymer compound of the present invention contains one or more repeating units of the above-mentioned formula (1).

In the formula, ring A and ring B represent each independently an aromatic hydrocarbon ring optionally having a substituent, and at least one of them is an aromatic hydrocarbon ring composed of a plurality of condensed benzene rings. To the aromatic ring and/or non-aromatic hydrocarbon-based condensed cyclic compound may further be condensed. Though an aromatic hydrocarbon ring in ring A and an aromatic hydrocarbon ring in ring B in a polymer compound of the present invention may have mutually the same ring structure or different ring structures, it is preferable, from the standpoint of heat resistance and fluorescent intensity, that an aromatic hydrocarbon ring in ring A and an aromatic hydrocarbon ring in ring B have mutually different ring structures.

As the aromatic hydrocarbon ring, a single benzene ring or those containing a plurality of condensed benzene rings are preferable, and examples thereof include aromatic hydrocarbon rings such as a benzene ring, naphthalene ring, anthracene ring, tetracene ring, pentacene ring, pyrene ring, phenanthrene ring and the like, and preferably mentioned are a benzene ring, naphthalene ring, anthracene ring and phenanthrene ring.

As the combination of ring A and ring B, preferably, combinations of benzene ring and naphthalene ring, benzene ring and anthracene ring, benzene ring and phenanthrene ring, naphthalene ring and anthracene ring, naphthalene ring and phenanthrene ring, anthracene ring and phenanthrene ring, are mentioned, and more preferable is a combination of benzene ring and naphthalene ring.

That an aromatic hydrocarbon ring in ring A and an aromatic hydrocarbon ring in ring B have mutually different ring structures means that when

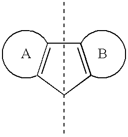

in the formula (1) is represented by planar structure, an aromatic hydrocarbon ring in ring A and an aromatic hydrocarbon ring in ring B are asymmetrical over a symmetrical axis (dotted line) connecting a peak of a 5-membered ring at the center of the structural formula and a middle point of a side facing the peak.

For example, when both ring A and ring B are naphthalene rings, the ring A and the ring B have different ring structures in the case of

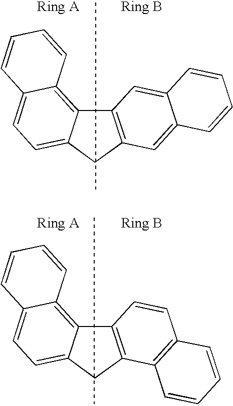

On the other hand, even if both ring A and ring B are naphthalene rings, the ring A and the ring B have the same ring structure in the case of

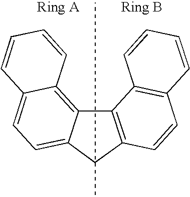

When the aromatic hydrocarbon ring has a substituent, it is preferable, from the standpoint of solubility in an organic solvent, element property, easiness of synthesis and the like, that the substituent is selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group and cyano group.

Here, the alkyl group may be any of straight-chain, branched or cyclic, the number of carbon atom is usually about 1 to 20, preferably 3 to 20, and specific examples thereof include a methyl group, ethyl group, propyl group, i-propyl group, butyl group, i-butyl group, t-butyl group, pentyl group, isoamyl group, hexyl group, cyclohexyl group, heptyl group, octyl group, 2-ethylhexyl group, nonyl group, decyl group, 3,7-dimethyloctyl group, lauryl group, trifluoromethyl group, pentafluoroethyl group, perfluorobutyl group, perfluorohexyl group, perfluorooctyl group and the like, and for balance between heat resistance and standpoints such as solubility in an organic solvent, element property, easiness of synthesis and the like, preferable are a pentyl group, isoamyl group, hexyl group, octyl group, 2-ethylhexyl group, decyl group and 3,7-dimethyloctyl group.

The alkoxy group may be any of straight-chain, branched or cyclic, the number of carbon atom is usually about 1 to 20, preferably 3 to 20, and specific examples thereof include a methoxy group, ethoxy group, propyloxy group, i-propyloxy group, butoxy group, i-butoxy group, t-butoxy group, pentyloxy group, hexyloxy group, cyclohexyloxy group, heptyloxy group, octyloxy group, 2-ethylhexyloxy group, nonyloxy group, decyloxy group, 3,7-dimethyloctyloxy group, lauryloxy group, trifluoromethoxy group, pentafluoroethoxy group, perfluorobutoxy group, perfluorohexyloxy group, perfluorooctyloxy group, methoxymethyloxy group, 2-methoxyethyloxy group and the like, and for balance between heat resistance and standpoints such as solubility in an organic solvent, element property, easiness of synthesis and the like, preferable are a pentyloxy group, hexyloxy group, octyloxy group, 2-ethylhexyloxy group, decyloxy group and 3,7-dimethyloctyloxy group.

The alkylthio group may be any of straight-chain, branched or cyclic, the number of carbon atom is usually about 1 to 20, preferably 3 to 20, and specific examples thereof include a methylthio group, ethylthio group, propylthio group, i-propylthio group, butylthio group, i-butylthio group, t-butylthio group, pentylthio group, hexylthio group, cyclohexylthio group, heptylthio group, octylthio group, 2-ethylhexylthio group, nonylthio group, decylthio group, 3,7-dimethyloctylthio group, laurylthio group, trifluoromethylthio group and the like, and for balance between heat resistance and standpoints such as solubility in an organic solvent, element property, easiness of synthesis and the like, preferable are a pentylthio group, hexylthio group, octylthio group, 2-ethylhexylthio group, decylthio group and 3,7-dimethyloctylthio group.

The aryl group is an atomic group obtained by removing one hydrogen atom from an aromatic hydrocarbon, and includes also those having a condensed ring, and those in which an independent benzene ring or two or more condensed rings are bonded directly or via a group such as vinylene and the like. The aryl group has a number of carbon atom of usually about 6 to 60, preferably 7 to 48, and specific examples thereof include a phenyl group, C₁ to C₁₂ alkoxyphenyl groups (C₁ to C₁₂ shows that the number of carbon atom is 1 to 12. Also in the following descriptions), C₁ to C₁₂ alkylphenyl groups, 1-naphtyl group, 2-naphtyl group, 1-anthracenyl group, 2-anthracenyl group, 9-anthracenyl group, pentafluorophenyl group and the like, and from the standpoint of solubility in an organic solvent, element property, easiness of synthesis and the like, preferable are C₁ to C₁₂ alkoxyphenyl groups and C₁ to C₁₂ alkylphenyl groups. Specific examples of the C₁ to C₁₂ alkoxy include a methoxy group, ethoxy group, propyloxy group, i-propyloxy group, butoxy group, i-butoxy group, t-butoxy group, pentyloxy group, hexyloxy group, cyclohexyloxy group, heptyloxy group, octyloxy group, 2-ethylhexyloxy group, nonyloxy group, decyloxy group, 3,7-dimethyloctyloxy group, lauryloxy group and the like.

Specific examples of the C₁ to C₁₂ alkylphenyl group include a methylphenyl group, ethylphenyl group, dimethylphenyl group, propylphenyl group, mesityl group, methylethylphenyl group, i-propylphenyl group, butylphenyl group, i-butylphenyl group, t-butylphenyl group, pentylphenyl group, isoamylphenyl group, hexylphenyl group, heptylphenyl group, octylphenyl group, nonylphenyl group, decylphenyl group, dodecylphenyl group and the like.

The aryloxy group has a number of carbon atom of usually about 6 to 60, preferably 7 to 48, and specific examples thereof include a phenoxy group, C₁ to C₁₂ alkoxyphenoxy groups, C₁ to C₁₂ alkylphenoxy groups, 1-naphtyloxy group, 2-naphtyloxy group, pentafluorophenyloxy group and the like, and from the standpoint of solubility in an organic solvent, element property, easiness of synthesis and the like, preferable are C₁ to C₁₂ alkoxyphenoxy groups and C₁ to C₁₂ alkylphenoxy groups.

Specific examples of the C₁ to C₁₂ alkoxy include a methoxy group, ethoxy group, propyloxy group, i-propyloxy group, butoxy group, i-butoxy group, t-butoxy group, pentyloxy group, hexyloxy group, cyclohexyloxy group, heptyloxy group, octyloxy group, 2-ethylhexyloxy group, nonyloxy group, decyloxy group, 3,7-dimethyloctyloxy group, lauryloxy group and the like.

Specific examples of the C₁ to C₁₂ alkylphenoxy group include a methylphenoxy group, ethylphenoxy group, dimethylphenoxy group, propylphenoxy group, 1,3,5-trimethylphenoxy group, methylethylphenoxy group, i-propylphenoxy group, butylphenoxy group, i-butylphenoxy group, t-butylphenoxy group, pentylphenoxy group, isoamylphenoxy group, hexylphenoxy group, heptylphenoxy group, octylphenoxy group, nonylphenoxy group, decylphenoxy group, dodecylphenoxy group and the like.

The arylthio group has a number of carbon atom of usually about 3 to 60, and specific examples thereof include a phenylthio group, C₁ to C₁₂ alkoxyphenylthio groups, C₁ to C₁₂ alkylphenylthio groups, 1-naphtylthio group, 2-naphtylthio group, pentafluorophenylthio group, and the like, and from the standpoint of solubility in an organic solvent, element property, easiness of synthesis and the like, preferable are C₁ to C₁₂ alkoxyphenylthio groups and C₁ to C₁₂ alkylphenylthio groups.

The arylalkyl group has a number of carbon atom of usually about 7 to 60, preferably 7 to 48, and specific examples thereof include phenyl-C₁ to C₁₂ alkyl groups, C₁ to C₁₂ alkoxyphenyl-C₁ to C₁₂ alkyl groups, C₁ to C₁₂ alkylphenyl-C₁ to C₁₂ alkyl groups, 1-naphthyl-C₁ to C₁₂ alkyl groups, 2-naphthyl-C₁ to C₁₂ alkyl groups and the like, and from the standpoint of solubility in an organic solvent, element property, easiness of synthesis and the like, preferable are C₁ to C₁₂ alkoxyphenyl-C₁ to C₁₂ alkyl groups and C₁ to C₁₂ alkylphenyl-C₁ to C₁₂ alkyl groups.

The arylalkoxy group has a number of carbon atom of usually about 7 to 60, preferably 7 to 48, and specific examples thereof include phenyl-C₁ to C₁₂ alkoxy groups such as a phenylmethoxy group, phenylethoxy group, phenylbutoxy group, phenylpentyloxy group, phenylhexyloxy group, phenylheptyloxy group, phenyloctyloxy group and the like, C₁ to C₁₂ alkoxyphenyl-C₁ to C₁₂ alkoxy groups, C₁ to C₁₂ alkylphenyl-C₁ to C₁₂ alkoxy groups, 1-naphthyl-C₁ to C₁₂ alkoxy groups, 2-naphthyl-C₁ to C₁₂ alkoxy groups and the like, and from the standpoint of solubility in an organic solvent, element property, easiness of synthesis and the like, preferable are C₁ to C₁₂ alkoxyphenyl-C₁ to C₁₂ alkoxy groups and C₁ to C₁₂ alkylphenyl-C₁ to C₁₂ alkoxy groups.

The arylalkylthio group has a number of carbon atom of usually about 7 to 60, preferably 7 to 48, and specific examples thereof include phenyl-C₁ to C₁₂ alkylthio groups, C₁ to C₁₂ alkoxyphenyl-C₁ to C₁₂ alkylthio groups, C₁ to C₁₂ alkylphenyl-C₁ to C₁₂ alkylthio groups, 1-naphthyl-C₁ to C₁₂ alkylthio groups, 2-naphthyl-C₁ to C₁₂ alkylthio groups and the like, and from the standpoint of solubility in an organic solvent, element property, easiness of synthesis and the like, preferable are C₁ to C₁₂ alkoxyphenyl-C₁ to C₁₂ alkylthio groups and C₁ to C₁₂ alkylphenyl-C₁ to C₁₂ alkylthio groups.

The arylalkenyl group has a number of carbon atom of usually about 8 to 60, and specific examples thereof include phenyl-C₂ to C₁₂ alkenyl groups, C₁ to C₁₂ alkoxyphenyl-C₂ to C₁₂ alkenyl groups, C₁ to C₁₂ alkylphenyl-C₂ to C₁₂ alkenyl groups, 1-naphthyl-C₂ to C₁₂ alkenyl groups, 2-naphthyl-C₂ to C₁₂ alkenyl groups and the like, and from the standpoint of solubility in an organic solvent, element property, easiness of synthesis and the like, preferable are C₁ to C₁₂ alkoxyphenyl-C₂ to C₁₂ alkenyl groups and C₂ to C₁₂ alkylphenyl-C₁ to C₁₂ alkenyl groups.

The arylalkynyl group has a number of carbon atom of usually about 8 to 60, and specific examples thereof include phenyl-C₂ to C₁₂ alkynyl groups, C₁ to C₁₂ alkoxyphenyl-C₂ to C₁₂ alkynyl groups, C₁ to C₁₂ alkylphenyl-C₂ to C₁₂ alkynyl groups, 1-naphthyl-C₂ to C₁₂ alkynyl groups, 2-naphthyl-C₂ to C₁₂ alkynyl groups and the like, and from the standpoint of solubility in an organic solvent, element property, easiness of synthesis and the like, preferable are C₁ to C₁₂ alkoxyphenyl-C₂ to C₁₂ alkynyl groups and C₁ to C₁₂ alkylphenyl-C₂ to C₁₂ alkynyl groups.

As the substituted amino group, amino groups substituted with one or two groups selected from an alkyl group, aryl group, arylalkyl group or mono-valent heterocyclic group are mentioned, and the alkyl group, aryl group, arylalkyl group or mono-valent heterocyclic group may have a substituent. The number of carbon atom of the substituted amino group is usually about 1 to 60, preferably 2 to 48 not including the number of carbon atom of the substituent.

Specifically exemplified are a methylamino group, dimethylamino group, ethylamino group, diethylamino group, propylamino group, dipropylamino group, i-propylamino group, diisopropylamino group, butylamino group, i-butylamino group, t-butylamino group, pentylamino group, hexylamino group, cyclohexylamino group, heptylamino group, octylamino group, 2-ethylhexylamino group, nonylamino group, decylamino group, 3,7-dimethyloctylamino group, laurylamino group, cyclopentylamino group, dicyclopentylamino group, cyclohexylamino group, dicyclohexylamino group, pyrrolidyl group, piperidyl group, ditrifluoromethylamino group, phenylamino group, diphenylamino group, C₁ to C₁₂ alkoxyphenylamino group, di(C₁ to C₁₂ alkoxyphenyl)amino group, di(C₁ to C₁₂ alkylphenyl)amino group, 1-naphthylamino group, 2-naphthylamino group, pentafluorophenylamino group, pyridylamino group, pyridazinylamino group, pyrimidylamino group, pyrazylamino group, triazylamino group, phenyl-C₁ to C₁₂ alkylamino group, C₁ to C₁₂ alkoxyphenyl-C₁ to C₁₂ alkylamino group, C₁ to C₁₂ alkylphenyl-C₁ to C₁₂ alkylamino group, di(C₁ to C₁₂ alkoxyphenyl-C₁ to C₁₂ alkyl)amino group, di(C₁ to C₁₂ alkylphenyl-C₁ to C₁₂ alkyl)amino group, 1-naphthyl-C₁ to C₁₂ alkylamino group, 2-naphthyl-C₁ to C₁₂ alkylamino group and the like.

As the substituted silyl group, silyl groups substituted with one, two or three groups selected from an alkyl group, aryl group, arylalkyl group or mono-valent heterocyclic group are mentioned. The number of carbon atom of the substituted silyl group is usually about 1 to 60, preferably 3 to 48. The alkyl group, aryl group, arylalkyl group or mono-valent heterocyclic group may have a substituent.

Specifically exemplified are a trimethylsilyl group, triethylsilyl group, tripropylsilyl group, tri-i-propylsilyl group, dimethyl-i-propylsilyl group, diethyl-i-propylsilyl group, t-butylsilyldimethylsilyl group, pentyldimethylsilyl group, hexyldimethylsilyl group, heptyldimethylsilyl group, octyldimethylsilyl group, 2-ethylhexyl-dimethylsilyl group, nonyldimethylsilyl group, decyldimethylsilyl group, 3,7-dimethyloctyl-dimethylsilyl group, lauryldimethylsilyl group, phenyl-C₁ to C₁₂ alkylsilyl group, C₁ to C₁₂ alkoxyphenyl-C₁ to C₁₂ alkylsilyl group, C₁ to C₁₂ alkylphenyl-C₁ to C₁₂ alkylsilyl group, 1-naphthyl-C₁ to C₁₂ alkylsilyl group, 2-naphthyl-C₁ to C₁₂ alkylsilyl group, phenyl-C₁ to C₁₂ alkyldimethylsilyl group, triphenylsilyl group, tri-p-xylylsilyl group, tribenzylsilyl group, diphenylmethylsilyl group, t-butyldiphenylsilyl group, dimethylphenylsilyl group and the like.

The acyl group has a number of carbon atom of usually about 2 to 20, preferably 2 to 18, and specific examples thereof include an acetyl group, propionyl group, butyryl group, isobutyryl group, pivaloyl group, benzoyl group, trifluoroacetyl group, pentafluorobenzoyl group and the like. As the halogen atom, a fluorine atom, chlorine atom, bromine atom, and iodine atom are exemplified.

The acyloxy group has a number of carbon atom of usually about 2 to 20, preferably 2 to 18, and specific examples thereof include an acetoxy group, propionyloxy group, butyryloxy group, isobutyryloxy group, pivaloyloxy group, benzoyloxy group, trifluoroacetyloxy group, pentafluorobenzoyloxy group and the like.

The imine residue has a number of carbon atom of usually about 2 to 20, preferably 2 to 18, and specific examples thereof include groups of the following structural formulae, and the like.

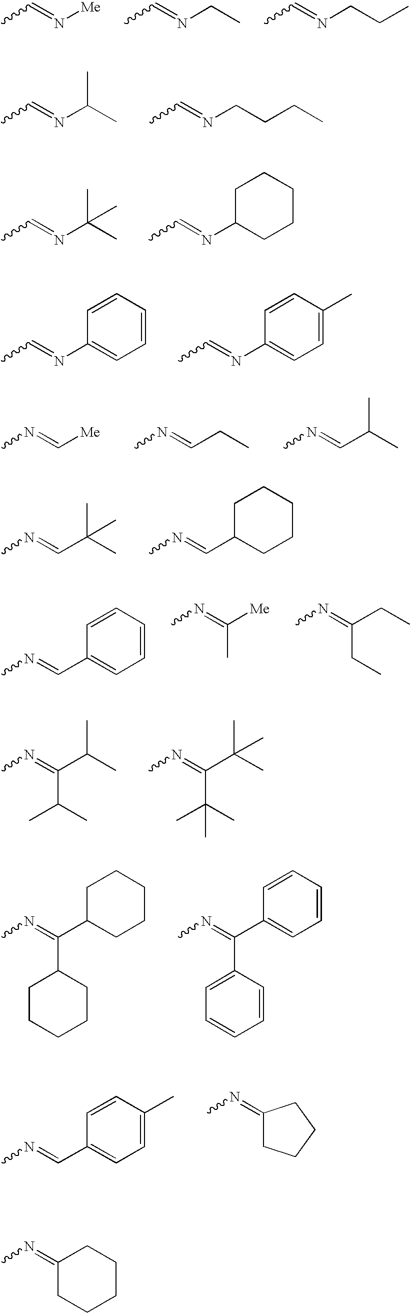

The amide group has a number of carbon atom of usually about 2 to 20, preferably 2 to 18, and specific examples thereof include a formamide group, acetamide group, propionamide group, butyroamide group, benzamide group, trifluoroacetamide group, pentafluorobenzyamide group, diformamide group, diacetamide group, dipropioamide group, dibutyroamide group, dibenzamide group, ditrifluoroacetamide group, dipentafluorobenzyamide group and the like.

As the acid imide group, residues obtained by removing a hydrogen atom bonded to its nitrogen atom from an acid imide are mentioned, and the number of carbon atom is about 4 to 20, and specifically exemplified are the following groups and the like.

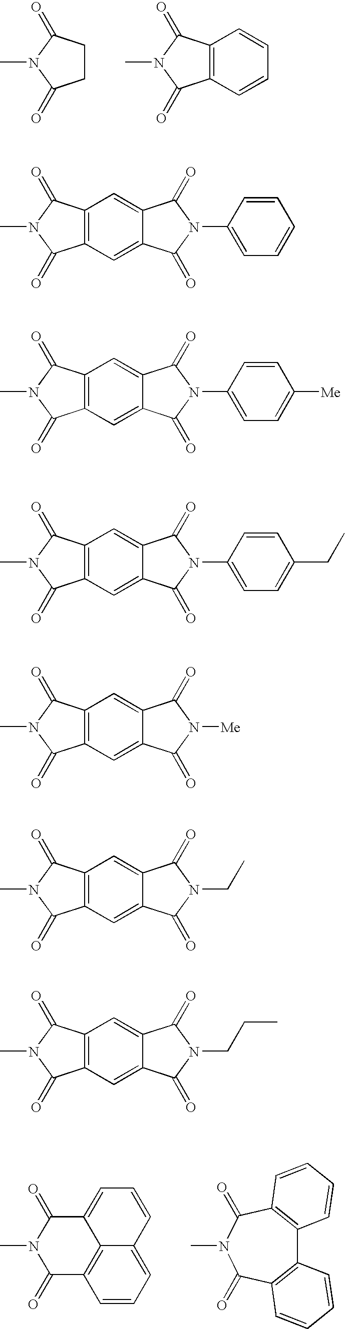

The mono-valent heterocyclic group means an atomic group left after removing one hydrogen atom from a heterocyclic compound, and the number of carbon atom is usually about 4 to 60, preferably 4 to 20. The number of carbon atom of a heterocyclic group does not include the number of carbon atom of a substituent. Here, the heterocyclic compound refers to organic compounds having a cyclic structure in which elements constituting the ring include not only a carbon atom, but also a hetero atom such as oxygen, sulfur, nitrogen, phosphorus, boron and the like contained in the ring. Specifically exemplified are a thienyl group, C₁ to C₁₂ alkylthienyl group, pyrrolyl group, furyl group, pyridyl group, C₁ to C₁₂ alkylpyridyl group, piperidyl group, quinolyl group, isoquinolyl group and the like, and preferable are a thienyl group, C₁ to C₁₂ alkylthienyl group, pyridyl group, C₁ to C₁₂ alkylpyridyl group.

As the substituted carboxyl group, carboxyl groups substituted with an alkyl group, aryl group, arylalkyl group or mono-valent heterocyclic group are mentioned, and the number of carbon atom is usually about 2 to 60, preferably 2 to 48, and specific examples thereof include a methoxycarbonyl group, ethoxycarbonyl group, propyloxycarbonyl group, i-propyloxycarbonyl group, butoxycarbonyl group, i-butoxycarbonyl group, t-butoxycarbonyl group, pentyloxycarbonyl group, hexyloxycarbonyl group, cyclohexyloxycarbonyl group, heptyloxycarbonyl group, octyloxycarbonyl group, 2-ethylhexyloxycarbonyl group, nonyloxycarbonyl group, decyloxycarbonyl group, 3,7-dimethyloctyloxycarbonyl group, dodecyloxycarbonyl group, trifluoromethoxycarbonyl group, pentafluoroethoxycarbonyl group, perfluorobutoxycarbonyl group, perfluorohexyloxycarbonyl group, perfluorooctyloxycarbonyl group, phenoxycarbonyl group, naphthoxycarbonyl group, pyridyloxycarbonyl group, and the like. The alkyl group, aryl group, arylalkyl group or mono-valent heterocyclic group may have a substituent. The number of carbon atom of the substituted carboxyl group does not include the number of carbon atom of the substituent.

In the formula (1), R_{w} and Rₓ represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, and R_{w} and Rₓ may mutually bond to form a ring.

The definition and specific examples of the alkyl group, alkoxy group, alkylthio group, aryl group, aryloxy group, arylthio group, arylalkyl group, arylalkoxy group, arylalkylthio group, arylalkenyl group, arylalkynyl group, substituted amino group, substituted silyl group, halogen atom, acyl group, acyloxy group, imine residue, amide group, acid imide group, mono-valent heterocyclic group and substituted carboxyl group represented by R_{w} and Rₓ are the same as the definition and specific examples for the substituent when the aromatic hydrocarbon ring has a substituent.

In the repeating unit of the above-mentioned formula (1), it is preferable, from the standpoint of heat stability, that R_{w} and Rₓ mutually bond to form a ring.

As the repeating unit of the above-mentioned formula (1) in this case, there are mentioned, for example, those of the following formula (2).

Here, ring A and ring B have the same meanings as described above, and ring C represents a hydrocarbon ring or heterocyclic ring.

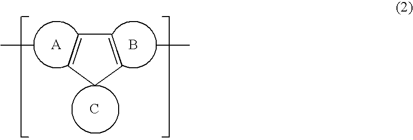

Here, in the above-mentioned formula (2), one carbon atom which is a part of ring C is connected to ring A and ring B by a single bond, in the structure of ring C (following formula 2a).

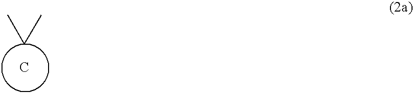

As the hydrocarbon ring in ring C, for example, hydrocarbon rings containing an aromatic ring are mentioned, and examples thereof include a structure as shown in the following formula (2b).

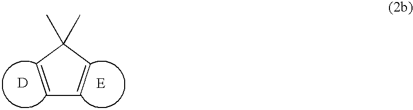

(here, ring D and ring E represent each independently an aromatic hydrocarbon ring optionally having a substituent).

As the hydrocarbon ring, also, aliphatic hydrocarbon rings are mentioned and examples thereof include a structure as shown in the following formula (2c).

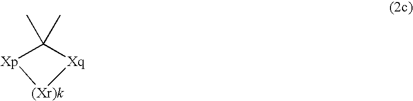

(here, Xp, Xq and Xr represent each independently a methylene group optionally having a substituent, or an ethenylene group optionally having a substituent. k represents 0 or a positive integer).

The number of carbon atom contained in the hydrocarbon ring is 3 or more, and preferably 4 to 20. A poly-cyclic structure combined with other rings may also be used. More specifically exemplified are C₄ to C₂₀ cycloalkyl rings and C₄ to C₂₀ cycloalkenyl rings optionally having a substituent.

As the heterocyclic ring, structures obtained by substituting a carbon atom contained in the ring in the above-mentioned formulae (2b) and (2c) by a hetero atom are exemplified. More specifically, C₄ to C₂₀ heterocyclic rings optionally having a substituent are exemplified.

Of them, C₄ to C₂₀ cycloalkyl rings and C₄ to C₂₀ cycloalkenyl rings optionally having a substituent and C₄ to C₂₀ heterocyclic rings optionally having a substituent are more preferable from the standpoint of the fluorescent intensity of the resulting compound in film condition and controllability of emitted color in a visible range from blue to red.

These rings may be substituted by an alkyl group, alkoxy group, alkylthio group, halogen atom and the like. Here, the alkyl group includes a methyl group, ethyl group, propyl group, i-propyl group, butyl group, i-butyl group, t-butyl group, pentyl group, isoamyl group, hexyl group, cyclohexyl group, heptyl group, octyl group, 2-ethylhexyl group, nonyl group, decyl group, 3,7-dimethyloctyl group, lauryl group, trifluoromethyl group, pentafluoroethyl group, perfluorobutyl group, perfluorohexyl group, perfluorooctyl group and the like. The alkoxy group includes a methoxy group, ethoxy group, propyloxy group, i-propyloxy group, butoxy group, i-butoxy group, t-butoxy group, pentyloxy group, hexyloxy group, cyclohexyloxy group, heptyloxy group, octyloxy group, 2-ethylhexyloxy group, nonyloxy group, decyloxy group, 3,7-dimethyloctyloxy group, lauryloxy group, trifluoromethoxy group, pentafluoroethoxy group, perfluorobutoxy group, perfluorohexyl group, perfluorooctyl group, methoxymethyloxy group, 2-methoxyethyloxy group and the like. The alkylthio group includes a methylthio group, ethylthio group, propylthio group, i-propylthio group, butylthio group, i-butylthio group, t-butylthio group, pentylthio group, hexylthio group, cyclohexylthio group, heptylthio group, octylthio group, 2-ethylhexylthio group, nonylthio group, decylthio group, 3,7-dimethyloctylthio group, laurylthio group, trifluoromethylthio group and the like. The halogen atom includes a fluorine atom, chlorine atom, bromine atom and iodine atom.

As the cycloalkyl ring, exemplified are cyclobutane, cyclopentane, cyclohexane, cycloheptane, cyclooctane, cyclononane, cyclodecane, cycloundecane, cyclododecane, cyclotridecane, cyclotetradecane, cyclopentadecane, cyclohexadecane, cycloheptadecane, cyclooctadecane, cyclononadecane, cyclopentadecane, cycloicosane, bicycle ring, adamantly ring and the like.

The cycloalkenyl ring includes also those having two double bonds, and specific examples thereof include a cyclohexene ring, cyclohexadiene ring, cycloheptene ring, cyclohexadecene ring, cyclooctatriene ring and the like.

Exemplified as the heterocyclic ring are a tetrahydrofuran ring, tetrahydrothiophene ring, tetrahydroindole ring, tetrahydropyrane ring, hexahydropyridine ring, tetrahydrothiopyrane ring, oxocane ring, tetrahydroquinoline ring, tetrahydroisoquinoline ring, crown ethers and the like.

It is advantageous that R_{w} and Rₓ form a ring having a total number of carbon or other elements of 5 to 20 from the standpoint of fluorescent intensity and light emitting efficiency of an element.

Specific examples of the repeating unit of the formula (1) include the following units (1A-1 to 1A-64, 1B-1 to 1B-64, 1C-1 to 1C-64, 1D-1 to 1D-18), and these units having a substituent such as an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group and cyano group and the like.

In the following formulae, a connecting bond on an aromatic hydrocarbon ring can exist at any position.

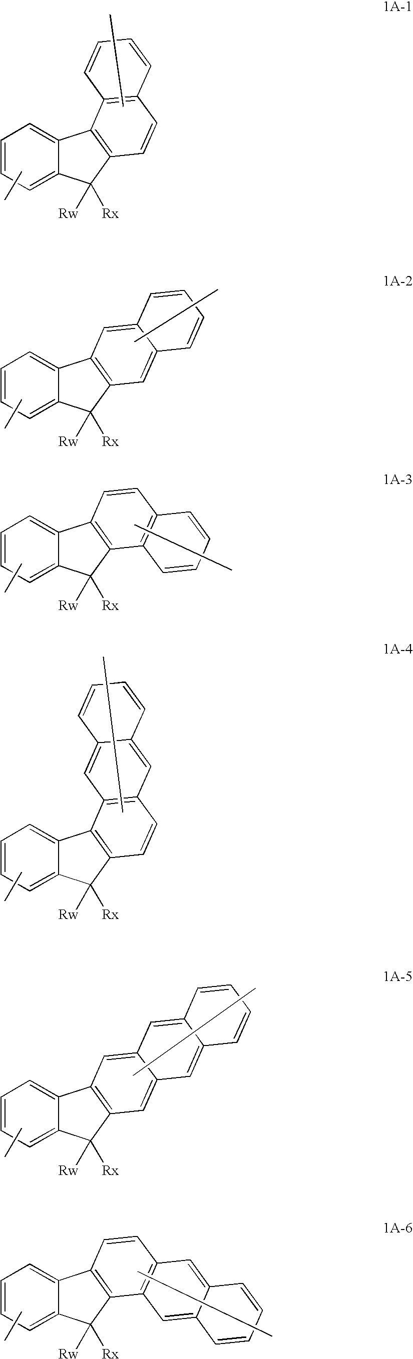

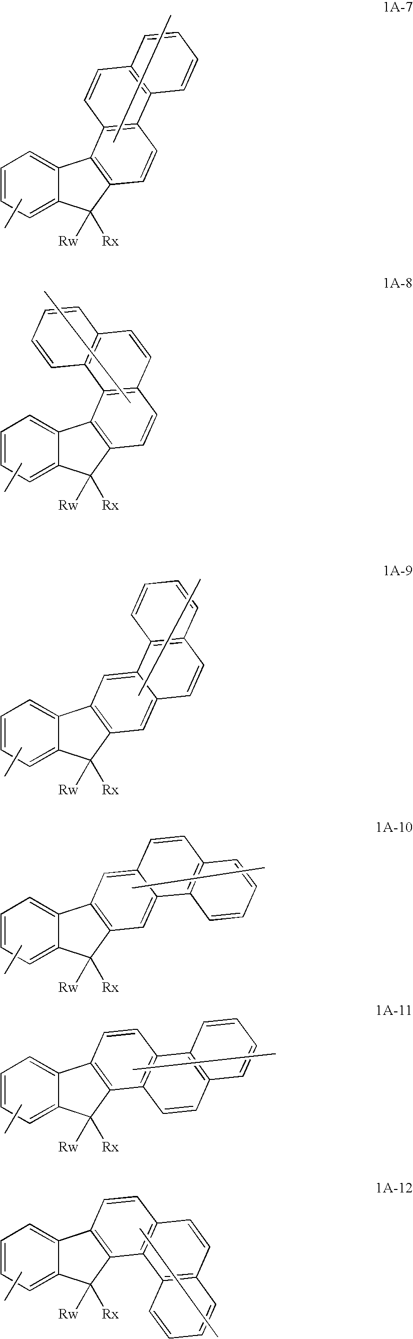

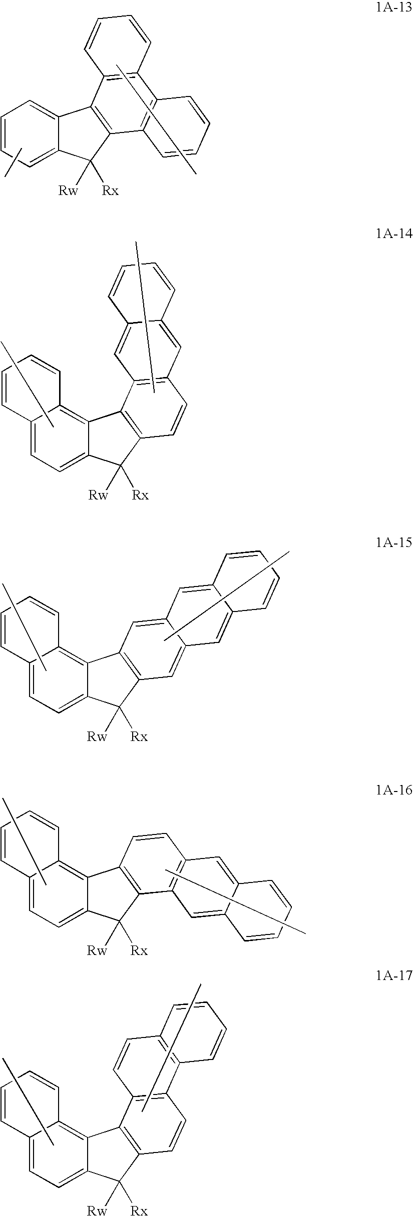

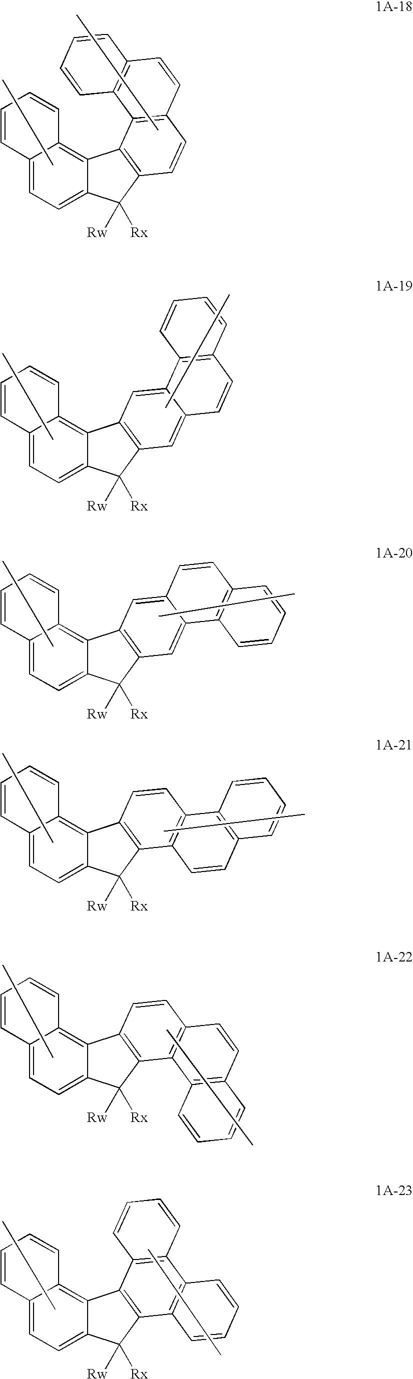

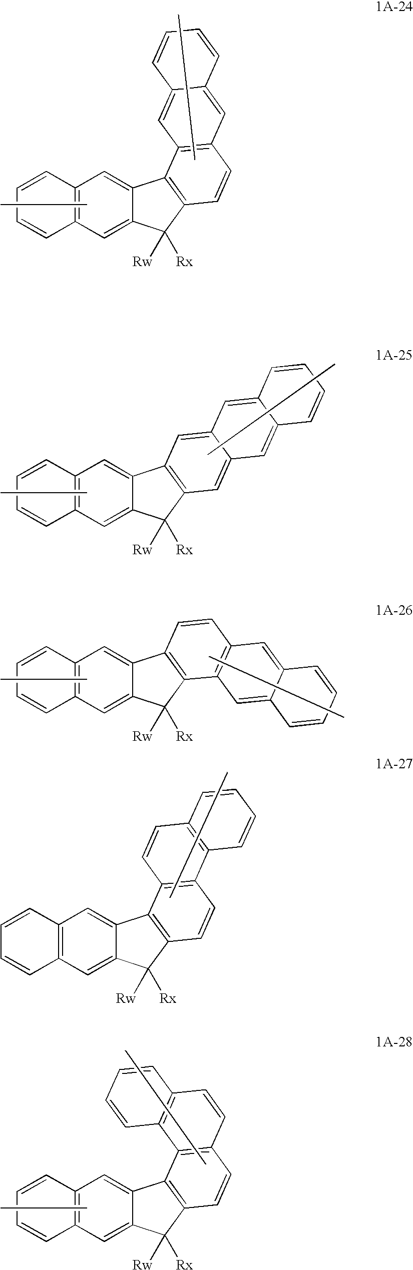

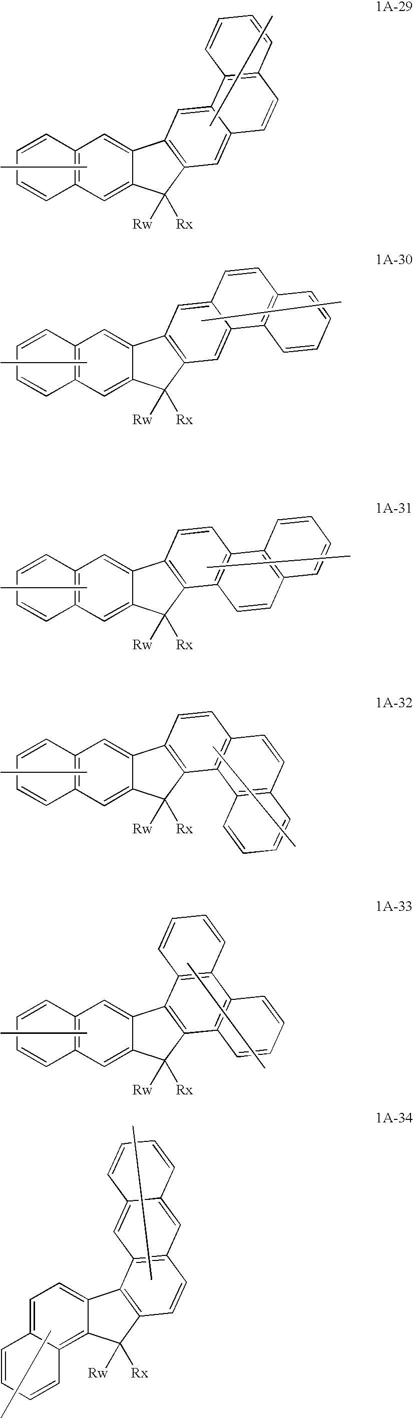

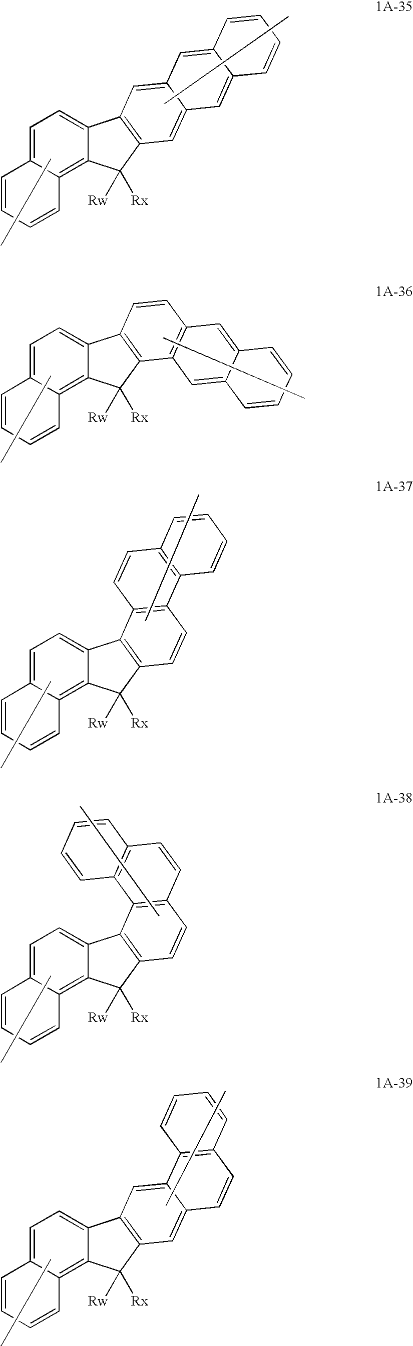

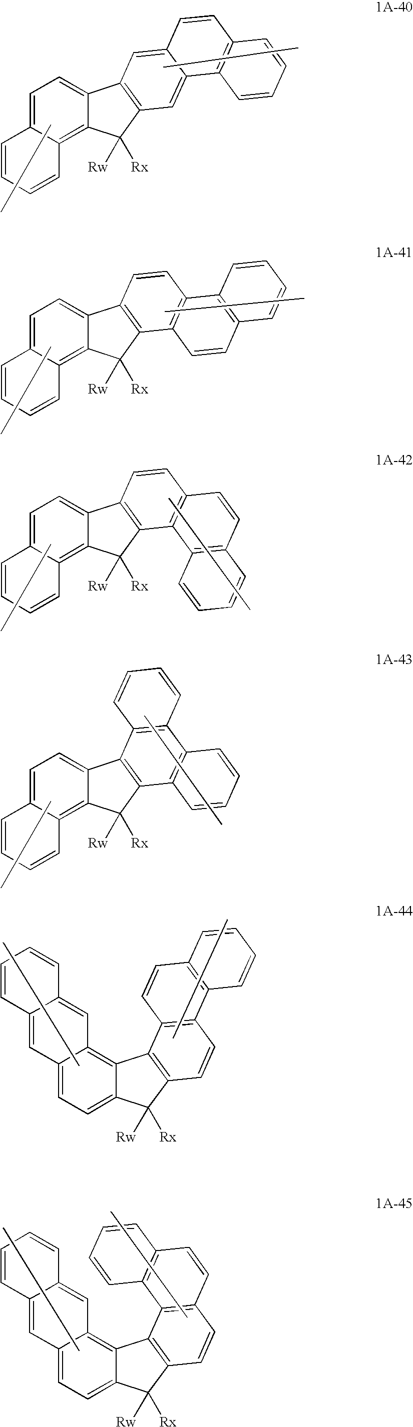

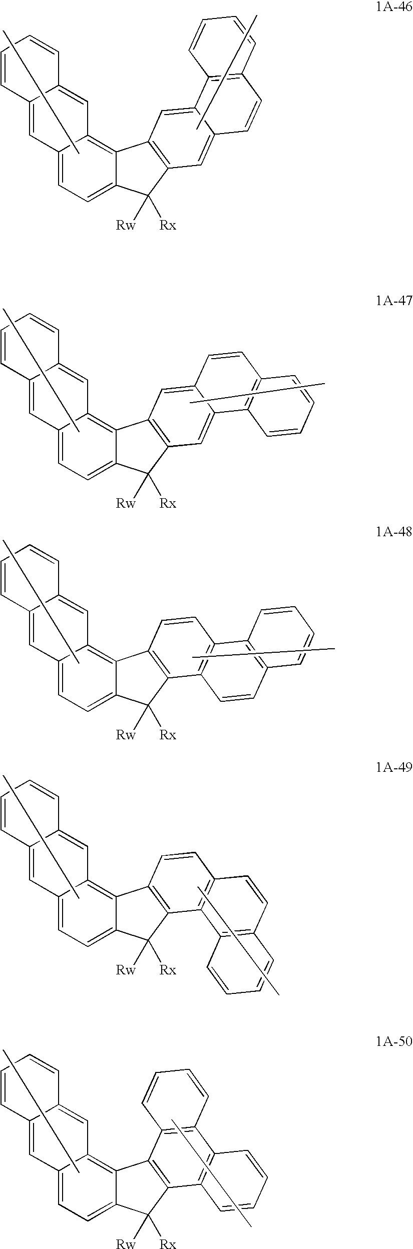

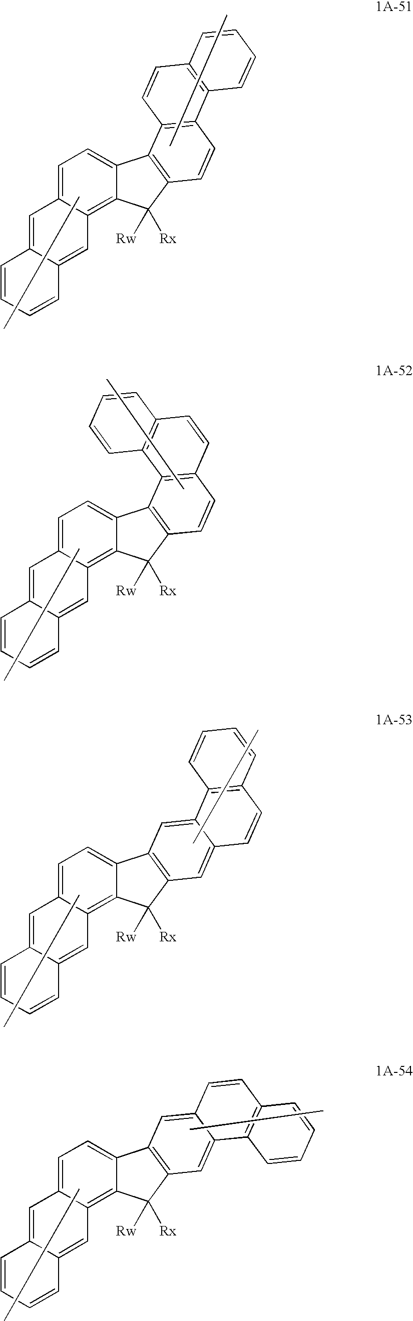

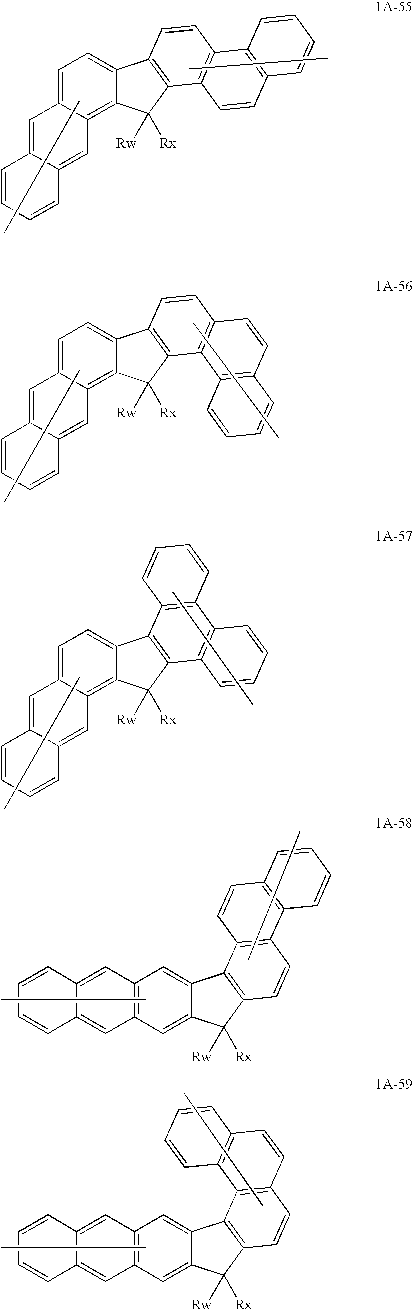

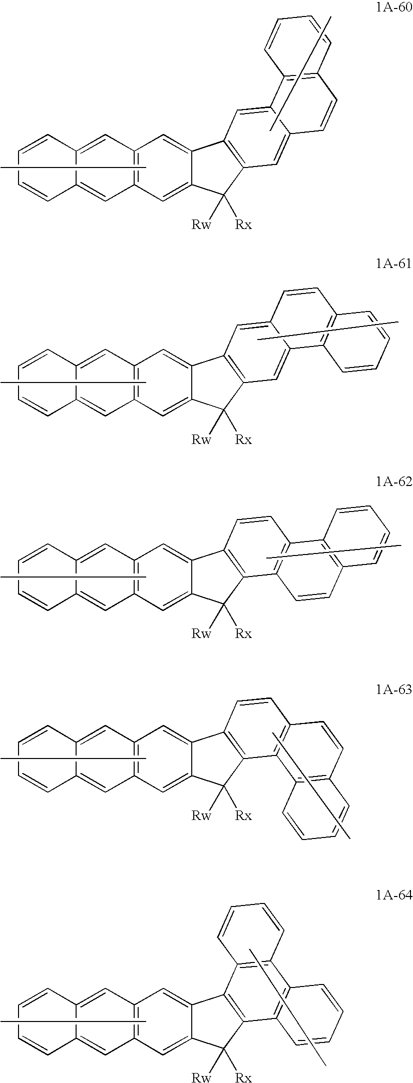

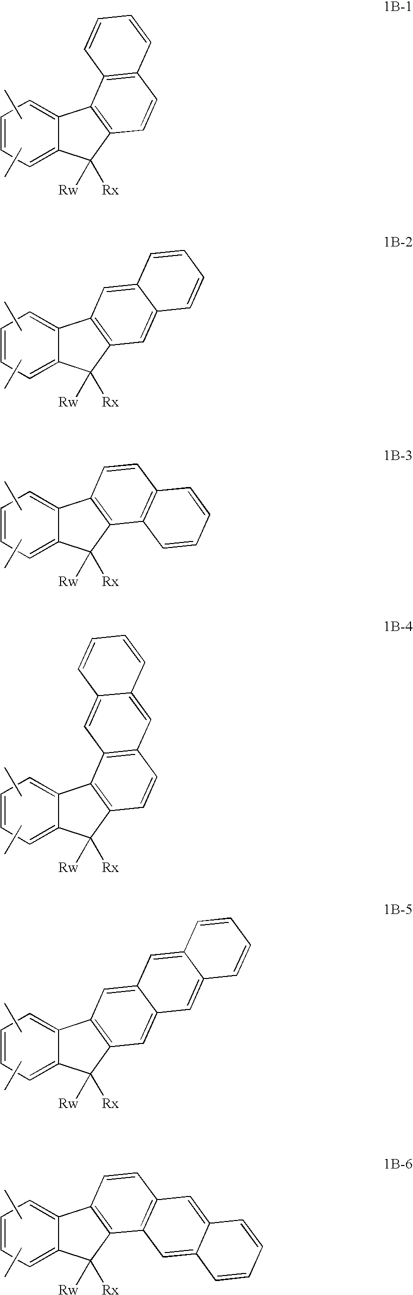

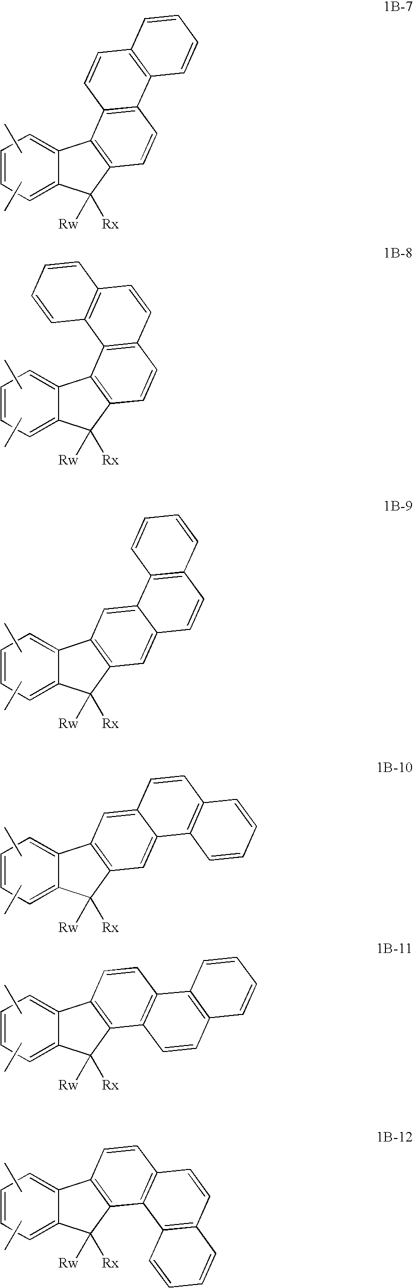

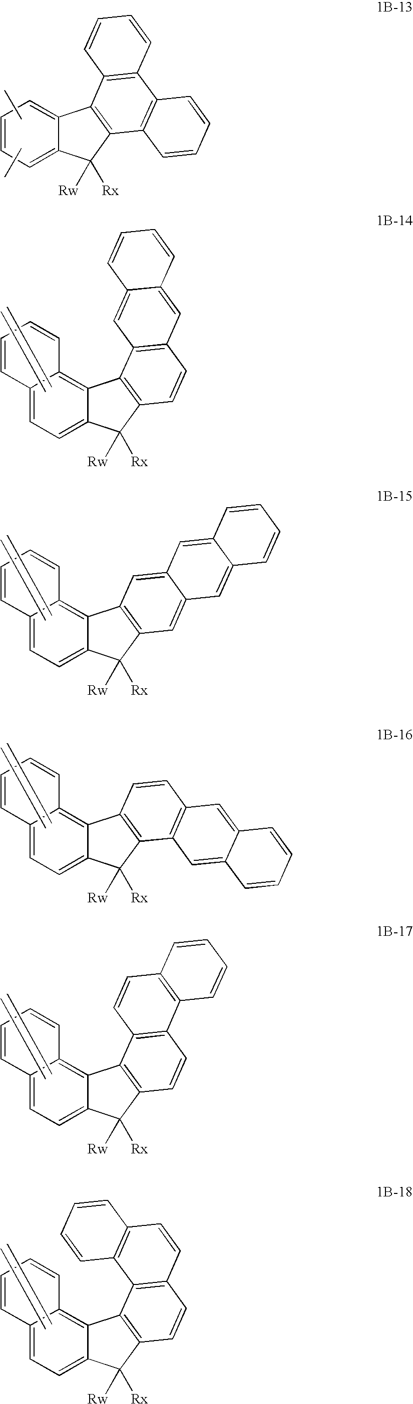

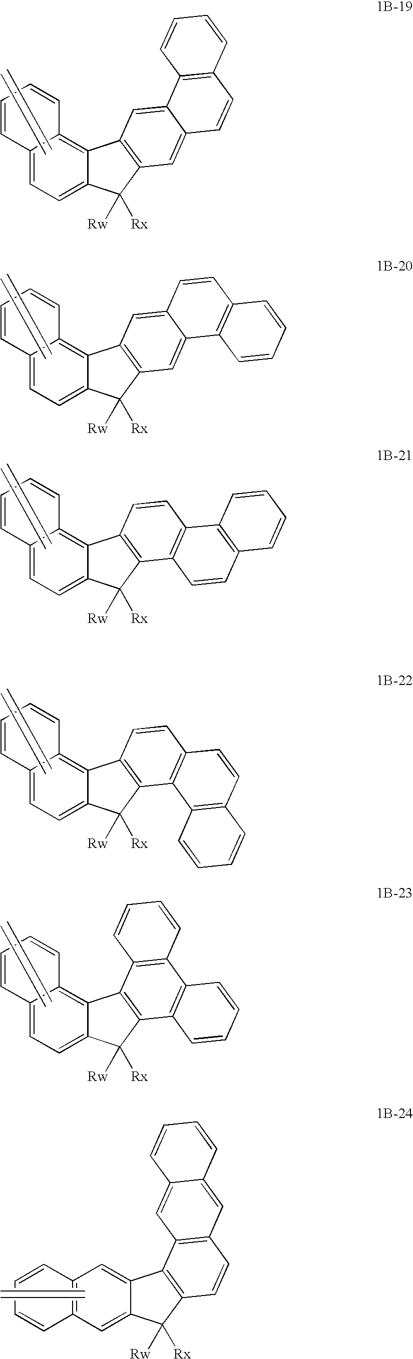

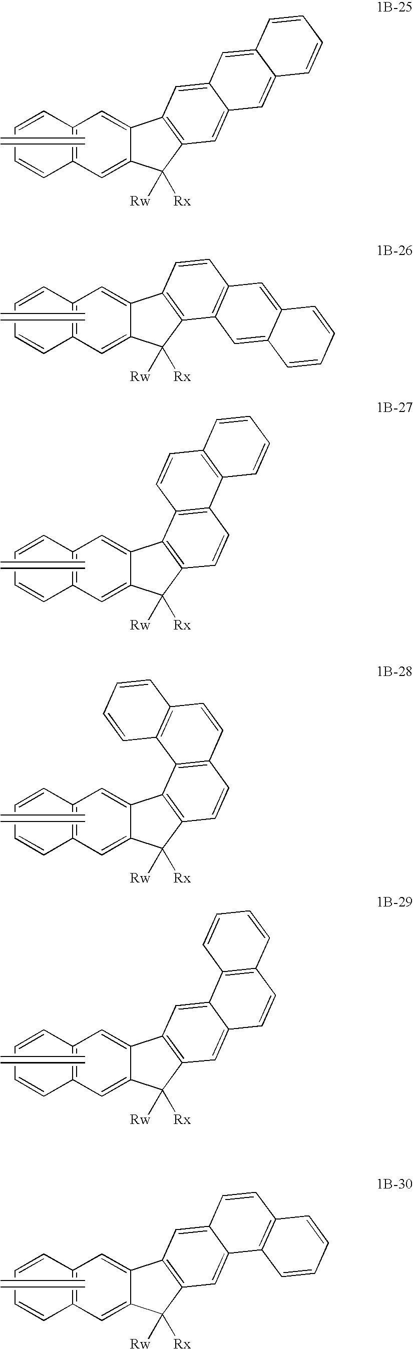

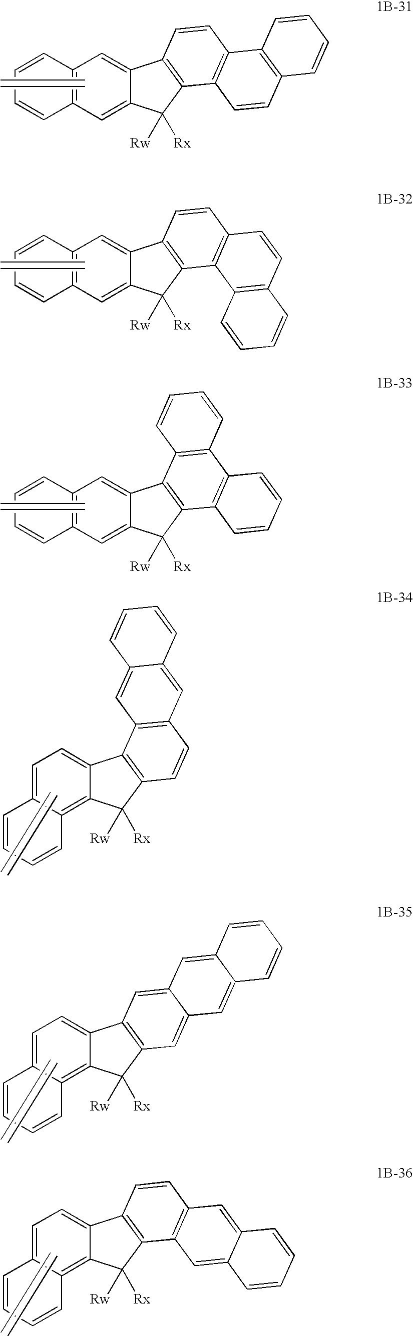

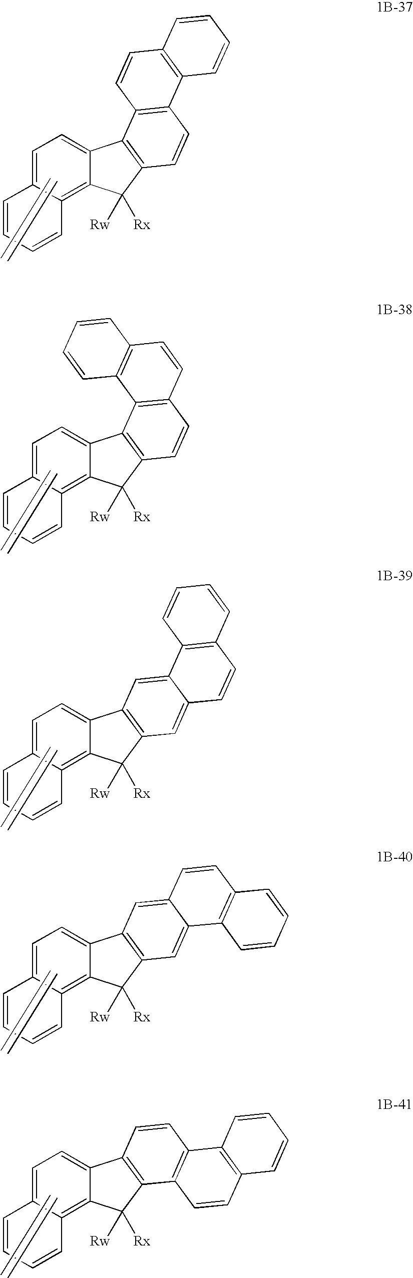

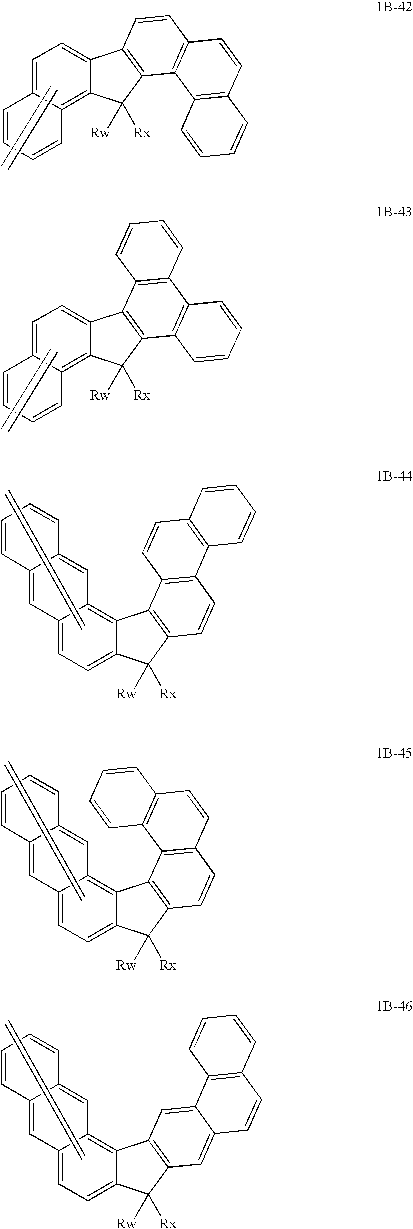

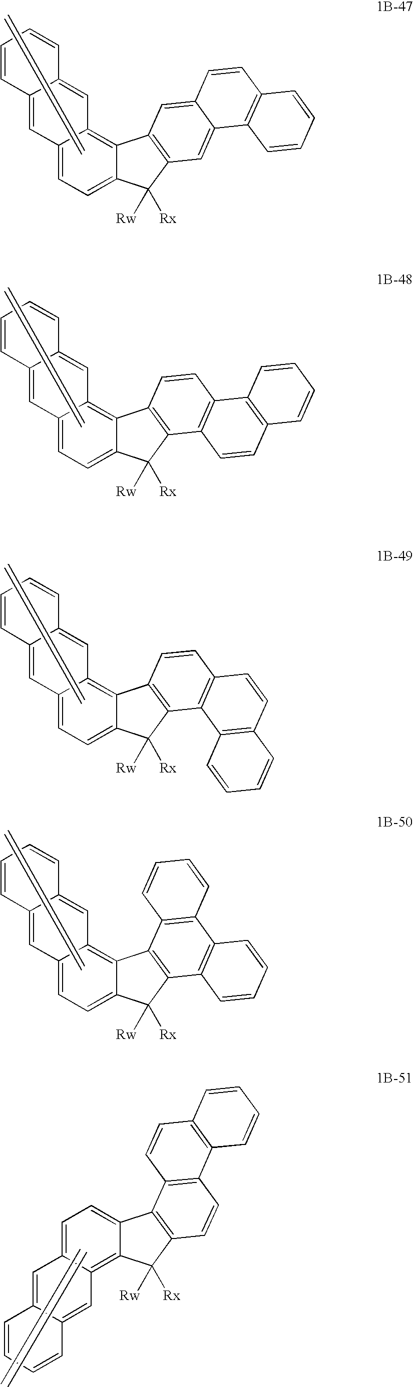

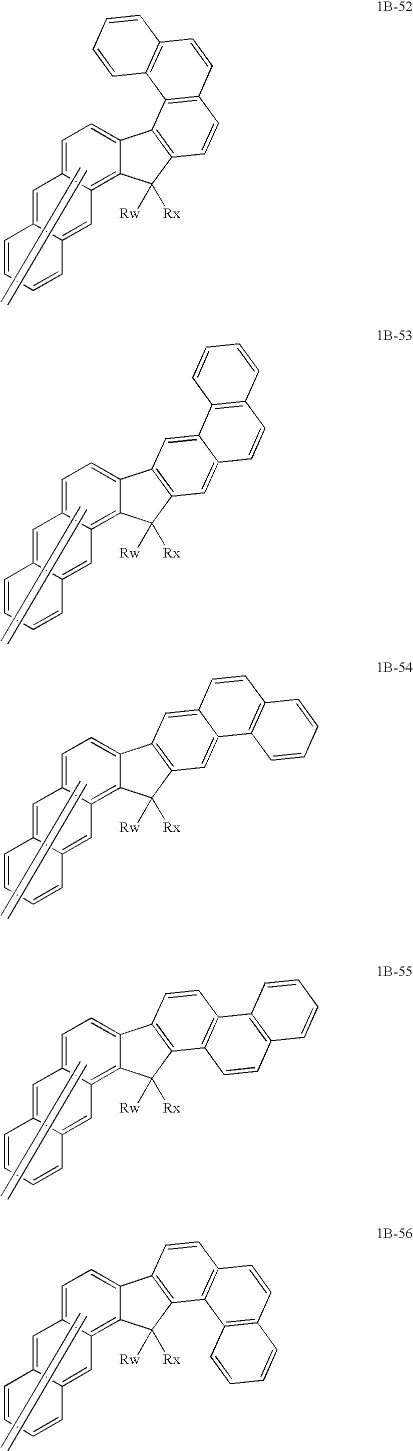

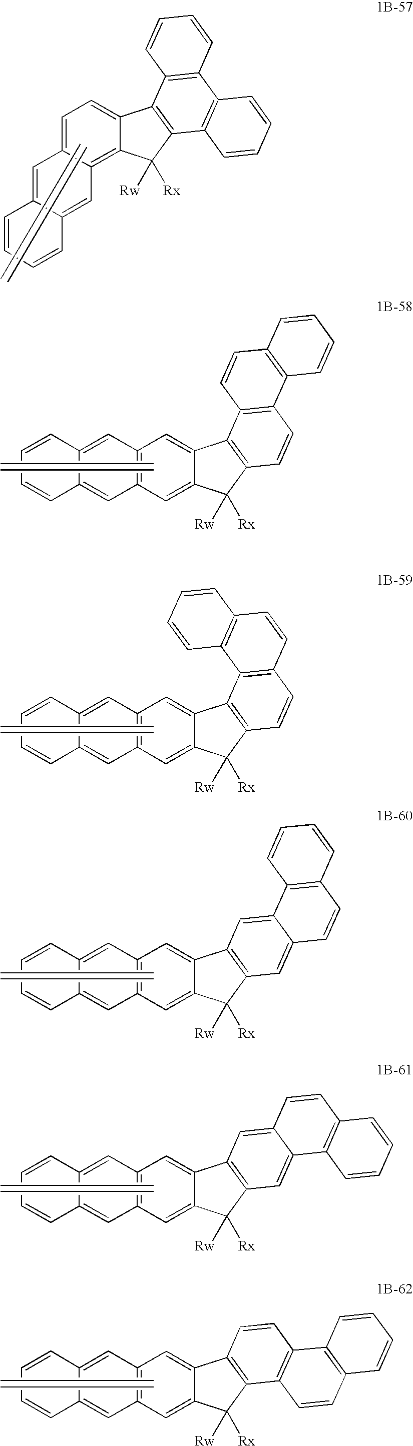

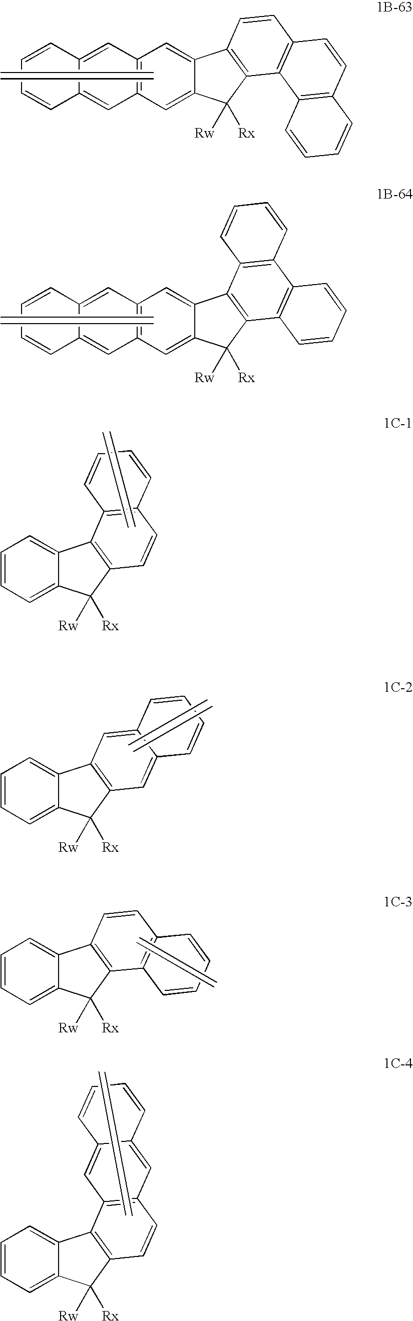

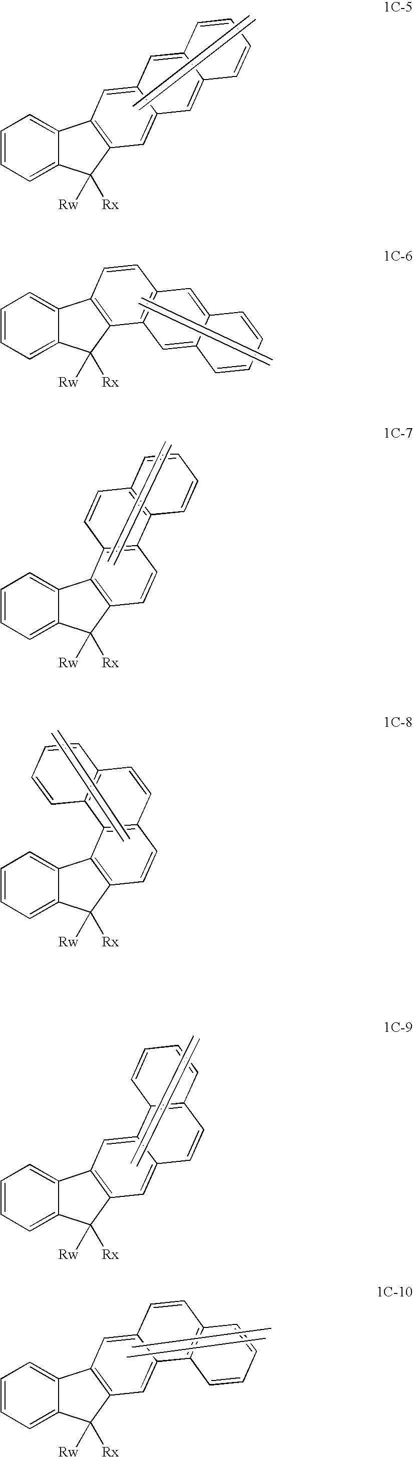

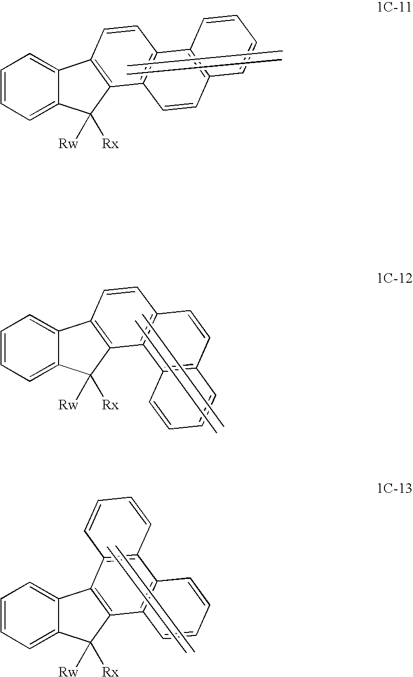

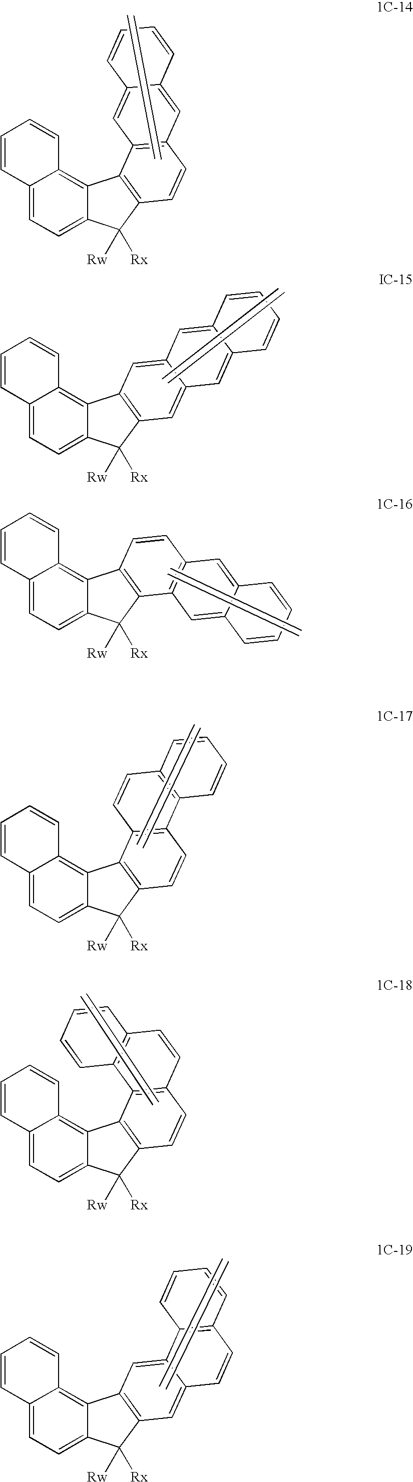

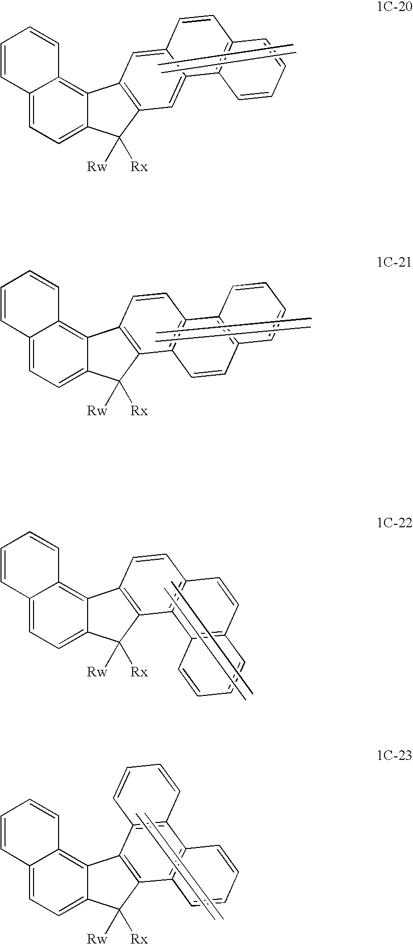

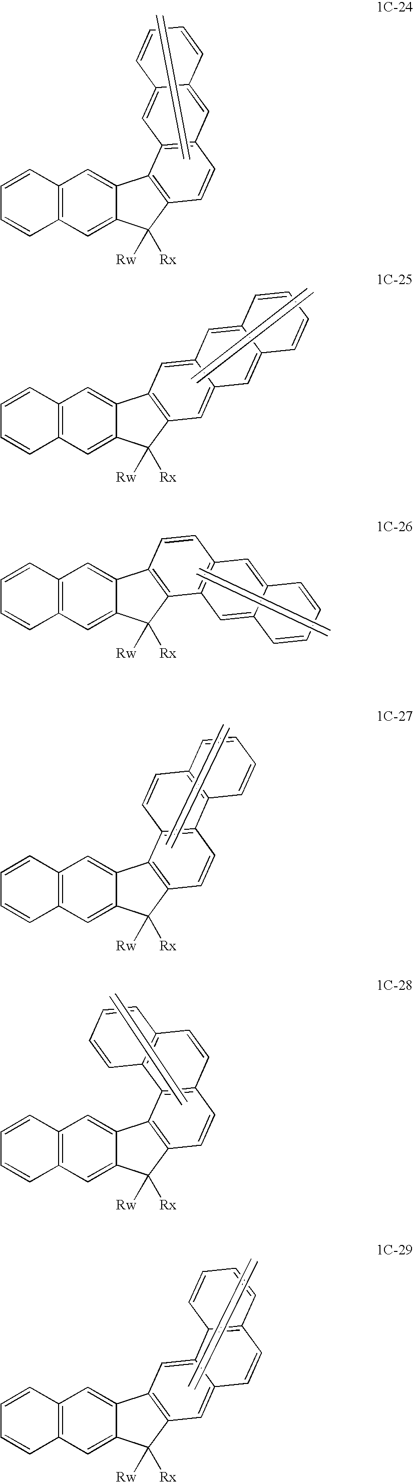

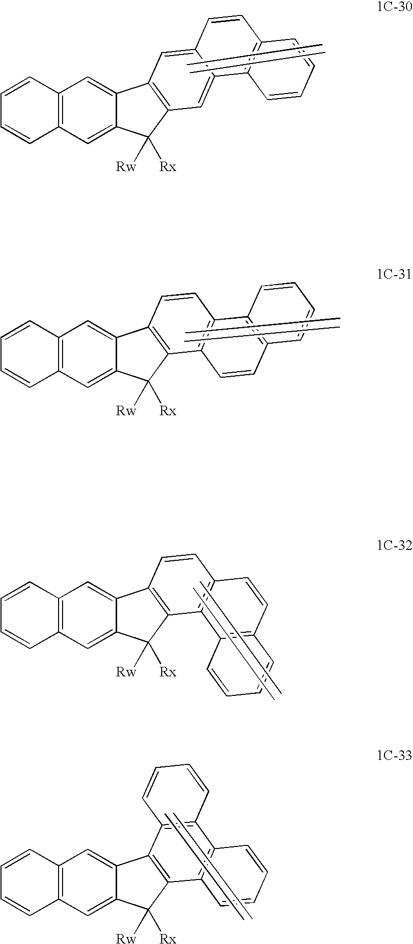

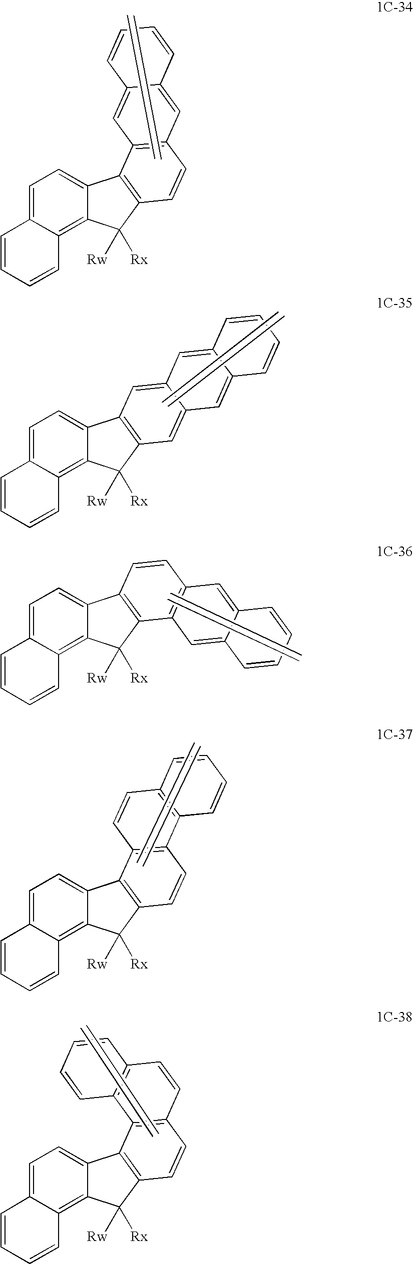

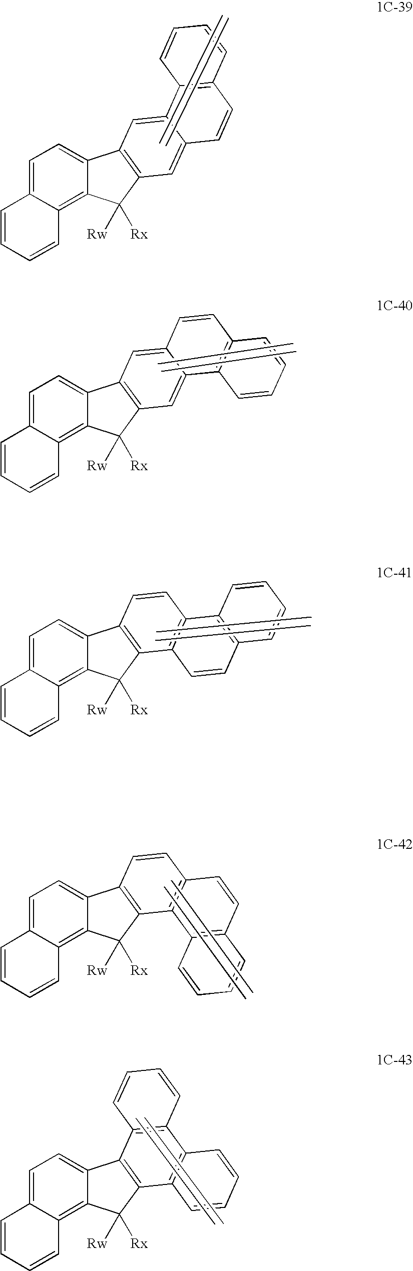

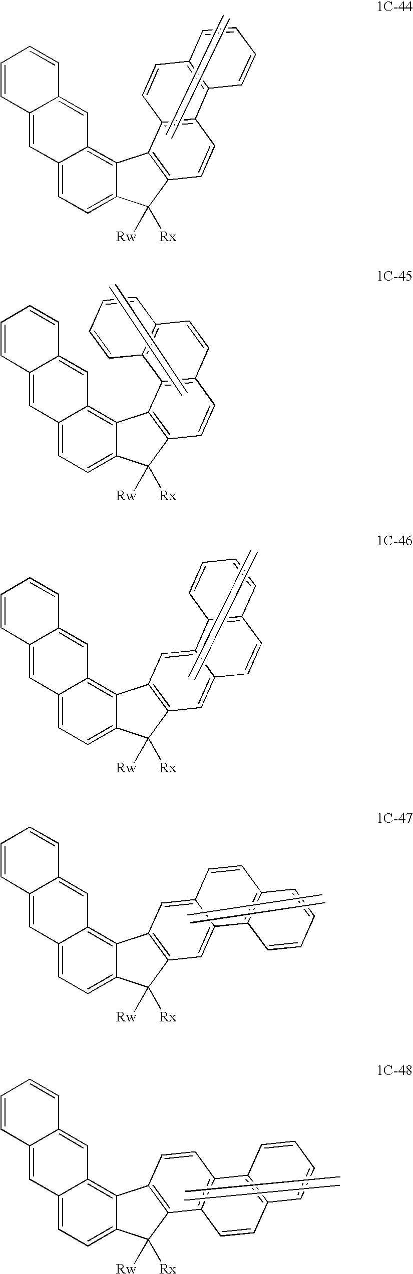

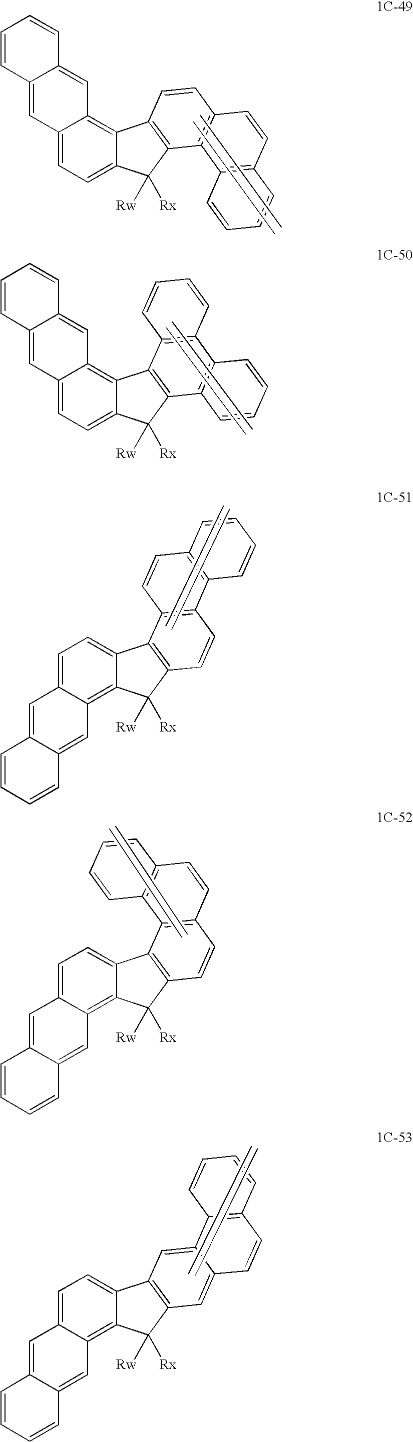

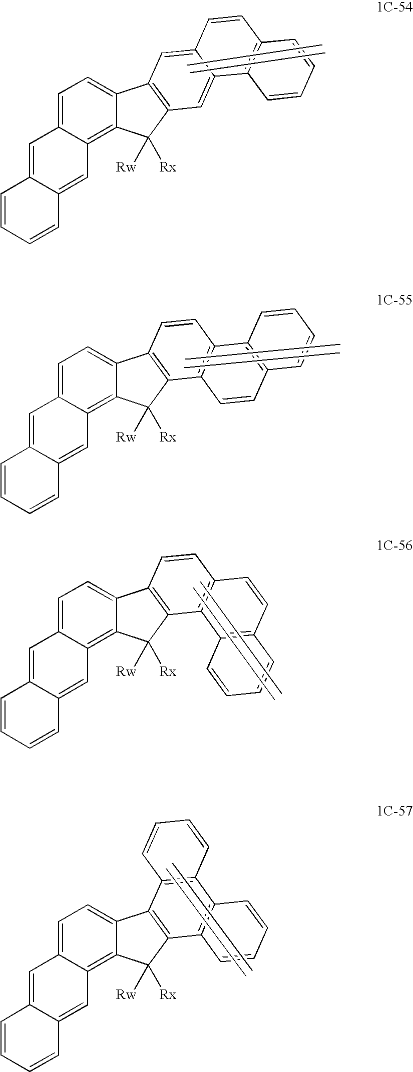

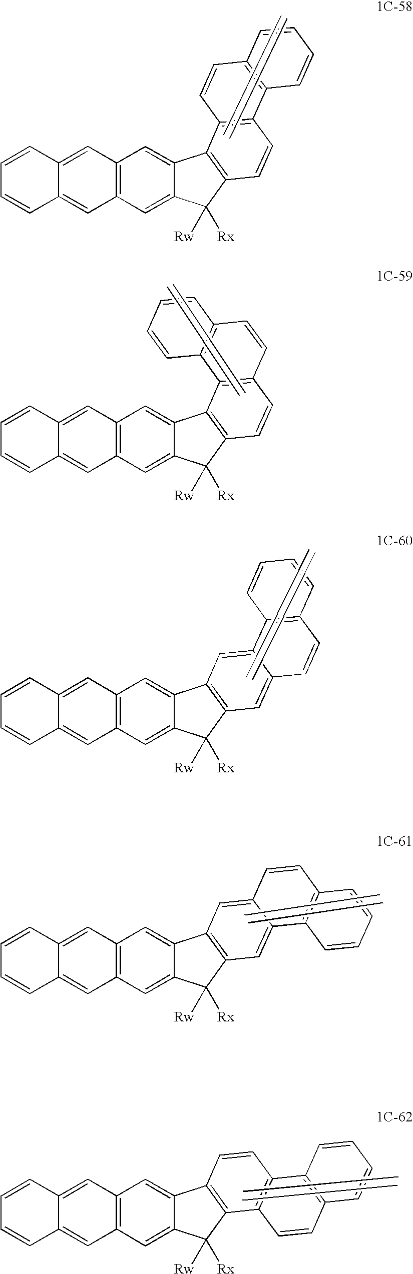

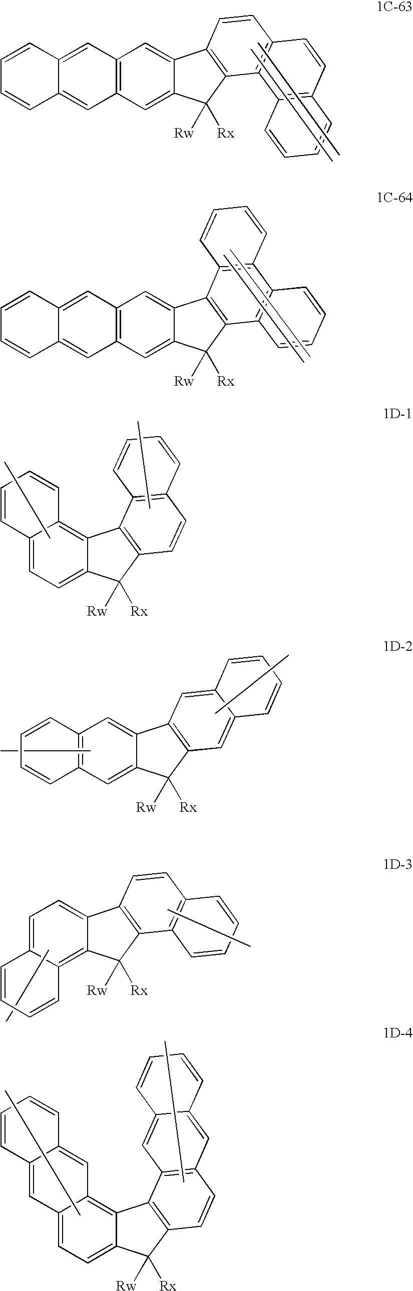

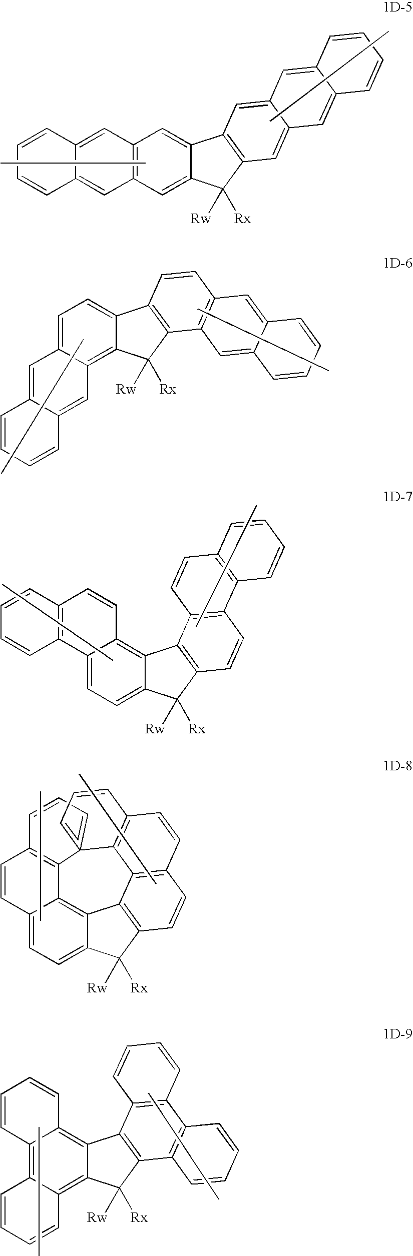

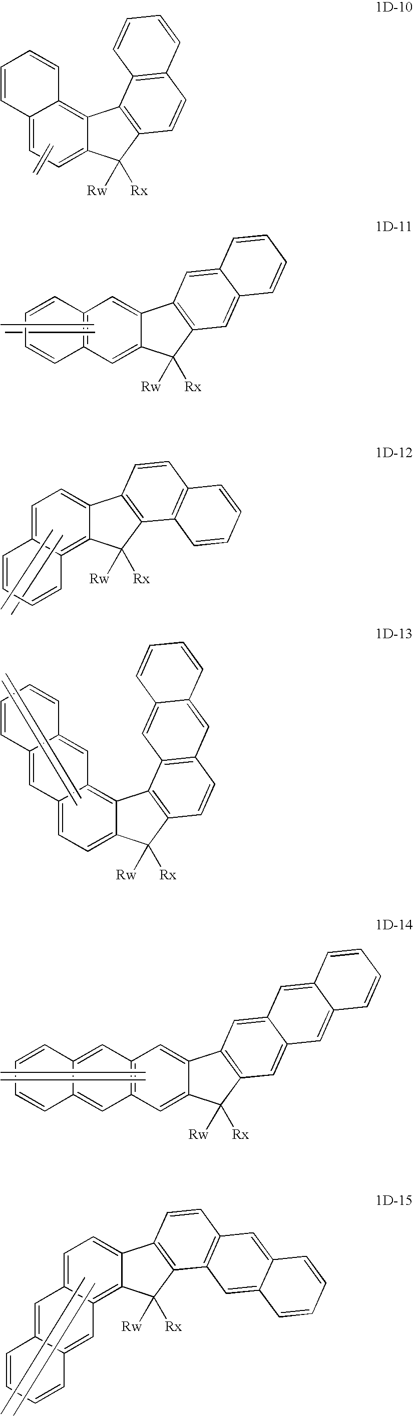

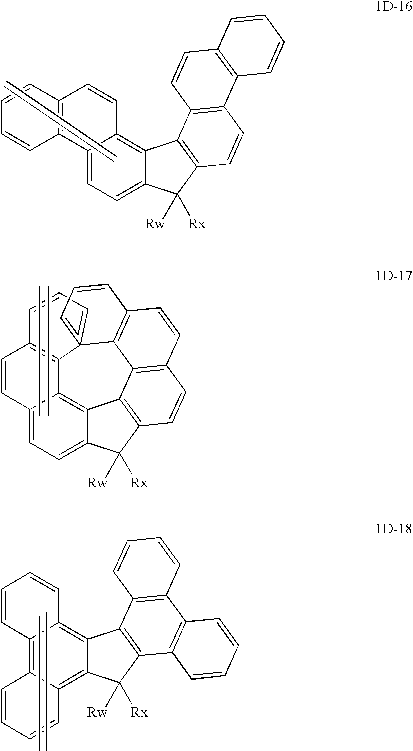

(wherein, R_{w} and Rₓ represent the same meanings as described above).

In the repeating unit of the above-mentioned formula (1), it is preferable, from the standpoint of heat resistance, fluorescent intensity and the like, that one connecting bond is present on ring A and one connecting bond is present on ring B, and it is more preferable that ring A and ring B are each composed of a combination of a benzene ring and a naphthalene ring.

Of them, repeating units of the following formulae (1-1) and (1-2) and repeating units of the following formulae (1-3) and (1-4) are preferable.

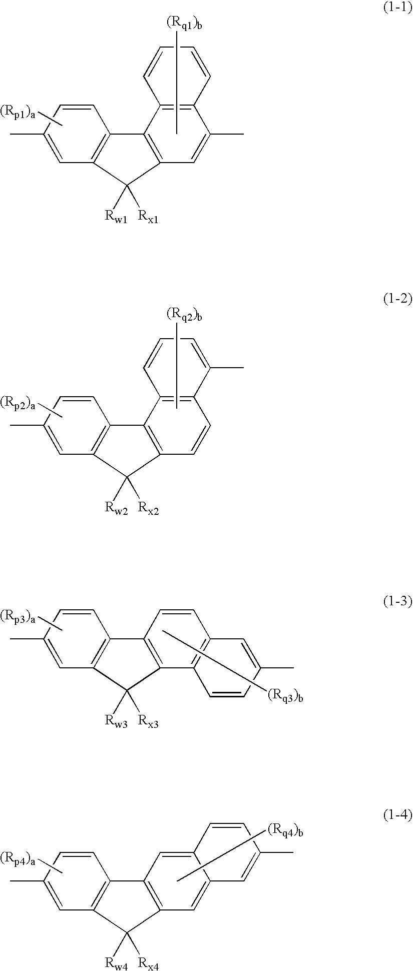

(wherein, Rₚ₁, R_{q1}, Rₚ₂, R_{q2}, Rₚ₃, R_{q3}, Rₚ₄ and R_{q4} represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group. a represents an integer of 0 to 3, and b represents an integer of 0 to 5. When a plurality of Rₚ₁s, R_{q1}s, Rₚ₂s, R_{q2}s, Rₚ₃s, R_{q3}s, Rₚ₄s and R_{q4}s are present, these may be the same or different. R_{w1}, Rₓ₁, R_{w2}, Rₓ₂, R_{w3}, Rₓ₃, R_{w4} and Rₓ₄ represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, and R_{w1} and Rₓ₁, R_{w2} and Rₓ₂, R_{w3} and Rₓ₃, R_{w4} and Rₓ₄ may mutually bond to form a ring).

In the above-mentioned formulae (1-1), (1-2), (1-3) and (1-4), it is preferable, from the standpoint of solubility in an organic solvent, element property, easiness of synthesis and the like, that Rₚ₁, R_{q1}, Rₚ₂, R_{q2}, Rₚ₃, R_{q3}, Rₚ₄ and R_{q4} represent an alkyl group, alkoxy group, alkylthio group, aryl group, aryloxy group, arylthio group, arylalkyl group, arylalkoxy group, arylalkylthio group, substituted amino group, substituted silyl group, fluorine atom, acyl group, acyloxy group, amide group, acid imide group, mono-valent heterocyclic group, carboxyl group, substituted carboxyl group or cyano group, and more preferably, an alkyl group, alkoxy group, aryl group, aryloxy group, arylalkyl group, arylalkoxy group, arylalkylthio group.

In the above-mentioned formulae (1-1), (1-2), (1-3) and (1-4), it is preferable, from the standpoint of solubility in an organic solvent, element property, easiness of synthesis and the like, that R_{w1}, Rₓ₁, R_{w2}, Rₓ₂, R_{w3}, Rₓ₃, R_{w4} and Rₓ₄ represent an alkyl group, alkoxy group, alkylthio group, aryl group, aryloxy group, arylthio group, arylalkyl group, arylalkoxy group, arylalkylthio group, substituted amino group, substituted silyl group, fluorine atom, acyl group, acyloxy group, amide group, acid imide group, mono-valent heterocyclic group, carboxyl group, substituted carboxyl group or cyano group, and more preferably, an alkyl group, alkoxy group, aryl group, aryloxy group, arylalkyl group, arylalkoxy group, arylalkylthio group, further preferably, an alkyl group, alkoxy group, aryl group.

As the alkyl group, alkoxy group and aryl group, more specifically exemplified are straight chain, branched or cyclic alkyl groups having a number of carbon atom of usually about 1 to 20 such as a methyl group, ethyl group, propyl group, i-propyl group, butyl group, i-butyl group, t-butyl group, pentyl group, isoamyl group, hexyl group, cyclohexyl group, heptyl group, cyclohexylmethyl group, octyl group, 2-ethylhexyl group, nonyl group, decyl group, 3,7-dimethyloctyl group, lauryl group, trifluoromethyl group, pentafluoroethyl group, perfluorobutyl group, perfluorohexyl group, perfluorooctyl group and the like; alkoxy groups having a number of carbon atom of usually about 1 to 20 such as a methoxy group, ethoxy group, propyloxy group, i-propyloxy group, butoxy group, i-butoxy group, t-butoxy group, pentyloxy group, hexyloxy group, cyclohexyloxy group, heptyloxy group, cyclohexylmethyloxy group, octyloxy group, 2-ethylhexyloxy group, nonyloxy group, decyloxy group, 3,7-dimethyloctyloxy group, lauryloxy group, trifluoromethoxy group, pentafluoroethoxy group, perfluorobutoxy group, perfluorohexyl group, perfluorooctyl group, methoxymethyloxy group, 2-methoxyethyloxy group and the like; and aryl groups having a number of carbon atom of usually about 6 to 60 such as a phenyl group, C₁ to C₁₂ alkoxyphenyl groups, C₁ to C₁₂ alkylphenyl groups, 1-naphtyl group, 2-naphtyl group, 1-anthracenyl group, 2-anthracenyl group, 9-anthracenyl group, pentafluorophenyl group and the like.

Here, specific examples of C₁ to C₁₂ alkoxy include methoxy, ethoxy, propyloxy, i-propyloxy, butoxy, i-butoxy, t-butoxy, pentyloxy, hexyloxy, cyclohexyloxy, heptyloxy, octyloxy, 2-ethylhexyloxy, nonyloxy, decyloxy, 3,7-dimethyloctyloxy, lauryloxy group and the like, and specific examples of C₁ to C₁₂ alkylphenyl groups include a methylphenyl group, ethylphenyl group, dimethylphenyl group, propylphenyl group, mesityl group, methylethylphenyl group, i-propylphenyl group, butylphenyl group, i-butylphenyl group, t-butylphenyl group, pentylphenyl group, isoamylphenyl group, hexylphenyl group, heptylphenyl group, octylphenyl group, nonylphenyl group, decylphenyl group, dodecylphenyl group and the like.

Specific examples of the repeating units of the above-mentioned formulae (1-1), (1-2), (1-3) and (1-4) include the following formula groups (1-1-2), (1-2-2), (1-3-2) and (1-4-2) in the case of mutual bonding of R_{w1} and Rₓ₁, R_{w2} and Rₓ₂, R_{w3} and Rₓ₃, R_{w4} and Rₓ₄ to form a ring. These structures may further have a substituent.

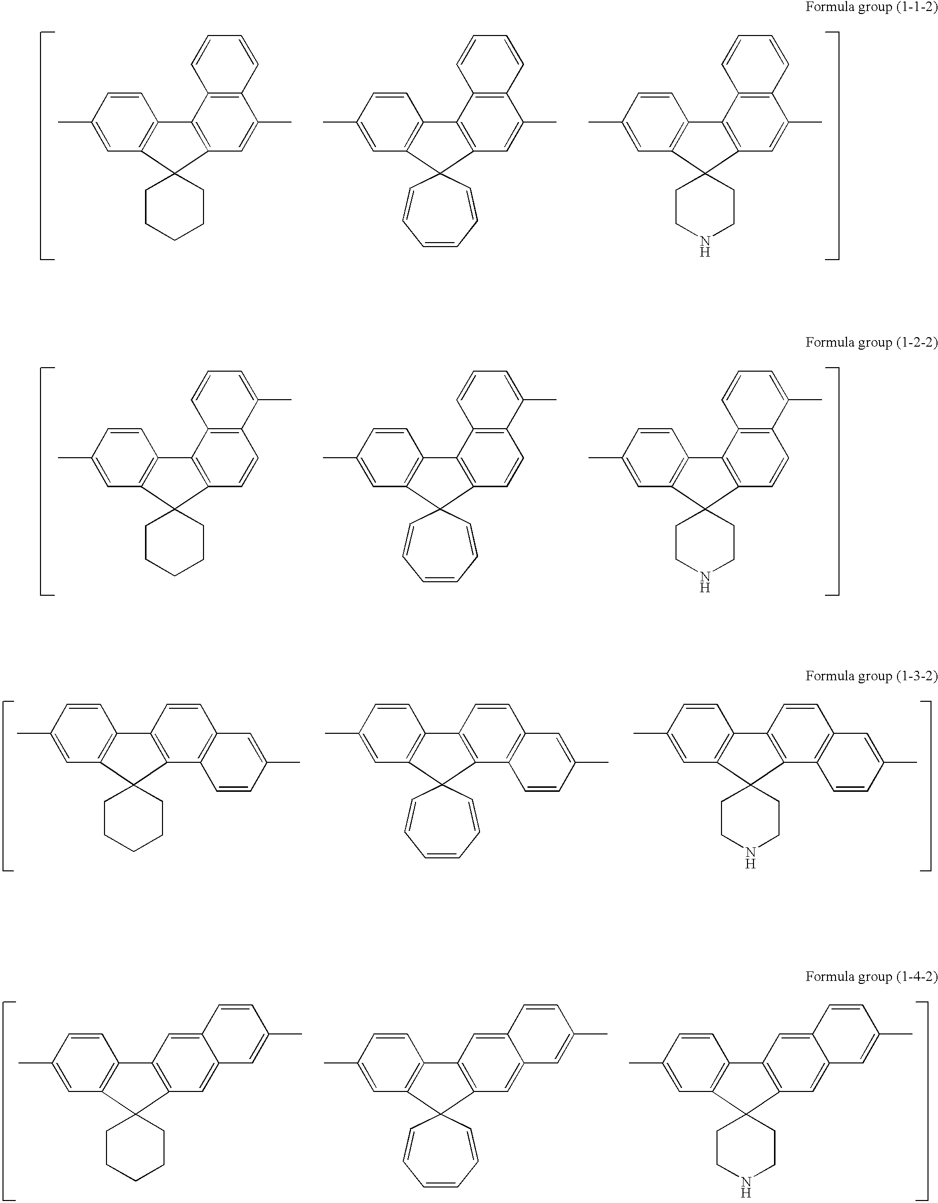

In the above-mentioned formulae (1-1) and (1-2), it is preferable, from the standpoint of increase of molecular weight and from the standpoint of improvement of heat resistance, that a=b=0.

Among the polymer compounds of the present invention, those containing a repeating unit of the formulae (1-1), (1-3) and (1-4) are preferable, and those of the formula (1-1) are further preferable, from the standpoint of easiness of synthesis of a raw material compound.

For balance between heat resistance and a standpoint of improving solubility of a synthesized polymer compound in an organic solvent, preferable as R_{w1} and Rₓ₁ are alkyl groups, and those having a number of carbon atom of 3 or more are further preferable, those of 7 or more are more preferable, those of 8 or more are further preferable. Most preferable is an n-octyl group, and a structure of the following formula (16) is mentioned.

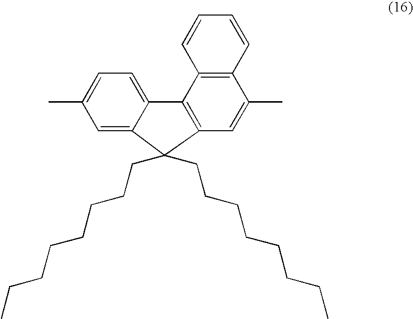

As the polymer compound of the present invention, there are mentioned polymer compounds characterized in that a structure obtained by condensing a naphthalene ring to an indene ring is present as a repeating unit in which the naphthalene ring and a 5-membered ring of the indene ring have two carbon atoms as a common atom and the number-average molecular weight in terms of polystyrene is 10³ to 10⁸. The phrase “the naphthalene ring and a 5-membered ring of the indene ring have two carbon atoms as a common atom” means, in other words, a phrase “the naphthalene ring and a 5-membered ring of the indene ring share adjacent two carbon atoms of the 5-membered ring”.

The sum of the amounts of repeating units (1) in the polymer compound of the present invention is usually 1 mol % or more and 100 mol % or less based on the sum of all repeating units in the polymer compound of the present invention, and preferably 20 mol % or more, further preferably 30 mol % or more and 100 mol % or less.

Among the polymer compounds of the present invention, mentioned as those having two repeating units of the formula (1) as a repeating unit are copolymers having two repeating units (referred to as repeating units (a) and (b)) in which ring structures excepting a substituent on the repeating unit are identical and any of the presence or absence of a substituent on an aromatic ring, kind of a substituent, and Rw and Rx are different. This copolymer is excellent in solubility in an organic solvent as compared with a homopolymer composed only of a repeating unit (a) and a homopolymer composed only of a repeating unit (b).

Specifically mentioned are a copolymer composed of two repeating units selected from the above-mentioned formula (1-1), a copolymer composed of two repeating units selected from the above-mentioned formula (1-2), a copolymer composed of two repeating units selected from the above-mentioned formula (1-3) and a copolymer composed of two repeating units selected from the above-mentioned formula (1-4).

Of them, preferable are copolymers in which no substituent is present on an aromatic ring, or substituents on an aromatic ring are identical and groups represented by Rw and/or Rx are different, from the standpoint of easiness of control of reactivity in producing a polymer compound.

One of properties desired for a polymer compound for polymer LED is electron injectability. Electron injectability is in general depend on a value of the lowest unoccupied molecular orbital (LUMO) of a polymer compound, and when the value of the absolute value of LUMO is higher, electron injectability is more excellent. It is preferable that the absolute value of LUMO is 2.5 eV or more, more preferably 2.7 eV or more, further preferably 2.8 eV or more.

For example, the reduction potential of a polymer compound is measured using a cyclic voltammetry (CV), and LUMO can be calculated from the reduction potential value. In the case of the polymer compound of the present invention, the reduction potential shows a negative value, when the reduction potential is higher (absolute value of reduction potential is smaller), the absolute value of LUMO is higher, and electron injectability is improved.

From the standpoint of electron injectability and from the standpoint of easiness of synthesis, it is preferable that repeating units R_{w1} and Rₓ₁, R_{w2} and Rₓ₂, R_{w3} and Rₓ₃, R_{w4} and Rₓ₄ of the above-mentioned formulae (1-1), (1-2), (1-3) and (1-4) are identical respectively, and it is more preferable that R_{w1}, Rₓ₁, R_{w2}, Rₓ₂, R_{w3}, Rₓ₃, R_{w4} and Rₓ₄ represent an aryl group or arylalkyl group. The definition and specific examples of the aryl group and arylalkyl group are the same as described above. As the aryl group, preferable are a phenyl group and phenyl groups carrying a substituted alkyl group from the standpoint of electron injectability, easiness of synthesis, solubility in an organic solvent, element property, and the like. Specifically mentioned are a phenyl group, 2-methylphenyl group, 3-methylphenyl group, 4-methylphenyl group, 2,6-dimethylphenyl group, 3,5-dimethylphenyl group, 2,4,6-trimethylphenyl group, 2-ethylphenyl group, 3-ethylphenyl group, 4-ethylphenyl group, 2,6-diethylphenyl group, 3,5-diethylphenyl group, 2-propylphenyl group, 3-propylphenyl group, 4-propylphenyl group, 2,6-dipropylphenyl group, 3,5-dipropylphenyl group, 2,4,6-tripropylphenyl group, 2-isopylphenyl group, 3-isopylphenyl group, 4-isopylphenyl group, 2,6-diisopylphenyl group, 3,5-diisopylphenyl group, 2,4,6-triisopylphenyl group, 2-butylphenyl group, 3-butylphenyl group, 4-butylphenyl group, 2,6-butylphenyl group, 3,5-butylphenyl group, 2,4,7-butylphenyl group, 2-t-butylphenyl group, 3-t-butylphenyl group, 4-t-butylphenyl group, 2,6-di-t-butylphenyl group, 3,5-di-t-butylphenyl group, 2,4,6-tri-t-butylphenyl group and the like, and preferable are structures of the following formula groups (1-1-3), (1-2-3), (1-3-3) and (1-4-3).

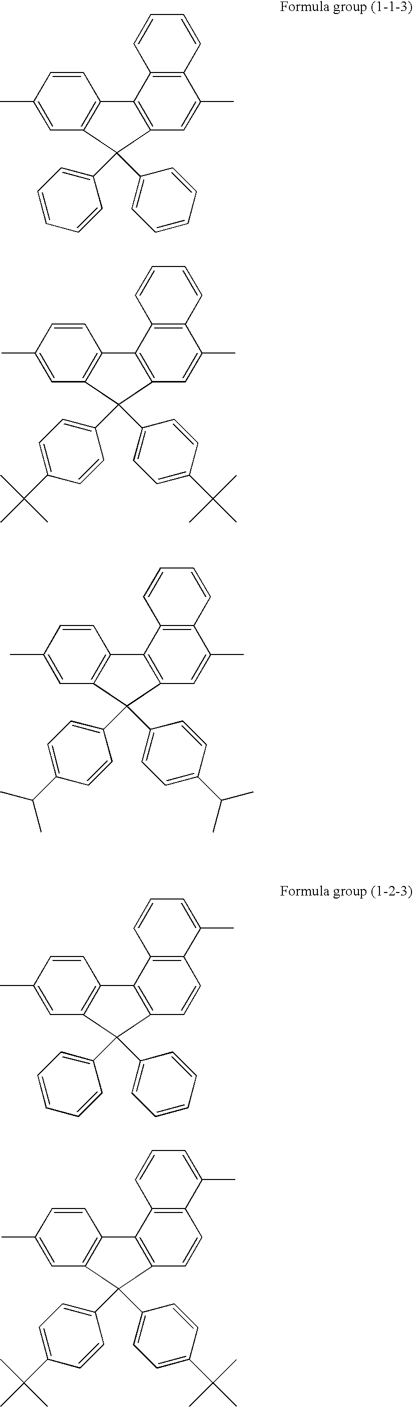

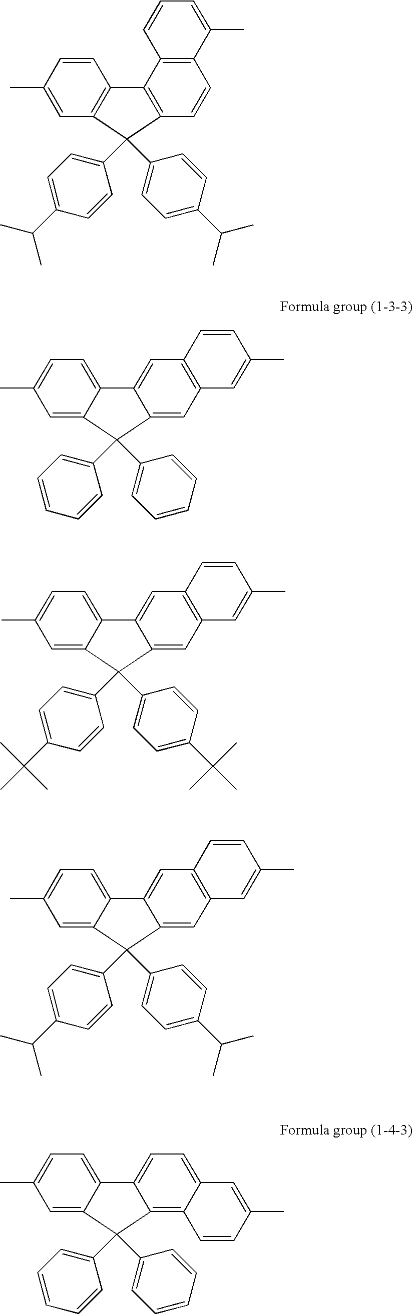

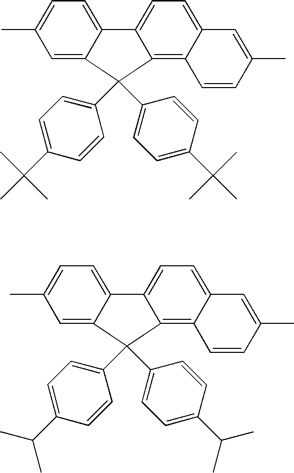

From the standpoint of solubility in an organic solvent and chemical stability, it is preferable that the repeating unit of the above-mentioned formula (1) has at least on substituent. Since a polymerization reaction is suppressed in some cases depending on the position of a substituent, it is preferable that substitution occurs at a position remote from a connecting bond by two or more aromatic carbons.

In the above-mentioned formulae (1-1), (1-2), (1-3) and (1-4), it is preferable, from the standpoint of balance of solubility in an organic solvent, chemical stability and smallness of an influence of suppressing a polymerization reaction, that a=0 and b=1. Structures of the following formula (1-1-14) or (1-1-5) are more preferable, and R_{q1} is more preferably an alkyl group.

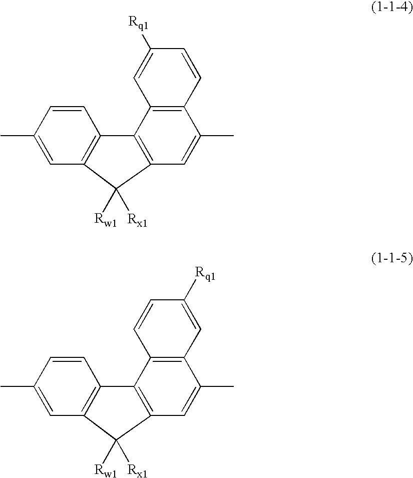

(wherein, R_{w1}, Rₓ₁ and R_{q1} have the same meanings as described above).

Here, the alkyl group R_{q1} has a number of carbon atom of usually 1 to 30, preferably 3 to 30. The alkyl group includes straight chain alkyl groups such as a methyl group, ethyl group, propyl group, butyl group, hexyl group, heptyl group, octyl group, nonyl group, decyl group, lauryl group, trifluoromethyl group, pentafluoroethyl group, perfluorobutyl group, perfluorohexyl group, perfluorooctyl group and the like, branched alkyl groups such as an i-propoyl group, i-butyl group, t-butyl group, pentyl group, isoamyl group, 2-ethylhexyl group, 3,7-dimethyloctyl group, 1,1-dimethylpropyl group and the like, alkyl groups having a cyclic structure such as 1-adamantyln group, 1-adamantylmethyl group, 2-adamantyln group, neopentyl group, cyclopentyl group, cyclopentylmethyl group, cyclohexyl group, cyclohexylmethyl group, cyclohexylethyl group, cyclooctyl group, cyclododecyl group, cyclopentadecyl group, cyclopentylmethyl group and the like.

Among alkyl groups, alkyl groups having a branched structure or cyclic structure are preferable, alkyl groups having a cyclic structure are more preferable, and a 1-adamantyl group or 2-adamantyl group is further preferable, from the standpoint of chemical stability.

As the polymer compound of the present invention, copolymers containing a repeating unit (1) contained in the polymer compound of the present invention and additionally, containing one or more other repeating units, are preferable from the standpoints of changing of emission wavelength, enhancement of emission efficiency, improvement of heat resistance and the like. As the repeating unit other than the repeating unit (1), repeating units of the following formulae (3), (4), (5) and (6) are preferable.

—Ar₁— (3)

Ar₂—X₁_{ff}Ar₃— (4)

—Ar₄—X₂— (5)

—X₃— (6)

In the formulae, Ar₁, Ar₂, Ar₃ and Ar₄ represent each independently an arylene group, divalent heterocyclic group or divalent group having a metal complex structure. X₁, X₂ and X₃ represent each independently —CR₉═CR₁₀—, —C═C—, —N(R₁₁)— or —(SiR₁₂R₁₃)ₘ—. R₉ and R₁₀ represent each independently a hydrogen atom, alkyl group, aryl group, mono-valent heterocyclic group, carboxyl group, substituted carboxyl group or cyano group. R₁₁, R₁₂ and R₁₃ represent each independently a hydrogen atom, alkyl group, aryl group, mono-valent heterocyclic group, arylalkyl group or substituted amino group. ff represents 1 or 2. m represents an integer of 1 to 12. When a plurality of R₉s, R₁₀s, R₁₁s, R₁₂s and R₁₃s are present, these may be the same or different.

The arylene group is an atomic group obtained by removing two hydrogen atoms from an aromatic hydrocarbon, and includes also those having a condensed ring, and those in which an independent benzene ring or two or more condensed rings are bonded directly or via a group such as vinylene and the like. The arylene group may have a substituent.

The substituent includes an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group and cyano group.

A moiety excepting substituents in the arylene group has a number of carbon atom of usually about 6 to 60, preferably 6 to 20. The total carbon number including substituents in the arylene group is usually about 6 to 100.

Exemplified as the arylene group are a phenylene group (for example, formulae 1 to 3 in the following figure), naphthalenediyl group (formulae 4 to 13 in the following figure), anthracene-diyl group (formulae 14 to 19 in the following figure), biphenyl-diyl group (formulae 20 to 25 in the following figure), fluorene-diyl group (formulae 36 to 38 in the following figure), terphenyl-diyl group (formulae 26 to 28 in the following figure), condensed ring compound group (formulae 29 to 35 in the following figure), stilbene-diyl (formulae A to D in the following figure), distilbene-diyl (formulae E, F in the following figure) and the like. Of them, a phenylene group, biphenylene group, fluorene-diyl group and stilbene-diyl group are preferable.

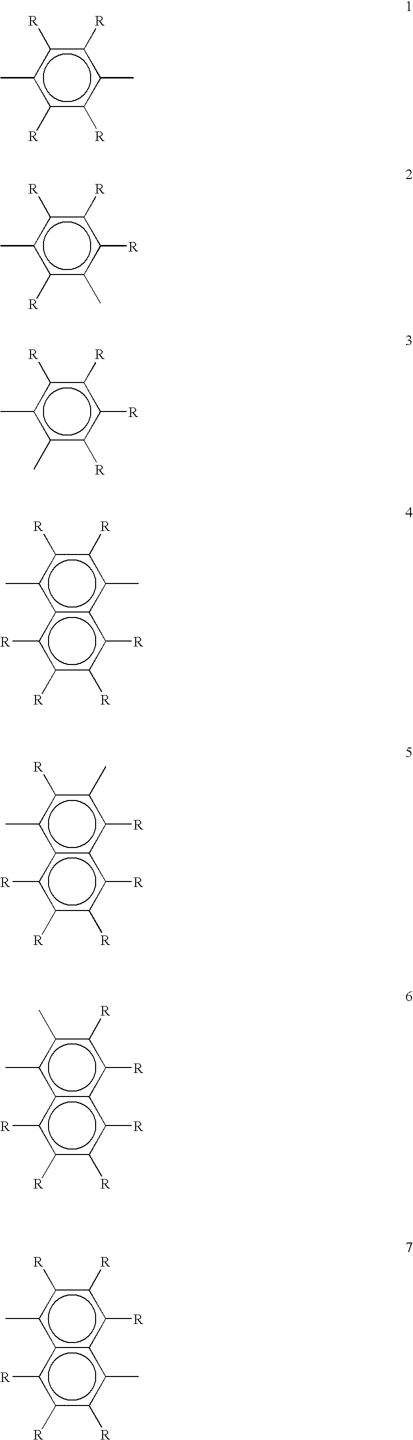

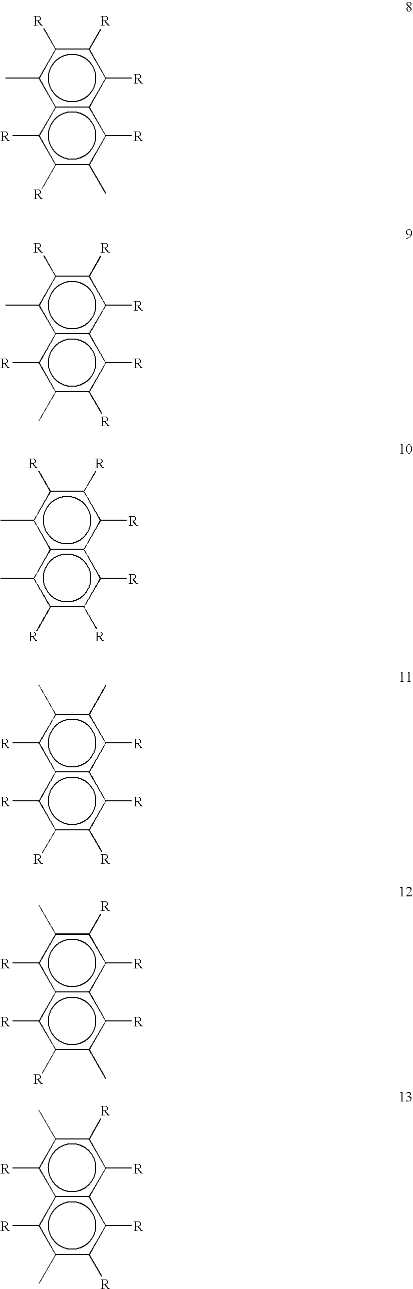

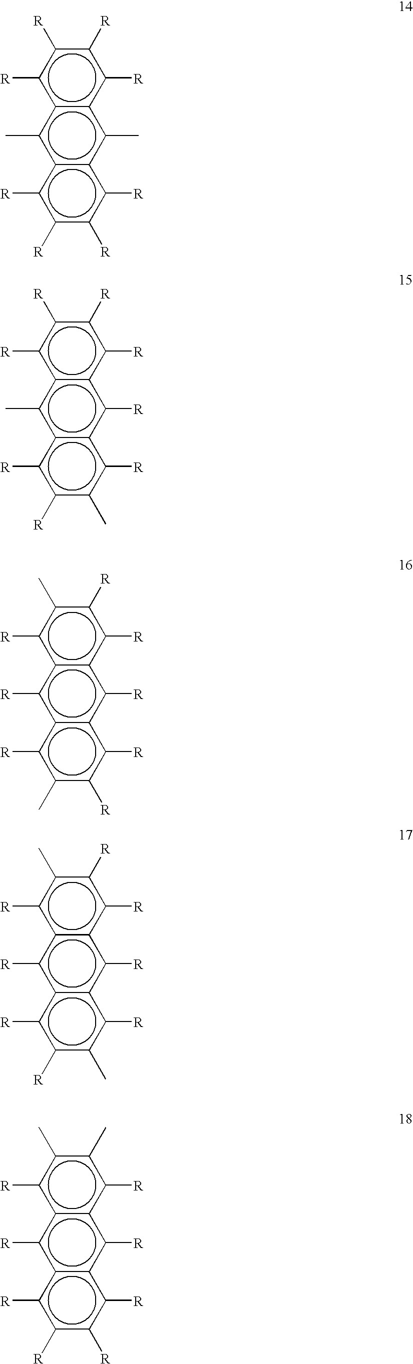

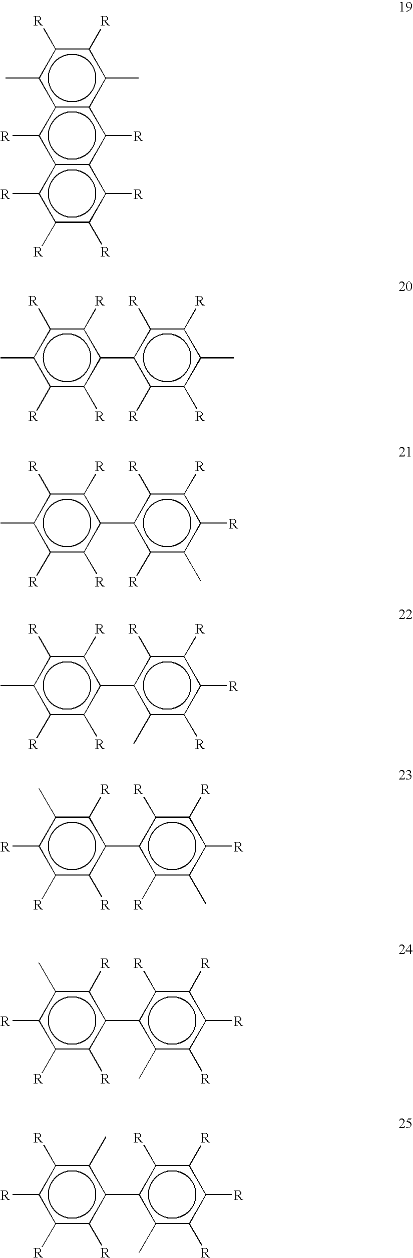

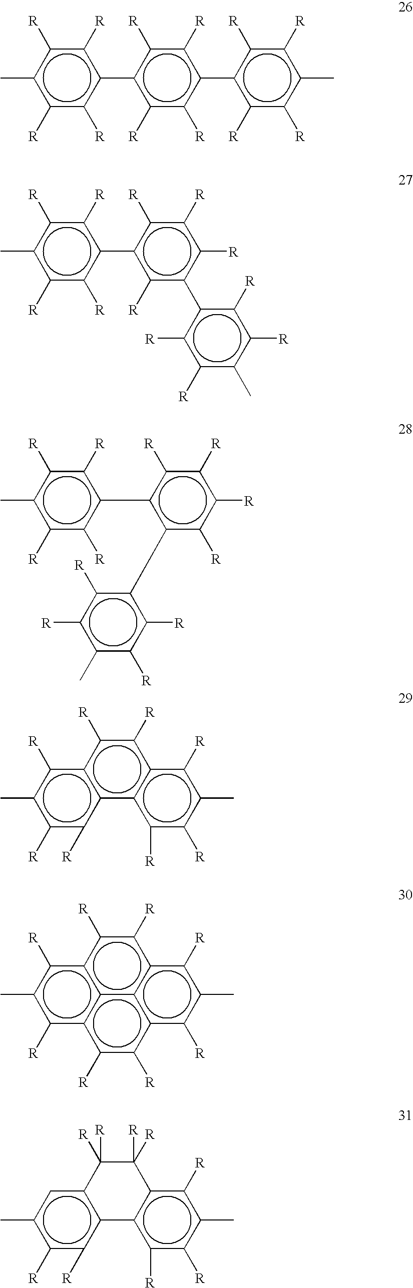

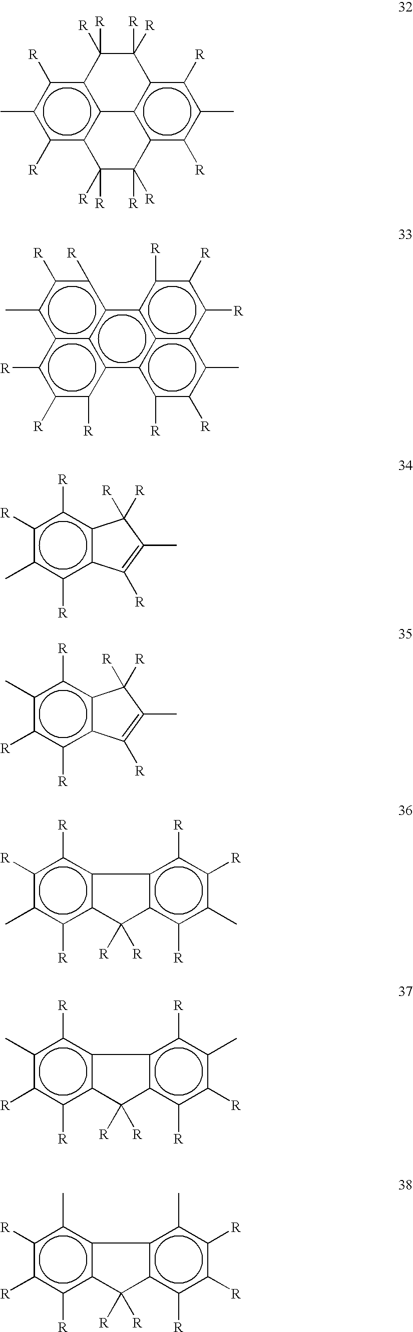

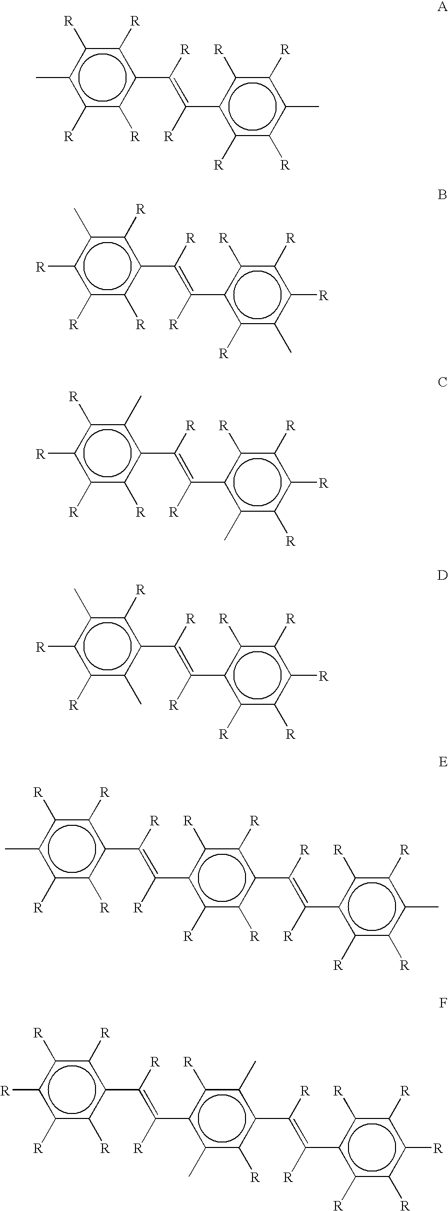

The divalent heterocyclic group as Ar₁, Ar₂, Ar₃ and Ar₄ is an atomic group left after removing two hydrogen atoms from a heterocyclic compound, and this group may have a substituent. Here, the heterocyclic compound refers to organic compounds having a cyclic structure in which elements constituting the ring include not only a carbon atom, but also a hetero atom such as oxygen, sulfur, nitrogen, phosphorus, boron, arsenic and the like. Of divalent heterocyclic groups, aromatic heterocyclic groups are preferable.

The substituent includes an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group and cyano group.

A moiety excepting substituents in the divalent heterocyclic group has a number of carbon atom of usually about 3 to 60. The total carbon number including substituents in the divalent heterocyclic group is usually about 3 to 100.

Examples of the divalent heterocyclic group include the following groups.

Divalent heterocyclic groups containing nitrogen as a hetero atom; pyridine-diyl group (formulae 39 to 44 in the following figure), diazaphenylene group (formulae 45 to 48 in the following figure), quinoline-diyl group (formulae 49 to 63 in the following figure), quinoxaline-diyl group (formulae 64 to 68 in the following figure), acridine-diyl group (formulae 69 to 72 in the following figure), bipyridyl-diyl group (formulae 73 to 75 in the following figure), phenanthroline-diyl group (formulae 76 to 78 in the following figure), and the like.

Groups containing silicon, oxygen, nitrogen, selenium and the like as a hetero atom, and having a fluorene structure (formulae 79 to 93 in the following figure).

5-membered ring heterocyclic groups containing silicon, oxygen, nitrogen, sulfur, selenium and the like as a hetero atom (formulae 94 to 98 in the following figure).

5-membered ring condensed hetero groups containing silicon, oxygen, nitrogen, selenium and the like as a hetero atom (formulae 99 to 110 in the following figure).

5-membered ring heterocyclic groups containing silicon, oxygen, nitrogen, sulfur, selenium and the like as a hetero atom, containing bonding at a-position of its hetero atom to form a dimer or oligomer (formulae 111 to 112 in the following figure).

5-membered ring heterocyclic groups containing silicon, oxygen, nitrogen, sulfur, selenium and the like as a hetero atom, containing bonding to a phenyl group at a-position of its hetero atom (formulae 113 to 119 in the following figure).

5-membered ring condensed heterocyclic groups containing oxygen, nitrogen, sulfur and the like as a hetero atom, containing substitution with a phenyl group, furyl group or thienyl group (formulae 120 to 125 in the following figure).

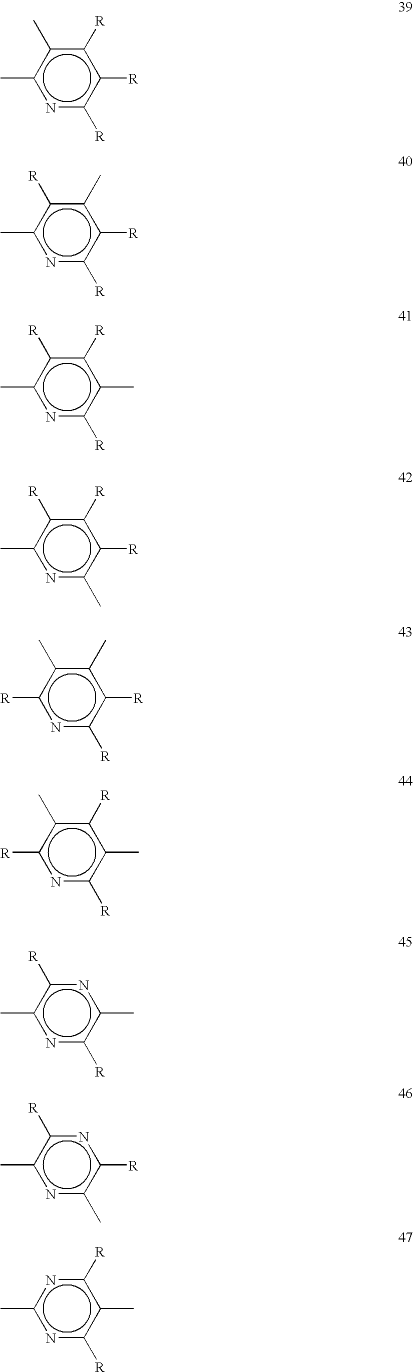

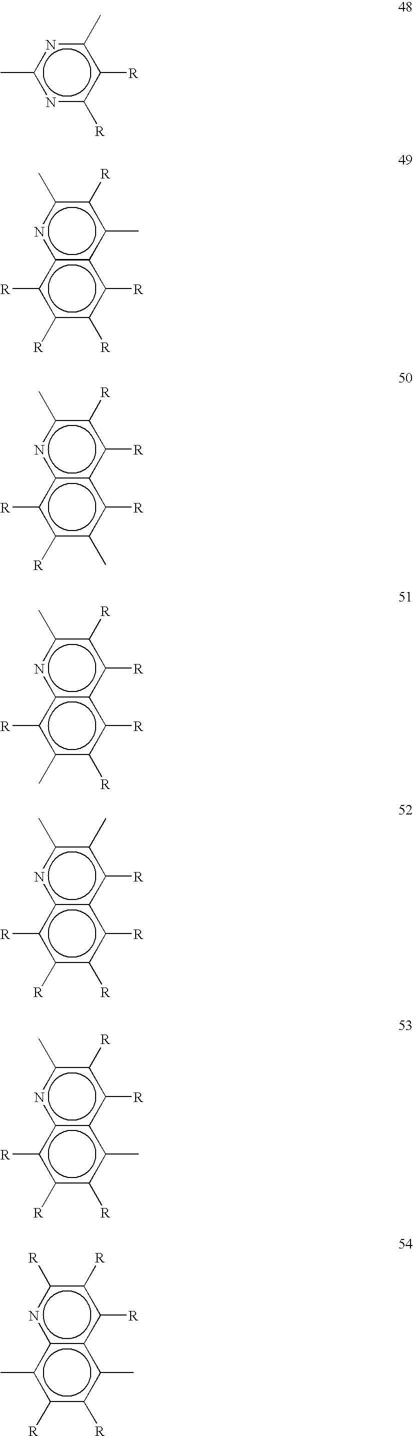

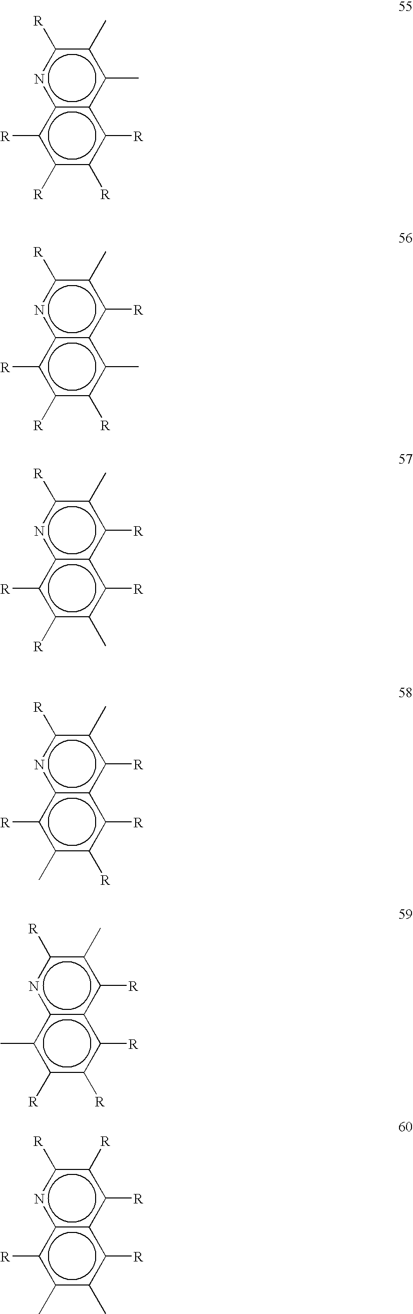

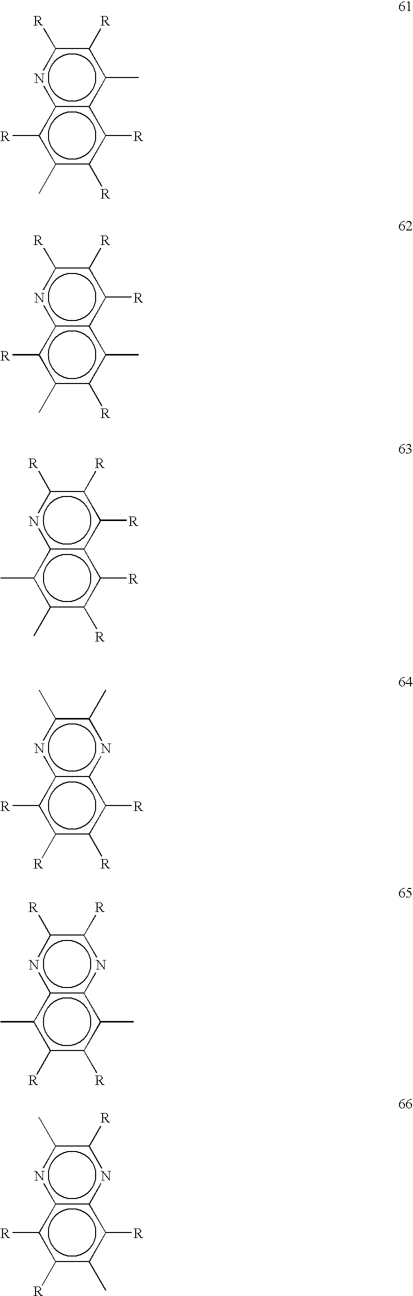

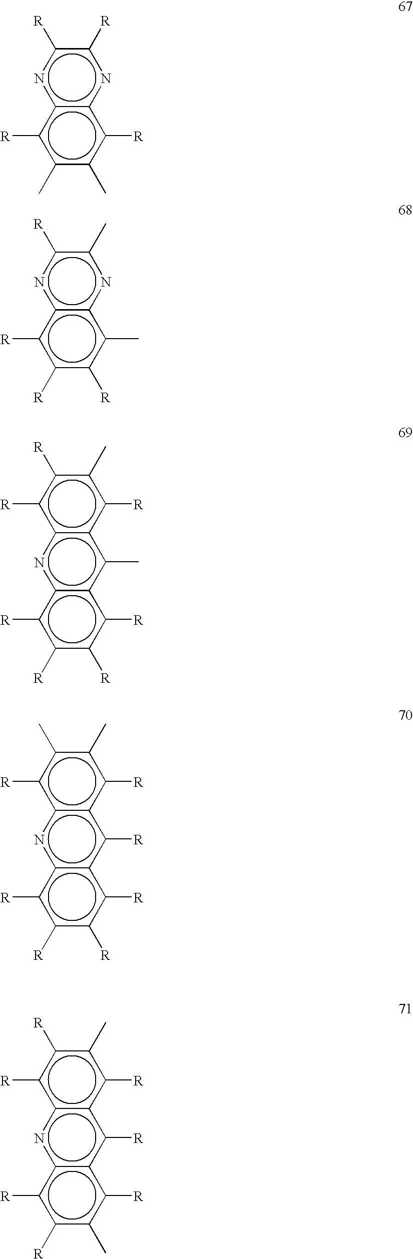

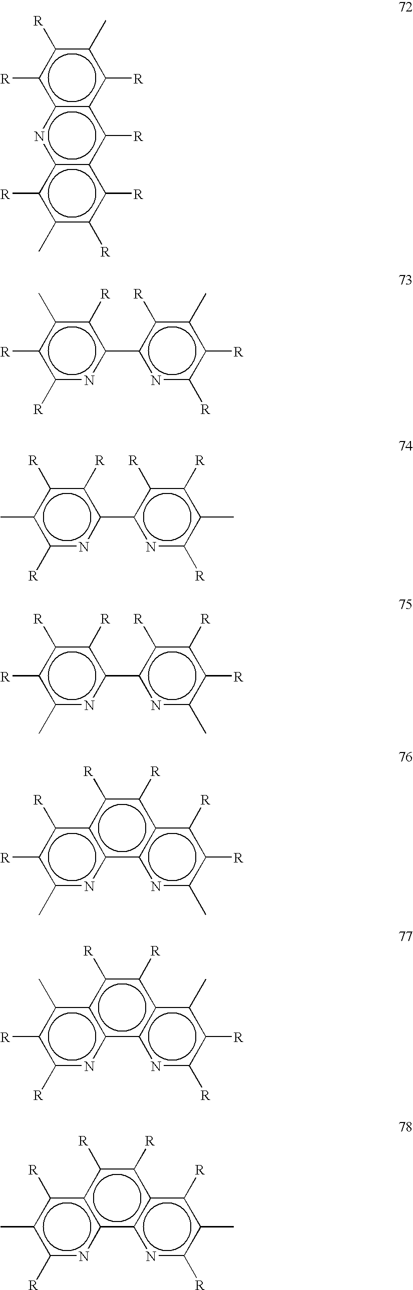

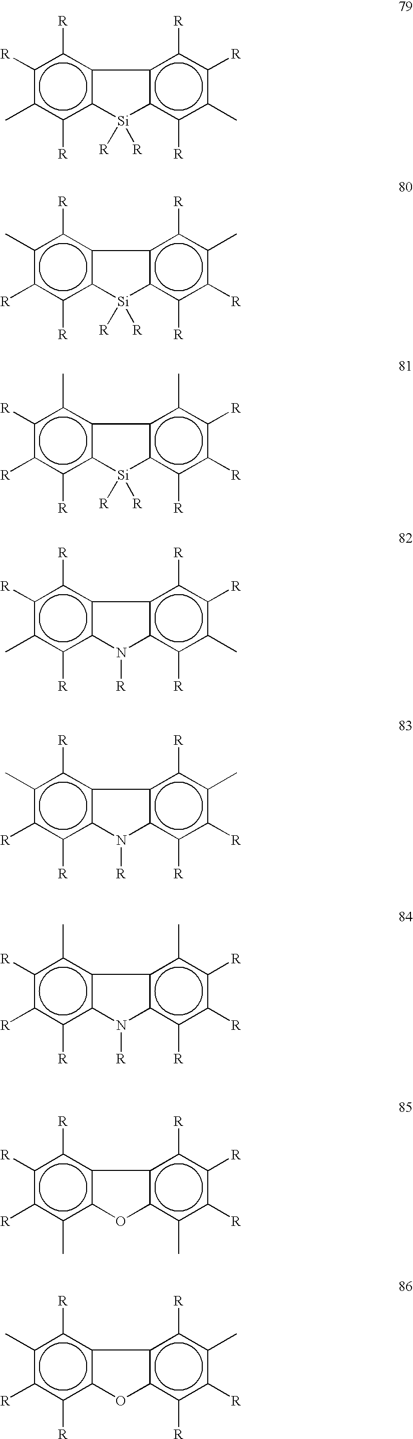

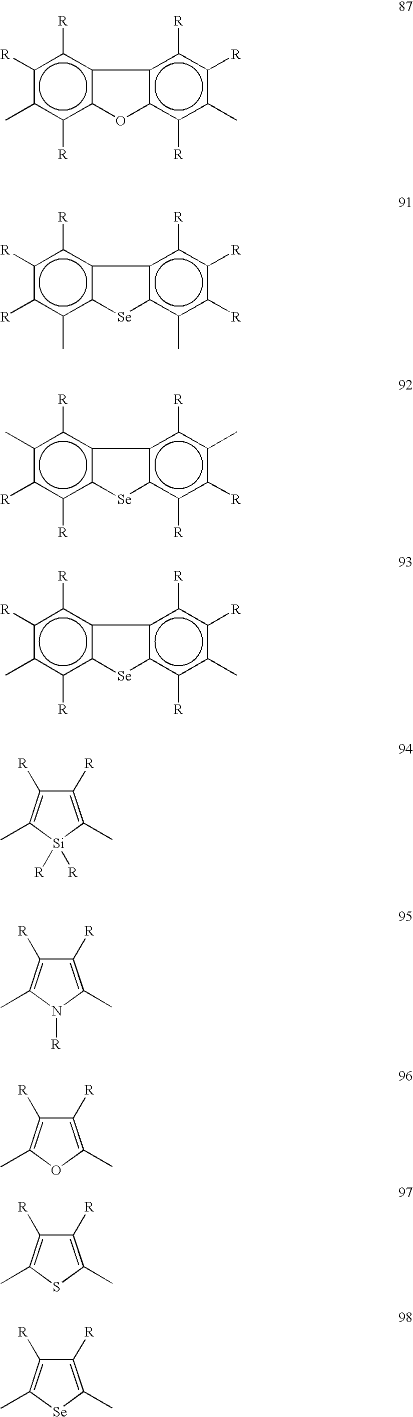

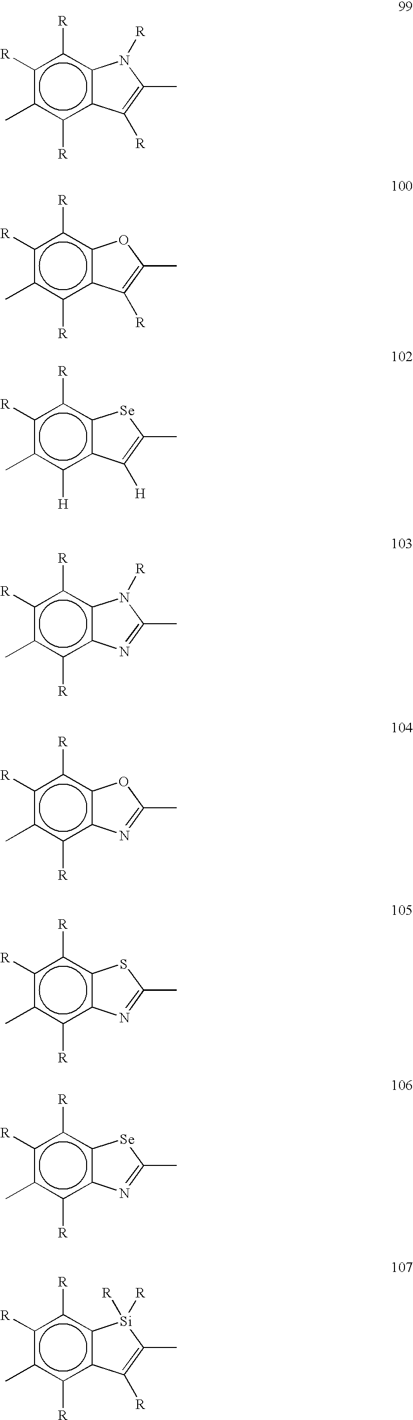

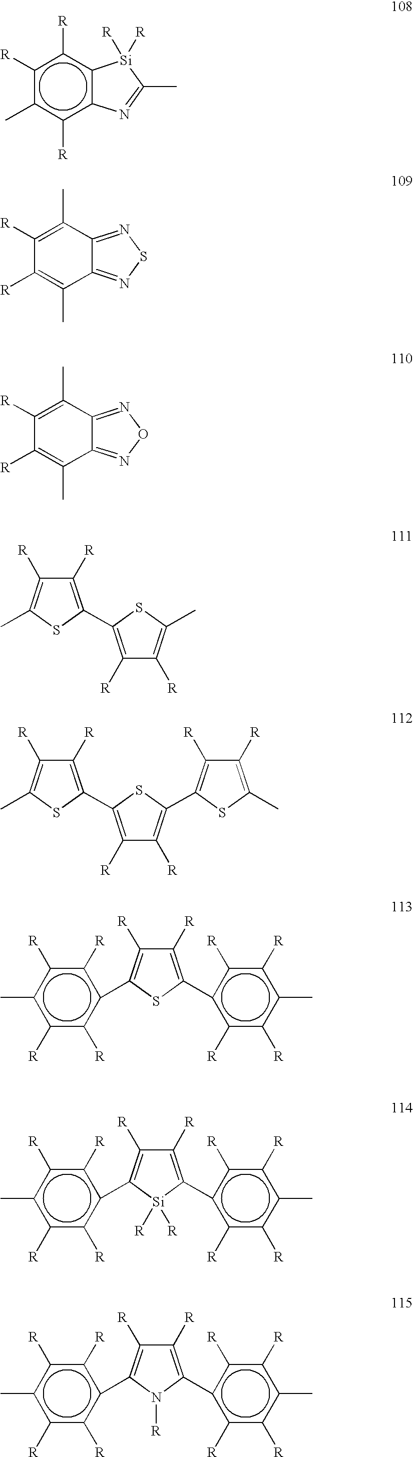

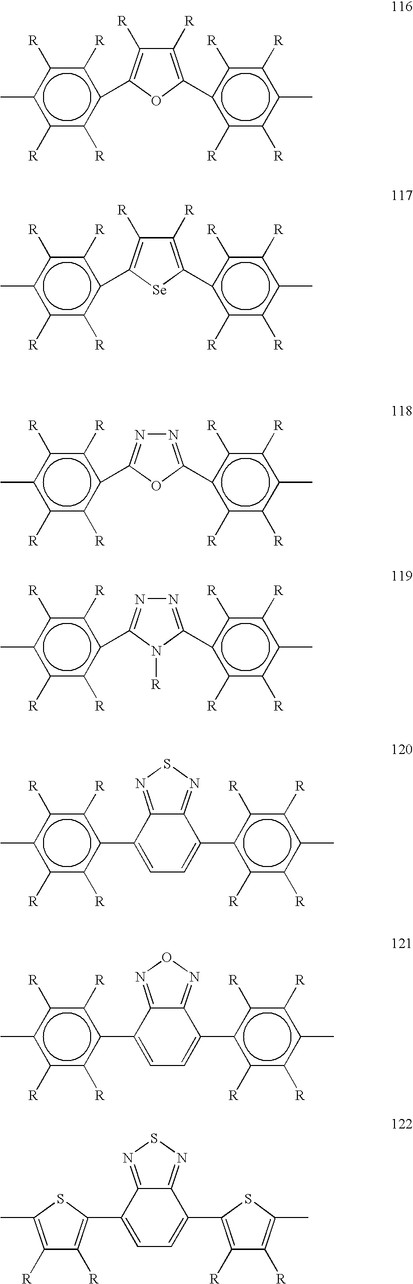

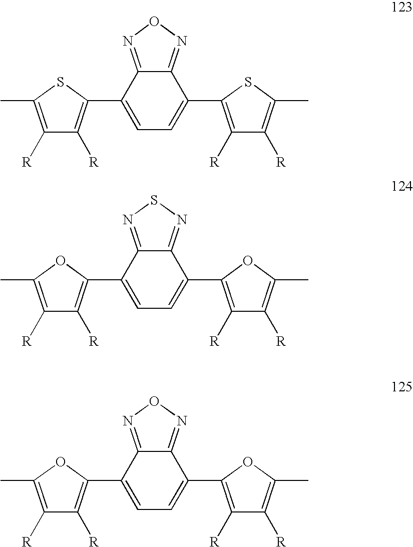

The divalent group having a metal complex structure as Ar₁, Ar₂, Ar₃ and Ar₄ is a divalent group left after removing two hydrogen atoms from an organic ligand of a metal complex structure having an organic ligand.

The organic ligand has a number of carbon atom of usually about 4 to 60, and examples thereof include 8-quinolinol and derivatives thereof, benzoquinolinol and derivatives thereof, 2-phenyl-pyridine and derivatives thereof, 2-phenyl-benzothiazole and derivatives thereof, 2-phenyl-benzoxazole and derivatives thereof, porphyrin and derivatives thereof, and the like.

As the center metal of the complex, for example, aluminum, zinc, beryllium, iridium, platinum, gold, europium, terbium and the like are mentioned.

As the metal complex having an organic ligand, metal complexes known as fluorescent materials and phosphorescence materials of lower molecular weight, triplet emitting complexes, and the like are mentioned.

As the divalent group having a metal complex structure, the following (126 to 132) are specifically exemplified.

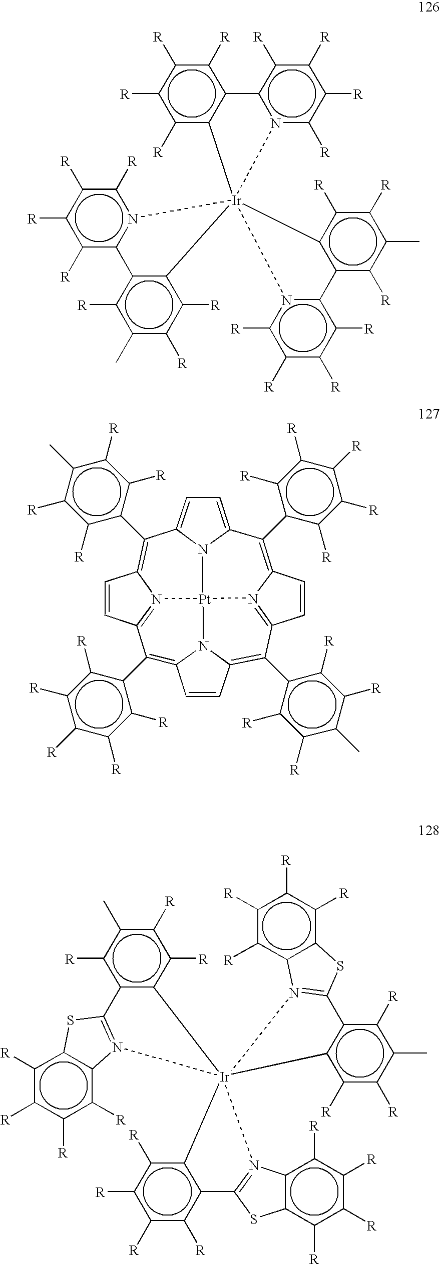

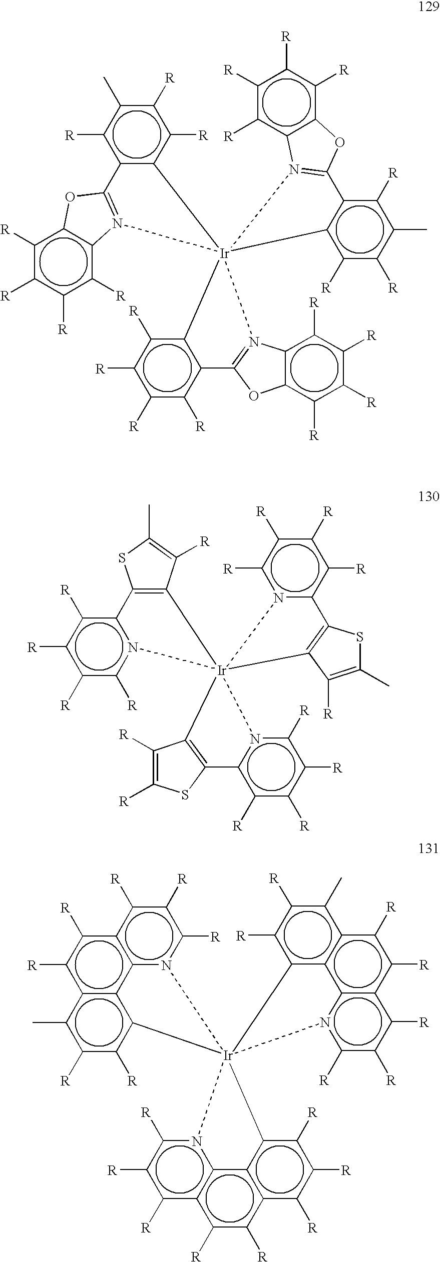

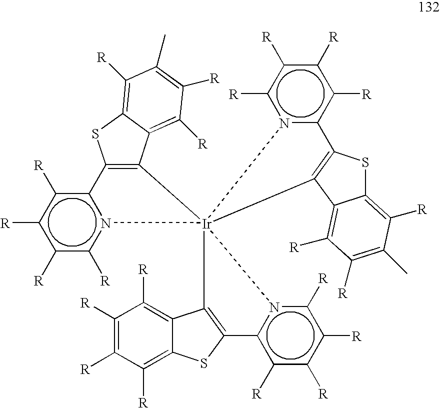

In the above-mentioned formulae 1 to 132, Rs represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group. A carbon atom in groups of the formulae 1 to 132 may be substituted by a nitrogen atom, oxygen atom or sulfur atom, and a hydrogen atom in groups of the formulae 1 to 132 may be substituted by a fluorine atom.

As the arylene group as a preferable repeating unit of the above-mentioned formula (3), repeating units of the following formulae (7), (8), (9), (10), (11) or (12) are preferable.

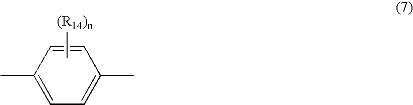

(wherein, R₁₄ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group. n represents an integer of 0 to 4. When a plurality of R₁₄s are present, these may be the same or different.)

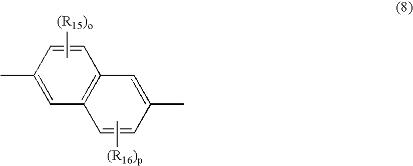

(wherein, R₁₅ and R₁₆ represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group. o and p represent each independently an integer of 0 to 3. When a plurality of R₁₅s and R₁₆s are present, these may be the same or different.)

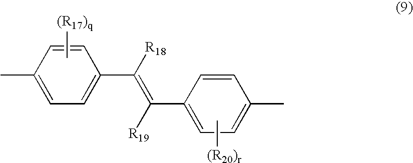

(wherein, R₁₇ and R₂₀ represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group. q and r represent each independently an integer of 0 to 4. R₁₈ and R₁₉ represent each independently a hydrogen atom, alkyl group, aryl group, mono-valent heterocyclic group, carboxyl group, substituted carboxyl group or cyano group. When a plurality of R₁₇s and R₂₀s are present, these may be the same or different.)

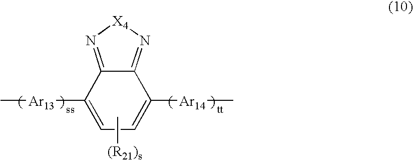

(wherein, R₂₁ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group. s represents an integer of 0 to 2. Ar₁₃ and Ar₁₄ represent each independently an arylene group, divalent heterocyclic group or divalent group having a metal complex structure. ss and tt represent each independently 0 or 1.
X₄ represents O, S, SO, SO₂, Se or Te. When a plurality of R₂₁s are present, these may be the same or different.)

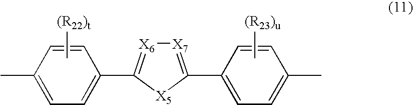

(wherein, R₂₂ and R₂₅ represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group. t and u represent each independently an integer of 0 to 4. X₅ represents O, S, SO₂, Se, Te, N—R₂₄ or SiR₂₅R₂₆. X₆ and X₇ represent each independently N or C—R₂₇. R₂₄, R₂₅, R₂₆ and R₂₇ represent each independently a hydrogen atom, alkyl group, aryl group, arylalkyl group or mono-valent heterocyclic group. When a plurality of R₂₂s, R₂₃s and R₂₇s are present, these may be the same or different).

Examples of a 5-membered ring at the center of a repeating unit of the formula (11) include thiadiazole, oxadiazole, triazole, thiophene, furan, silole and the like.

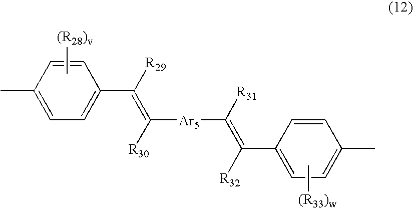

(wherein, R₂₈ and R₃₃ represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group. v and w represent each independently an integer of 0 to 4. R₂₉, R₃₀, R₃₁ and R₃₆ represent each independently a hydrogen atom, alkyl group, aryl group, mono-valent heterocyclic group, carboxyl group, substituted carboxyl group or cyano group. Ar₅ represents an arylene group, divalent heterocyclic group or divalent group having a metal complex structure. When a plurality of R₂₈s and R₃₃s are present, these may be the same or different).

Among repeating units of the above-mentioned formula (4), repeating units of the following formula (13) are preferable from the standpoints of changing of emission wavelength, enhancement of emission efficiency, improvement of heat resistance.

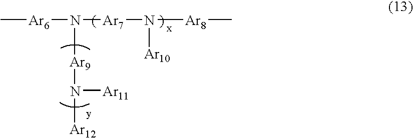

(wherein, Ar₆, Ar₇, Ar₈ and Ar₉ represent each independently an arylene group or divalent heterocyclic group. Ar₁₀, Ar₁₁ and Ar₁₂ represent each independently an aryl group or mono-valent heterocyclic group. Ar₆, Ar₇, Ar₈, Ar₉, Ar₁₀, Ar₁₁ and Ar₁₂ may have a substituent. x and y represent each independently 0 or a positive integer).

From the standpoint of stability of a light emitting device and easiness of synthesis, it is preferable that 1 to 3 repeating units of the formula (13) are contained, and it is more preferable that 1 or 2 repeating units are contained. Further preferably, only one repeating unit of the formula (13) is contained.

When two repeating units of the formula (13) are contained as a repeating unit in the polymer compound of the present invention, a combination of a repeating unit in which x=y=0 and a repeating unit in which x=1 and y=0, or a combination of two repeating units in which x=1 and y=0, is preferable from the standpoints of control of emission wavelength and element property and the like.

The sum of a repeating unit of the formula (1) and a repeating unit of the following formula (13) is preferably 50 mol % or more, further preferably 70 mol % or more, most preferably 90 mol %, based on all repeating units.

When a repeating unit of the above-mentioned formula (1) and a repeating unit of the above-mentioned formula (13) are contained in the present invention, their molar ratio is preferably 98:2 to 60:40.

From the standpoint of fluorescent intensity, element property and the like, the amount of a repeating unit of the above-mentioned formula (13) is more preferably 30 mol % or less, further preferably 20 mol % or less based on the sum of a repeating unit of the above-mentioned formula (1) and a repeating unit of the above-mentioned formula (13).

When an EL element is produced using only one polymeric compound of the present invention, the ratio of a repeating unit of the above-mentioned formula (1) to a repeating unit of the above-mentioned formula (13) is preferably 95:5 to 70:30, more preferably 90:10 to 80:20, from the standpoint of element property and the like.

In the present invention, when a repeating unit of the above-mentioned formula (1) and a repeating unit of the above-mentioned formulae (3) to (12) (wherein, excepting a case in which the above-mentioned formula (4) is the above-mentioned formula (13)) are contained, their molar ratio is preferably 98:1 to 60:40, more preferably 98:1 to 70:30.

Specific examples of the repeating unit of the above-mentioned formula (13) include those of the following formulae (133 to 140).

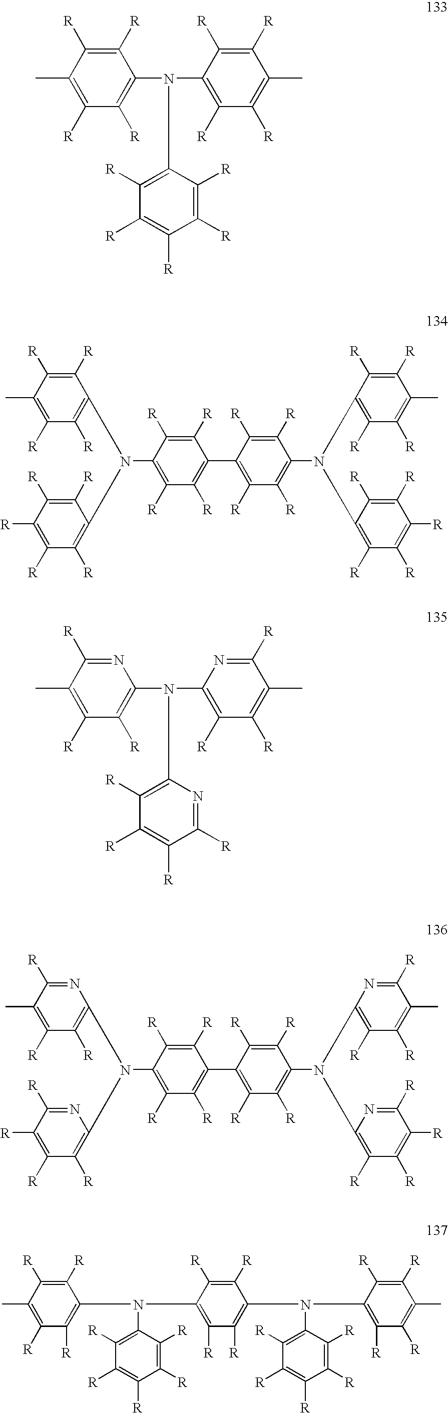

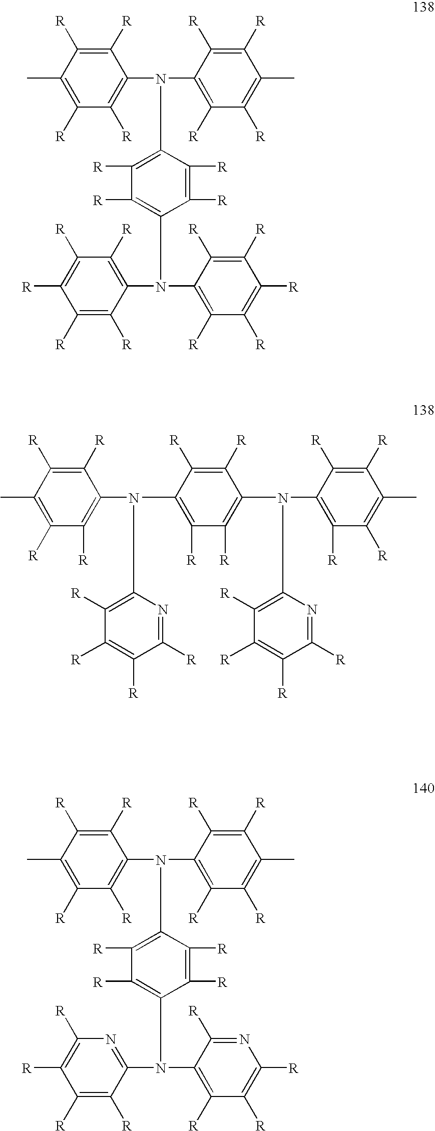

In the above-mentioned formulae, R has the same meaning as for the above-mentioned formulae 1 to 132.

In the above-mentioned formulae, Rs represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group. For enhancing solubility in an organic solvent, it is preferable that at least one group other than a hydrogen atom is contained, and it is preferable that the form of a repeating unit including a substituent shows small symmetry.

In a substituent in which R contains alkyl in the above-mentioned formula, it is preferable that cyclic or branched alkyl is contained in at least one substituent for enhancing solubility of a polymer compound in an organic solvent.

Further, when R contains partially an aryl group or heterocyclic group in the above-mentioned formula, these may further have at least one substituent.

Among structures of the above-mentioned formulae 133 to 140, structures of the above-mentioned formula 134 and the above-mentioned formula 137 are preferable from the standpoint of control of emission wavelength.

In the repeating unit of the above-mentioned formula (13), it is preferable that Ar₆, Ar₇, Ar₈ and Ar₉ represent each independently an arylene group and Ar₁₀, Ar₁₁ and Ar₁₂ represent each independently an aryl group, from the standpoints of control of emission wavelength and element property and the like.

It is preferable that Ar₆, Ar₇ and Ar₈ represent each independently an un-substituted phenylene group, un-substituted biphenyl group, un-substituted naphthylene group, un-substituted anthracene-diyl group.

From the standpoint of solubility in an organic solvent, element property and the like, it is preferable that Ar₁₀, Ar₁₁ and Ar₁₂ represent each independently an aryl group having 3 or more substituents, it is more preferable that Ar₁₀, Ar₁₁ and Ar₁₂ represent a phenyl group having 3 or more substituents, naphthyl group having 3 or more substituents or anthranyl group having 3 or more substituents, it is further preferable that Ar₁₀, Ar₁₁ and Ar₁₂ represent a phenyl group having 3 or more substituents.

Particularly, it is preferable that Ar₁₀, Ar₁₁ and Ar₁₂ represent each independently group of the following formula (13-1) and x+y=3, it is more preferable that x+y=1, it is further preferable that x=1 and y=0.

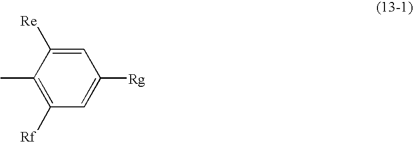

(wherein, Re, Rf and Rg represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, mono-valent heterocyclic group or halogen atom. A hydrogen atom contained in Re, Rf and Rg may be substituted by a fluorine atom).

More preferably, in the above-mentioned formula (13-1), Re and Rf represent each independently an alkyl group having 3 or less carbon atoms, alkoxy group having 3 or less carbon atoms, alkylthio group having 3 or less carbon atoms and Rg represents an alkyl group having 3 to 20 carbon atoms, alkoxy group having 3 to 20 carbon atoms, alkylthio group having 3 to 20 carbon atoms.

In the repeating unit of the above-mentioned formula (13), Ar₇ is preferably the following formula (19-1) or (19-2).

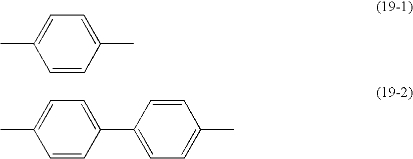

(wherein, benzene rings contained in structures of (19-1) and (19-2) may have each independently 1 to 4 substituents. These substituents may be mutually the same or different. A plurality of substituents may be connected to form a ring. Further, another aromatic hydrocarbon ring or heterocyclic ring may be bonded next to the benzene ring).

Particularly preferable specific examples of the repeating unit of the above-mentioned formula (13) include those of the following formulae (141 to 142).

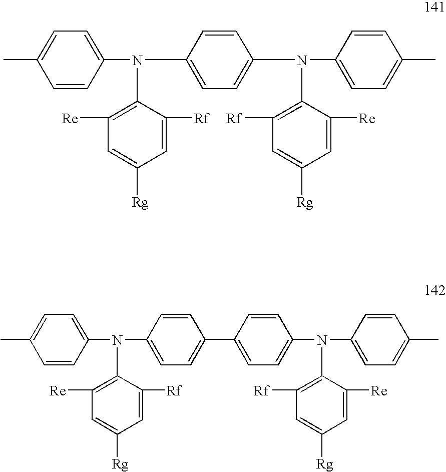

As preferable specific examples of the formula (13), repeating units of the following formulae (17), (19) and (20) are preferable from the standpoint of control of emission wavelength. Repeating units of the following formula (17) are further preferable from the standpoint of fluorescent intensity. In this case, heat resistance can be increased.

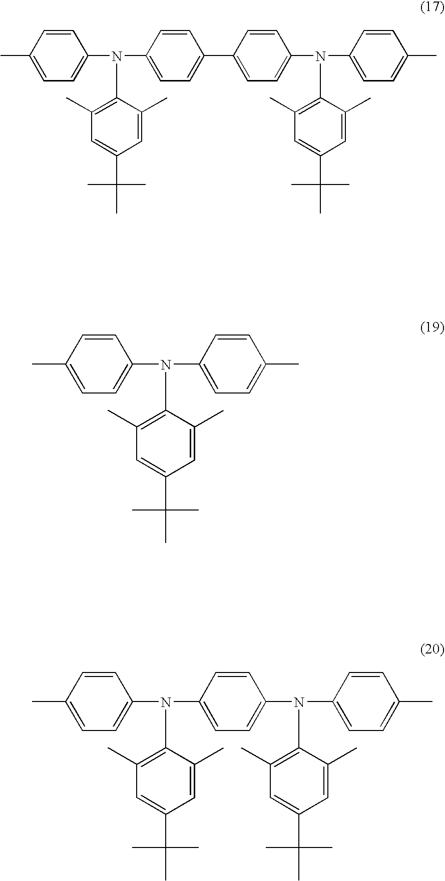

The polymer compound of the present invention may contain a repeating unit other than repeating units of the above-mentioned formulae (1), (3) to (13), in a range not deteriorating a light emitting property and charge transporting property. Further, these repeating units and other repeating units may be connected by a non-conjugated unit, or a non-conjugated part may be contained in the repeating unit. As the bonding structure, exemplified are those described below, and combinations of two or more of those described below. Here, R is a group selected from the same substituents as described above, and Ar may contain a hetero atom such as oxygen, sulfur, nitrogen, silicon, selenium and the like. Hydrocarbon groups having 6 to 60 carbon atoms are shown below.

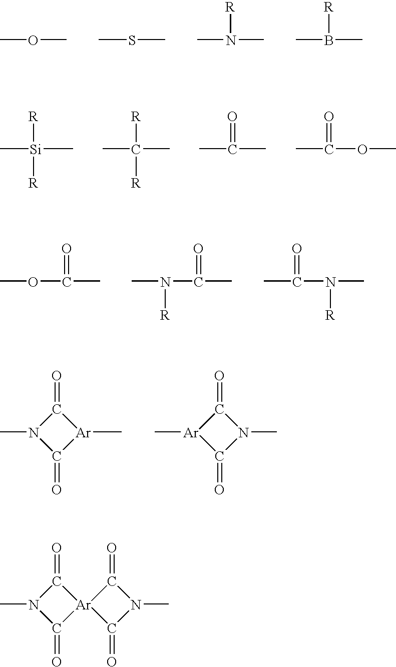

As the polymer compound composed only of any repeating unit of the above-mentioned formula (1) among polymer compounds of the present invention, preferable are those composed only of any repeating unit of the above-mentioned formula (1-1), (1-2), (1-3) or (1-4) and those composed of two or more repeating units selected from repeating units of the above-mentioned formula (1-1), (1-2), (1-3) and (1-4), and more preferable are those composed only of a repeating unit of the formula (1-1), further preferable are those composed substantially only of a repeating unit of the formula (16), from the standpoint of element property and the like.

As the polymer compound containing a repeating unit other than the repeating unit of the above-mentioned formula (1), preferable are those composed of at least one repeating unit selected from repeating units of the above-mentioned formulae (1-1), (1-2), (1-3) and (1-4), and at least one repeating unit of the above-mentioned formulae (3) to (13), more preferable are those composed of any one of repeating units of the formulae 133, 134 and 137, and a repeating unit of the formula (1-1), further preferable are those composed of any one of repeating units of the formulae 134 and 137, and a repeating unit of the formula (1-1), and more preferable are those composed only of a repeating unit of the formula (16) and a repeating unit of the formula (17), and those composed only of a repeating unit of the formula (16) and a repeating unit of the formula (20), from the standpoint of a fluorescent property, element property and the like.

The polymer compound of the present invention may be a random, block or graft copolymer, or a polymer having an intermediate structure, for example, a random copolymer having a block property. From the standpoint of obtaining a polymer light emitting body having high quantum yield of fluorescence or phosphorescence, a random copolymer having a block property and a block or graft copolymer are more preferable than a complete random copolymer. Those having branching in the main chain and thus having 3 or more end parts, and dendrimers are also included.

When ring A and ring B have different structures in the structure of the above-mentioned formula (1), the adjacent structure of the formula (1) is a structure of any of the following formulae (31), (32) and (33). From the standpoint of electron injectability and transportability, the polymer compound contains at least one of (31) to (33) is preferable.

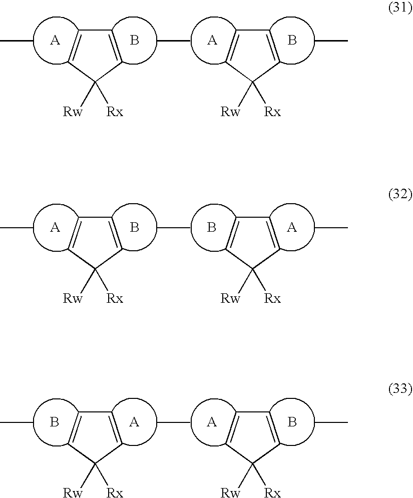

(wherein, ring A and ring B represent each independently an aromatic hydrocarbon ring optionally having a substituent, the aromatic hydrocarbon ring in ring A and the aromatic hydrocarbon ring in ring B have mutually different ring structures, a connecting bond is present on both ring A and ring B, R_{w} and Rₓ represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, and R_{w} and Rₓ may mutually bond to form a ring.)

When a polymer compound in which ring B is an aromatic hydrocarbon ring containing a plurality of condensed benzene rings is used as a material for polymer LED, the ratio of a B ring-B ring chain of the following formula (32) is preferably 0.4 or less based on all chains containing ring B in the polymer compound, more preferably 0.3 or more, further preferably 0.2 or more, more preferably substantially 0, from the standpoint of suppressing change in light emission wavelength during driving of the element. From the standpoint of suppressing change in light emission wavelength during driving of the element, ring A is preferably a benzene ring.

The chain containing ring B includes not only a B ring-A ring chain in the above-mentioned formula (31) and a B ring-B ring chain in the above-mentioned formula (32), but also chains in which a repeating unit other than the structure of the above-mentioned formula (1) is adjacent. When the repeating unit other than the structure of the above-mentioned formula (1) contains ring B, if there is a chain between ring B in the above-mentioned formula (1) and ring B of the repeating unit other than the structure of the above-mentioned formula (1), this chain is also included in the ring B-ring B chain.

In a polymer compound having many chains between aromatic hydrocarbon rings containing a plurality of condensed benzene rings, when an element is driven for a long period of time, light emission of longer wavelength may be observed as compared with the light emission wavelength at the initial period of driving. Specifically, when a repeating unit of the above-mentioned formula (1-1) is contained and there are a lot of naphthalene-naphthalene chains, if an element is driven for a long period of time, light emission of longer wavelength may be observed as compared with light emission wavelength in the initial period of driving. The ratio of a naphthalene ring-naphthalene ring chain is, based on all chains containing a naphthalene ring in the polymer compound, preferably 0.4 or less, more preferably 0.3 or more, further preferably 0.2 or more, more preferably substantially 0.

As the structure having few chains between aromatic hydrocarbon rings containing a plurality of condensed benzene rings, preferable is a structure in which two adjacent structures of the above-mentioned formula (1) are connected at head (H) and tail (T) as shown in the above-mentioned formula (31). As the polymer compound, preferable are polymer compounds in which the above-mentioned adjacent formulae (1) are substantially all H-T bonded. Particularly in the case of (1-1) and (1-2), H-T connecting is preferable.

When a copolymer contains a repeating unit of the above-mentioned formula (1) in a ratio of 50 mol % or more based on all repeating units, and if a proportion that the repeating unit of the formula (1) is adjacent to a repeating unit of the formula (1) is represented by Q₁₁, Q₁₁ is preferably 25% or more.

For polymerizing a monomer to obtain a polymer compound of the present invention, those containing two or more structures of the above-mentioned formula (1) can be used as a monomer. Exemplified as the monomer are those having a structure in which two or more polymerization active groups are added to a di- to penta-mer. For example, monomers containing polymerization active groups bonded to a connecting bond of the above-mentioned formulae (31) to (33) are mentioned.

As a method for obtaining a polymer compound containing the above-mentioned formula (31) in large amount or a polymer compound containing a ring B-ring B chain in small amount, there is a method of carrying out polymerization using a compound in which a substituent correlated with polymerization bonded to ring A and a substituent correlated with polymerization bonded to ring B are different. For example, when polymerization is carried out using a compound in which a borate is bonded to ring A and a halogen atom is bonded to ring B, a polymer compound containing a ring B-ring B chain in small amount is obtained.

The polymer compound of the present invention is preferably a random copolymer having a block property, or a block or graft copolymer, and that which contains a chain of a repeating unit of the above-mentioned formula (1) has higher fluorescent intensity and more excellent element property. When repeating units of the above-mentioned formula (1) contained in a polymer compound of the present invention are contained in the same proportion, that which contains a longer chain of a repeating unit of the above-mentioned formula (1) has more excellent fluorescent intensity and element property.

In the case of a copolymer containing a repeating unit of the above-mentioned formula (1) and a repeating unit of the above-mentioned formula (13) in which the ratio of a repeating unit of the above-mentioned formula (13) is 15 to 50 mol % based on all repeating units, if the proportion that a repeating unit of the formula (13) is adjacent to a repeating unit of the formula (13) is represented by Q₂₂, Q₂₂ is preferably 15 to 50% or more, more preferably 20 to 40%, from the standpoint of fluorescent intensity, element property and the like.

As the polymer compound or its composition having enhanced fluorescent intensity, element property and the like when a specific chain is contained, preferable are polymer compounds and their compositions containing a repeating unit of the above-mentioned formula (13) and a repeating unit of the following formula (1-1) or (1-2).

When the polymer compound or its composition contains a repeating unit of the above-mentioned formula (13) and a repeating unit of the following formula (1-1) or (1-2), if the proportion that the formula (13) is bonded to a mark * of the formula (1-1) or the formula (1-2) among all repeating units of the above-mentioned formula (13) is represented by Q_{21N}, Q₂₂ is preferably in a range of 15 to 50%, more preferably 20 to 40%. When Q₂₂ is in a range of 15 to 50%, Q_{21N} is preferably in a range of 20 to 40%.

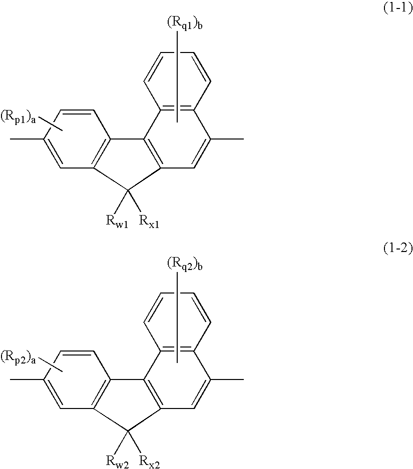

(wherein, Rₚ₁, R_{q1}, Rₚ₂, R_{q2}, a, b, R_{w1}, Rₓ₁, R_{w2} and Rₓ₂ represent the same meanings as described above).

As a method of checking a chain of a polymer compound, an NMR measurement method can be used. In the present invention, a polymer compound was dissolved in deuterated tetrahydrofuran and measurement was conducted at 30° C.

To be capable of standing various processes for producing a light emitting device and the like, it is preferable that a polymer compound has a glass transition temperature of 100° C. or more.

The polymer compound of the present invention has a number-average molecular weight in terms of polystyrene of usually about 10³ to 10⁸, preferably 10⁴ to 10⁶. The weight-average molecular weight in terms of polystyrene is usually about 10³ to 10⁸, and from the standpoint of a film forming property and from the standpoint of efficiency in the case of making an element, preferably 5×10⁴ to 5×10⁶. 10⁵ to 5×10⁶ is further preferable. In the case of polymer compounds having a molecular weight in a preferable range, even if the compound is used singly in an element or two or more of them are mixed and used in an element, high efficiency is obtained. Likewise, from the standpoint of enhancing a film forming property of a polymer compound, the degree of dispersion (weight-average molecular weight/number-average molecular weight) is preferably 1.5 or more.

When the polymer compound of the present invention is a conjugated polymer, the weight-average molecular weight is preferably 4×10⁴ to 5×10⁶, more preferably 5×10⁴ to 5×10⁶, further preferably 10⁵ to 5×10⁶ from the standpoint of a film forming property and from the standpoint of efficiency of making an element.

When the repeating unit is composed only of a structure of the above-mentioned formula (16), the elution curve of GPC is substantially unimodal, and the degree of dispersion is preferably 1.5 or more, more preferably 1.5 or more and 12 or less, further preferably 2 or more and 7 or less, more preferably 4 or more and 7 or less.

In the case of substantially only a structure of the above-mentioned formula (16) and a structure of the above-mentioned formula (17), the elution curve of GPC is preferably unimodal. Unimodal referred to in the present invention includes not only a case in which the curve has two summits, but also a case in which, in a process of increase of the curve, rapid increase is present, and after this, time of very tender increase continues for a long period, thereafter, rapid increase is present again, and a case in which, in a process of decrease of the curve, rapid decrease is present, and after this, time of very tender decrease continues for a long period, thereafter, rapid decrease is present again. The degree of dispersion is preferably 1.5 or more.

The elution curve of GPC is generally measured by GPC (gel permeation chromatography). In measurement of the elution curve of GPC in the present invention, tetrahydrofuran was used as a mobile phase and the flow rate was 0.6 mL/min. In the column, two TSKgel Super HM-H (manufactured by Tosoh Corp.) and one TSKgel Super H2000 (manufactured by Tosoh Corp.) were connected serially, and a differential refractive index detector was used as a detector. GPC is called also SEC (size exclusion chromatography) in some cases.

The elution curve of GPC of a polymer compound composed substantially only of a repeating unit of the above-mentioned formula (16) is preferably unimodal near symmetry. From the standpoint of reproducibility of an element property, a difference between the area of the elution curve on the left side of a peak top boundary and the area of the elution curve on the right side of a peak top boundary, in the elution curve of GPC, is preferably 0.5 or less, more preferably 0.3 or less, based on the value of the smaller area among the left and right areas. Further, it is preferable that the area on the right side of a peak top boundary (lower molecular weight side) is smaller than the area on the left side (higher molecular weight side).

The polymer compound of the present invention may have a branched structure in the main chain, and as the branched structure, that of the following formula (41) is preferable.

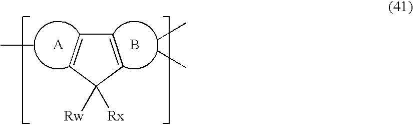

(wherein, ring A, ring B, Rw and Rx represent the same meanings as described above, and three connecting bonds are present on ring A and/or ring B.)

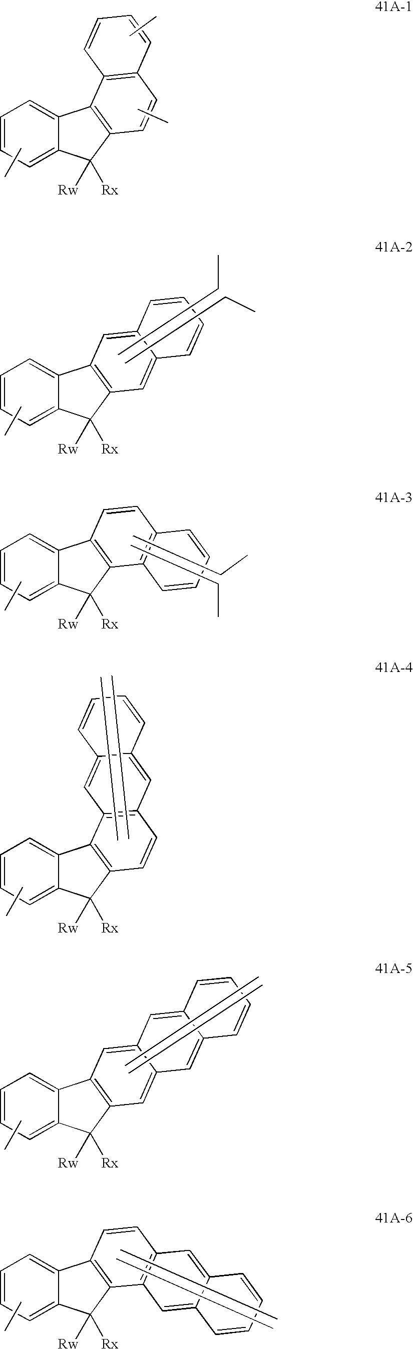

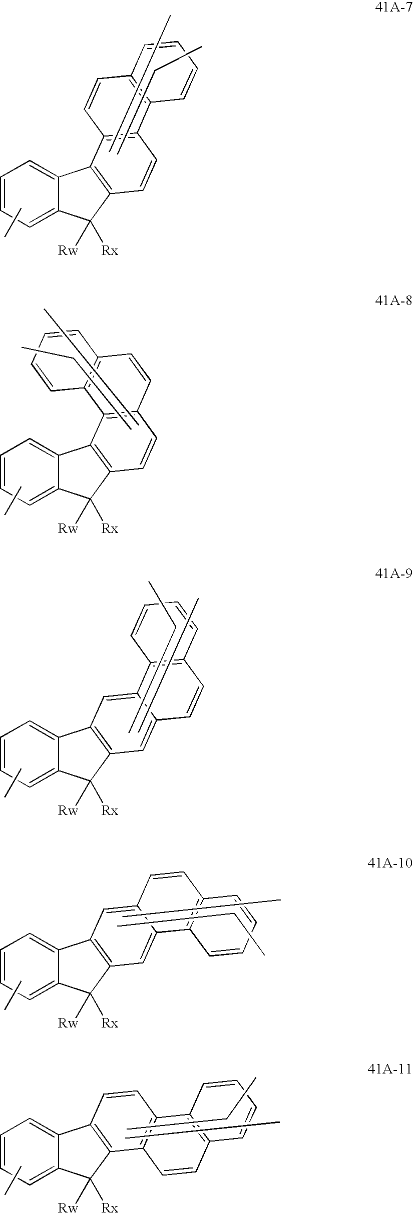

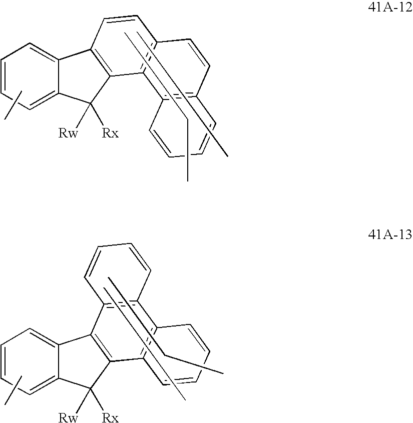

As the branched structure, mentioned are those obtained by attaching a further connecting bond to an aromatic ring of any of the above-mentioned formulae (1A-1) to (1A-64), (1B-1) to (1B-64), (1C-1) to (1C-64).

Specific examples of the branched structure include the following structures.

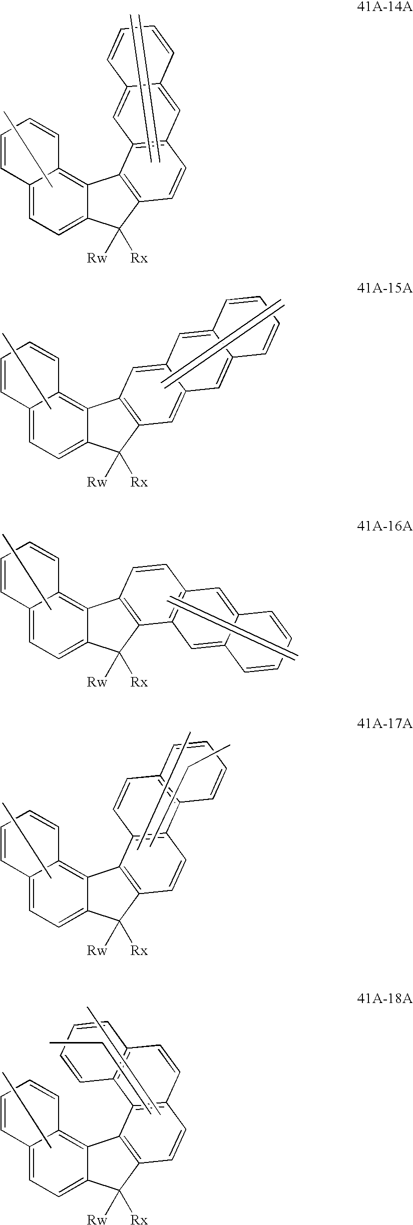

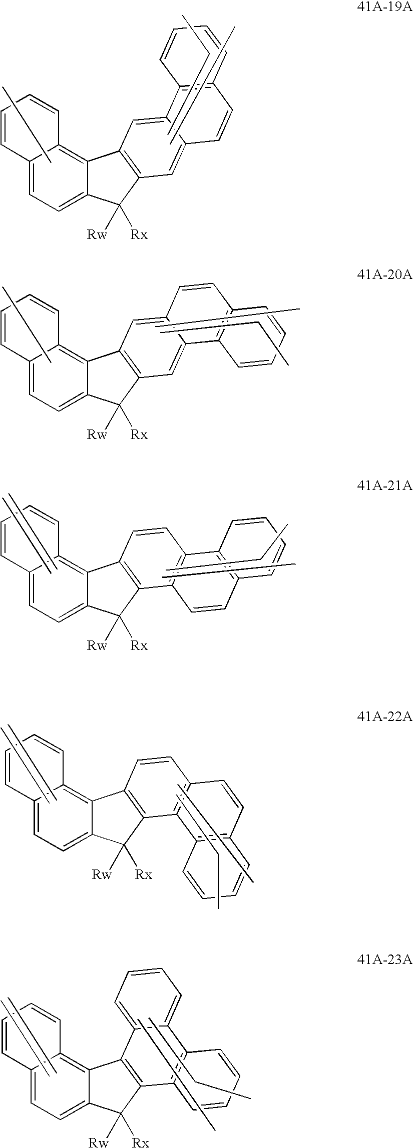

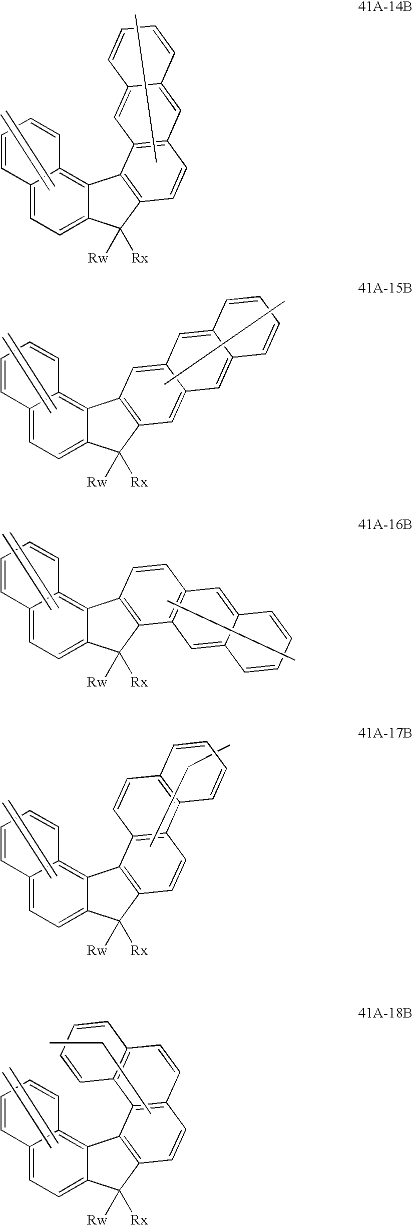

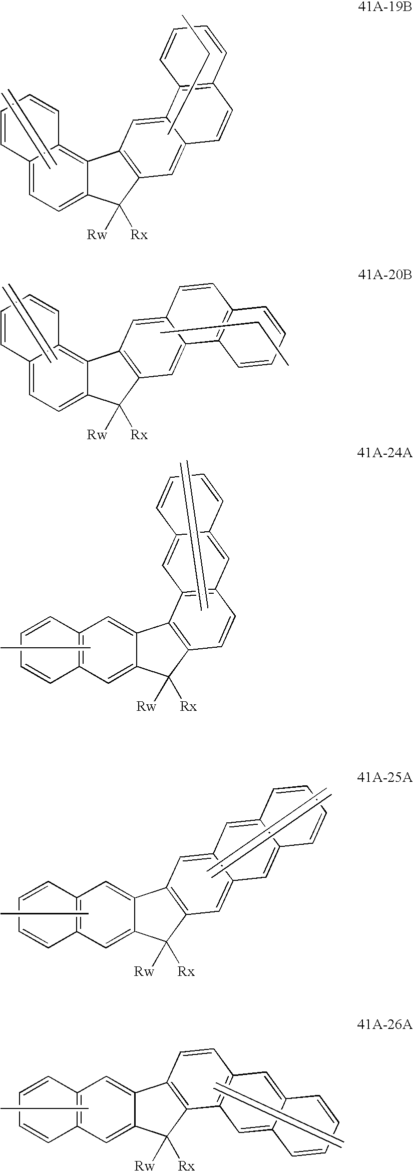

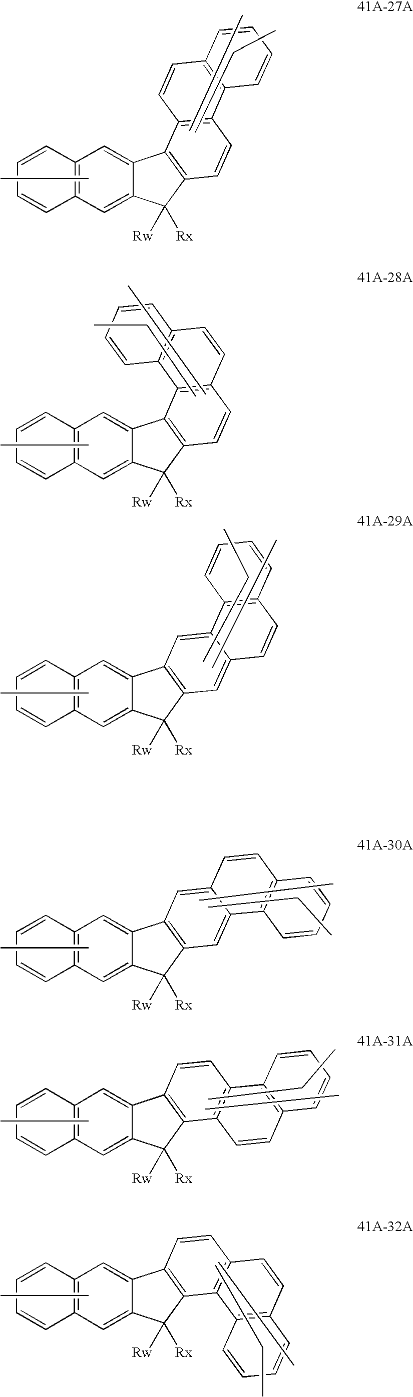

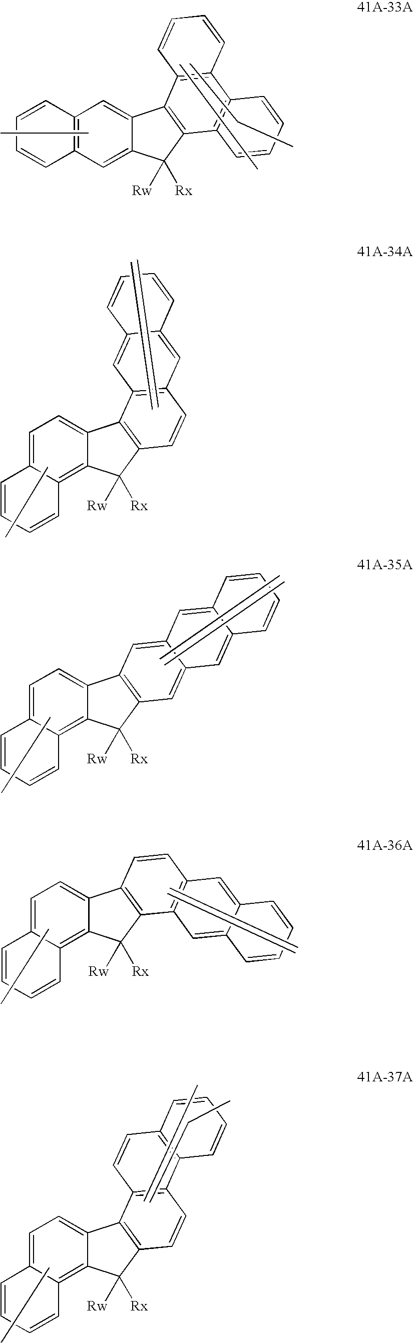

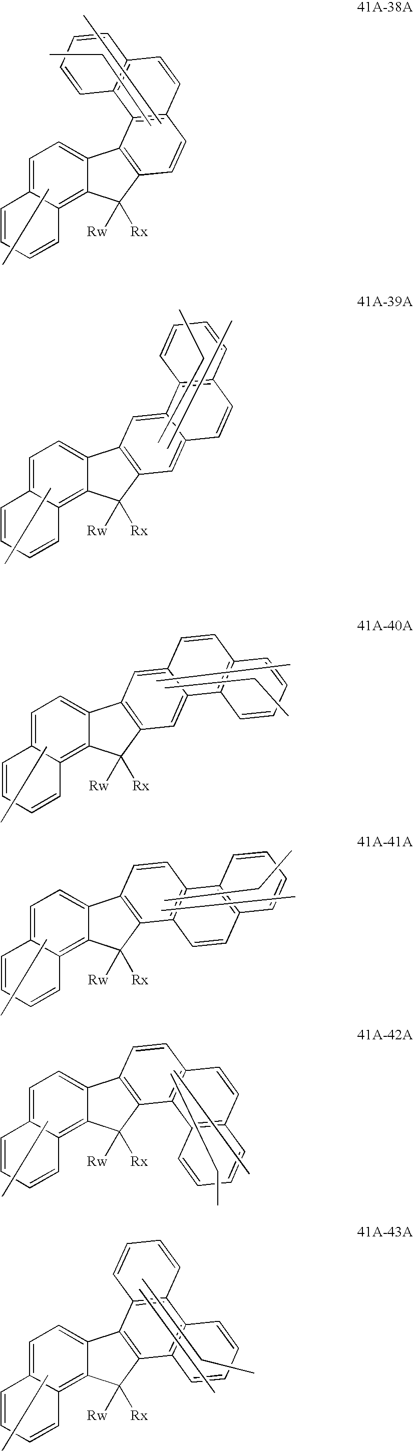

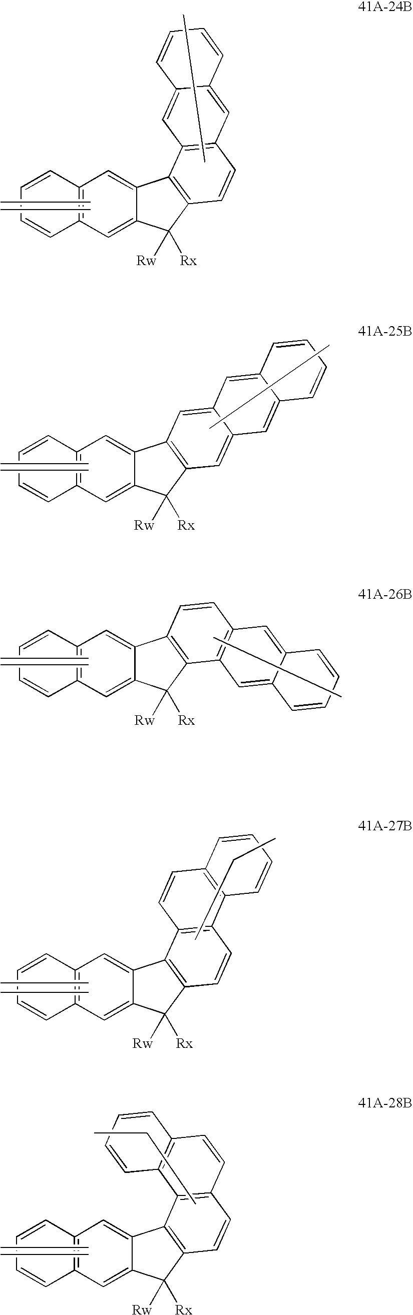

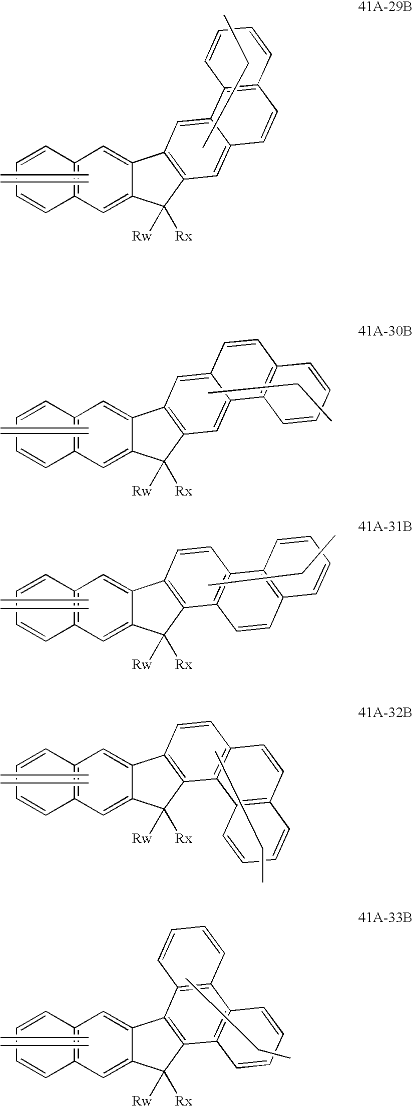

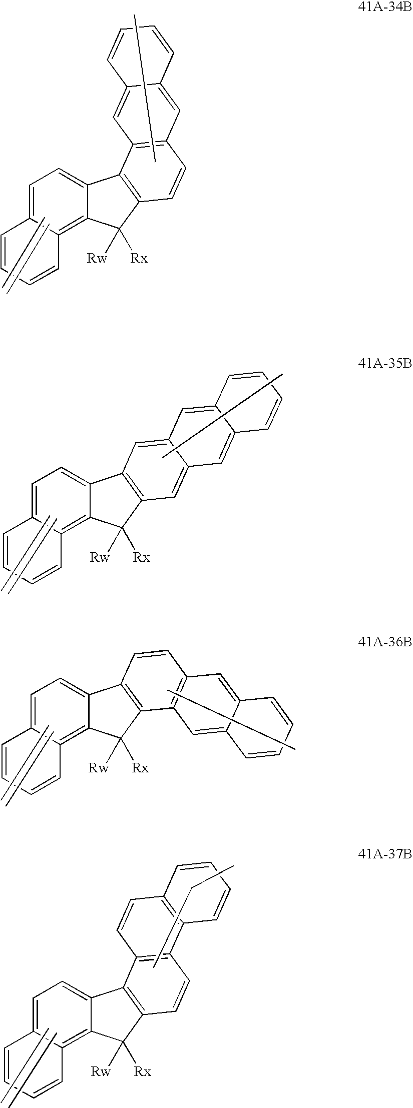

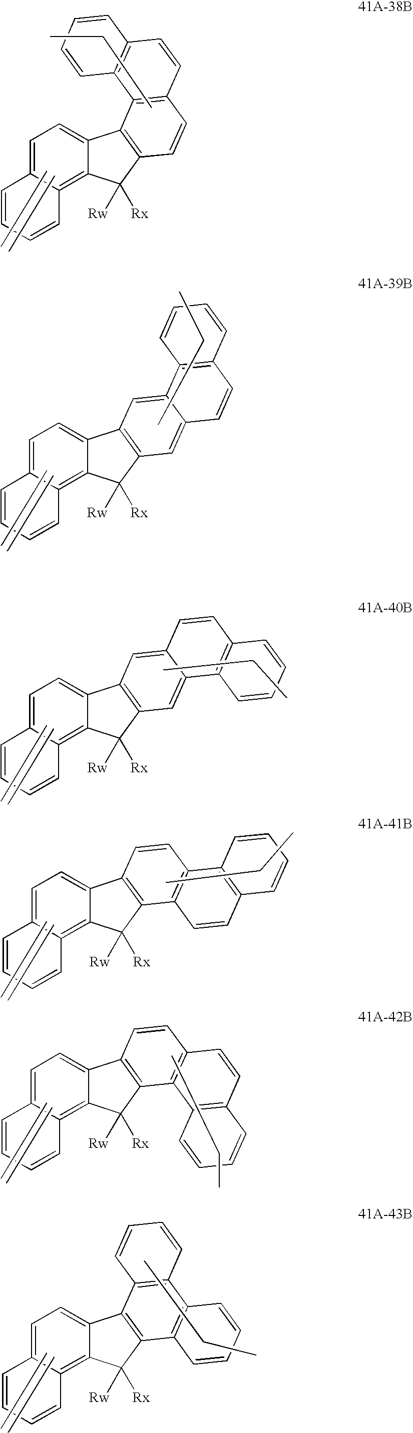

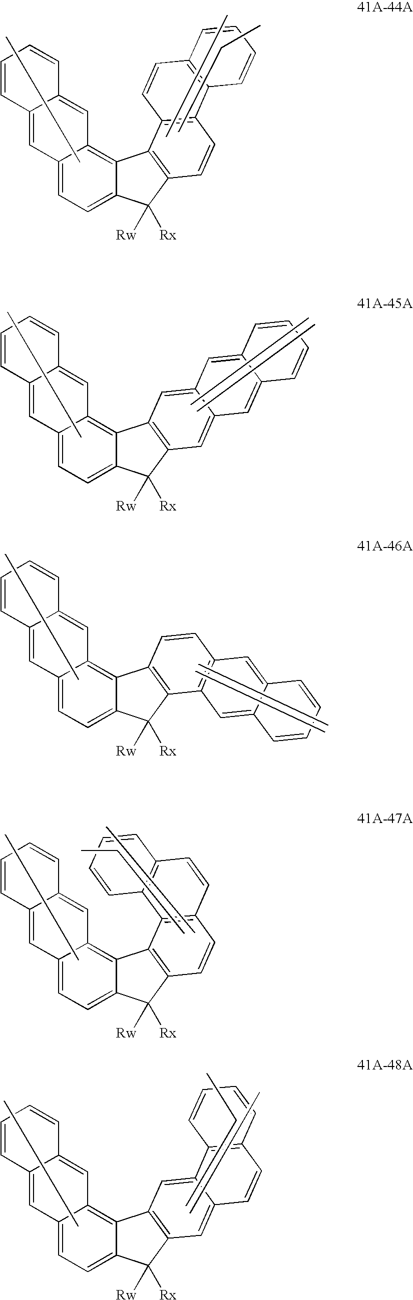

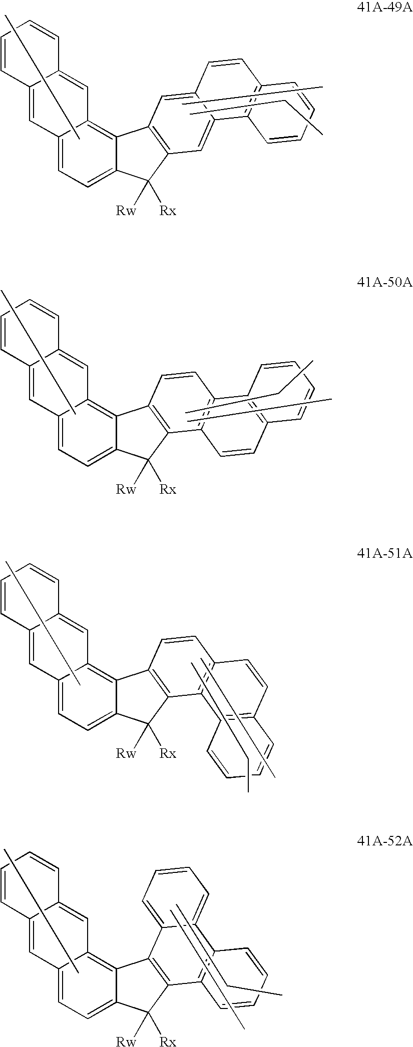

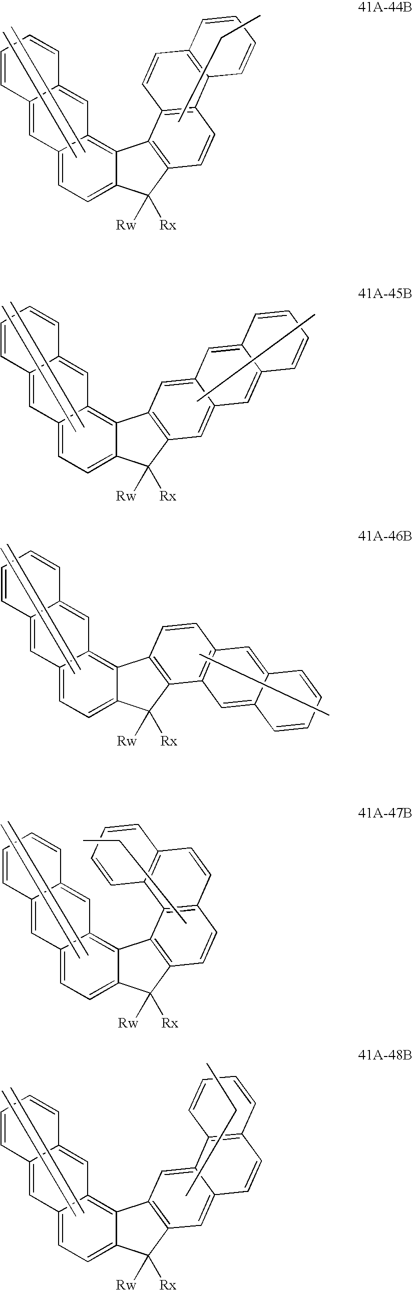

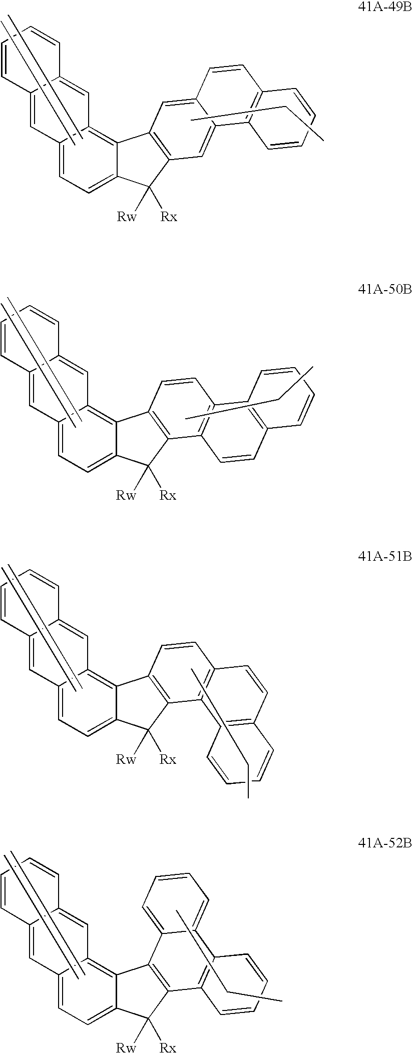

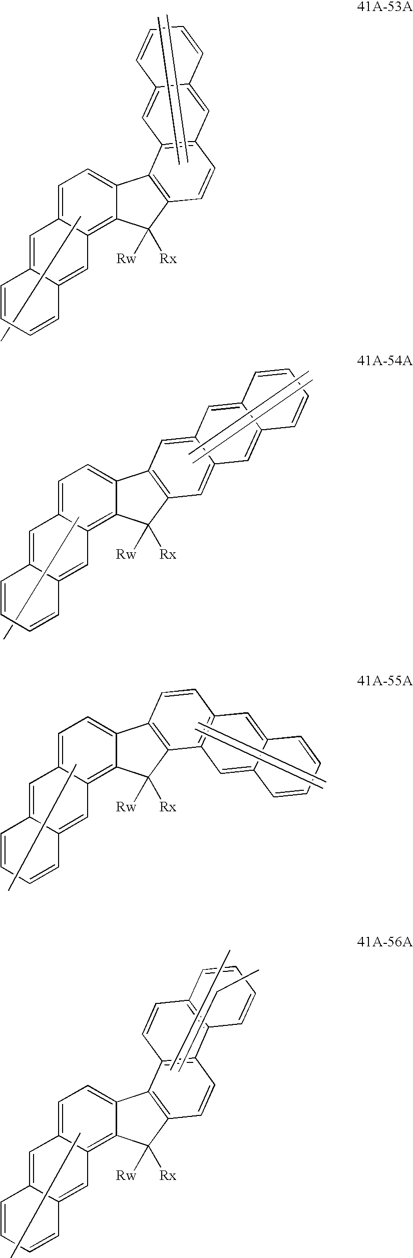

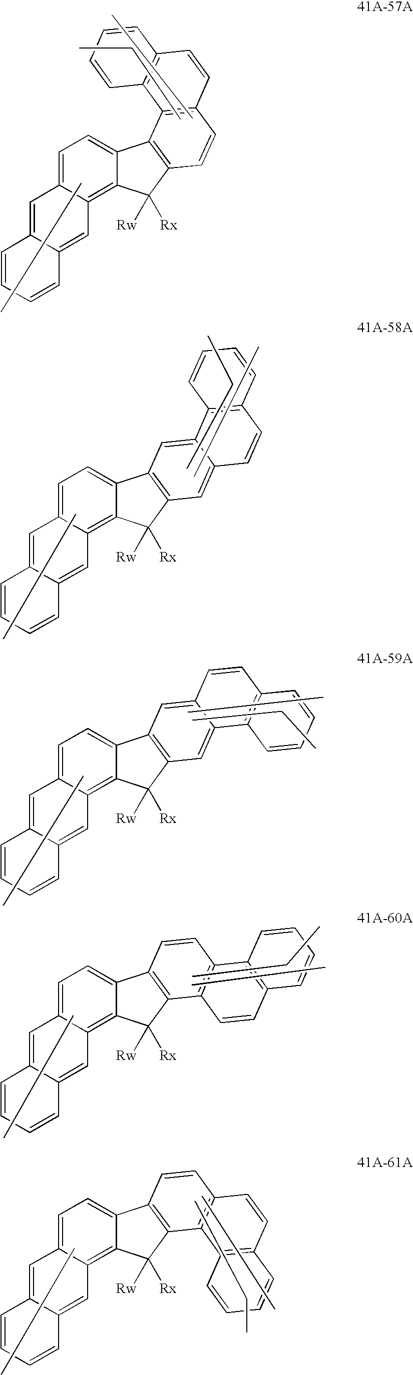

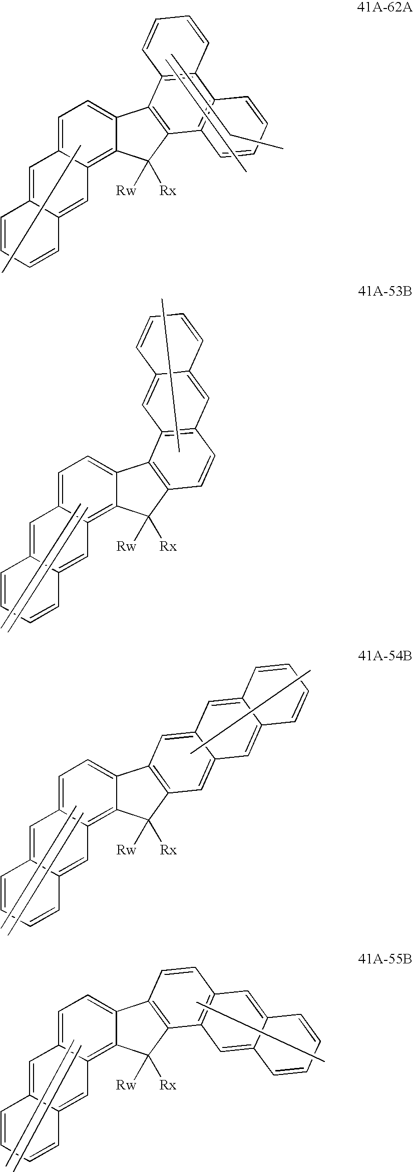

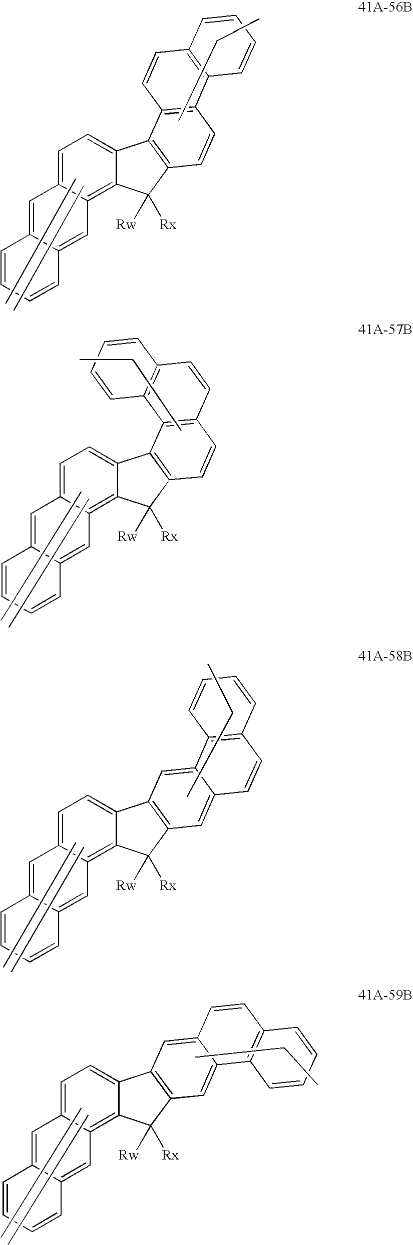

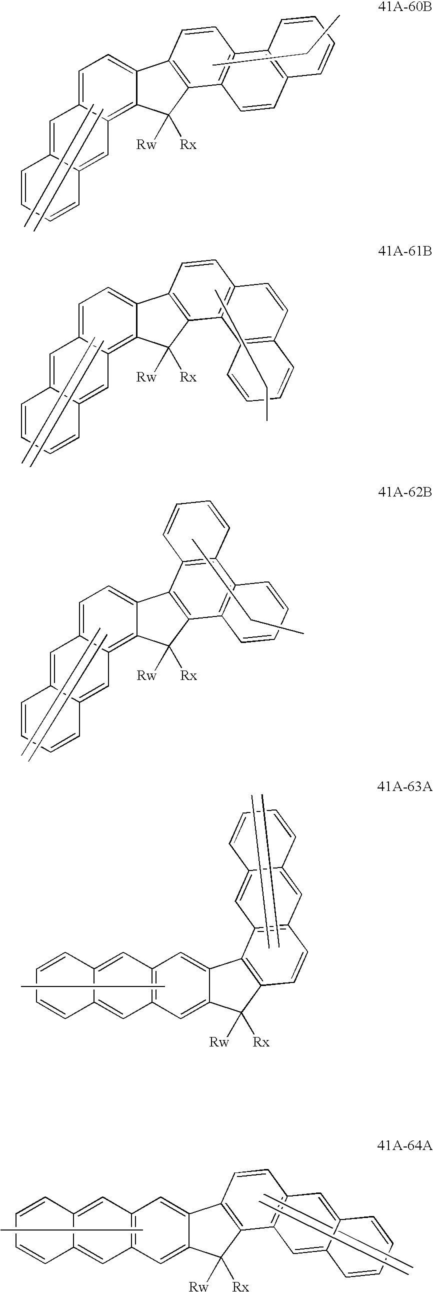

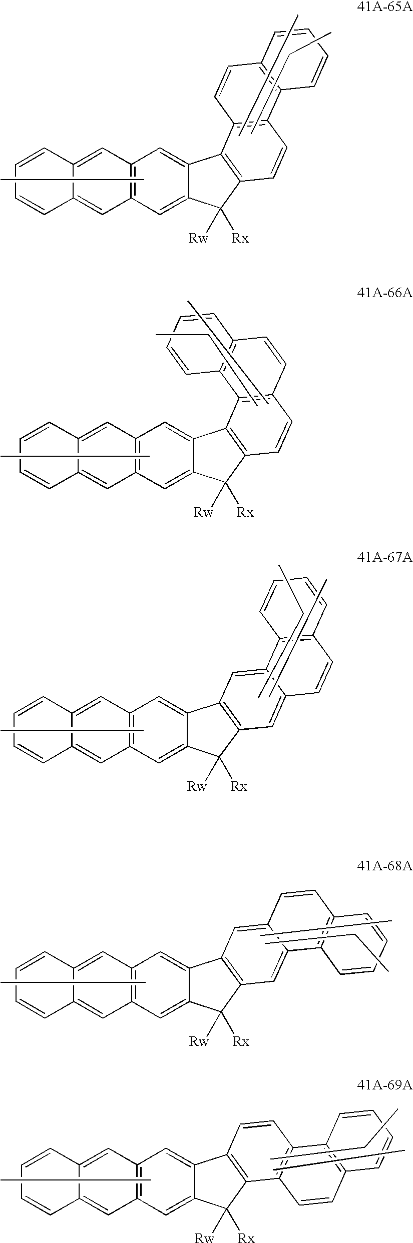

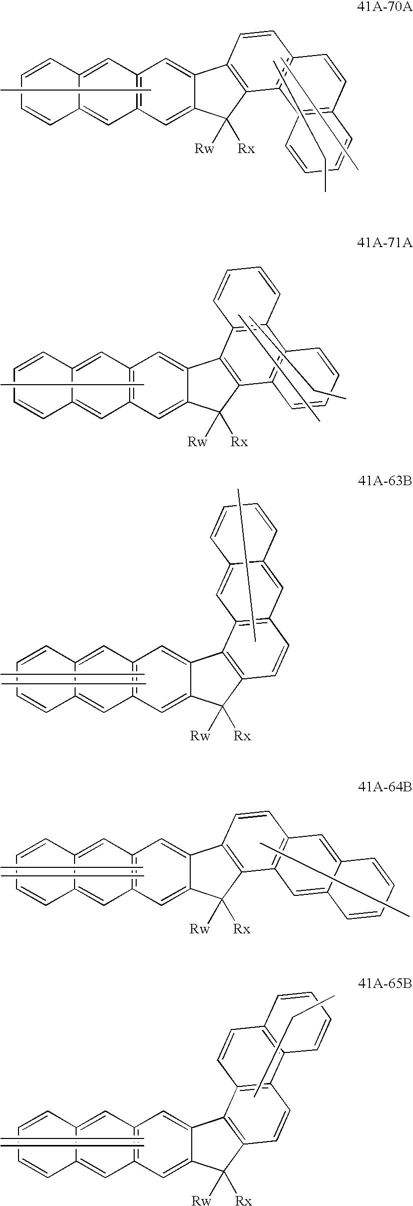

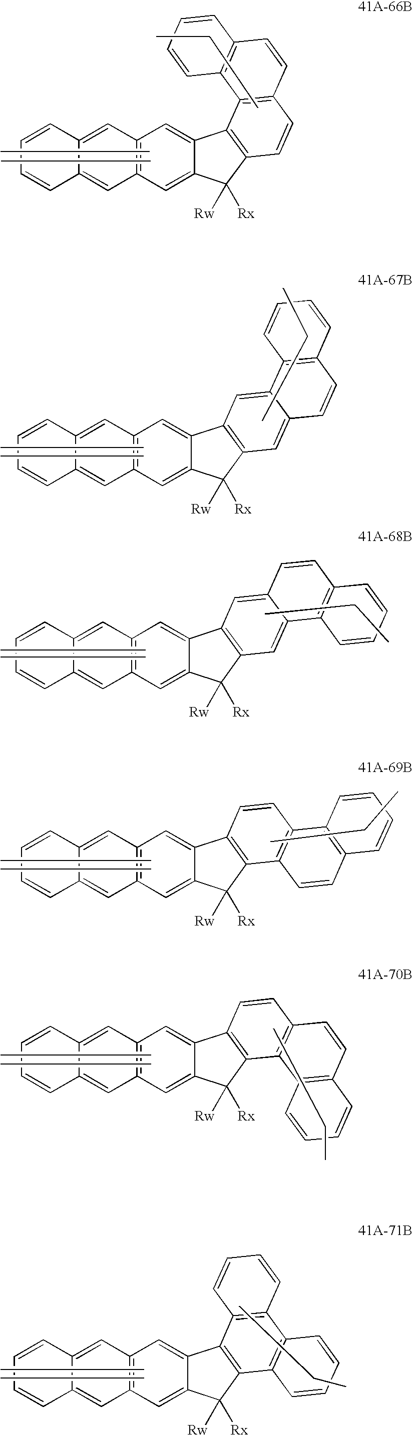

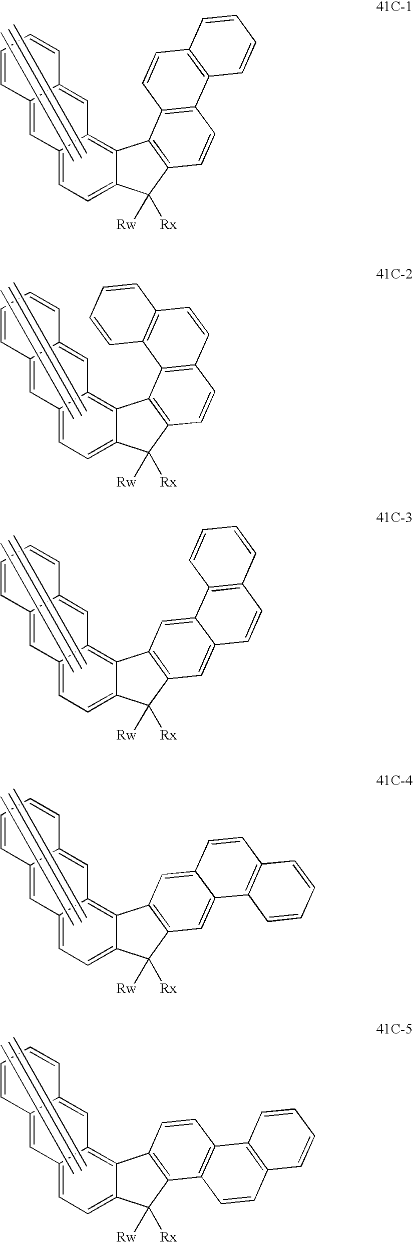

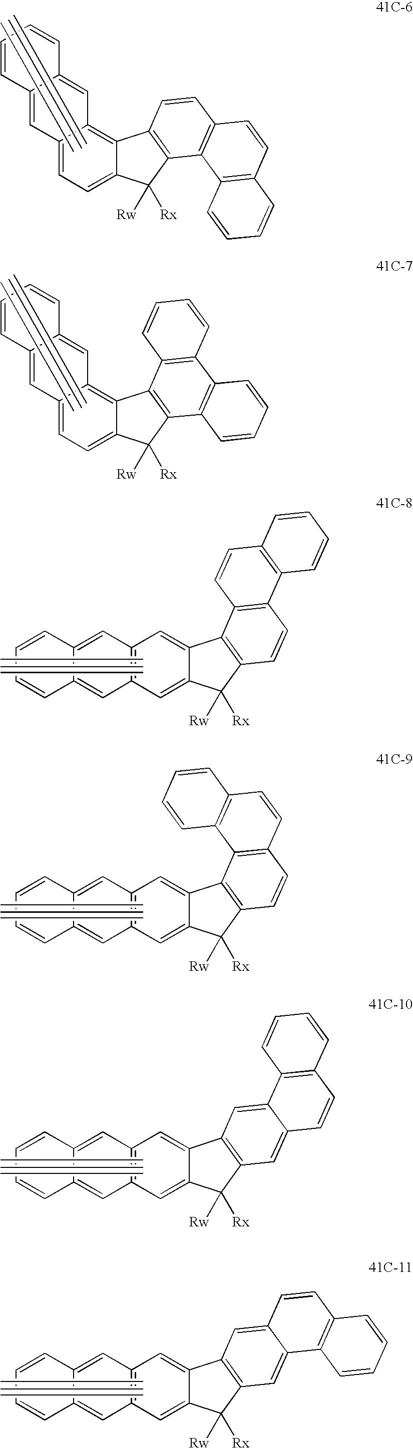

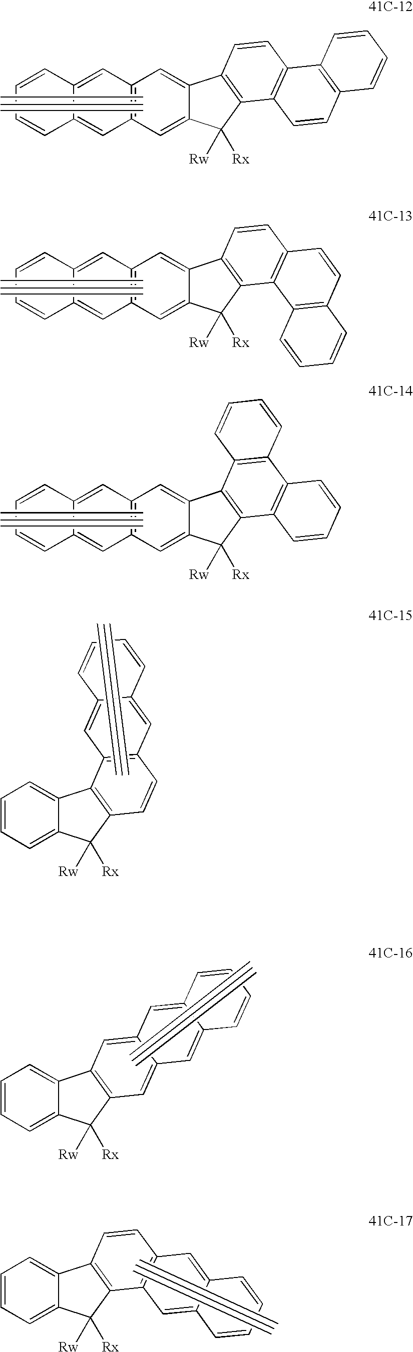

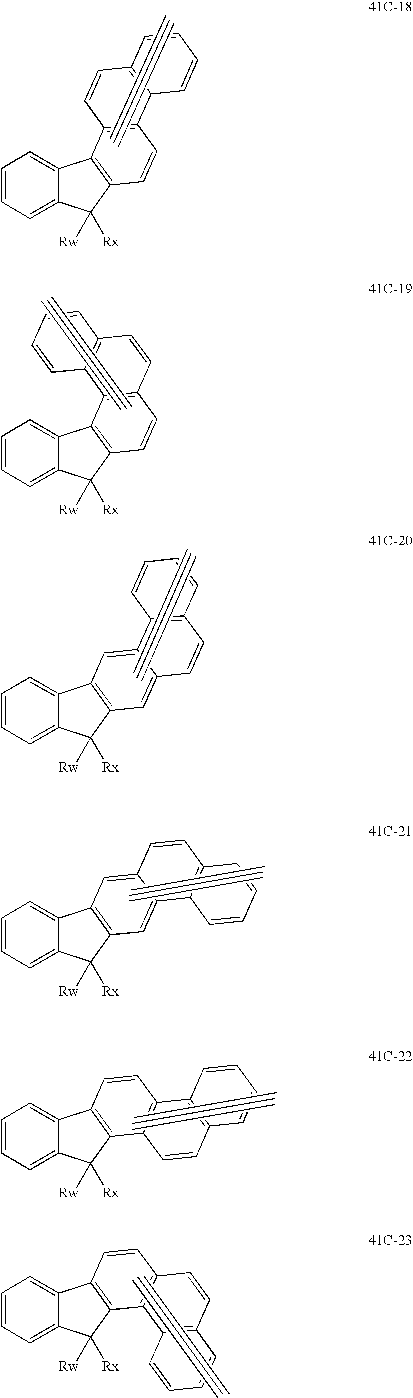

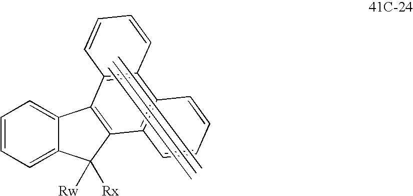

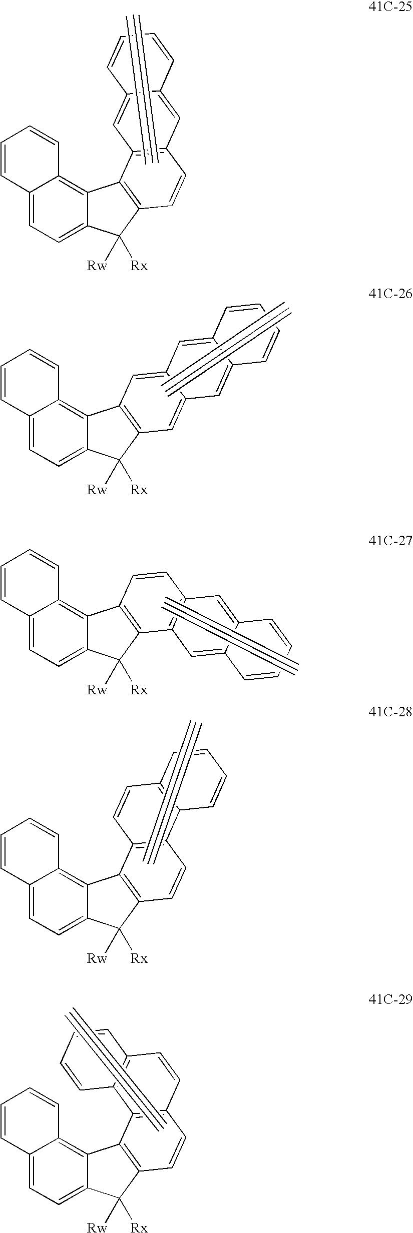

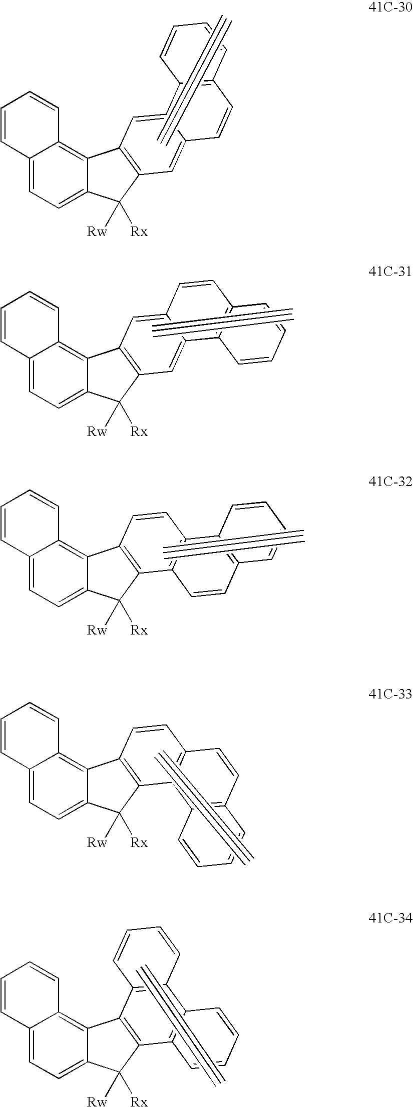

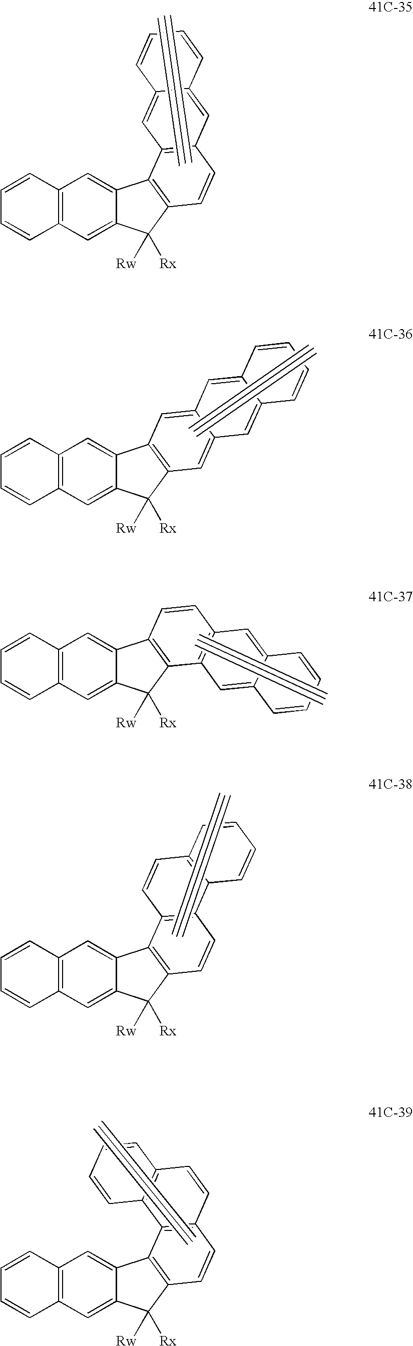

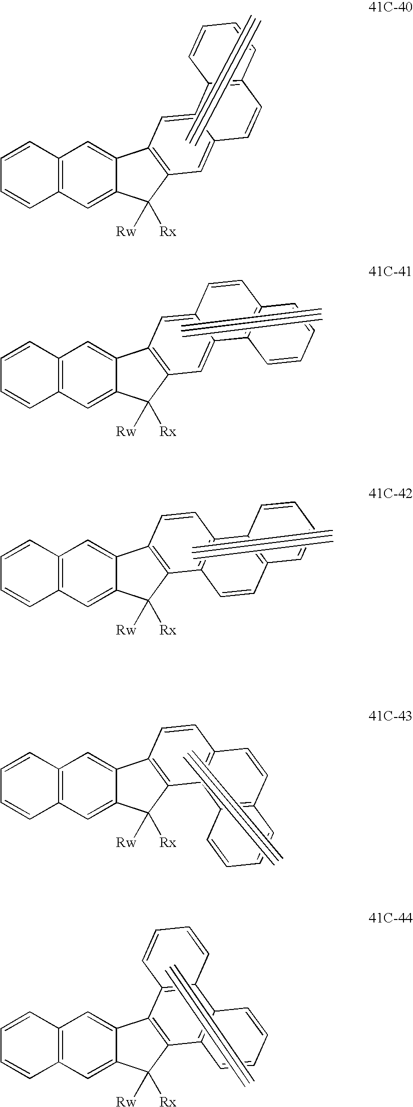

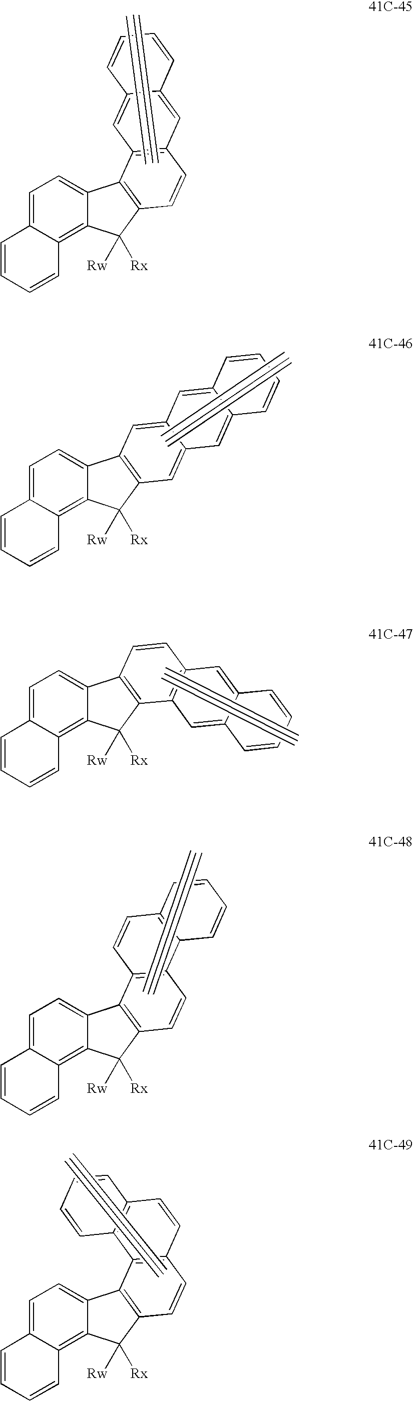

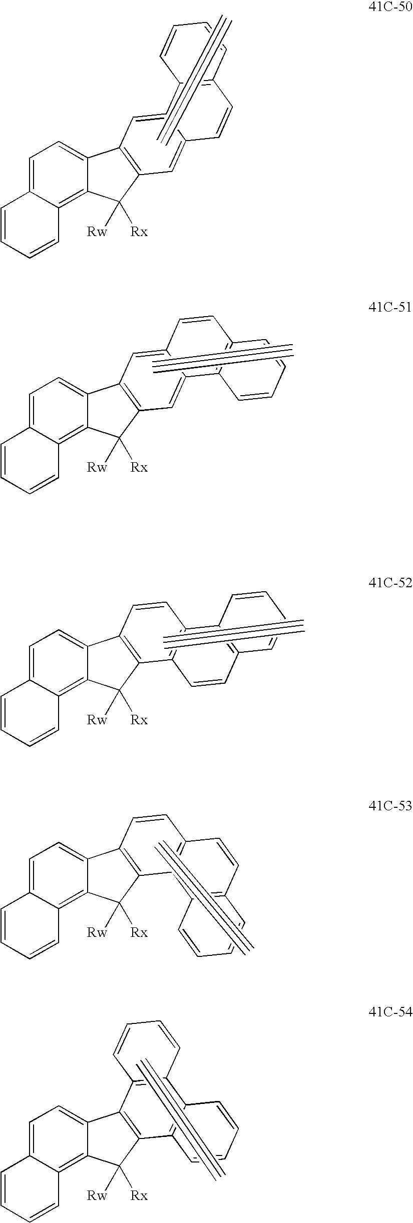

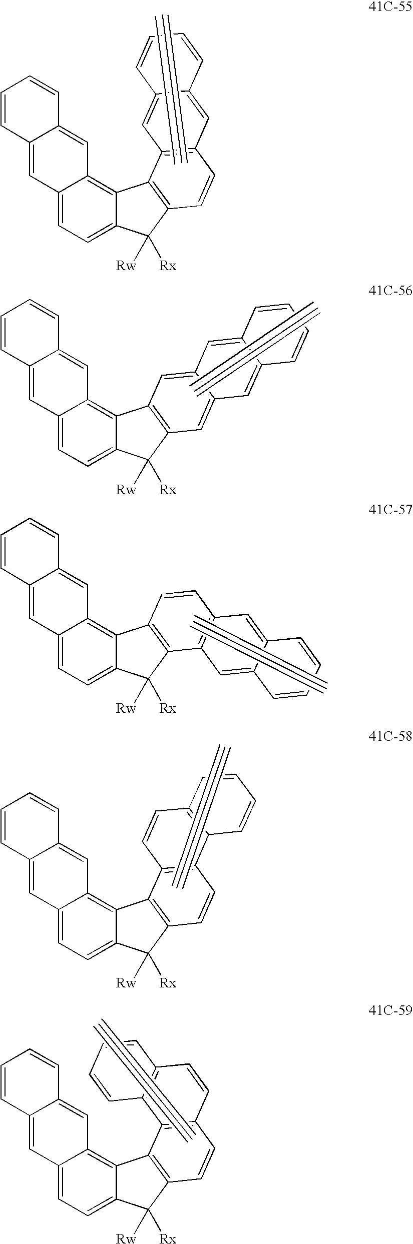

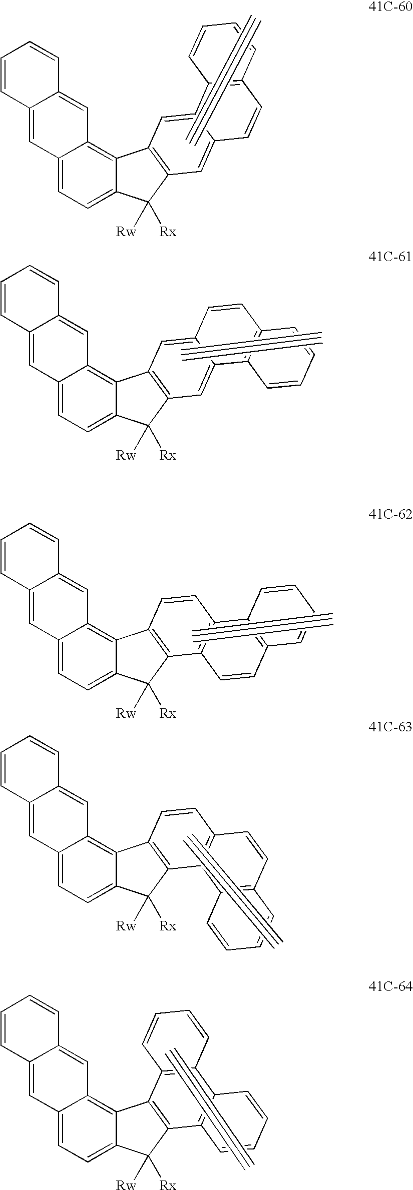

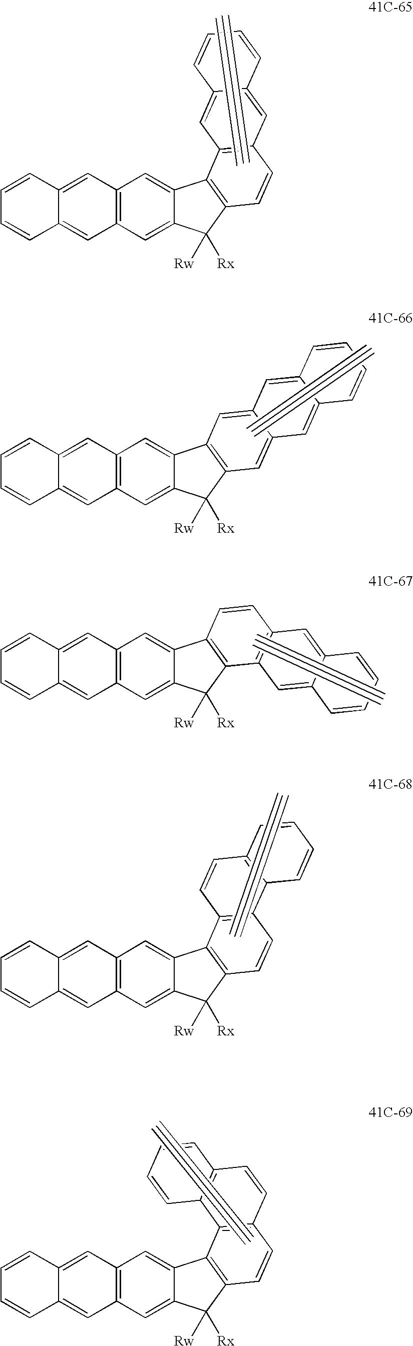

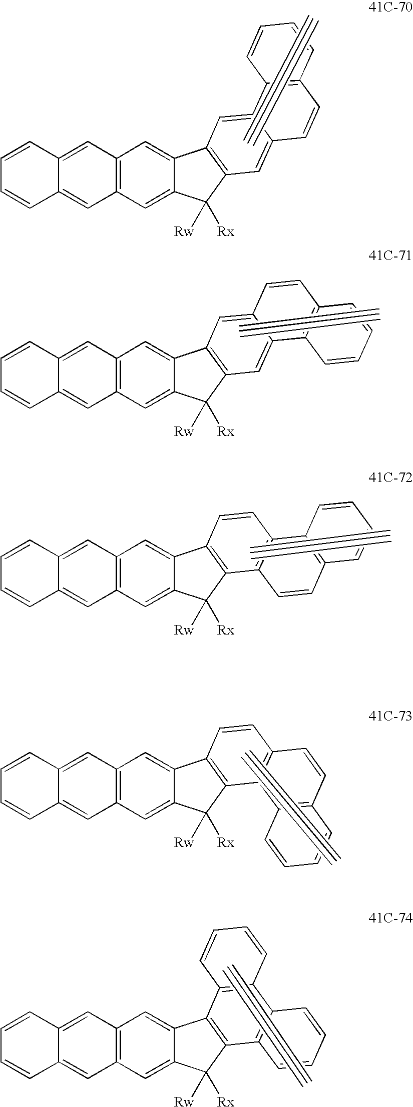

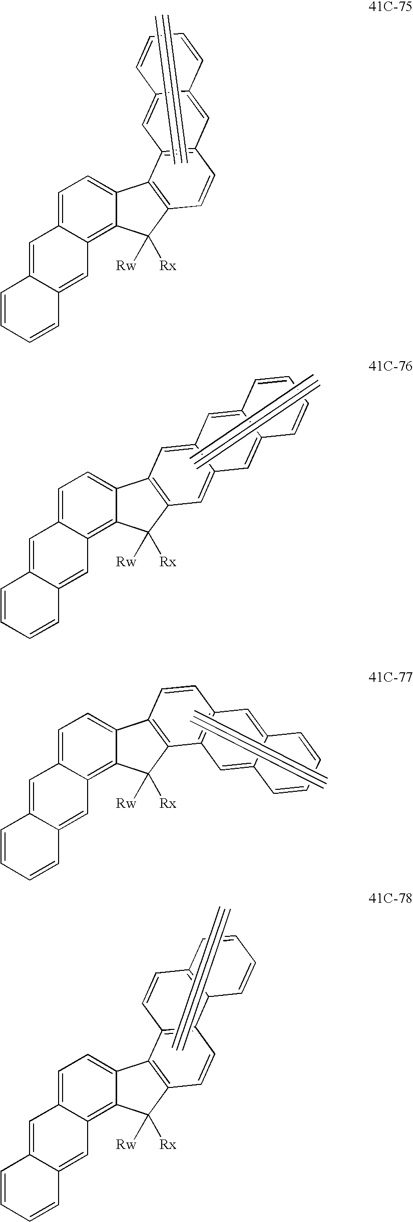

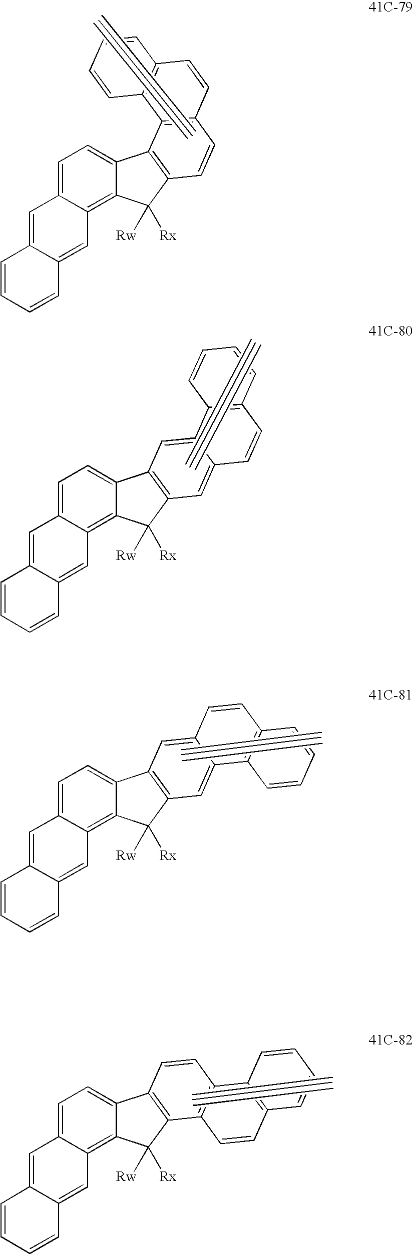

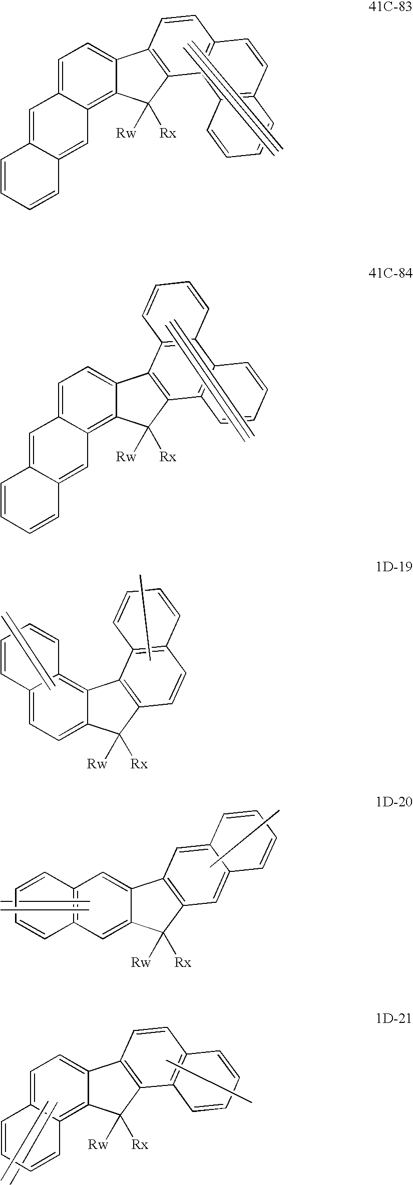

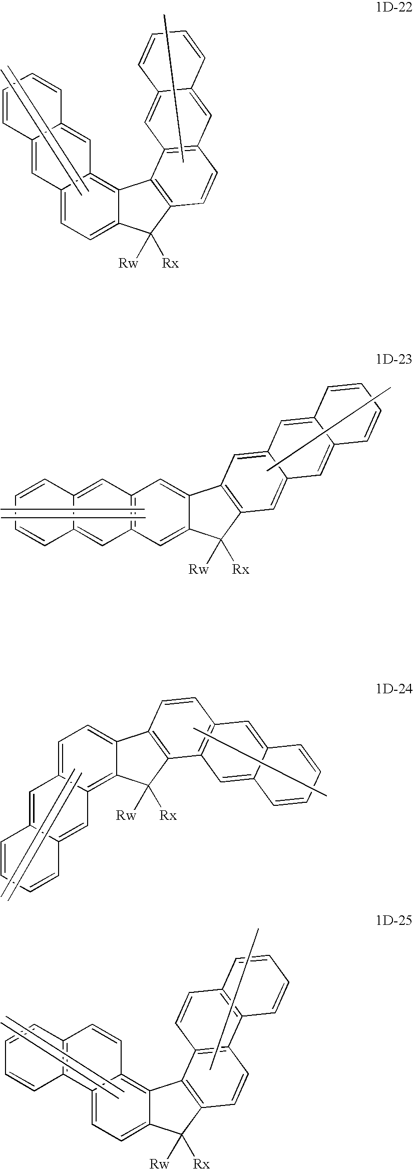

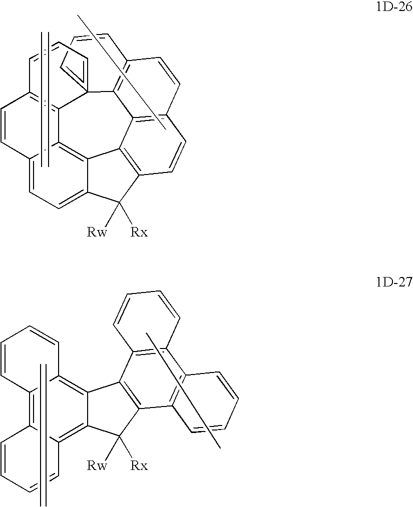

(wherein, Rw and Rx represent the same meanings as described above).

As the branched structure, the following formula (41-1) is more preferable.

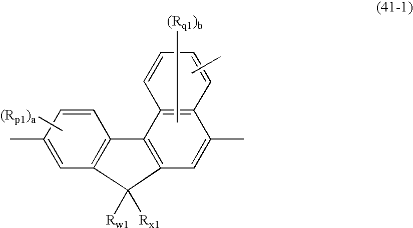

(wherein, Rₚ₁, R_{q1}, R_{w1}, Rₓ₁, a and b represent the same meanings as described above).

The ratio of the branched structure is preferably 0.1 mol % or more, further preferably in a range of 0.1 to 10 mol % based on a repeating unit of the above-mentioned formula (1).

An end group of the polymer compound of the present invention is preferably protected by a stable group since when a polymerization active group remains intact, there is a possibility of decrease in light emission property and life when an element is made. A structure containing a conjugation bond continuous with a conjugation structure of the main chain is preferable, and for example, a structure bonding to an aryl group or heterocyclic group via a carbon-carbon bond is exemplified. Specifically exemplified are substituents described in chemical formula 10 in Japanese Patent Application Laid-Open (JP-A) No. 9-45478, and the like.

In the polymer compound of the present invention, it is preferable that at least one of its molecule chain ends has an aromatic end group selected from mono-valent heterocyclic groups, mono-valent aromatic amine groups, mono-valent groups derived from heterocyclic coordination metal complexes and aryl groups having a formula weight of 90 or more. The aromatic end groups may be present singly or in combination. The ratio of end groups other than the aromatic end group is preferably 30% or less, more preferably 20% or less, further preferably 10% or less based on all end groups, and substantially no presence is more preferable, from the standpoint of a fluorescent property and element property. Here, the molecular chain end means an aromatic end group present at the end of a polymer compound according to the production method of the present invention, a leaving group of a monomer used for polymerization which does not leave in polymerization but remains at the end of a polymer compound, or a proton bonded instead of an aromatic end group though a leaving group of a polymer leaved in a monomer present at the end of a polymer compound. When a polymer compound of the present invention is produced using a leaving group of a monomer used for polymerization which does not leave in polymerization but remains at the end of a polymer compound, among these molecule chain ends, for example, a monomer having a halogen atom, as a raw material, then, there is a tendency of decrease of a fluorescent property and the like if a halogen remains at the end of a polymer compound, thus, it is preferable that a leaving group of a monomer does not substantially remain at the end.

In the polymer compound of the present invention, by sealing at least one of its molecule chain ends by an aromatic end group selected from mono-valent heterocyclic groups, mono-valent aromatic amine groups, mono-valent groups derived from heterocyclic coordination metal complexes and aryl groups having a formula weight of 90 or more, it is expected to impart various properties to the polymer compound. Specifically mentioned are an effect of elongating time necessary for decrease in luminance of an element, an effect of enhancing charge injectability, charge transporting property, light emission property and the like, an effect of reinforcing compatibility and mutual action between copolymers, an anchor-like effect, and the like.

As the mono-valent heterocyclic group, the above-mentioned groups are mentioned, and specifically, the following structures are exemplified.

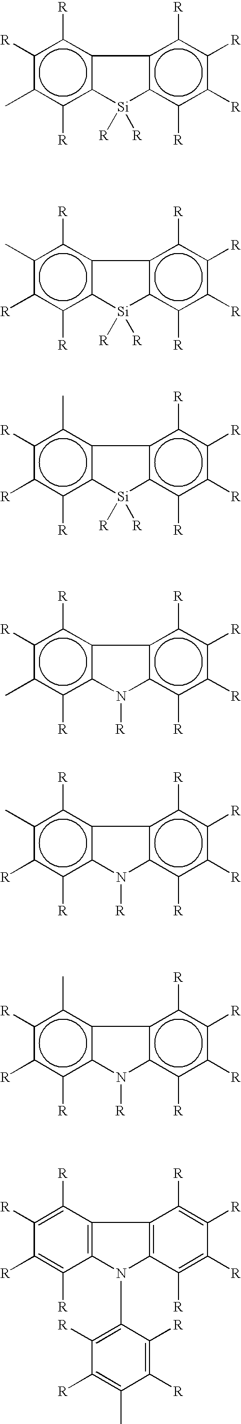

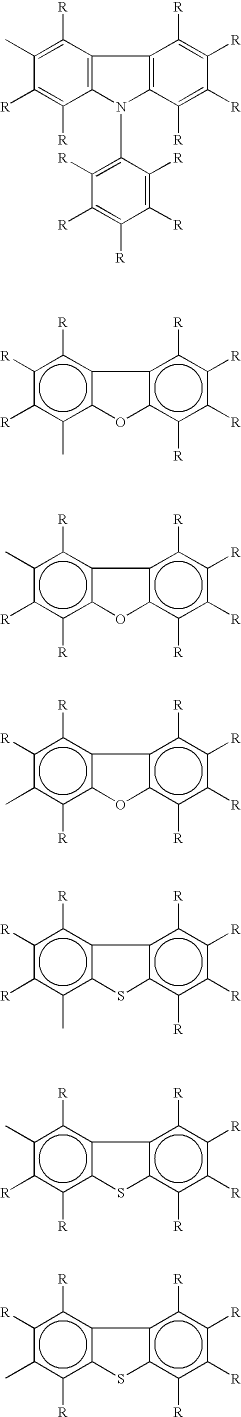

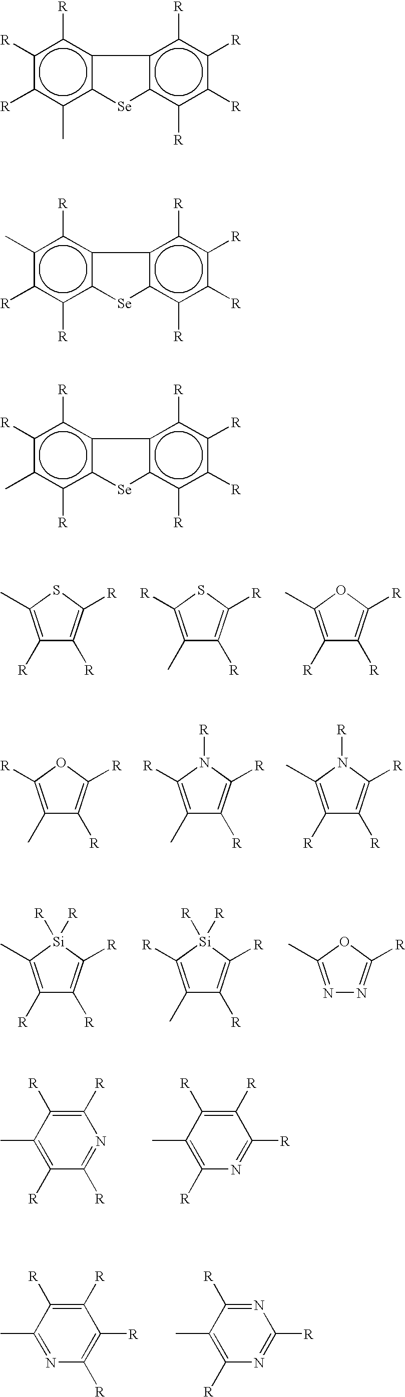

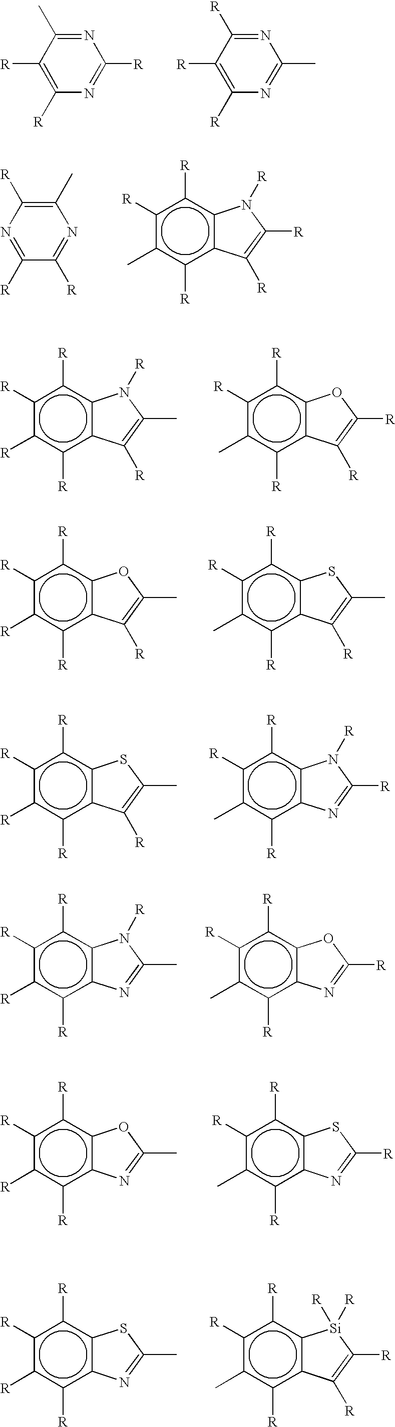

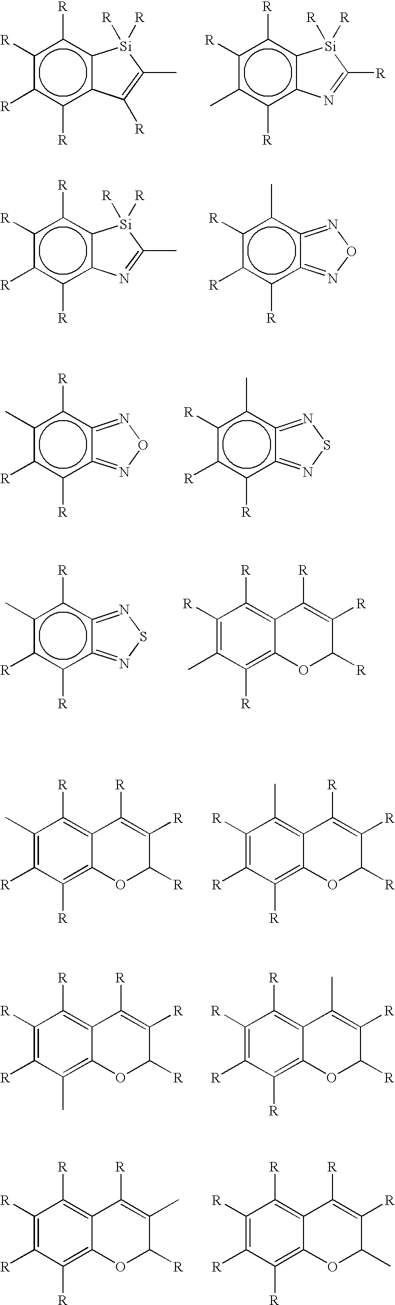

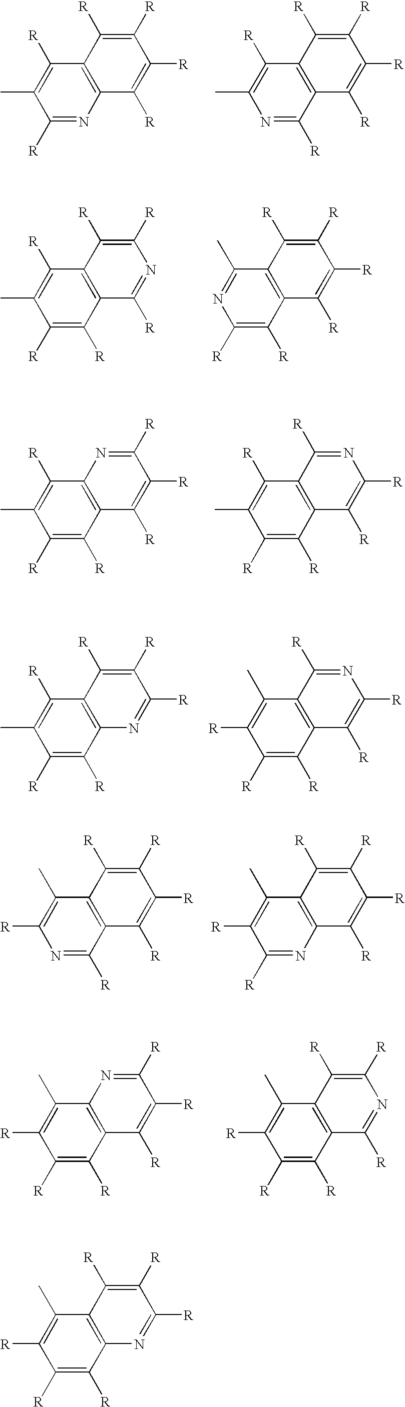

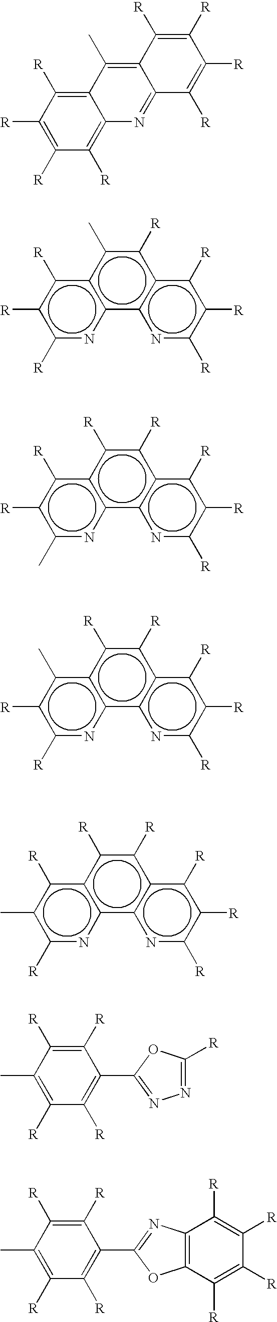

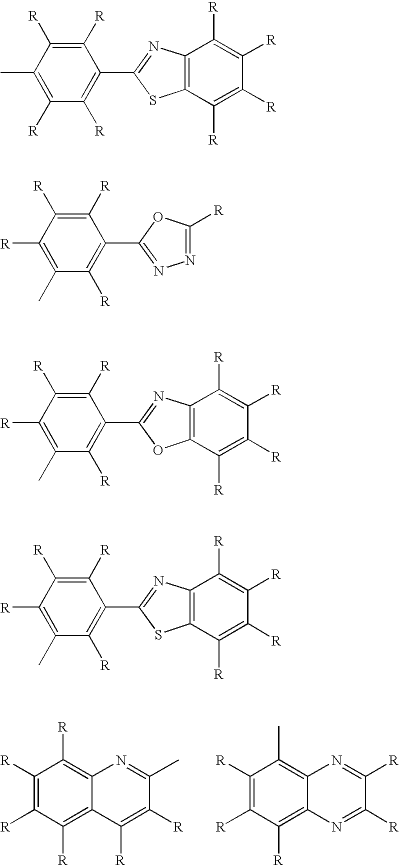

As the mono-valent aromatic amine group, exemplified are structures of the above-mentioned formula (13) in which one of two present connecting bonds is sealed by R.

As the mono-valent group derived from a heterocyclic coordination metal complex, exemplified are structures in which one of two present connecting bonds in a divalent group having the above-mentioned metal complex structure is sealed by R.

Among the end groups, the aryl group having a formula weight of 90 or more has usually about 6 to 60 carbon atoms. Here, the formula weight of the aryl group means a sum of products of the atomic weight and atomic number of elements in a chemical formula representing the aryl group.

The aryl group includes a phenyl group, naphthyl group, anthracenyl group, group having a fluorene structure, condensed ring compound group and the like.

Examples of the phenyl group sealing an end include:

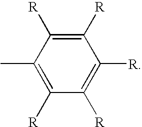

Examples of the naphthyl group sealing an end include:

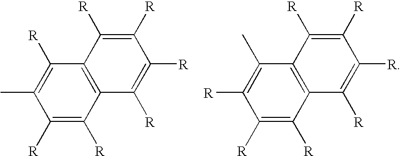

Examples of the anthracenyl group include:

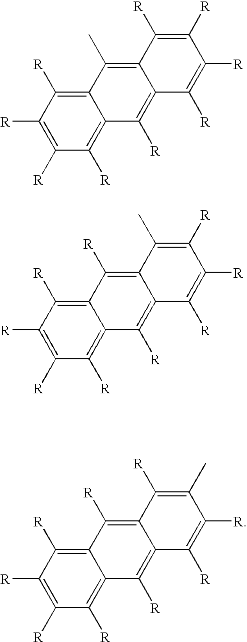

Examples of the group containing a fluorene structure include:

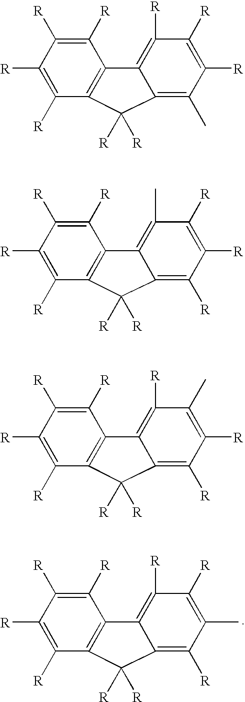

Examples of the condensed ring compound group include:

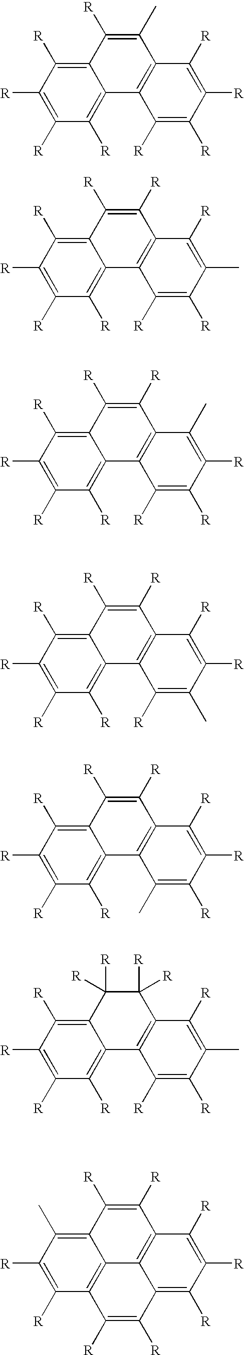

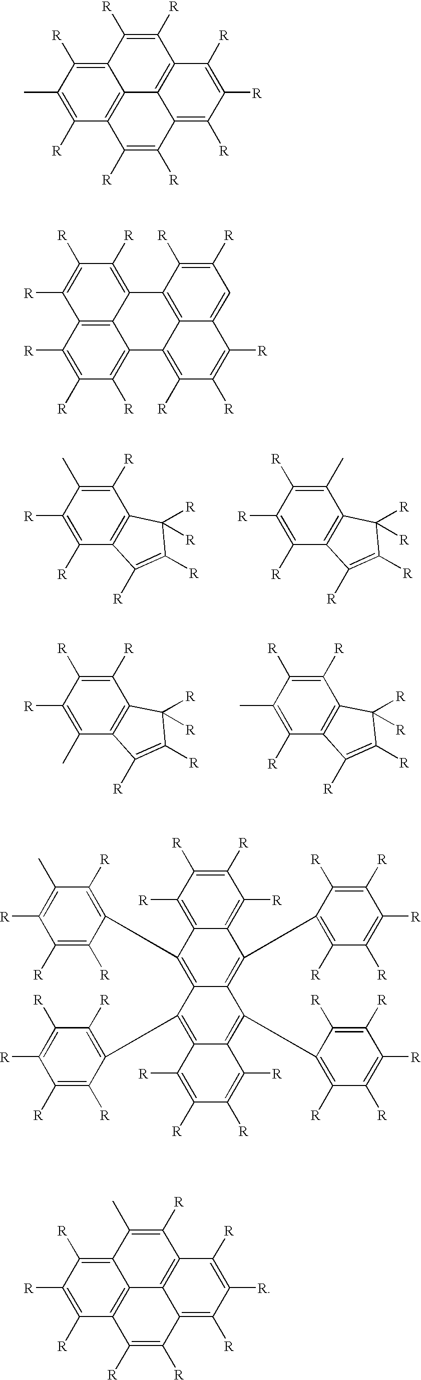

As the end group enhancing charge injectability, charge transporting property, preferable are mono-valent heterocyclic groups, mono-valent aromatic amine groups and condensed ring compound groups, and more preferable are mono-valent heterocyclic groups and condensed ring compound groups.

As the end group enhancing a light emission property, preferable are mono-valent groups derived from a naphthyl group, anthracenyl group, condensed ring compound group, heterocyclic ring coordination metal complex.

As the end group having an effect of elongating time required for decrease in luminance of an element, preferable are aryl groups having a substituent, and phenyl groups having 1 to 3 alkyl groups.

As the end group having an effect of enhancing compatibility and mutual action between polymer compounds, preferable are aryl groups having a substituent. By use of phenyl groups having a substituted alkyl group having 6 or more carbon atoms, an anchor-like effect can be performed. The anchor effect means an effect that an end group plays an anchor-like role on an agglomerate of a polymer, to enhance a mutual action.

As the group enhancing an element property, the following structures are preferable.

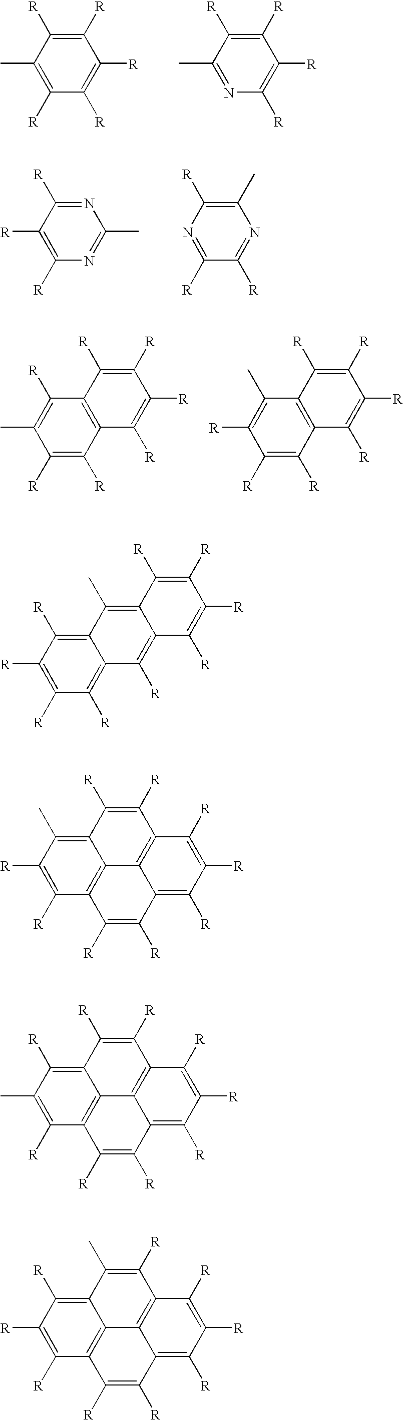

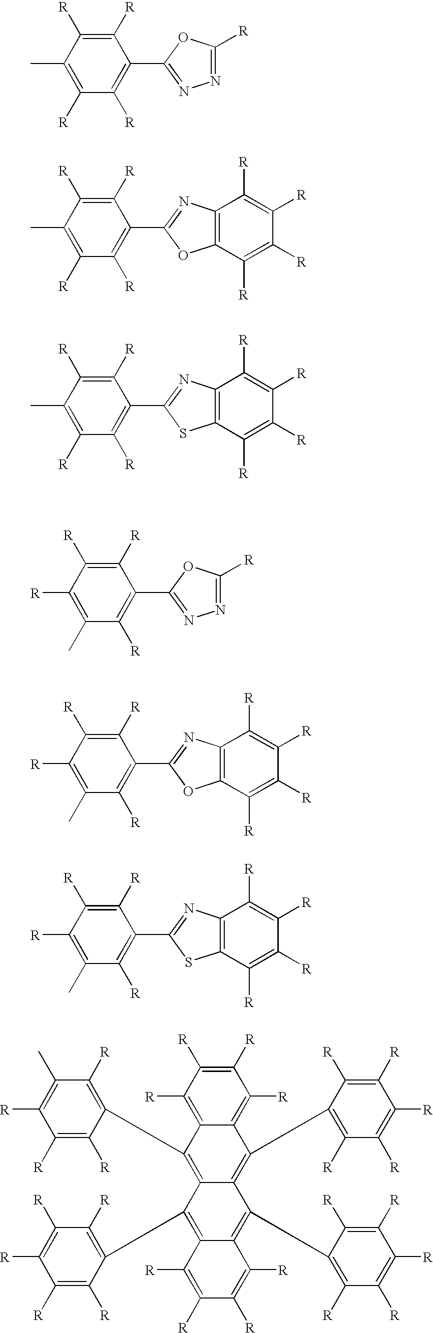

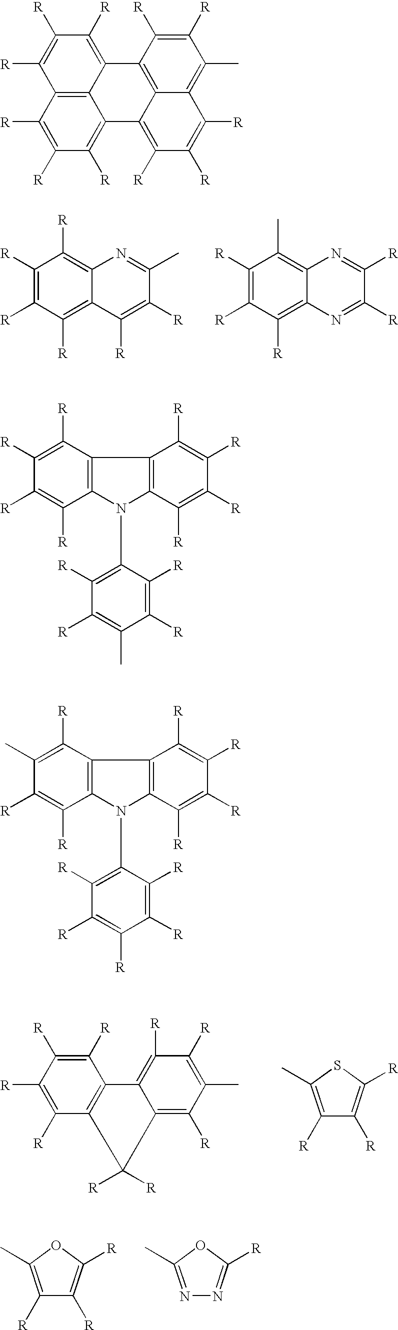

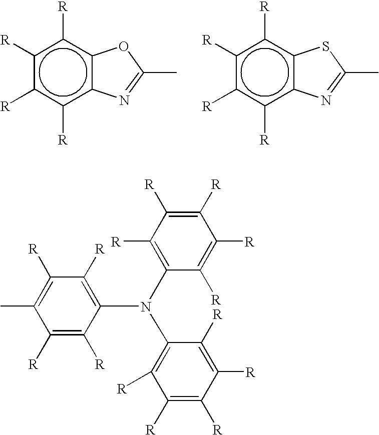

As R in the formulae, the above-mentioned examples for R are mentioned, and preferable hydrogen, cyano group, alkyl group having 1 to 20 carbon atoms, alkoxy group, alkylthio group, aryl group having 6 to 18 carbon atoms, aryloxy group, and heterocyclic group having 4 to 14 carbon atoms.

As the group enhancing an element property, the following structures are more preferable.

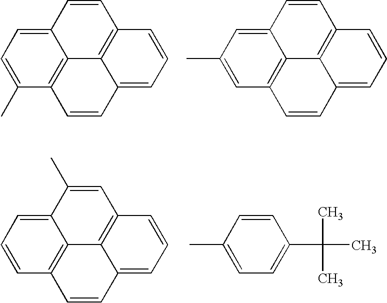

As the good solvent for a polymer compound of the present invention, chloroform, methylene chloride, dichloroethane, tetrahydrofuran, toluene, xylene, mesitylene, tetralin, decalin, n-butylbenzene and the like are exemplified. Depending on the structure and molecular weight of a polymer compound, a polymer compound usually can be dissolved in an amount of 0.1 wt % or more in these solvent.

Next, the method of producing a polymer compound of the present invention will be illustrated.

The polymer compound having a repeating unit of the formula (1) can be produced, for example, by using a compound of the formula (14) as one of raw materials and condensation-polymerizing this.

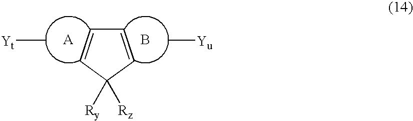

The polymer compound having a repeating unit of the formula (1-1), (1-2), (1-3) or (1-4) can be produced by using, as one of raw materials, a compound of the formula (14-1), (14-2), (14-3) or (14-4):

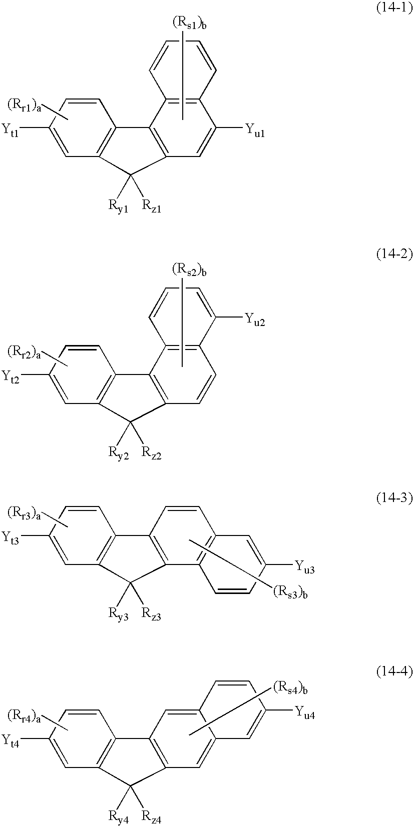

(wherein, Rᵣ₁, Rₛ₁, Rᵣ₂, Rₛ₂, Rᵣ₃, Rₛ₃, Rᵣ₄ and Rₛ₄ represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group. a represents an integer of 0 to 3, and b represents an integer of 0 to 5, and when a plurality of Rᵣ₁s, Rₛ₁s, Rᵣ₂s, Rₛ₂s, Rᵣ₃s, Rₛ₃s, Rᵣ₄s and Rₛ₄s are present, these may be the same or different. R_{y1}, R_{z1}, R_{y2}, R_{z2}, R_{y3}, R_{z3}, R_{y4} and R_{z4} represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group; imine residue, amide group, acid imide group, mono-valent heterocyclic group, carboxyl group, substituted carboxyl group or cyano group, and R_{y1} and R_{z1}, R_{y2} and R_{z2}, R_{y3} and R_{z3}, R_{y4} and R_{z4} may mutually bond to form a ring. Yₜ₁, Yᵤ₁, Yₜ₂, Yᵤ₂, Yₜ₃, Yᵤ₃, Yₜ₄ and Yᵤ₄ represent each independently a substituent correlatable with polymerization.)

The definitions and specific examples of the alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group and substituted carboxyl group in Rᵣ₁, Rₛ₁, Rᵣ₂, Rₛ₂, Rᵣ₃, Rₛ₃, Rᵣ₄, Rₛ₄, R_{y1}, R_{z1}, R_{y2}, R_{z2}, R_{y3}, R_{z3}, R_{y4} and R_{z4} are the same as the definitions and specific examples of the substituent when the above-mentioned aromatic hydrocarbon ring of the formula (1) has a substituent.

The substituents correlatable with polymerization in Yₜ₁, Yᵤ₁, Yₜ₂, Yᵤ₂, Yₜ₃, Yᵤ₃, Yₜ₄ and Yᵤ₄ are preferably selected each independently from halogen atoms, alkylsulfonate groups, arylsulfonate groups and arylalkylsulfonate groups since, then, synthesis thereof is easy and the compound can be used as a raw material for various polymerization reactions.

In the formula (14-1), (14-3) or (14-4), Yₜ₁, Yᵤ₁, Yₜ₃, Yᵤ₃, Yₜ₄ and Yᵤ₄ represent preferably a bromine atom since, then, synthesis thereof is easy, functional group conversion is easy and the compound can be used as a raw material for various polymerization reactions.

In the formula (14-1), (14-3) or (14-4), it is preferable that a=b=a′=b′=0 from the standpoint of enhancing heat resistance.

Of them, a compound of the formula (14-1) is preferable from the standpoint of easiness of synthesis of the compound, and a compound of the following formula (26) is preferable from the standpoint of solubility in a solvent when a polymer is made.

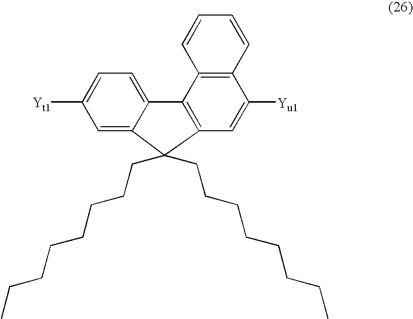

(wherein, Yₜ₁ and Yᵤ₁ represent the same meanings as described above).

In producing a dendrimer or a polymer compound having branching in the main chain and thus having 3 or more end parts, it can be produced by using a compound of the following formula (14B) as one of raw materials and polymerizing this.

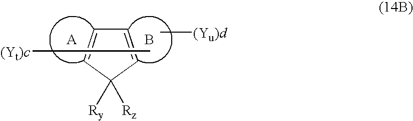

(wherein, R_{y}, R_{z}, Yₜ and Yᵤ represent the same meanings as described above. c represents 0 or a positive integer, d represents 0 or a positive integer, and 3≦c+d≦6, preferably 3≦c+d≦4. When a plurality of Yₜs and Yᵤs are present, these may be the same or different).

A polymer compound containing a repeating unit of the above-mentioned formula (2) can be produced, for example, by condensation-polymerizing a compound of the following formula (14C).

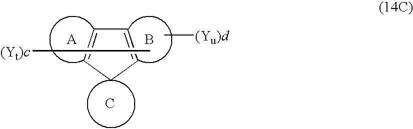

(wherein, ring A, ring B and ring C represent the same meanings as described above. Yₜ and Yᵤ represent the same meanings as described above. c represents 0 or a positive integer, d represents 0 or a positive integer, and 2≦c+d≦6). As the raw material of the formula (14B), compounds of the following formulae (14-5), (14-6) and (14-7) are preferably mentioned.

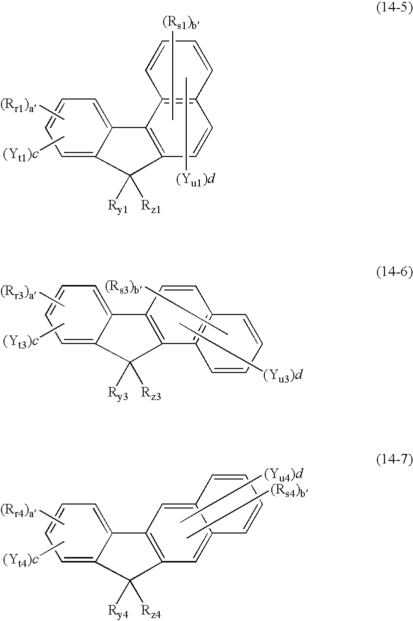

(wherein, Rᵣ₁, Rₛ₁, Rᵣ₂, Rₛ₂, Rᵣ₃, Rₛ₃, Rᵣ₄, Rₛ₄, R_{y1}, R_{z1}, R_{y2}, R_{z2}, R_{y3}, R_{z3}, R_{y4}, R_{z4}, Yₜ₁, Yᵤ₁, Yₜ₃, Yᵤ₃, Yₜ₄ and Yᵤ₄ represent the same meanings as described above, a′ represents an integer of 0 to 4, b′ represents an integer of 0 to 5, c represents an integer of 0 to 3, d represents an integer of 0 to 5, a′+c≦4, b′+d≦6, and 3≦c+d≦6. When a plurality of Rᵣ₁s, Rₛ₁, Rᵣ₂s, Rₛ₂s, Rᵣ₃s, Rₛ₃s, Rᵣ₄s, Rₛ₄s, R_{y1}s, R_{z1}s, Yₜ₁s, Yᵤ₁s, Yₜ₃s, Yᵤ₃, Yₜ₄s and Yᵤ₄s are present, these may be the same or different).

In the method producing a polymer compound of the present invention, the raw material monomer preferably contains a compound of the above-mentioned formula (14B) or (14-5) to (14-7) since, then, a polymer compound having higher molecular weight is obtained. In this case, the content of the compound of the above-mentioned formula (14B) or (14-5) to (14-7) is preferably in a range from 0.1 to 10 mol %, further preferably 0.1 to 1 mol %.

When the polymer compound of the present invention has a repeating unit other than the formula (1), polymerization may be advantageously carried out in the co-existence of a compound having two substituents correlated with polymerization as the repeating unit other than the formula (1).

As the compound having two polymerizable substituents as the repeating unit other than a repeating unit of the formula (1), compounds of the following formulae (21) to (24) are exemplified.

By polymerizing a compound of any of the following formulae (21) to (24), in addition to the above-mentioned compound of the formula (14):

Y₅—Ar₁—Y₆ (21)

Y₇Ar₂—X₁_{ff}Ar₃—Y₈ (22)

Y₉—Ar₄—X₂—Y₁₀ (23)

Y₁₁—X₃—Y₁₂ (24)

(wherein, Ar₁, Ar₂, Ar₃, Ar₄, ff, X₁, X₂ and X₃ represent the same meanings as described above. Y₅, Y₆, Y₇, Y₈, Y₉, Y₁₀, Y₁₁ and Y₁₂ represent each independently a polymerizable substituent.), a polymer compound can be produced having at least one unit of (3), (4), (5) or (6) in addition to a unit of the formula (1).

The polymer compound having a sealed end can be produced by polymerization using, as a raw material, a compound of the following formula (25) or (27) in addition to the above-mentioned formulae (14), (15-1), (21) to (24).

E₁-Y₁₃ (25)

E₂-Y₁₄ (27)

(wherein, E1 and R2 represent a mono-valent heterocyclic group, aryl group having a substituent or mono-valent aromatic amine group, and Y₁₃ and Y₁₄ represent each independently a substituent correlatable with polymerization).

As the compound having two substituents correlated with condensation corresponding to the above-mentioned formula (13) as the repeating unit other than a repeating unit of the above-mentioned formula (1), compounds of the following formula (15-1) are mentioned.

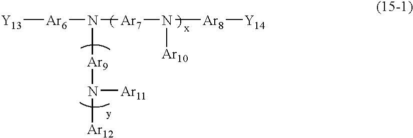

(wherein, the definitions and preferable examples of Ar₆, Ar₇, Ar₈, Ar₉, Ar₁₀, Ar₁₁, Ar₁₂, x and y are the same as described above. Y₁₃ and Y₁₄ represent each independently a substituent correlated with polymerization).

The substituent correlated with polymerization in the production method of the present invention includes a halogen atom, alkylsulfonate group, arylsulfonate group, arylalkylsulfonate group, borate group, sulfoniummethyl group, phosphoniummethyl group, phosphonatemethyl group, methyl monohalide group, —B(OH)₂, formyl group, cyano group, vinyl group and the like.

Here, the halogen atom include a fluorine atom, chlorine atom, bromine atom and iodine atom.

Examples of the alkylsulfonate group include a methanesulfonate group, ethanesulfonate group, trifluoromethanesulfonate group and the like, examples of the arylsulfonate group include a benzenesulfonate group, p-toluenesulfonate group and the like, and examples of the arylsulfonate group include a benzylsulfonate group and the like.

As the borate group, groups of the following formulae are exemplified.

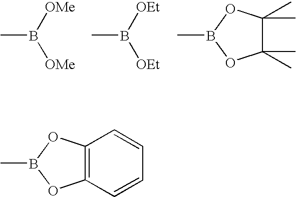

In the formulae, Me represents a methyl group and Et represents an ethyl group.

As the sulfoniummethyl group, groups of the following formulae are exemplified.

—CH₂S⁺Me₂X⁻, —CH₂S⁺Ph₂X⁻

(wherein, X represents a halogen atom and Ph represents a phenyl group.)

As the phosphoniummethyl group, groups of the following formula are exemplified.

—CH₂P⁺Ph₃X⁻ (X represents a halogen atom.)

As the phosphonatemethyl group, groups of the following formula are exemplified.

—CH₂PO(OR′)₂ (X represents a halogen atom, R′ represents an alkyl group, aryl group or arylalkyl group.)

As the methyl monohalide group, a methyl fluoride group, methyl chloride group, methyl bromide group and methyl iodide group are exemplified.

A preferable substituent as the substituent correlated with condensation polymerization differs depending on the kind of the polymerization reaction, and in the case of use of a 0-valent nickel complex such as, for example, Yamamoto coupling reaction and the like, mentioned are halogen atoms, alkylsulfonate groups, arylsulfonate group or arylakylsulfonate groups. In the case of use of a nickel catalyst or palladium catalyst such as Suzuki coupling reaction and the like, mentioned are alkylsulfonate groups, halogen atoms, borate groups, —B(OH)₂ and the like.

The production method of the present invention can be carried out, specifically, by dissolving a compound having a plurality of substituents correlated with polymerization, as a monomer, in an organic solvent if necessary, and using, for example, an alkali and a suitable catalyst, at temperatures of not lower than the melting point and not higher than the boiling point of the organic solvent. For example, known methods can be used described in “Organic Reactions”, vol. 14, p. 270 to 490, John Wiley & Sons, Inc., 1965, “Organic Syntheses”, Collective Volume VI, p. 407 to 411, John Wiley & Sons, Inc., 1988, Chem. Rev., vol. 95, p. 2457 (1995), J. Organomet. Chem., vol. 576, p. 147 (1999), Makromol. Chem., Macromol. Symp., vol. 12, p. 229 (1987), and the like.

In the method of condensation polymerization in the method of producing a polymer compound of the present invention, a known condensation reaction can be used depending on the substituent correlated with condensation polymerization of a compound of the above-mentioned formula (14), (14-1), (14-2), (14-3), (14-4), (14B), (14C), (14-5), (14-6), (14-7), (21), (22), (23), (24), (25), (26), (27) or (15-1).

When the polymer compound of the present invention generates a double bond in condensation polymerization, for example, a method described in JP-A No. 5-202355 is mentioned. Namely, polymerization by a Wittig reaction of a compound having a formyl group and a compound having a phosphoniummethyl group, or of a compound having a formyl group and a phosphoniummethyl group, polymerization by a Heck reaction of a compound having a vinyl group and a compound having a halogen atom, polycondensation by a dehydrohalogenation method of a compound having two or more methyl halide groups, polycondensation by a sulfonium salt decomposition method of a compound having two or more methylsulfonium groups, polymerization by a Knoevenagel reaction of a compound having a formyl group and a compound having a cycno group, polymerization by a McMurry reaction of a compound having two or more formyl groups, and the like, are exemplified.

When the polymer compound of the present invention generates a triple bond in the main chain by condensation polymerization, for example, a Heck reaction, Sonogashira reaction can be utilized.

In the case of generating no double bond or triple bond, for example, a method of polymerization by a Suzuki coupling reaction from the corresponding monomer, a method of polymerization by a Grignard method, a method of polymerization by a Ni(0) complex method, a method of polymerization by an oxidizer such as FeCl₃ and the like, a method of electrochemical oxidation polymerization, a method by decomposition of an intermediate polymer having a suitable leaving group, and the like, are exemplified.

Of them, polymerization by a Wittig reaction, polymerization by a Heck reaction, polymerization by a Knoevenagel reaction, method of polymerization by a Suzuki coupling reaction, method of polymerization by a Grignard reaction and method of polymerization by a nickel 0-valent complex are preferable since the structure can be controlled easily. Of them, the method of polymerization by a nickel 0-valent complex is preferable from the standpoint of easiness of molecular weight control and from the standpoint of heat resistance and element properties such as life of polymer LED, light emission initiation voltage, current density, increase of voltage in driving, and the like.

Since the polymer compound of the present invention has an asymmetrical skeleton as shown in the formula (1) in its repeating unit, the direction of a repeating unit is present in the polymer compound. In the case of control of the direction of a repeating unit, for example, a method of polymerization in which the direction of a repeating unit is controlled by selecting a combination of a polymerization reaction to be used and a substituent correlated with condensation polymerization of the corresponding monomer, and the like, are exemplified.

In the case of control of a sequence of two or more repeating units in the polymer compound of the present invention, a method in which an oligomer having part or all of repeating units in the intended sequence is synthesized before polymerization, a method in which substituents correlated with condensation polymerization in monomers to be used and a polymerization reaction to be used are selected, and a sequence of repeating units is controlled in polymerization, and the like, are exemplified.

In the production method of the present invention, it is preferable that substituents correlated with condensation polymerization (Yₜ, Yᵤ, Yₜ₁, Yᵤ₁, Yₜ₂, Yᵤ₂, Yₜ₃, Yᵤ₃, Yₜ₄ and Yᵤ₄, Y₅, Y₆, Y₇, Y₈, Y₉, Y₁₀, Y₁₁ and Y₁₂) are selected each independently from halogen atoms, alkylsulfonate groups, arylsulfonate groups and arylalkylsulfonate groups, and condensation polymerization is carried out in the present of a nickel 0-valent complex.

The raw material compound includes dihalogenated compounds, bis(alkylsulfonate) compounds, bis(arylsulfonate) compounds, bis(arylalkylsulfonate) compounds or halogen-alkylsulfonate compounds, halogen-arylsulfonate compounds, halogen-arylalkylsulfonate compounds, alkylsulfonate-arylsulfonate compounds, alkylsulfonate-arylalkylsulfonate compounds, and arylsulfonate-arylalkylsulfonate compounds.

In this case, there is mentioned a method in which, by using, for example, a halogen-alkylsulfonate compound, halogen-arylsulfonate compound, halogen-arylalkylsulfonate compound, alkylsulfonate-arylsulfonate compound, alkylsulfonate-arylalkylsulfonate compound, and arylsulfonate-arylalkylsulfonate compound as the raw material compound, a polymer compound in which the direction of a repeating unit and a sequence are controlled is produced.

Among the production methods of the present invention, preferable is a production method in which substituents correlated with condensation polymerization (Yₜ, Yᵤ, Yₜ₁, Yᵤ₁, Yₜ₂, Yᵤ₂, Yₜ₃, Yᵤ₃, Yₜ₄ and Yᵤ₄, Y₅, Y₆, Y₇, Y₈, Y₉, Y₁₀, Y₁₁ and Y₁₂) are selected each independently from halogen atoms, alkylsulfonate groups, arylsulfonate groups, arylalkylsulfonate groups, boric acid group or borate groups, the ratio of the sum (J) of mol numbers of halogen atoms, alkylsulfonate groups, arylsulfonate groups and arylalkylsulfonate groups to the sum (K) of mol numbers of boric acid group (—B(OH)₂) and borate groups, in all raw material compounds, is substantially 1 (usually, K/J is in a range of 0.7 to 1.2), and condensation polymerization is carried out using a nickel catalyst or palladium catalyst.

As specific combinations of raw material compounds, there are mentioned combinations of a dihalogenated compound, bis(alkylsulfonate) compound, bis(arylsulfonate) compound or bis(arylalkylsulfonate) compound with a diboric acid compound or diborate compound.

Further mentioned are a halogen-boric acid compound, halogen-borate compound, alkylsulfonate-boric acid compound, alkylsulfonate-borate compound, arylsulfonate-boric acid compound, arylsulfonate-borate compound, arylalkylsulfonate-boric acid compound, arylalkylsulfonate-boric acid compound and arylalkylsulfonate-borate compound.

In this case, there is mentioned a method in which by using, for example, a halogen-boric acid compound, halogen-borate compound, alkylsulfonate-boric acid compound, alkylsulfonate-borate compound, arylsulfonate-boric acid compound, arylsulfonate-borate compound, arylalkylsulfonate-boric acid compound, arylalkylsulfonate-boric acid compound or arylalkylsulfonate-borate compound as the raw material compound, a polymer compound in which the direction of a repeating unit and a sequence are controlled in produced.

The organic solvent differs depending on the reaction and compound to be used, and for suppressing a side reaction, in general, it is preferable that a solvent to be used is subjected to a sufficient deoxidation treatment and the reaction is progressed in an inert atmosphere. Further, it is preferable to perform a dehydration treatment likewise. However, this is not the case when a reaction in a two-phase system with water such as a Suzuki coupling reaction is conducted.

Exemplified as the solvent are saturated hydrocarbons such as pentane, hexane, heptane, octane, cyclohexane and the like, unsaturated hydrocarbons such as benzene, toluene, ethylbenzene, xylene and the like, halogenated saturated hydrocarbons such as carbon tetrachloride, chloroform, dichloromethane, chlorobutane, bromobutane, chloropentane, bromopentane, chlorohexane, bromohexane, chlorocyclohexane, bromocyclohexane and the like, halogenated unsaturated hydrocarbons such as chlorobenzene, dichlorobenzene, trichlorobenzene and the like, alcohols such as methanol, ethanol, propanol, isopropanol, butanol, t-butyl alcohol and the like, carboxylic acids such as formic acid, acetic acid, propionic acid and the like, ethers such as dimethyl ether, diethyl ether, methyl-t-butyl ether, tetrahydrofuran, tetrahydropyran, dioxane and the like, amines such as trimethylamine, triethylamine, N,N,N′,N′-tetramethylethylenediamine, pyridine and the like, amides such as N,N-dimethylformamide, N,N-dimethylacetamide, N,N-diethylacetamide, N-methylmorpholine oxide, and the like, and single solvents or mixed solvents thereof may also be used. Of them, ethers are preferable, and tetrahydrofuran and diethyl ether are further preferable.

For reacting, an alkali or suitable catalyst is appropriately added. These may be advantageously selected depending on the reaction to be used. As the alkali or catalyst, those sufficiently dissolved in the solvent used in the reaction are preferable. As the method of mixing an alkali or catalyst, there is exemplified a method in which a solution of an alkali or catalyst is added slowly while stirring the reaction liquid under an inert atmosphere such as argon and nitrogen and the like, or reversely, the reaction liquid is slowly added to a solution of an alkali or catalyst.

When the polymer compound of the present invention is used in polymer LED and the like, its purity exerts an influence on the performance of an element such as light-emitting properties, therefore, it is preferable that a monomer before polymerization is purified by a method such as distillation, sublimation purification, re-crystallization and the like. Further, it is preferable that, after polymerization, a purification treatment such as re-precipitation purification, fractionation by chromatography, and the like is carried out. Among the polymer compounds of the present invention, those produced by the method of polymerization by a nickel 0-valent complex are preferable from the standpoint of element properties such as the life of polymer LED, light emission initiation voltage, current density, increase of voltage in driving, and the like, or heat resistance and the like.

Compounds of the formulae (14), (14-1), (14-2), (14-3), (14-4), (14B), (14C), (14-5), (14-6), (14-7) and (26) wherein Yₜ, Yᵤ, Yₜ₁, Yᵤ₁, Yₜ₂, Yᵤ₂, Yₜ₃, Yᵤ₃, Yₜ₄ and Yᵤ₄ represent a halogen useful as a raw material of a polymer compound of the present invention are obtained by synthesizing compounds having a structure in which Yₜ, Yᵤ, Yₜ₁, Yᵤ₁, Yₜ₂, Yᵤ₂, Yₜ₃, Yᵤ₃, Yₜ₄ and Yᵤ₄ in the formulae (14-1), (14-2), (14-3), (14-4), (14B), (14C), (14-5), (14-6), (14-7) and (26) are substituted by a hydrogen atom, then, halogenating them with various halogenation reagents such as, for example, chlorine, bromine, iodine, N-chlorosuccinimide, N-bromosuccinimide, benzyltrimethylammonium tribromide and the like.

Among compounds of the formulae (14), (14-1), (14-2), (14-3), (14-4), (14B), (14C), (14-5), (14-6), (14-7) and (26) useful as a raw material of a polymer compound of the present invention, those in which Yₜ, Yᵤ, Yₜ₁, Yᵤ₁, Yₜ₂, Yᵤ₂, Yₜ₃, Yᵤ₃, Yₜ₄ and Yᵤ₄ represent a halogen are preferable, and from the standpoint of increasing of molecular weight and easiness of purification after completion of the reaction, the halogen is preferably bromine, and from the standpoint of easiness of synthesis of a compound, those of the following formula (14-8) are preferable.

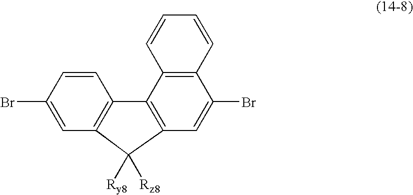

(wherein, R_{y8} and R_{z8} represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, and R_{y8} and R_{z8} may mutually bond to form a ring).

Particularly, R_{y8} and R_{z8} preferably represent an alkyl group, aryl group, arylalkyl group or mono-valent heterocyclic group, and further preferable is a case of alkyl group, and from the standpoint of solubility when a polymer is made, preferable is a case of n-octyl group.

As the method of synthesizing a compound of the above-mentioned formula (14-1), (14-3) or (14-4) wherein Yₜ₁, Yᵤ₁, Yₜ₃, Yᵤ₃, Yₜ₄ and Yᵤ₄ represent a bromine atom, exemplified is a method of brominating a compound of the following formula (14-9), (14-10) or (14-11) with a brominating agent

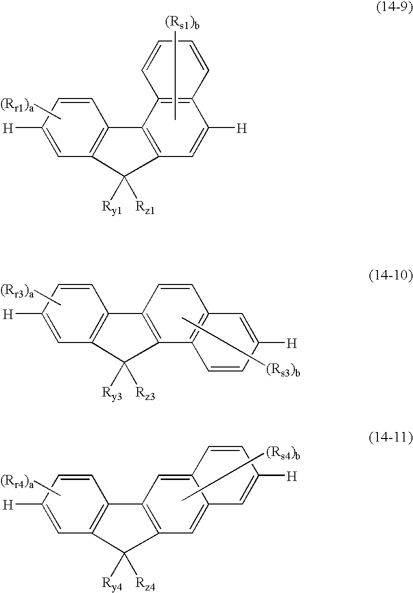

(wherein, Rᵣ₁, Rₛ₁, Rᵣ₃, Rₛ₃, Rᵣ₄, Rₛ₄, R_{y1}, R_{z1}, R_{y3}, R_{z3}, R_{y4}, R_{z4}, and a and b have the same meanings as described above. H represents a hydrogen atom).

As the brominating agent, N-bromosuccinimide, N-bromophthalic imide, bromine, benzyltrimethylammonium tribromide and the like are exemplified.

Of them, a method of synthesizing a compound of the above-mentioned formula (14-1) by a method of brominating a compound of the above-mentioned formula (14-1) with a brominating agent is preferable from the standpoint of reaction yield.

Further, it is preferable that a=b=0 from the standpoint of reaction yield.

Compounds of the formulae (14), (14-1), (14-2), (14-3), (14-4), (14B), (14C), (14-5), (14-6), (14-7) and (26) wherein Yₜ, Yᵤ, Yₜ₁, Yᵤ₁, Yₜ₂, Yᵤ₂, Yₜ₃, Yᵤ₃, Yₜ₄ and Yᵤ₄ represent an alkylsulfonate group, arylsulfonate group or arylalkylsulfonate group useful as a raw material of a polymer compound of the present invention are obtained by, for example, subjecting compounds having a functional group which can be derived into a hydroxyl group such as an alkoxy group and the like to a coupling reaction, ring-closing reaction and the like to synthesize compounds of the formulae (14), (14-1), (14-2), (14-3), (14-4), (14B), (14C), (14-5), (14-6), (14-7) and (26) wherein Yₜ, Yᵤ, Yₜ₁, Yᵤ₁, Yₜ₂, Yᵤ₂, Yₜ₃, Yᵤ₃, Yₜ₄ and Yᵤ₄ are substituted by a functional group which can be derived into a hydroxyl group such as an alkoxy group and the like, then, synthesizing compounds wherein Yₜ, Yᵤ, Yₜ₁, Yᵤ₁, Yₜ₂, Yᵤ₂, Yₜ₃, Yᵤ₃, Yₜ₄ and Yᵤ₄ are substituted by a hydroxyl group by various reaction such as use of a de-alkylating agent and the like with, for example, boron tribromide and the like, then, sulfonylating the hydroxyl group with, for example, various sulfonyl chloride, sulfonic anhydride and the like.

Compounds of the formulae (14), (14-1), (14-2), (14-3), (14-4), (14B), (14C), (14-5), (14-6), (14-7) and (26) wherein Yₜ, Yᵤ, Yₜ₁, Yᵤ₁, Yₜ₂, Yᵤ₂, Yₜ₃, Yᵤ₃, Yₜ₄ and Yᵤ₄ represent a boric acid group or borate group useful as a raw material of a polymer compound of the present invention are obtained by synthesizing compounds of the formulae (14), (14-1), (14-2), (14-3), (14-4), (14B), (14C), (14-5), (14-6), (14-7) and (26) wherein Yₜ, Yᵤ, Yₜ₁, Yᵤ₁, Yₜ₂, Yᵤ₂, Yₜ₃, Yᵤ₃, Yₜ₄ and Yᵤ₄ are substituted by a halogen atom by the above-mentioned methods and the like, then, allowing alkyllithium, metal magnesium and the like to act on them, further converting them into boric acid with trimethyl borate, to convert a halogen atom into a boric acid group, and after boric acid formation, allowing alcohol to act on them to effect borating. Further, these are obtained by synthesizing compounds of the formulae (14), (14-1), (14-2), (14-3), (14-4), (14B), (14C), (14-5), (14-6), (14-7) and (26) wherein Yₜ, Yᵤ, Yₜ₁, Yᵤ₁, Yₜ₂, Yᵤ₂, Yₜ₃, Yᵤ₃, Yₜ₄ and Yᵤ₄ are substituted by a halogen, trifluoromethanesulfonate group and the like by the above-mentioned methods and the like, then, borating them by a method described in non-patent literature (Journal of Organic Chemistry, 1995, 60, 7508-7510, Tetrahedron Letters, 1997, 28 (19), 3447-3450) and the like. Among the polymer compounds of the present invention, those produced by the method of polymerization with a nickel 0-valent complex are preferable from the standpoint of a life property.

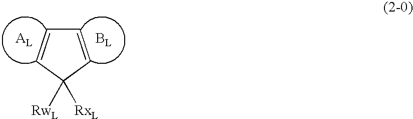

Next, a method of synthesizing a compound of the formula (2-0) will be illustrated.

The compound of the formula (2-0) can be synthesized by reacting a compound of the following formula (2-1) or (2-4) in the presence of an acid catalyst.

(wherein, ring A_{L} and ring B_{L} represent each independently an aromatic hydrocarbon ring optionally having a substituent, at least one of ring A_{L} and ring B_{L} is an aromatic hydrocarbon ring composed of a plurality of condensed benzene rings, and two binding hands are present on ring A_{L} and/or ring B_{L}, R_{wL} and R_{xL} represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, and R_{wL} and R_{xL} may mutually bond to form a ring. X_{L} represents a bromine atom or iodine atom).

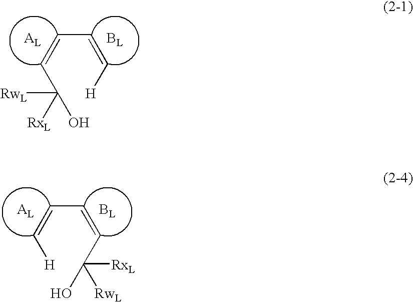

(wherein, ring A_{L}, ring B_{L}, R_{WL} and R_{XL} represent the same meanings as described above. The definitions and specific examples of the substituent on ring A_{L} and ring B_{L}, and the alkyl group, alkoxy group, alkylthio group, aryl group, aryloxy group, arylthio group, arylalkyl group, arylalkoxy group, arylalkylthio group, arylalkenyl group, arylalkynyl group, substituted amino group, substituted silyl group, halogen atom, acyl group, acyloxy group, imine residue, amide group, acid imide group, mono-valent heterocyclic group and substituted carboxyl group in R_{WL} and R_{XL} are the same as the definitions and specific examples of the substituent when the above-mentioned aromatic hydrocarbon ring of the formula (1) has a substituent).

As the acid, any of Lewix acid and Broensted acid may be used, and exemplified are hydrochloric acid, hydrobromic acid, hydrofluoride acid, sulfuric acid, nitric acid, phosphoric acid, polyphosphoric acid, formic acid, acetic acid, trifluoroacetic acid, trichloroacetic acid, propionic acid, oxalic acid, benzoic acid, methanesulfonic acid, benzenesulfonic acid, p-toluenesulfonic acid, boron fluoride, aluminum chloride, tin chloride (IV), iron chloride (II), titanium tetrachloride or mixtures thereof.

The reaction may use the above-mentioned acid as a solvent, or may be carried out in other solvent. The reaction temperature is about −100° C. to 200° C. though varying depending on the reaction conditions such as an acid, solvent and the like.

As the compound of the above-mentioned formula (2-1) or (2-4), for example, the following structures are mentioned.

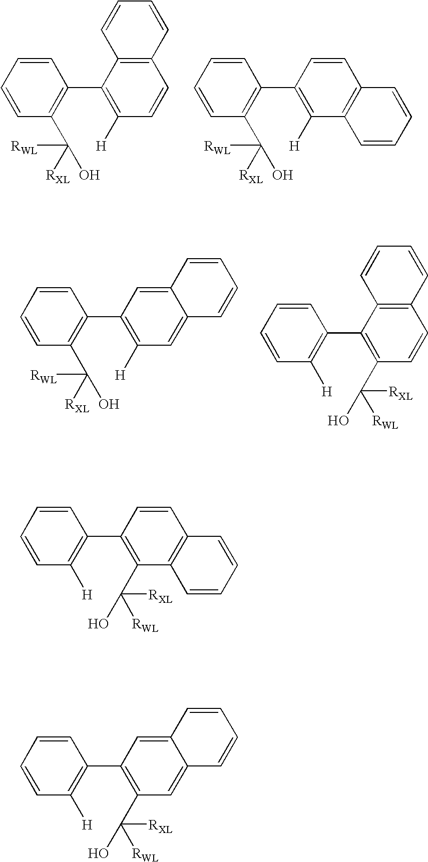

When R_{WL} and R_{XL} mutually bond to form a ring, for example, the following structures are mentioned.

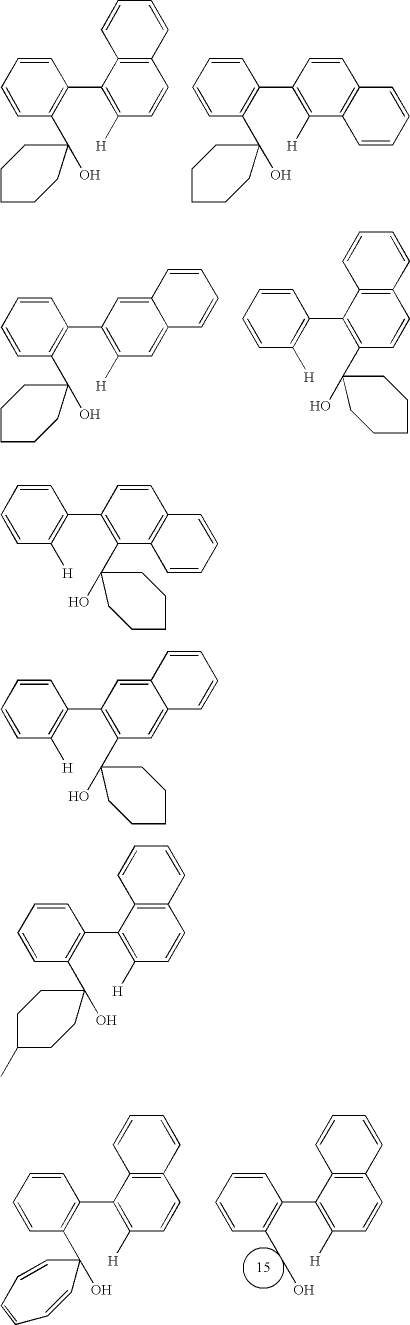

In the above-mentioned formulae, an aromatic ring may carry a substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group.

Further, the present invention discloses a method of producing a compound of the above-mentioned formula (2-1), containing reacting a compound of the following formula (2-2) with a metallizing agent to convert X_{L} into M_{L}, then, reacting this with a compound of the following formula (2-3), and a method of producing a compound of the above-mentioned formula (2-4), containing reacting a compound of the following formula (2-5) with a metallizing agent to convert X_{L} into M_{L}, then, reacting this with a compound of the following formula (2-3).

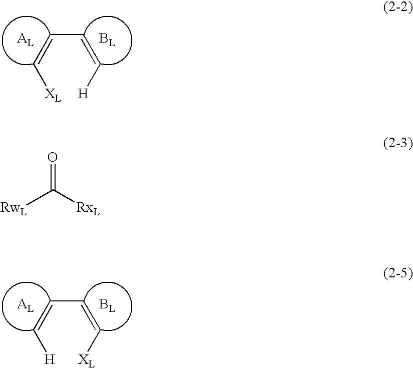

In the formulae, ring A_{L}, ring B_{L}, R_{WL} and R_{XL} represent the same meanings as described above. X_{L} represent a bromine atom or iodine atom. M_{L} represents a metal atom or its salt.

By using the method of the present invention, a ring structure of the above-mentioned formula (2-0) can be constructed in a short process from a commercially available raw material as compared with an existent method such as a synthesis route described in WO 2004/061048. In particular, when R_{WL} and R_{XL} are different or R_{WL} and R_{XL} form a ring, process numbers is small advantageously. When R_{WL} and R_{XL} represent an alkyl group, an aspect of yield is also preferable. For example, in the method of reacting a Grignard reagent to an ester, a mixture of a tertiary alcohol body, secondary alcohol body and ketone body is obtained, however, by using the method of the present invention, generation of by-products can be suppressed.

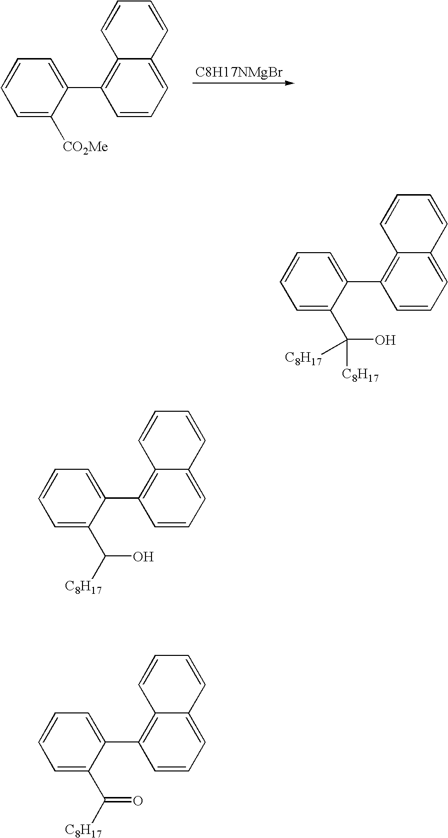

As the metal atom represented by M_{L}, alkali metals such as lithium, sodium, potassium and the like are exemplified, and as the salt of a metal atom, exemplified are magnesium salts such as chloromagnesium, bromomagnesium, iodomagnesium and the like, copper salts such as copper chloride, copper bromide, copper iodide and the like, zinc salts such as zinc chloride, zinc bromide, zinc iodide and the like, tin salts such as trimethyltin, tributyltin and the like. From the standpoint of reaction yield, a lithium atom or magnesium salt is preferable.

After exchanging a metal of the compound metallized by the above-mentioned method, a compound of the above-mentioned formula (2-2) may be reacted to this.

As the metal reagent for metal exchange, exemplified are magnesium salts such as magnesium chloride, magnesium bromide and the like, copper salts such as copper chloride(I), copper chloride(II), copper bromide(I), copper bromide(II), copper iodide(I) and the like, zinc salts such as zinc chloride, zinc bromide, zinc iodide and the like, tin salts such as chlorotrimethyltin, chlorotributyltin and the like, and from the standpoint of yield, magnesium salts are preferable.

As the compound of the above-mentioned formula (2-3), for example, the following structures are mentioned.

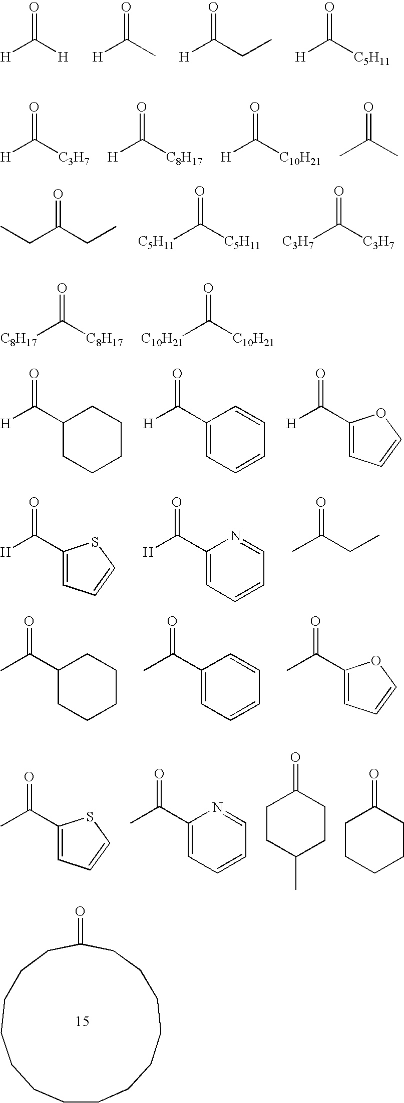

The compound of the above-mentioned formula (2-0) wherein R_{XL} represents an alkyl group can be synthesized also by reacting a compound of the following formula (2-6) with compounds represented by R_{WL} and R_{XL2}-X_{L2} in the presence of a salt.

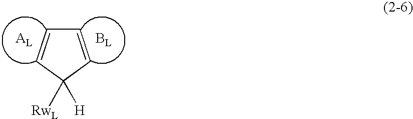

In the formula, ring A_{L}, ring B_{L} and R_{WL} represent the same meanings as described above. R_{XL2} represents an alkyl group, X_{L2} represent a chlorine atom, bromine atom, iodine atom, alkylsulfonate group, arylsulfonate group or arylalkylsulfonate group.

As the base used in the reaction, exemplified are metal hydrides such as lithium hydride, sodium hydride, potassium hydride and the like, organolithium reagents such as methyllithium, n-butyllithium sec-butyllithium, t-butyllithium, phenyllithium and the like, Grignard reagents such as methylmagnesium bromide, methylmagnesium chloride, ethylmagnesium bromide, ethylmagnesium chloride, allylmagnesium bromide, allylmagnesium chloride, phenylmagnesium bromide, benzylmagnesium chloride and the like, alkali metal amides such as lithiumdiisopropylamide, lithiumhexamethyldisilazide, sodiumhexamethyldisilazide, potassiumhexamethyldisilazide and the like, inorganic bases such as lithium hydroxide, sodium hydroxide, potassium hydroxide, lithium carbonate, sodium carbonate, potassium carbonate and the like, or mixtures thereof.

The reaction can be carried out in the presence of a solvent under an inert gas atmosphere such as nitrogen, argon and the like. The reaction temperature is preferably from −100° C. to the boiling point of a solvent.

As the solvent used in the reaction, exemplified are saturated hydrocarbons such as pentane, hexane, heptane, octane, cyclohexane and the like, unsaturated hydrocarbons such as benzene, toluene, ethylbenzene, xylene and the like, ethers such as dimethyl ether, diethyl ether, methyl-t-butyl ether, tetrahydrofuran, tetrahydropyran, dioxane and the like, amines such as trimethylamine, triethylamine, N,N,N′,N′-tetramethylethylenediamine, pyridine and the like, amides such as N,N-dimethylformamide, N,N-dimethylacetamide, N,N-diethylacetamide, N-methylmorpholine oxide, N-methyl-2-pyrrolidone, and the like, and single solvents or mixed solvents thereof may also be used.

When the inorganic base is used, it is preferable to carry out the reaction in the presence of a phase transfer catalyst such as tetrabutylammonium bromide, tetrabutylammonium hydroxide, Aliquat 336 and the like.

Particularly, a compound of the above-mentioned formula (2-6) is represented by the following formula (2-7), and reacted with a compound of the following formula (2-8) in the presence of a base, thus, a compound of the following formula (2-9) can be synthesized.

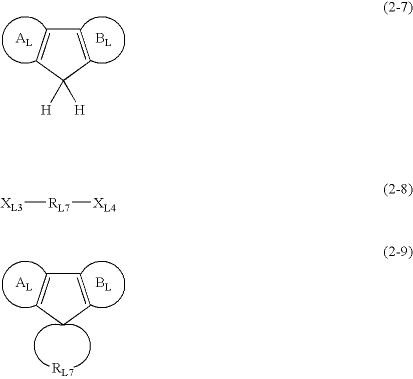

In the formulae, ring A_{L} and ring B_{L} represent the same meanings as described above. R_{L7} represents an alkylene group forming a 5- or more-membered ring in the above-mentioned formula (2-9), and X_{L3} and X_{L4} represent a chlorine atom, bromine atom, iodine atom, alkylsulfonate group, arylsulfonate group or arylalkylsulfonate group.

The alkylene group R_{L7} has about 4 to 20 carbon atoms, and specifically exemplified are a tetramethylene group, pentamethylene group, hexamethylene group and the like, and the alkylene group may carry a substituent, alternatively, the methylene group may be substituted by an oxygen atom, nitrogen atom, silicon atom, sulfur atom or phosphorus atom.

As the compound of the above-mentioned formula (2-9), for example, the following structures are mentioned.

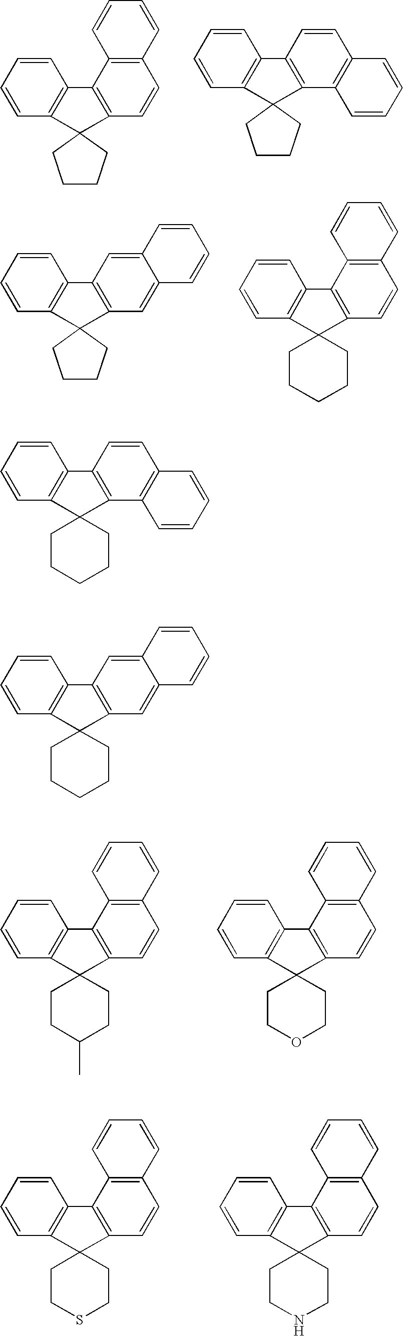

In the above-mentioned formulae, an aromatic ring may carry a substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group.

The compound of the above-mentioned formula (14-1), (14-3) or (14-3) can be synthesized, specifically, by a route shown in the following formula.

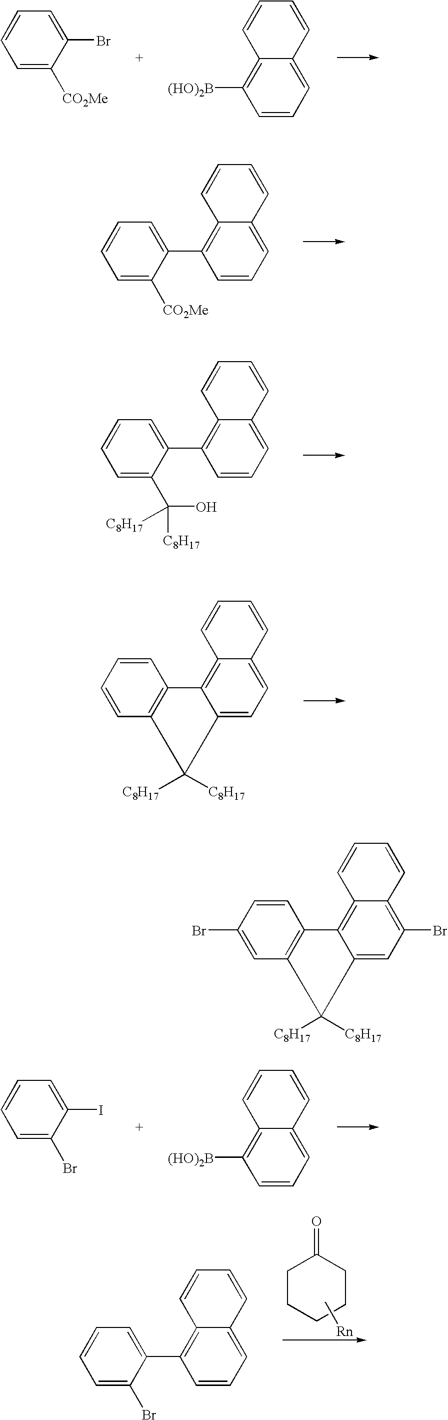

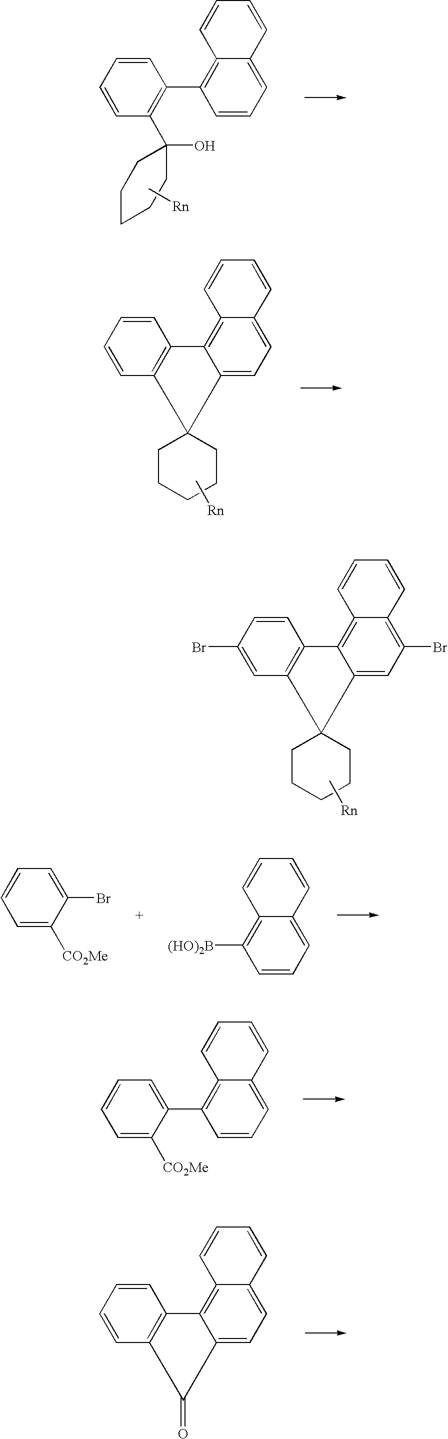

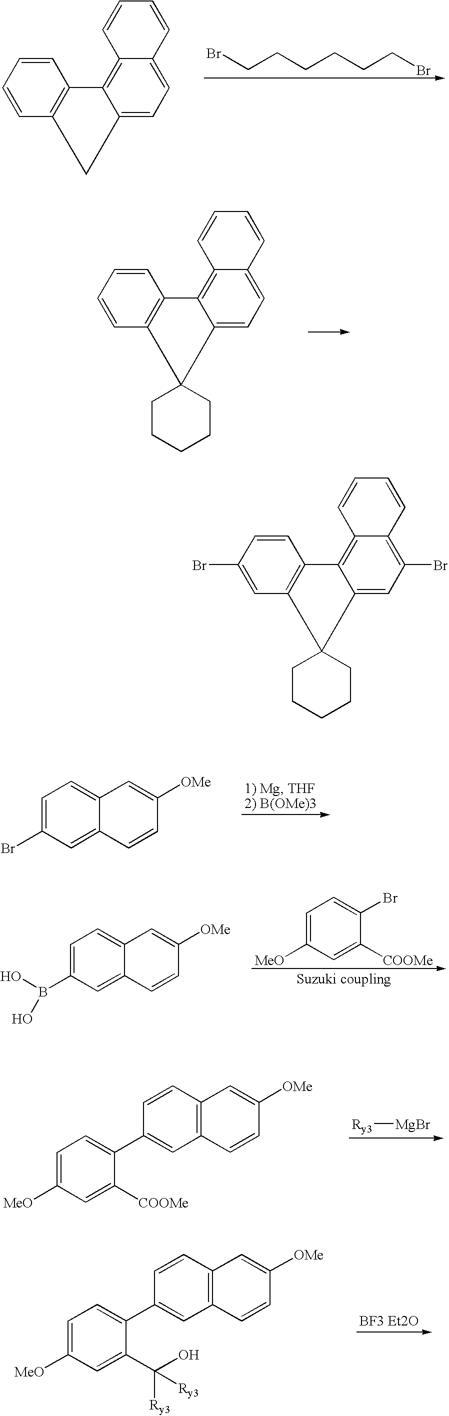

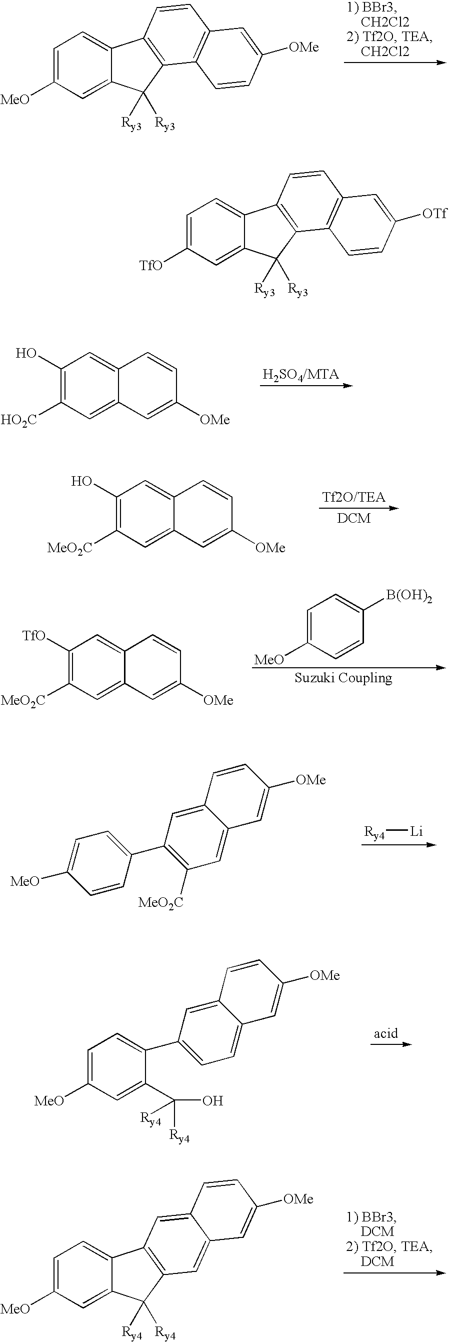

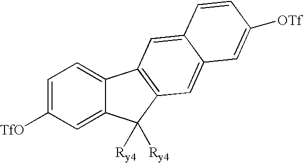

Next, use of the polymer compound of the present invention will be illustrated.

The polymer compound of the present invention usually emits fluorescence or phosphorescence in solid condition and can be used as a polymer light emitting body (light emitting material of high molecular weight).

The polymer compound has an excellent charge transporting ability, and can be suitably used as a polymer LED material or charge transporting material. The polymer LED using this polymer light emitting body is a high performance polymer LED which can be driven at low voltage with high efficiency. Therefore, the polymer LED can be preferably used for a back light of a liquid crystal display, curved or plane light source for illumination, segment type display, flat panel display of dot matrix, and the like.

The polymer compound of the present invention can also be used as a coloring matter for laser, organic solar battery material, and conductive film material such as an organic semiconductor for organic transistor, conductive film, organic semiconductor film and the like.

Further, it can be used also as a light emitting film material emitting fluorescence or phosphorescence.

Next, the polymer LED of the present invention will be illustrated.

The polymer LED of the present invention is characterized in that an organic layer is present between an anode and a cathode and the organic layer contains a polymer compound of the present invention.

The organic layer (layer containing organic substance) may be any of a light emitting layer, hole transporting layer, electron transporting layer and the like, and it is preferable that the organic layer is a light emitting layer.

Here, the light emitting layer means a layer having a function of light emission, the hole transporting layer means a layer having a function of transporting holes, and the electron transporting layer means a layer having a function of transporting electrons. The electron transporting layer and the hole transporting layer are generically called a charge transporting layer. Two or more light emitting layers, two or more hole transporting layers and two or more electron transporting layers may be used each individually.

When the organic layer is a light emitting layer, the light emitting layer as an organic layer may further contain a hole transporting material, electron transporting material or light emitting material. Here, the light emitting material means a material showing fluorescence or phosphorescence.

When the polymer compound and the hole transporting material of the present invention are mixed, the mixing ratio of the hole transporting material based on the whole mixtures is 1 wt % to 80 wt %, preferably 5 wt % to 60 wt %. When the polymer material and electron transporting material of the present invention are mixed, the mixing ratio of the electron transporting material based on the whole mixtures is 1 wt % to 80 wt %, preferably 5 wt % to 60 wt %. Further, when the polymer compound and light emitting material of the present invention are mixed, the mixing ratio of the light emitting material based on the whole mixtures is 1 wt % to 80 wt %, preferably 5 wt % to 60 wt %. When the polymer compound, light emitting material, hole transporting material and/or electron transporting material of the present invention are mixed, the mixing ratio of the light emitting material based on the whole mixtures is 1 wt % to 50 wt %, preferably 5 wt % to 40 wt %, the ratio of the sum the hole transporting material and electron transporting material is 1 wt % to 50 wt %, preferably 5 wt % to 40 wt %, and the content of the polymer compound of the present invention is 99 wt % to 20 wt %.

As the hole transporting material, electron transporting material and light emitting material to be mixed, known low molecular weight compounds, triplet light emitting complexes or polymer compounds can be used, and polymer compounds are preferably used. Exemplified as the hole transporting material, electron transporting material and light emitting material as polymer compounds are polyfluorene, its derivatives and copolymers, polyarylene, its derivatives and copolymers, polyarylenevinylene, its derivatives and copolymers, and aromatic amine, its derivatives and copolymers disclosed in WO 99/13692, WO99/48160, GB2340304A, WO00/53656, WO01/19834, WO00/55927, GB2348316, WO00/46321, WO00/06665, WO99/54943, WO99/54385, U.S. Pat. No. 5,777,070, WO98/06773, WO97/05184, WO00/35987, WO 00/53655, WO01/34722, WO99/24526, WO00/22027, WO00/22026, WO98/27136, U.S. Pat. No. 573,636, WO98/21262, U.S. Pat. No. 5,741,921, WO 97/09394, WO 96/29356, WO96/10617, EP0707020, WO95/07955, JP-A No. 2001-181618, JP-A No. 2001-123156, JP-A No. 2001-3045, JP-A No. 2000-351967, JP-A No. 2000-303066, JP-A No. 2000-299189, JP-A No. 2000-252065, JP-A No. 2000-136379, JP-A No. 2000-104057, JP-A No. 2000-80167, JP-A No. 10-324870, JP-A No. 10-114891, JP-A No. 9-111233, JP-A No. 9-45478 and the like.

As the fluorescent material of lower molecular weight, there can be used, for example, naphthalene derivatives, anthracene or its derivatives, perylene or its derivatives, and polymethine, xanthene, coumarin and cyanine coloring matters, metal complexes of 8-hydrozyquinoline or its derivatives, aromatic amine, tetraphenylcyclopentadiene or its derivatives, or tetraphenylbutadiene or its derivatives, and the like.

Specifically, known compounds such as those described in, for example, JP-A Nos. 57-51781, 59-194393, and the like can be used.

As the triplet light emitting complex, for example, Ir(ppy)3, Btp₂Ir(acac) containing iridium as a center metal, PtOEP containing platinum as a center metal, Eu(TTA)3-phen containing europium as a center metal, and the like are mentioned.

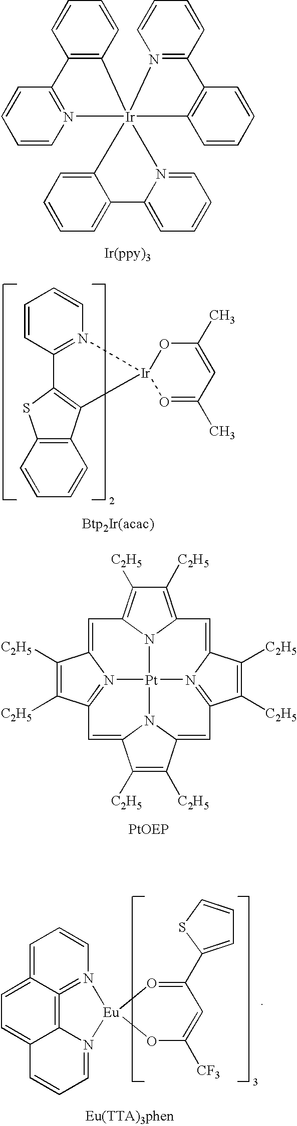

The triplet light emitting complex is described, for example, in Nature, (1998), 395, 151, Appl. Phys. Lett. (1999), 75(1), 4, Proc. SPIE-Int. Soc. Opt. Eng. (2001), 4105 (Organic Light-Emitting Materials and Devices I V), 119, J. Am. Chem. Soc., (2001), 123, 4304, Appl. Phys. Lett., (1997), 71(18), 2596, Syn. Met., (1998), 94(1), 103, Syn. Met., (1999), 99(2), 1361, Adv. Mater., (1999), 11(10), 852, Jpn. J. Appl. Phys., 34, 1883 (1995), and the like.

The composition of the present invention contains at least one material selected from hole transporting materials, electron transporting materials and light emitting materials, and a polymer compound of the present invention, and can be used as the light emitting material or electron transporting material.

The content ratio of at least one material selected from hole transporting materials, electron transporting materials and light emitting materials to a polymer compound of the present invention may be determined depending on use, and in the case of use of a light emitting material, the same content ratio as in the above-mentioned light emitting layer is preferable.

As another embodiment of the present invention, a polymer composition containing two or more polymer compounds of the present invention (polymer compound containing a repeating unit of the formula (1)) is exemplified.

Specifically, a polymer composition containing two or more polymer compounds containing a repeating unit of the formula (1) in which the total amount of the polymer compounds is 50 wt % or more based on the total amount is preferable because of excellent light emitting efficiency, life property and the like when used as a light emitting material of polymer LED. More preferably, the total amount of the polymer compounds is 70 wt % or more. The polymer composition of the present invention can enhance element properties such as life and the like than in the case of use of a polymer compound singly in polymer LED.

A preferable example of the polymer composition is a polymer composition containing at least one polymer compound composed only of a repeating unit of the above-mentioned formula (1) and at least one copolymer containing a repeating unit of the above-mentioned formula (1) in an amount of 50 mol % or more. It is preferable that the copolymer contains a repeating unit of the above-mentioned formula (1) in an amount of 70 mol % or more from the standpoint of light emission efficiency, life property and the like.

Another preferable example is a polymer composition containing two or more copolymers containing a repeating unit of the above-mentioned formula (1) in an amount of 50 mol % or more in which the copolymers contain also mutually different repeating units. It is more preferable that at least one of the copolymers contains a repeating unit of the above-mentioned formula (1) in an amount of 70 mol % or more from the standpoint of light emission efficiency, life property and the like.

Still another preferable example is a polymer composition containing two or more copolymers containing a repeating unit of the above-mentioned formula (1) in an amount of 50 mol % or more in which the copolymers are composed of the same combination of repeating units though the copolymerization ratios thereof are mutually different. It is more preferable that at least one of the copolymers contains a repeating unit of the above-mentioned formula (1) in an amount of 70 mol % or more from the standpoint of light emission efficiency, life property and the like.

Alternatively, another preferable example is a polymer composition containing two or more polymer compounds composed only of a repeating unit of the above-mentioned formula (1).

A more preferable example is a polymer composition in which at least one polymer compound contained in the polymer composition shown in the above-mentioned example is a copolymer containing a repeating unit of the above-mentioned formula (1) in an amount of 50 mol % or more, and a repeating unit of the above-mentioned formula (13) is also contained, and the molar ratio of a repeating unit of the above-mentioned formula (1) to a repeating unit of the above-mentioned formula (13) is 99:1 to 50:50. It is more preferable that the above-mentioned molar ratio is 98:2 to 70:30 from the standpoint of light emission efficiency, life property and the like.

Another more preferable example is a polymer composition containing at least one polymer compound composed only of a repeating unit of the above-mentioned formula (1) and at least one copolymer containing a repeating unit of the above-mentioned formula (1) in an amount of 50 mol % or more, in which the copolymer is composed of a repeating unit of the above-mentioned formula (1) and a repeating unit of the above-mentioned formula (13), and the molar ratio of a repeating unit of the above-mentioned formula (1) to a repeating unit of the above-mentioned formula (13) is 90:10 to 50:50. It is more preferable that the molar ratio is 90:10 to 60:40 from the standpoint of light emission efficiency, life property and the like, and further preferably 85:15 to 75:25.

When the polymer compound of the present invention is used in the form of polymer composition, the repeating unit of the above-mentioned formula (1) is preferably selected from a repeating unit of the above-mentioned formula (1-1) or a repeating unit of the formula (1-2), and a case of a repeating unit of the formula (1-1) is more preferable, a case of a repeating unit of the formula (1-1) in which a and b are 0 is further preferable, a case in which R_{W1} and R_{X1} represent an alkyl group is more preferable, a case in which the alkyl group has 3 or more carbon atoms is further preferable, and a case of a repeating unit of the above-mentioned formula (16) is more preferable, from the standpoint of solubility in an organic solvent and from the standpoint of element properties such as light emission efficiency, life property and the like. Further, it is preferable that the repeating unit of the above-mentioned formula (13) is a repeating unit of the above-mentioned formula 134 or a repeating unit of the above-mentioned formula 137, and more preferably a repeating unit of the above-mentioned formula (17) or a repeating unit of the formula (20).

As the polymer composition of the present invention, preferable are a polymer composition containing one polymer compound composed only of a repeating unit of the above-mentioned formula (1) and one copolymer containing a repeating unit of the above-mentioned formula (1) in an amount of 50 mol % or more, and a polymer composition containing two copolymers containing a repeating unit of the above-mentioned formula (1) in an amount of 50 mol % or more in which the copolymers are composed of the same combination of repeating units though the copolymerization ratios thereof are mutually different, from the standpoint of solubility in an organic solvent and from the standpoint of element properties such as light emission efficiency, life property and the like.

As the polymer composition containing one polymer compound composed only of a repeating unit of the above-mentioned formula (1) and one copolymer containing a repeating unit of the above-mentioned formula (1) in an amount of 50 mol % or more, a polymer composition containing a polymer compound composed only of a repeating unit of the above-mentioned formula (1) and a polymer compound composed of a repeating unit of the above-mentioned formula (1) and a repeating unit of the above-mentioned formula (13) is preferable, a polymer composition containing a polymer compound composed only of a repeating unit of the above-mentioned formula (1-1) and a polymer compound composed of a repeating unit of the above-mentioned formula (1-1) and a repeating unit of the above-mentioned formula 134, and a polymer composition containing a polymer compound composed only of a repeating unit of the above-mentioned formula (1-1) and a polymer compound composed of a repeating unit of the above-mentioned formula (1-1) and a repeating unit of the above-mentioned formula 137 are more preferable, a polymer composition containing a polymer compound composed only of a repeating unit of the above-mentioned formula (16) and a polymer compound composed of a repeating unit of the above-mentioned formula (16) and a repeating unit of the above-mentioned formula (17) and a polymer composition containing a polymer compound composed only of a repeating unit of the above-mentioned formula (16) and a polymer compound composed of a repeating unit of the above-mentioned formula (16) and a repeating unit of the above-mentioned formula (20) are further preferable, and a polymer composition containing a polymer compound composed only of a repeating unit of the above-mentioned formula (16) and a polymer compound composed of a repeating unit of the above-mentioned formula (16) and a repeating unit of the above-mentioned formula (17) in which the ratio of a repeating unit of the above-mentioned formula (16) is 70 mol % or more based on all repeating units and a polymer composition containing a polymer compound composed only of a repeating unit of the above-mentioned formula (16), and a polymer compound composed of a repeating unit of the above-mentioned formula (16) and a repeating unit of the above-mentioned formula (20) in which the ratio of a repeating unit of the above-mentioned formula (16) is 70 mol % or more based on all repeating units are more preferable, from the standpoint of solubility in an organic solvent and from the standpoint of element properties such as light emission efficiency, life property and the like.

As the polymer composition containing two copolymers containing a repeating unit of the above-mentioned formula (1) in an amount of 50 mol % or more in which the copolymers are composed of the same combination of repeating units though the copolymerization ratios thereof are mutually different, a polymer composition containing two copolymers composed of a repeating unit of the above-mentioned formula (1) and a repeating unit of the above-mentioned formula (13) in which the copolymers are composed of the same combination of repeating units though the copolymerization ratios thereof are mutually different is preferable, a polymer composition containing two copolymers composed of a repeating unit of the above-mentioned formula (1-1) and a repeating unit of the above-mentioned formula 134 in which the copolymers are composed of the same combination of repeating units though the copolymerization ratios thereof are mutually different and a polymer composition containing two copolymers composed of a repeating unit of the above-mentioned formula (1-1) and a repeating unit of the above-mentioned formula 137 in which the copolymers are composed of the same combination of repeating units though the copolymerization ratios thereof are mutually different, are more preferable, and a polymer composition containing two copolymers composed of a repeating unit of the above-mentioned formula (16) and a repeating unit of the above-mentioned formula (17) in which the copolymers are composed of the same combination of repeating units though the copolymerization ratios thereof are mutually different and a polymer composition containing two copolymers composed of a repeating unit of the above-mentioned formula (16) and a repeating unit of the above-mentioned formula (20) in which the copolymers are composed of the same combination of repeating units though the copolymerization ratios thereof are mutually different, are further preferable, from the standpoint of solubility in an organic solvent and from the standpoint of element properties such as light emission efficiency, life property and the like. Regarding the composition of the copolymer, a polymer composition containing a copolymer in which the molar ratio of a repeating unit of the above-mentioned formula (1) to a repeating unit other than the repeating unit of the above-mentioned formula (1) is 99:1 to 90:10 and a copolymer in which the molar ratio of a repeating unit of the above-mentioned formula (1) to a repeating unit other than the repeating unit of the above-mentioned formula (1) is 80:20 to 50:50 is preferable, and a polymer composition containing a copolymer in which the molar ratio of a repeating unit of the above-mentioned formula (1) to a repeating unit other than the repeating unit of the above-mentioned formula (1) is 98:2 to 95:5 and a copolymer in which the molar ratio of a repeating unit of the above-mentioned formula (1) to a repeating unit other than the repeating unit of the above-mentioned formula (1) is 70:30 to 60:40 is more preferable, from the standpoint of solubility in an organic solvent and from the standpoint of element properties such as light emission efficiency, life property and the like.

Regarding the mixing ratio of the polymer compound, it is preferable that the molar ratio of a repeating unit of the above-mentioned formula (1) to a repeating unit other than the repeating unit of the above-mentioned formula (1), in a polymer composition, is 99:1 to 70:30, from the standpoint of element properties such as light emission efficiency, life property and the like.

In the case of a polymer composition containing at least one copolymer containing a repeating unit of the above-mentioned formula (13), it is preferable to mix polymer compounds or copolymers so that the molar ratio of a repeating unit of the above-mentioned formula (1) to a repeating unit of the above-mentioned formula (13), in a polymer composition, is 99:1 to 70:30, and a mixing ratio of 95:5 to 80:20 is more preferable, from the standpoint of element properties such as light emission efficiency, life property and the like.

In the case of the polymer composition containing a polymer compound composed only of a repeating unit of the above-mentioned formula (16) and a polymer compound composed of a repeating unit of the above-mentioned formula (16) and a repeating unit of the above-mentioned formula (17) and the polymer composition containing two copolymers composed of a repeating unit of the above-mentioned formula (16) and a repeating unit of the above-mentioned formula (17) in which the copolymers are composed of the same combination of repeating units though the copolymerization ratios thereof are mutually different, it is preferable to mix polymer compounds or copolymers so that the molar ratio of a repeating unit of the above-mentioned formula (16) to a repeating unit of the above-mentioned formula (17), in a polymer composition, is 99:1 to 70:30, and a mixing ratio of 95:5 to 80:20 is more preferable, from the standpoint of element properties such as light emission efficiency, life property and the like.

In the case of the polymer composition containing a polymer compound composed only of a repeating unit of the above-mentioned formula (16) and a polymer compound composed of a repeating unit of the above-mentioned formula (16) and a repeating unit of the above-mentioned formula (20) and the polymer composition containing two copolymers composed of a repeating unit of the above-mentioned formula (16) and a repeating unit of the above-mentioned formula (20) in which the copolymers are composed of the same combination of repeating units though the copolymerization ratios thereof are mutually different, it is preferable to mix polymer compounds or copolymers so that the molar ratio of a repeating unit of the above-mentioned formula (16) to a repeating unit of the above-mentioned formula (20), in a polymer composition, is 99:1 to 70:30, and a mixing ratio of 95:5 to 80:20 is more preferable, from the standpoint of element properties such as light emission efficiency, life property and the like.

The polymer composition of the present invention has a number-average molecular weight in terms of polystyrene of usually about 10³ to 10⁸, preferably 10⁴ to 10⁶. The weight-average molecular weight in terms of polystyrene of usually about 10³ to 10⁸, and from the standpoint of a film forming property and from the standpoint of efficiency when an element is formed, preferably 5×10⁴ to 5×10⁶, further preferably 10⁵ to 5×10⁶. Here, the average molecular weight of a polymer composition is a value obtained by analyzing a composition obtained by mixing two or more polymer compounds, by GPC.

The thickness of a light emitting layer of the polymer LED of the present invention may be advantageously selected so as to give optimum driving voltage and light emission efficiency though the optimum value varied depending on the material to be used, and it is, for example, 1 nm to 1 μm, preferably 2 nm to 500 nm, further preferably 5 nm to 200 nm.

As the method for forming a light emitting layer, a method of film formation from a solution is exemplified. As the film formation method from a solution, application methods such as a spin coat method, casting method, micro gravure coat method, gravure coat method, bar coat method, roll coat method, wire bar coat method, dip coat method, spray coat method, screen printing method, flexo printing method, offset printing method, inkjet printing method and the like can be used. Printing methods such as a screen printing method, flexo printing method, offset printing method, inkjet printing method and the like are preferable since pattern formation and multicolor separate painting are easy.

As the solution (ink composition) used in printing methods, at least one of polymer compounds of the present invention may be advantageously contained, and in addition to the polymer compound of the present invention, additives such as a hole transporting material, electron transporting material, light emitting material, solvent, stabilizer and the like may be contained.

The ratio of a polymer compound of the present invention in the ink composition is usually 20 wt % to 100 wt %, preferably 40 wt % to 100 wt % based on the total weight of the composition excluding a solvent.

The ratio of a solvent when the ink composition contains a solvent is 1 wt % to 99.9 wt %, preferably 60 wt % to 99.5 wt %, further preferably 80 wt % to 99.0 wt % based on the total weight of the composition.

Though the viscosity of a ink composition varies depending on a printing method, when an ink composition passes through a discharge apparatus such as in inkjet print method and the like, the viscosity at 25° C. is preferably in a range of 1 to 20 mPa·s, more preferably in a range of 5 to 20 mPa·s, further preferably in a range of 7 to 20 mPa·s, for preventing clogging and curving in flying in discharging.

The solution of the present invention may contain additives for regulating viscosity and/or surface tension in addition to the polymer compound of the present invention. As the additive, a polymer compound (thickening agent) having high molecular weight for enhancing viscosity and a poor solvent, a compound of low molecular weight for lowering viscosity, a surfactant for decreasing surface tension, and the like may be appropriately combined and used.

As the above-mentioned polymer compound having high molecular weight, a compound which is soluble in the same solvent as in the polymer compound of the present invention and which does not disturb light emission and charge transportation may be used. For example, polystyrene of high molecular weight, polymethyl methacrylate, polymer compounds of the present invention having larger molecular weights, and the like can be used. The weight-average molecular weight is preferably 500000 or more, more preferably 1000000 or more.

It is also possible to use a poor solvent as a thickening agent. Namely, by adding a poor solvent in small amount based on the solid content in a solution, viscosity can be enhanced. When a poor solvent is added for this purpose, the kind and addition amount of the solvent may be advantageously selected within a range not causing deposition of solid components in a solution. When stability in preservation is taken into consideration, the amount of a poor solvent is preferably 50 wt % or less, further preferably 30 wt % or less based on the whole solution.

The solution of the present invention may contain an antioxidant in addition to the polymer compound of the present invention for improving storage stability. As the antioxidant, a compound which is soluble in the same solvent as in the polymer compound of the present invention and which does not disturb light emission and charge transportation is permissible, and exemplified are phenol-based antioxidants, phosphorus-based antioxidants and the like.

As the solvent used in film formation from a solution, compounds which can dissolve or uniformly disperse a hole transporting material are preferable. Exemplified as the solvent are chlorine-based solvents such as chloroform, methylene chloride, 1,2-dichloroethane, 1,1,2-trichloroethane, chlorobenzene, o-dichlorobenzene and the like, ether-based solvents such as tetrahydrofuran, dioxane and the like, aromatic hydrocarbon-based solvents such as toluene, xylene and the like, aliphatic hydrocarbon-based solvents such as cyclohexane, methylcyclohexane, n-pentane, n-hexane, n-heptane, n-octane, n-nonane, n-decane and the like, ketone-based solvents such as acetone, methyl ethyl ketone, cyclohexanone and the like, ester-based solvents such as ethyl acetate, butyl acetate, ethylcellosolve acetate and the like, polyhydric alcohols such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin, 1,2-hexanediol and the like and derivatives thereof, alcohol-based solvents such as methanol, ethanol, propanol, isopropanol, cyclohexanol and the like, sulfoxide-based solvents such as dimethyl sulfoxide and the like, amide-based solvents such as N-methyl-2-pyrrolidone, N,N-dimethylformamide and the like. These organic solvents can be used singly or in combination of two or more. Among the above-mentioned solvents, at least one organic solvent having a structure containing at least one benzene ring and having a melting point of 0° C. or less and a boiling point of 100° C. or more is preferably contained.

The solvent preferably includes aromatic hydrocarbon-based solvents, aliphatic hydrocarbon-based solvents, ester-based solvents and ketone-based solvents from the standpoint of solubility in an organic solvent, uniformity in film formation, viscosity and the like, and toluene, xylene, ethylbenzene, diethylbenzene, trimethylbenzene, n-propylbenzene, i-propylbenzene, n-butylbenzene, i-butylbenzene, s-butylbenzene, anisole, ethoxybenzene, 1-methylnaphthalene, cyclohexane, cyclohexanone, cyclohexylbenzene, bicyclohexyl, cyclohexenylcyclohexanone, n-heptylcyclohexane, n-hexylcyclohexanone, 2-propylcyclohexanone, 2-heptanone, 3-heptanone, 4-heptanone, 2-octanone, 2-nonanone, 2-decanone and dicyclohexylketone are preferable, and it is more preferable that at least one of xylene, anisole, cyclohexylbenzene and bicyclohexyl is contained.

The number of solvents in a solution is preferably 2 or more, more preferably 2 to 3, further preferably 2, from the standpoint of a film forming property and from the standpoint of element properties and the like.

When two solvents are contained in a solution, one of them may be solid at 25° C. From the standpoint of a film forming property, it is preferable that one solvent has a boiling point of 180° C. or more, and another solvent has a boiling point of 180° C. or less, and it is more preferable that one solvent has a boiling point of 200° C. or more, and another solvent has a boiling point of 180° C. or less. From the standpoint of viscosity, it is preferable that a polymer compound is dissolved in an amount of 1 wt % or more at 60° C. in both solvents, and it is preferable that one of two solvents dissolves a polymer compound in an amount of 1 wt % or more at 25° C.

When three solvents are contained in a solution, one or two solvents may be solid at 25° C. From the standpoint of a film formation property, it is preferable that at least one of three solvents has a boiling point of 180° C. or more and at least one solvent has a boiling point of 180° C. or less, and it is more preferable that at least one of three solvents has a boiling point of 200° C. or more and 300° C. or less and at least one solvent has a boiling point of 180° C. or less. From the standpoint of viscosity, it is preferable that a polymer compound is dissolved in an amount of 1 wt % or more at 60° C. in two solvents among three solvents, and it is preferable that a polymer compound is dissolved in an amount of 1 wt % or more at 25° C. in one of three solvents.

When two or more solvents are contained in a solution, the content of a solvent having highest boiling point is preferably 40 to 90 wt %, more preferably 50 to 90 wt %, further preferably 65 to 85 wt % based on the weight of all solvents in the solution from the standpoint of viscosity and film forming property.

As the solution of the present invention, preferable are a solution composed of anisole and bicyclohexyl, a solution composed of anisole and cyclohexylbenzene, a solution composed of xylene and bicyclohexyl, and a solution composed of xylene and cyclohexylbenzene, from the standpoint of viscosity and film forming property.

From the standpoint of solubility of a polymer compound in a solvent, a difference between the solubility parameter of a solvent and the solubility parameter of a polymer compound is preferably 10 or less, more preferably 7 or less.

The solubility parameter of a solvent and the solubility parameter of a polymer can be measured by a method described in “Solvent Handbook (Kodansha, 1976)”.

The polymer compounds of the present invention may be contained singly or in combination of two or more in a solution, and a polymer compound other than the polymer compound of the present invention may also be contained in a range not deteriorating element properties and the like.

When one polymer compound of the present invention is contained in a solution, it is preferable that this compound is a polymer compound containing one repeating unit of the above-mentioned formula (1) and one or more repeating units of the above-mentioned formula (13), and it is more preferable that this compound is a polymer compound containing one repeating unit of the above-mentioned formula (16) and one or more repeating units of the above-mentioned formula (13), from the standpoint of element properties and the like. At least one of repeating units of the above-mentioned formula (13) is preferably a repeating unit of the above-mentioned formula (17) or (20) and more preferably a repeating unit of the above-mentioned formula (17).

When two or more polymer compounds of the present invention are contained in a solution, it is preferable to contain one polymer compound composed only of a repeating unit of the above-mentioned formula (1) and one polymer compound containing one repeating unit of the above-mentioned formula (1) and one repeating unit of the above-mentioned formula (13), and to contain two polymer compounds containing one repeating unit of the above-mentioned formula (1) and one repeating unit of the above-mentioned formula (13), it is more preferable to contain one polymer compound composed only of a repeating unit of the above-mentioned formula (16) and one polymer compound containing one repeating unit of the above-mentioned formula (16) and one repeating unit of the above-mentioned formula (17), to contain two polymer compounds containing one repeating unit of the above-mentioned formula (16) and one repeating unit of the above-mentioned formula (17), to contain one polymer compound composed only of a repeating unit of the above-mentioned formula (16) and one polymer compound containing one repeating unit of the above-mentioned formula (16) and one repeating unit of the above-mentioned formula (20), and to contain two polymer compounds containing one repeating unit of the above-mentioned formula (16) and one repeating unit of the above-mentioned formula (20), and it is further preferable to contain one polymer compound composed only of a repeating unit of the above-mentioned formula (16) and one polymer compound containing one repeating unit of the above-mentioned formula (16) and one repeating unit of the above-mentioned formula (17), from the standpoint of element properties and the like.

The solution of the present invention may contain water, metal and its salt in an amount of 1 to 1000 ppm. As the metal, specifically, lithium, sodium, calcium, potassium, iron, copper, nickel, aluminum, zinc, chromium, manganese, cobalt, platinum, iridium and the like are mentioned. Further, silicon, phosphorus, fluorine, chlorine or bromine may be contained in an amount of 1 to 1000 ppm.

Using the solution of the present invention, a film can be formed by a spin coat method, casting method, micro gravure coat method, gravure coat method, bar coat method, roll coat method, wire bar coat method, dip coat method, spray coat method, screen printing method, flexo printing method, offset printing method, inkjet printing method and the like. Particularly, the solution of the present invention is preferably used for film formation by a screen printing method, flexo printing method, offset printing method, inkjet printing method, and more preferably used for film formation by an inkjet method.

When a film is formed using the solution of the present invention, a polymer compound contained in the solution has high glass transition temperature, therefore, baking at temperatures of 100° C. or more is possible, and even if baking is carried out at a temperature of 130° C., decrease in element properties is very small. Depending on the kind of a polymer compound, it is also possible to carry out baking at temperatures of 160° C. or more.

As the film which can be formed using the solution of the present invention, a light emitting film, electrically conductive film and organic semiconductor film are exemplified.

The light emitting film of the present invention shows a quantum yield of light emission of preferably 50% or more, more preferably 60% or more, further preferably 70% or more from the standpoint of the luminance and light emission voltage of an element, and the like.

The electrically conductive film of the present invention has a surface resistance of 1 KΩ/□ or less. By doping a film with a Lewis acid, ionic compound and the like, electric conductivity can be enhanced. The surface resistance is preferably 100 KΩ/□ or less, further preferably 10 KΩ/□ or less.

In the organic semiconductor film of the present invention, one larger parameter of electron mobility or hole mobility is preferably 10⁻⁵ cm²/V/s or more. More preferably, it is 10⁻³ cm²/V/s or more, and further preferably 10⁻¹ cm²/V/s or more.

By forming the organic semiconductor film on a Si base plate carrying a gate electrode and an insulation film of SiO₂ and the like formed thereon, and forming a source electrode and a drain electrode with Au and the like, an organic transistor can be obtained.

In the polymer light emitting device of the present invention, the maximum external quantum yield when a voltage of 3.5 V or more is applied between an anode and a cathode is preferably 1% or more, more preferably 1.5% or more from the standpoint of the luminance of an element and the like.

As the polymer light emitting device (hereinafter, referred to as polymer LED) of the present invention, mentioned are polymer LED having an electron transporting layer provided between a cathode and a light emitting layer, polymer LED having a hole transporting layer provided between an anode and a light emitting layer, polymer LED having an electron transporting layer provided between a cathode and a light emitting layer and a hole transporting layer provided between an anode and a light emitting layer, and the like.

For example, the following structures a) to d) are specifically mentioned.

a) anode/light emitting layer/cathode

b) anode/hole transporting layer/light emitting layer/cathode

c) anode/light emitting layer/electron transporting layer/cathode

d) anode/hole transporting layer/light emitting layer/electron transporting layer/cathode

(wherein, / means adjacent lamination of layers, applied also in the followings)

The polymer LED of the present invention includes also those in which a polymer compound of the present invention is contained in a hole transporting layer and/or electron transporting layer.

When the polymer compound of the present invention is used in a hole transporting layer, it is preferable that the polymer compound of the present invention is a polymer compound containing a hole transporting group, and specific examples thereof include copolymers with an aromatic amine, copolymers with stilbene, and the like.

When the polymer compound of the present invention is used in an electron transporting layer, it is preferable that the polymer compound of the present invention is a polymer compound containing an electron transporting group, and specific examples thereof include copolymers with oxadiazole, copolymers with triazole, copolymers with quinoline, copolymers with quinoxaline, copolymers with benzothiazole, and the like.

When the polymer LED of the present invention contains a hole transporting layer, exemplified as the hole transporting material to be used are polyvinylcarbazole or its derivative, polysilane or its derivative, polysiloxane derivative having an aromatic amine in a side chain or main chain, pyrazoline derivative, arylamine derivative, stilbene derivative, triphenyldiamine derivative, polyaniline or its derivative, polythiophene or its derivative, polypyrrole or its derivative, poly(p-phenylenevinylene) or its derivative, poly(2,5-thienylenevinylene) or its derivative, and the like.

Specifically, exemplified as the hole transporting material are those described in JP-A Nos. 63-70257, 63-175860, 2-135359, 2-135361, 2-209988, 3-37992 and 3-152184, and the like.

Among them, preferable as the hole transporting material used in a hole transporting layer are polymer hole transporting materials such as polyvinylcarbazole or its derivative, polysilane or its derivative, polysiloxane derivative having an aromatic amine compound group in a side chain or main chain, polyaniline or its derivative, polythiophene or its derivative, poly(p-phenylenevinylene) or its derivative, poly(2,5-thienylenevinylene) or its derivative, and the like, and polyvinylcarbazole or its derivative, polysilane or its derivative, polysiloxane derivative having an aromatic amine in a side chain or main chain are further preferable.

Exemplified as the hole transporting material of low molecular weight are pyrazoline derivative, arylamine derivative, stilbene derivative, triphenyldiamine derivative. In the case of the hole transporting material of low molecular weight, it is preferably dispersed in a polymer binder in use.

The polymer binder to be mixed is preferably that which does not extremely disturb electron charge transportation, and those showing not strong absorption against visible ray are suitably used. Exemplified as the polymer binder are poly(N-vinylcarbazole), polyaniline or its derivative, polythiophene or its derivative, poly(p-phenylenevinylene) or its derivative, poly(2,5-thienylenevinylene) or its derivative, polycarbonate, polyacrylate, polymethyl acrylate, polymethyl methacrylate, polystyrene, polyvinyl chloride, polysiloxane and the like.

Polyvinylcarbazole or its derivative can be obtained, for example, from a vinyl monomer by cation polymerization or radical polymerization.

As the polysilane or its derivative, compounds described in Chem. Rev., vol. 89, p. 1359 (1989), GB Patent No. 2300196 publication, and the like are exemplified. Also as the synthesis method, methods described in them can be used, and particularly, a Kipping method is suitably used.

In the polysiloxane or its derivative, the siloxane skeleton structure shows little hole transporting property, thus, those having a structure of the above-mentioned hole transporting material of low molecular weight in a side chain or main chain are suitably used Particularly, those having an aromatic amine showing a hole transporting property in a side chain or main chain are exemplified.

The film formation method of a hole transporting layer is not particularly restricted, and in the case of a hole transporting material of low molecular weight, a method of film formation from a mixed solution with a polymer binder is exemplified. In the case of a hole transporting material of high molecular weight, a method of film formation from a solution is exemplified.

As the solvent used for film formation from a solution, those which can dissolve or uniformly disperse a hole transporting material are preferable. Exemplified as the solvent are chlorine-based solvents such as chloroform, methylene chloride, 1,2-dichloroethane, 1,1,2-trichloroethane, chlorobenzene, o-dichlorobenzene and the like, ether-based solvents such as tetrahydrofuran, dioxane and the like, aromatic hydrocarbon-based solvents such as toluene, xylene and the like, aliphatic hydrocarbon-based solvents such as cyclohexane, methylcyclohexane, n-pentane, n-hexane, n-heptane, n-octane, n-nonane, n-decane and the like, ketone-based solvents such as acetone, methyl ethyl ketone, cyclohexanone and the like, ester-based solvents such as ethyl acetate, butyl acetate, ethylcellosolve acetate and the like, polyhydric alcohols such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin, 1,2-hexanediol and the like and derivatives thereof, alcohol-based solvents such as methanol, ethanol, propanol, isopropanol, cyclohexanol and the like, sulfoxide-based solvents such as dimethyl sulfoxide and the like, amide-based solvents such as N-methyl-2-pyrrolidone, N,N-dimethylformamide and the like. These organic solvents can be used singly or in combination of two or more.

As the method for film formation from a solution, there can be used application methods from a solution such as a spin coat method, casting method, micro gravure coat method, gravure coat method, bar coat method, roll coat method, wire bar coat method, dip coat method, spray coat method, screen printing method, flexo printing method, offset printing method, inkjet printing method and the like.

Regarding the thickness of a hole transporting layer, the optimum value varies depending on a material used, and it may be advantageously selected so that the driving voltage and light emission efficiency become optimum, and a thickness at least causing no formation of pin holes is necessary, and when the thickness is too large, the driving voltage of an element increases undesirably. Therefore, the thickness of the hole transporting layer is, for example, 1 nm to 1 μm, preferably 2 nm to 500 nm, further preferably 5 nm to 200 nm.

When the polymer LED of the present invention has an electron transporting layer, known materials can be used as the electron transporting material to be used, and exemplified are oxadiazole derivative, anthraquinodimethane or its derivative, benzoquinone or its derivative, naphthoquinone or its derivative, anthraquinone or its derivative, tetracyanoanthraquinodimethane or its derivative, fluorenone derivative, diphenyldicyanoethylene or its derivative, diphenoquinone derivative, metal complex of 8-hydroxyquinoline or its derivative, polyquinoline or its derivative, polyquinoxaline or its derivative, polyfluorene or its derivative, and the like.

Specifically, those described in JP-A Nos. 63-70257, 63-175860, 2-135359, 2-135361, 2-209988, 3-37992, 3-152184, and the like are exemplified.

Of them, oxadiazole derivative, benzoquinone or its derivative, anthraquinone or its derivative, metal complex of 8-hydroxyquinoline or its derivative, polyquinoline or its derivative, polyquinoxaline or its derivative, polyfluorene or its derivative are preferable, and 2-(4-biphenylyl)-5-(4-t-butylphenyl)-1,3,4-oxadiazole, benzoquinone, anthraquinone, tris(8-quinolinol)aluminum and polyquinoline are further preferable.

The film formation method of an electron transporting layer is not particularly restricted, and in the case of a electron transporting material of low molecular weight, exemplified are a vacuum vapor-deposition method from powder, film formation methods from solution or melted conditions, and in the case of a electron transporting material of high molecular weight, film formation methods from solution or melted condition are exemplified, respectively. In film formation from solution or melted condition, the above-mentioned polymer binder may be used together.

As the solvent used in film formation from a solution, compounds which can dissolve or uniformly disperse an electron transporting material and/or polymer binder are preferable. Exemplified as the solvent are chlorine-based solvents such as chloroform, methylene chloride, 1,2-dichloroethane, 1,1,2-trichloroethane, chlorobenzene, o-dichlorobenzene and the like, ether-based solvents such as tetrahydrofuran, dioxane and the like, aromatic hydrocarbon-based solvents such as toluene, xylene and the like, aliphatic hydrocarbon-based solvents such as cyclohexane, methylcyclohexane, n-pentane, n-hexane, n-heptane, n-octane, n-nonane, n-decane and the like, ketone-based solvents such as acetone, methyl ethyl ketone, cyclohexanone and the like, ester-based solvents such as ethyl acetate, butyl acetate, ethylcellosolve acetate and the like, polyhydric alcohols such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin, 1,2-hexanediol and the like and derivatives thereof, alcohol-based solvents such as methanol, ethanol propanol, isopropanol, cyclohexanol and the like, sulfoxide-based solvents such as dimethyl sulfoxide and the like, amide-based solvents such as N-methyl-2-pyrrolidone, N,N-dimethylformamide and the like. These organic solvents can be used singly or in combination of two or more.

As the film formation method from solution or melted condition, application methods such as a spin coat method, casting method, micro gravure coat method, gravure coat method, bar coat method, roll coat method, wire bar coat method, dip coat method, spray coat method, screen printing method, flexo printing method, offset printing method, inkjet printing method and the like can be used.

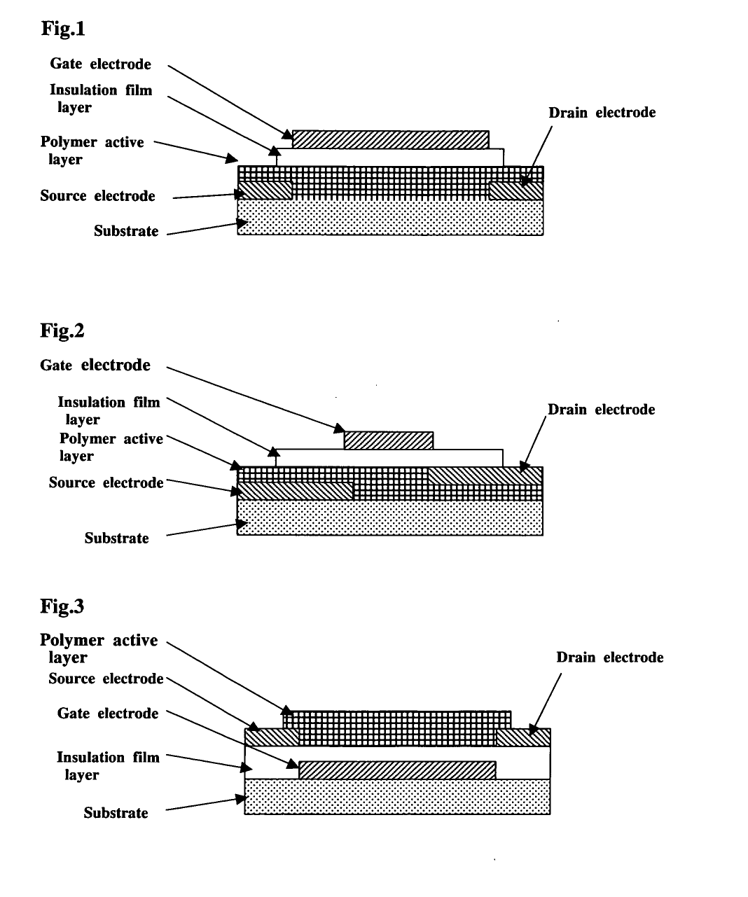

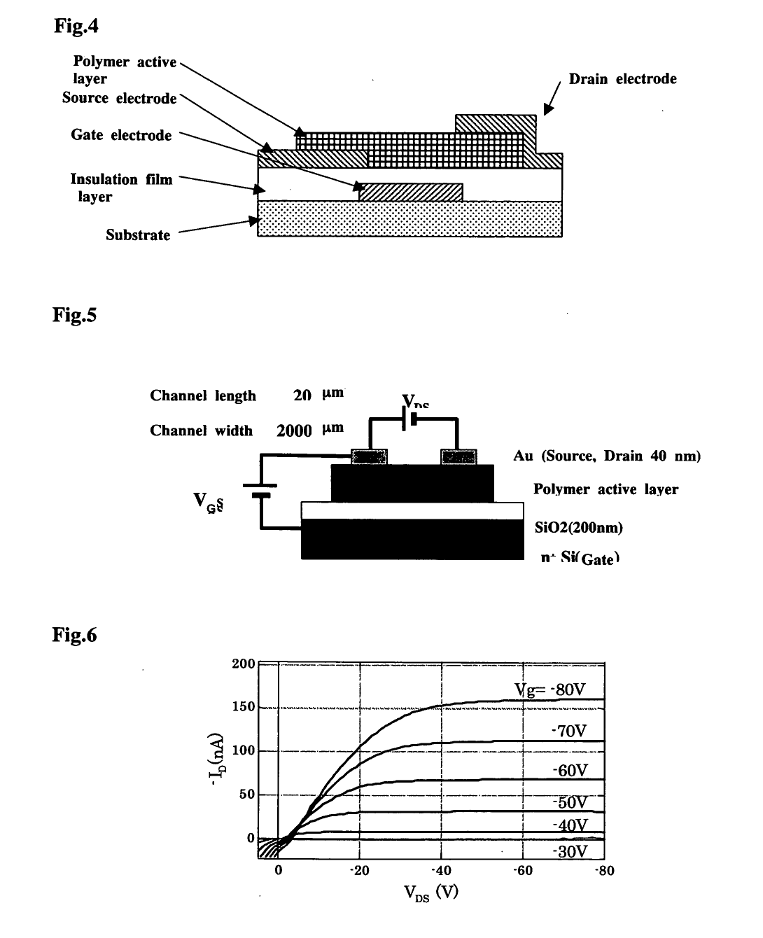

In the structure of a polymer electric field effect transistor of the present invention, it may be usually advantageous that a source electrode and a drain electrode are provided next to an active layer composed of a polymer, further, a gate electrode is provided sandwiching an insulating layer next to the active layer, and for example, structures in FIGS. 1 to 4 are exemplified.

The polymer electric field effect transistor is usually formed on a supporting base plate. The material of the supporting base plate is not particularly restricted providing it does not disturb a property as an electric field effect transistor, and a glass base plate, flexile film base plate and plastic base plate can also be used.

The polymer electric field effect transistor can be produced by known methods, for example, a method described in JP-A No. 5-110069.

In forming an active layer, it is very advantageously preferable to use a polymer soluble in an organic solvent from the standpoint of production. As the film formation method from a solution prepared by dissolving a polymer in an organic solvent, application methods such as a spin coat method, casting method, micro gravure coat method, gravure coat method, bar coat method, roll coat method, wire bar coat method, dip coat method, spray coat method, screen printing method, flexo printing method, offset printing method, inkjet printing method and the like can be used.

Preferable is an insulated polymer electric field effect transistor obtained by producing a polymer electric field effect transistor and then, insulating this. By this, the polymer electric field effect transistor is blocked from atmospheric air, and decrease in the property of a polymer electric field effect transistor can be suppressed.

As the insulation method, a method of covering with a UV hardening resin, thermosetting resin, inorganic SiONx film and the like, a method of pasting a glass plate or film with a UV hardening resin, thermosetting resin and the like, are mentioned. It is preferable that a process after manufacturing of a polymer electric field effect transistor until insulation is conducted without exposing to atmospheric air (for example, in a dried nitrogen atmosphere, in vacuum, and the like), for effectively performing blocking from atmospheric air.

Regarding the thickness of an electron transporting layer, the optimum value varies depending on a material used, and it may be advantageously selected so that the driving voltage and light emission efficiency become optimum, and a thickness at least causing no formation of pin holes is necessary, and when the thickness is too large, the driving voltage of an element increases undesirably. Therefore, the thickness of the electron transporting layer is, for example, 1 nm to 1 μm, preferably 2 nm to 500 nm, further preferably 5 nm to 200 nm.

Among electron charge transporting layers provided next to an electrode, those having a function of improving an charge injecting efficiency from an electrode and having an effect of lowering the driving voltage of an element are, in particularly, called generally an charge injection layer (hole injection layer, electron injection layer).

Further, for improving close adherence with an electrode or improving charge injection from an electrode, the above-mentioned electron charge injection layer or an insulation layer having a thickness of 2 nm or less may be provided next to the electrode, alternatively, for improving close adherence of an interface or preventing mixing, a thin buffer layer may be inserted into an interface of an electron charge transporting layer and a light emitting layer.

The order and number of layers to be laminated, and thickness of each layer can be appropriately determined in view of light emission efficiency and element life.

In the present invention, as the polymer LED carrying a provided charge injection layer (electron injection layer, hole injection layer), mentioned are polymer LED having an charge injection layer provided next to a cathode and polymer LED having an charge injection layer next to an anode.

For example, the following structures e) to p) are specifically mentioned.

e) anode/hole injection layer/light emitting layer/cathode

f) anode/light emitting layer/electron injection layer/cathode

g) anode/hole injection layer/light emitting layer/electron injection layer/cathode

h) anode/hole injection layer/hole transporting layer/light emitting layer/cathode

i) anode/hole injection layer/light emitting layer/electron injection layer/cathode

j) anode/hole injection layer/hole transporting layer/light emitting layer/electron injection layer/cathode

k) anode/hole injection layer/light emitting layer/electron transporting layer/cathode

l) anode/light emitting layer/electron transporting layer/electron injection layer/cathode

m) anode/hole injection layer/light emitting layer/electron transporting layer/electron injection layer/cathode

n) anode/hole injection layer/hole transporting layer/light emitting layer/electron transporting layer/cathode

o) anode/hole transporting layer/light emitting layer/electron transporting layer/electron injection layer/cathode

p) anode/hole injection layer/hole transporting layer/light emitting layer/electron transporting layer/electron injection layer/cathode

The polymer LED of the present invention includes also those in which a polymer compound of the present invention is contained in a hole transporting layer and/or electron transporting layer, as described above.

The polymer LED of the present invention includes those in which a polymer compound of the present invention is contained in a hole injection layer and/or electron injection layer. When a polymer compound of the present invention is used in a hole injection layer, it is preferable that the polymer compound is used simultaneously with an electron receptive compound. When a polymer compound of the present invention is used in an electron transporting layer, it is preferable that the polymer compound is used simultaneously with an electron donating compound. Here, for simultaneous use, there are methods such as mixing, copolymerization, introduction as a side chain, and the like.

As specific examples of the charge injection layer, exemplified are a layer containing an electric conductive polymer, a layer provided between an anode and a hole transporting layer and containing a material having ionization potential of a value between an anode material and a hole transporting material contained in a hole transporting layer, a layer containing a material having electron affinity of a value between a cathode material and an electron transporting material contained in an electron transporting layer, and the like.

When the above-mentioned charge injection layer contains an electric conductive polymer, electric conductivity of the electric conductive polymer is preferably 10⁻⁵ S/cm or more and 10³ S/cm or less, and for decreasing leak current between light emission picture elements, more preferably 10⁻⁵ S/cm or more and 10² S/cm or less, further preferably 10⁻⁵ S/cm or more and 10¹ or less.

When the above-mentioned charge injection layer contains an electric conductive polymer, electric conductivity of the electric conductive polymer is preferably 10⁻⁵ S/cm or more and 10³ or less, and for decreasing leak current between light emission picture elements, more preferably 10⁻⁵ S/cm or more and 10² or less, further preferably 10⁻⁵ S/cm or more and 10¹ or less.

Usually, for controlling the electric conductivity of the electric conductive polymer to 10⁻⁵ S/cm or more and 10³ or less, the electric conductive polymer is doped with a suitable amount of ions.

As the kind of ions to be doped, an anion is used in a hole injection layer and a cation is used in en electron injection layer. Examples of the anion include a polystyrenesulfonic ion, alkylbenzenesulfonic ion, camphorsulfonic ion and the like, and examples of the cation include a lithium ion, sodium ion, potassium ion, tetrabutylammonium ion and the like.

The thickness of the electron injection layer is, for example, 1 nm to 100 nm, preferably 2 nm to 50 nm.

The material used in the electron injection layer may be appropriately selected depending on a relation with the material of an electrode and an adjacent layer, and exemplified are polyaniline or its derivative, polythiophene or its derivative, polypyrrole and its derivative, polyphenylenevinylene and its derivative, polythienylenevinylene and its derivative, polychinolin and its derivative, polyquinoxaline and its derivative, electric conductive polymer such as polymer containing an aromatic amine structure in a side chain or main chain, metal phthalocyanine (copper phthalocyanine and the like), carbon and the like.

An insulation layer having a thickness of 2 nm or less has a function of making charge injection easy. As the material of the above-mentioned insulation layer, a metal fluoride, metal oxide, organic insulating material and the like are mentioned. As the polymer LED carrying an insulation layer having a thickness of 2 nm or less provide thereon, there are mentioned polymer LED in which an insulation layer having a thickness of 2 nm or less is provided next to a cathode, and polymer LED in which an insulation layer having a thickness of 2 nm or less is provided next to an anode.

Specifically, the following structures q) to ab) are mentioned, for example.

q) anode/insulation layer having a thickness of 2 nm or less/light emitting layer/cathode

r) anode/light emitting layer/insulation layer having a thickness of 2 nm or less/cathode

s) anode/insulation layer having a thickness of 2 nm or less/light emitting layer/insulation layer having a thickness of 2 nm or less/cathode

t) anode/insulation layer having a thickness of 2 nm or less/hole injection layer/light emitting layer/cathode

u) anode/hole injection layer/light emitting layer/insulation layer having a thickness of 2 nm or less/cathode

v) anode/insulation layer having a thickness of 2 nm or less/hole transporting layer/light emitting layer/insulation layer having a thickness of 2 nm or less/cathode

w) anode/insulation layer having a thickness of 2 nm or less/light emitting layer/electron transporting layer/cathode

x) anode/light emitting layer/electron transporting layer/insulation layer having a thickness of 2 nm or less/cathode

y) anode/insulation layer having a thickness of 2 nm or less/light emitting layer/electron transporting layer/insulation layer having a thickness of 2 nm or less/cathode

z) anode/insulation layer having a thickness of 2 nm or less/hole transporting layer/light emitting layer/electron transporting layer/cathode

aa) anode/hole transporting layer/light emitting layer/electron transporting layer/insulation layer having a thickness of 2 nm or less/cathode

ab) anode/insulation layer having a thickness of 2 nm or less/hole transporting layer/light emitting layer/electron transporting layer/insulation layer having a thickness of 2 nm or less/cathode

The polymer LED of the present invention includes those having an element structure as exemplified in the above-mentioned a) to ab) in which any one of the hole injection layer, hole transporting layer, light emitting layer, electron transporting layer, electron injection layer contains a polymer compound of the present invention.

The base plate forming polymer LED of the present invention may be that forming an electrode and which does not change in forming a layer of an organic substance, and examples thereof include base plates of glass, plastic, polymer film, silicon and the like. In the case of an opaque base plate, it is preferable that the opposite electrode is transparent or semi-transparent.

Usually, at least one of an anode and cathode contained in polymer LED of the present invention is transparent or semi-transparent. It is preferable, that a cathode is transparent or semi-transparent. As the material of the cathode, an electric conductive metal oxide film, semi-transparent metal film and the like are used. Specifically, films (NESA and the like) formed using electric conductive glass composed of indium oxide, zinc oxide, tin oxide, and composite thereof: indium-tin-oxide (ITO), indium-zinc-oxide and the like, gold, platinum, silver, copper and the like are used, and ITO, indium-zinc-oxide, tin oxide are preferable. As the manufacturing method, a vacuum vapor-deposition method, sputtering method, ion plating method, plating method and the like are mentioned. As the anode, organic transparent electric conductive films made of polyaniline or its derivative, polythiophene or its derivative, and the like may be used.

The thickness of an anode can be appropriately selected in view of light transmission and electric conductivity, and it is, for example, 10 nm to 10 μm, preferably 20 nm to 1 μm, further preferably 50 nm to 500 nm.

For making charge injection easy, a layer made of a phthalocyanine derivative, electric conductive polymer, carbon and the like, or a layer having an average thickness of 2 nm or less made of a metal oxide, metal fluoride, organic insulation material and the like, may be provided on an anode.

As the material of a cathode used in polymer LED of the present invention, materials of small work function are preferable. For example, metals such as lithium, sodium, potassium, rubidium, cesium, beryllium, magnesium, calcium, strontium, barium, aluminum, scandium, vanadium, zinc, yttrium, indium, cerium, samarium, europium, terbium, ytterbium and the like, alloys of two or more of them, or alloys made of at least one of them and at least one gold, silver, platinum, copper, manganese, titanium, cobalt, nickel, tungsten and tin, graphite or graphite intercalation compounds and the like are used. Examples of the alloy include magnesium-silver alloy, magnesium-indium alloy, magnesium-aluminum alloy, indium-silver alloy, lithium-aluminum alloy, lithium-magnesium alloy, lithium-indium alloy, calcium-aluminum alloy and the like. The cathode may take a laminated structure including two or more layers.

The thickness of a cathode can be appropriately selected in view of electric conductivity and durability, and it is, for example, 10 nm to 10 μm, preferably 20 nm to 1 μm, further preferably 50 nm to 500 nm.

As the cathode manufacturing method, a vacuum vapor-deposition method, sputtering method, lamination method of thermally press-binding a metal film, and the like are used. A layer made of an electric conductive polymer, or a layer having an average thickness of 2 nm or less made of a metal oxide, metal fluoride, organic insulation material and the like, may be provided between a cathode and an organic substance layer, and after manufacturing a cathode, a protective layer for protecting the polymer LED may be installed. For use of the polymer LED stably for a long period of time, it is preferable to install a protective layer and/or protective cover, for protecting an element from outside.

As the protective layer, a polymer compound, metal oxide, metal fluoride, metal boride and the like can be used. As the protective cover, a glass plate, and a plastic plate having a surface subjected to low water permeation treatment, and the like can be used, and a method of pasting the cover to an element base plate with a thermosetting resin or photo-curable resin to attain sealing is suitably used. When a space is kept using a spacer, blemishing of an element can be prevented. If an inert gas such as nitrogen, argon and the like is filled in this space, oxidation of a cathode can be prevented, further, by placing a drying agent such as barium oxide and the like in this space, it becomes easy to suppress moisture adsorbed in a production process from imparting damage. It is preferable to adopt one strategy among these methods.

The polymer LED of the present invention can be used as a sheet light source, segment display, dot matrix display, back light of a liquid crystal display.

For obtaining light emission in the form of sheet using polymer LED of the present invention, it may be advantages to place a sheet anode and a sheet cathode so as to overlap. For obtaining light emission in the form of pattern, there are a method in which a mask having a window in the form of pattern is placed on the surface of the above-mentioned sheet light emitting device, a method in which an organic substance layer in non-light emitting parts is formed with extremely large thickness to give substantially no light emission, a method in which either anode or cathode, or both electrodes are formed in the form pattern. By forming a pattern by any of these methods, and placing several electrodes so that on/off is independently possible, a display of segment type is obtained which can display digits, letters, simple marks and the like. Further, for providing a dot matrix element, it may be permissible that both an anode and a cathode are formed in the form of stripe, and placed so as to cross. By using a method in which several polymer fluorescent bodies showing different emission colors are painted separately or a method in which a color filter or a fluorescence conversion filter is used, partial color display and multi-color display are made possible. In the case of a dot matrix element, passive driving is possible, and active driving may be carried out in combination with TFT and the like. These displays can be used as a display of a computer, television, portable terminal, portable telephone, car navigation, view finder of video camera, and the like.

Further, the above-mentioned sheet light emitting device is of self emitting and thin type, and can be suitably used as a sheet light source for back light of a liquid crystal display, or as a sheet light source for illumination. If a flexible base plate is used, it can also be used as a curved light source or display.

The present invention will be illustrate further in detail below, but the invention is not limited to them.

### (Number-Average Molecular Weight and Weight-Average Molecular Weight)

Here, as the number-average molecular weight and the weight-average molecular weight, a number-average molecular weight and a weight-average molecular weight in terms of polystyrene were measured by GPC (manufactured by Shimadzu Corp., LC-10Avp). A polymer to be measured was dissolved in tetrahydrofuran so as to give a concentration of about 0.5 wt %, and the solution was injected in an amount of 50 μL into GPC. Tetrahydrofuran was used as the mobile phase of GPC, and allowed to flow at a flow rate of 0.6 mL/min. In the column, two TSKgel Super HM-H (manufactured by Tosoh Corp.) and one TSKgel Super H2000 (manufactured by Tosoh Corp.) were connected serially. A differential refractive index detector (RID-10A: manufactured by Shimadzu Corp.) was used as a detector.

### (Fluorescent Spectrum)

Fluorescent spectrum was measured according to the following method. A 0.8 wt % toluene or chloroform solution of a polymer was spin-coated on quartz to form a film of the polymer. This film was excited at a wavelength of 350 nm, and fluorescent spectrum was measured using a fluorescence spectrophotometer (Fluorolog manufactured by Horiba, Ltd.). For obtaining relative fluorescence intensity in the film, fluorescent spectrum plotted against wave number was integrated in the spectrum measuring range utilizing the intensity of Raman line of water as a standard, and measurement was performed using a spectrophotometer (Cary 5E, manufactured by Varian), obtaining a value allocated to the absorbance at the excited wavelength.

### (Glass Transition Temperature)

The glass transition temperature was measured by DSC (DSC2920, manufactured by TA Instruments)

### (Measurement of LUMO)

For measurement of LUMO of a polymer compound, cyclic voltammetry (ALS600, manufactured by BAS) was used, and measurement was performed in an acetonitrile solvent containing 0.1 wt % tetrabutylammonium-tetrafluoroborate. A polymer compound was dissolved in chloroform to give a concentration of about 0.2 wt %, then, a chloroform solution of the polymer compound was applied in an amount of 1 mL on an action electrode, and chloroform was vaporized to form a film of the polymer compound. For measurement, a silver/silver ion electrode as a reference electrode, glassy carbon electrode as an action electrode, and a platinum electrode as a counter electrode, were used, and measurement was effected in a glove box purged with nitrogen. The sweeping rates of potential were both measured at 50 mV/s. LUMO was calculated from the reduction potential obtained by the cyclic voltammetry.

### (Measurement of HPLC)

Measurement apparatus: Agilent 1100 LC

Measuring conditions: L-Column ODS, 5 μm, 2.1 mm×150 mm;

A liquid: acetonitrile, B liquid: THD

Gradient

B liquid:

0%→(60 min)→0%→(10 min)→100%→(10 min)→100%

Sample concentration: 5.0 mg/mL (THF solution)

Injection amount: 1 μL

Detection wavelength: 350 nm

### (Measurement of NMR)

For measurement of NMR, a polymer was used as a deuterated tetrahydrofuran solution, and measurement was conducted at 30° C. using magnetic resonance apparatus: Advance 600 manufactured by Bulker.

### SYNTHESIS EXAMPLE 1

### Synthesis of 1-bromo-4-t-butyl-2,6-dimethylbenzene

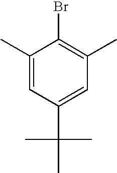

Under an inert atmosphere, 225 g of acetic acid was charged in a 500 ml three-necked flask, and 24.3 g of 5-t-butyl-m-xylene was added. Subsequently, 31.2 g of bromine was added, then, the mixture was reacted at 15 to 20° C. for 3 hours.

The reaction solution was added to 500 ml of water, and the deposited precipitate was filtrated. This was washed with 250 ml of water twice, to obtain 34.2 g of white solid.

¹H-NMR (300 MHz/CDCl₃):

δ (ppm)=1.3 (s, 9H), 2.4 (s, 6H), 7.1 (s, 2H)

MS (FD+) M+ 241

### Synthesis of N,N′-diphenyl-N,N′-bis(4-t-butyl-2,6-dimethylphenyl)-1,4-phenylenediamine

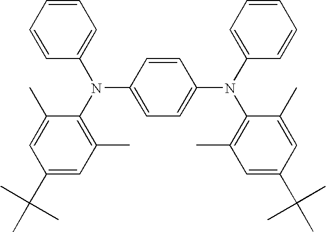

Under an inert atmosphere, 36 ml of dehydrated toluene was charged in a 100 ml three-necked flask, and 0.63 g of tri(t-butyl)phosphine was added. Subsequently, 0.41 g of tris(dibenzylideneacetone)dipalladium, 9.6 g of 1-bromo-4-t-butyl-2,6-dimethylbenzene, 5.2 g of t-butoxysodium, and 4.7 g of N,N′-diphenyl-1,4-phenylenediamine were added, then, the mixture was reacted at 100° C. for 3 hours.

The reaction solution was added to 300 ml of saturated saline, and extracted with 300 ml of chloroform heated at about 50° C. The solvent was distilled off, then, 100 ml of toluene was added, and heated until dissolution of solid, and allowed to cool, then, the precipitate was filtrated to obtain 9.9 g of white solid.

### Synthesis of N,N′-bis(4-bromophenyl)-N,N′-bis(4-t-butyl-2,6-dimethylphenyl)-1,4-phenylenediamine

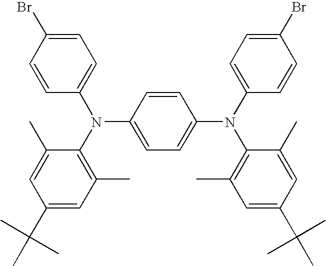

Under an inert atmosphere, 350 ml of dehydrated N,N-dimethylformamide was charged in a 100 ml three-necked flask, and 5.2 g of N′-diphenyl-N,N′-bis(4-t-butyl-2,6-dimethylphenyl)-1,4-phenylenediamine was dissolved, then, a solution of N-bromosuccinimide 3.5 g/N,N-dimethylformamide was dropped under cooling with an ace bath, and the mixture was reacted over night and day.

150 ml of water added to the reaction solution, and the deposited precipitate was filtrated, and washed with 50 ml of methanol twice, to obtain 4.4 g of white solid.

¹H-NMR (300 MHz/THF-d8):

δ(ppm)=1.3 (s, 18H), 2.0 (s, 12H), 6.6˜6.7 (d, 4H), 6.8˜6.9 (br, 4H), 7.1 (s, 4H), 7.2˜7.3 (d, 4H)

MS (FD+) M⁺ 738

### SYNTHESIS EXAMPLE 2

### Synthesis of N,N′-diphenyl-N,N′-bis(4-t-butyl-2,6-dimethylphenyl)-benzidine

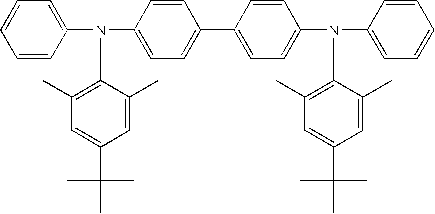

Under an inert atmosphere, 1660 ml of dehydrated toluene was charged in a 300 ml three-necked flask, and 275.0 g of N,N′-diphenylbenzidine and 449.0 g of 4-t-butyl-2,6-dimethylbromobenzene were added. Subsequently, 7.48 g of tris(dibenzylideneacetone)dipalladium and 196.4 g of t-butoxysodium were added, then, 5.0 g of tri(t-butyl)phosphine was added. Thereafter, the mixture was reacted at 105° C. for 7 hours.

2000 ml of toluene was added to the reaction solution, filtrated through cerite, and the filtrate was washed with 1000 ml of water three times, then, concentrated to 700 ml. To this was added 1600 ml of toluene/methanol (1:1) solution, the deposited crystal was filtrated, and washed with methanol. 479.4 g of white solid was obtained.

MS (APCI (+)): (M+H)⁺ 657.4

### Synthesis of N,N′-bis(4-bromophenyl)-N,N′-bis(4-t-butyl-2,6-dimethylphenyl)-benzidine

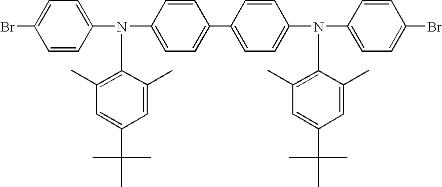

Under an inert atmosphere, into 4730 g of chloroform was dissolved 472.8 g of the above-mentioned N,N′-diphenyl-N,N′-bis(4-t-butyl-2,6-dimethylphenyl)-benzidine, then, 281.8 g of N-bromosuccinimide was charged in 12-division over 1 hour under shading and cooling with an ice bath and reacted for 3 hours.

1439 ml of chloroform was added to the reaction solution, filtrated, and the filtrate chloroform solution was washed with 2159 ml of 5% sodium thiosulfate, and toluene was removed to obtain a white crystal. The resultant white crystal was re-crystallized from toluene/ethanol, to obtain 678.7 g white crystal.

MS (APCI (+)): (M+H)⁺ 815.2

### SYNTHESIS EXAMPLE 3

### Synthesis of Compound T

### (Synthesis of Compound S)

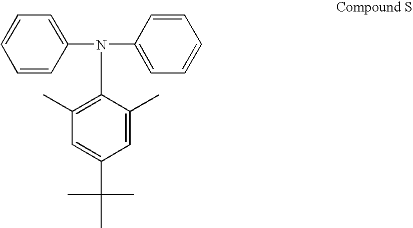

Under an inert atmosphere, 100 ml of dehydrated toluene was charged in a 300 ml three-necked flask, and 16.9 g of diphenylamine and 25.3 g of 1-bromo-4-t-butyl-2,6-dimethylbenzene were added. Subsequently, 0.92 g of tris(dibenzylideneacetone)dipalladium and 12.0 g of t-butoxysodium were added, then, 1.01 g of tri(t-butyl)phosphine was added. Thereafter, the mixture was reacted at 100° C. for 7 hours.

The reaction solution was poured into a saturated saline solution and extracted with 100 ml of toluene. The toluene layer was washed with dilute hydrochloric acid and saturated saline solution, then, the solvent was distilled off to obtain black solid. This was separated and purified by silica gel column chromatography (hexane/chloroform 9/1), to obtain 30.1 g of white solid.

¹H-NMR (300 MHz/CDCl₃): δ (ppm)=1.3 (s, 9H), 2.0 (s, 6H), 6.8˜7.3 (m, 10H)

### (Synthesis of Compound T)

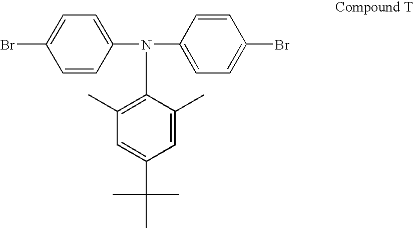

Under an inert atmosphere, 333 ml of dehydrated N,N-dimethylformamide and 166 ml of hexane were charged in a 1000 ml three-necked flask, and 29.7 g of the above-mentioned N,N-diphenyl-N-(4-t-butyl-2,6-dimethylphenyl)-amine was dissolved, then, 100 ml of solution of N-bromosuccinimide 33.6 g/N,N-dimethylformamide was dropped under shading and cooling with an ice bath, and reacted over night and day.

The reaction solution was concentrated under reduced pressure until 200 ml, 1000 ml of water was added, and the deposited precipitate was filtrated. Further, resultant crystal was re-crystallized from DMF/ethanol twice, to obtain 23.4 g of white solid.

¹H-NMR (300 MHz/CDCl₃):

δ(ppm) 1.3 (s, 9H), 2.0 (s, 6H), 6.8 (d, 2H), 7.1 (s, 2H), 7.3 (d, 2H),

MS (APCI (+)): M⁺ 488

### SYNTHESIS EXAMPLE 4

### Synthesis of Compound G

### (Synthesis of Compound D)

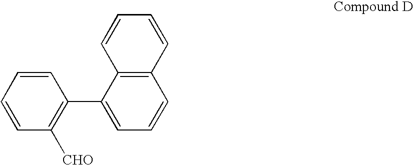

Under an inert atmosphere, 5.00 g (29 mmol) of 1-naphthaleneboronic acid, 6.46 g (35 mmol) of 2-bromobenzaldehyde, 10.0 g (73 mmol) of potassium carbonate, 36 ml of toluene and 36 mol of ion exchanged water were charged in a 300 ml three-necked flask, and argon was bubbled through at room temperature for 20 minutes while stirring. Subsequently, 16.8 mg (0.15 mmol) of tetrakis(triphenylphosphine)palladium was added, further, argon was bubbled through at room temperature for 10 minutes while stirring. The mixture was heated up to 100° C. and reacted for 25 hours. The reaction solution was cooled down to room temperature, then, the organic layer was extracted by toluene, and dried over sodium sulfate, then, the solvent was distilled off. The product was purified by silica gel column using toluene:cyclohexane=1:2 mixed solvent as a developing solvent, to obtain 5.18 g (yield: 86%) of compound D as white crystal.

¹H-NMR (300 MHz/CDCl₃):

δ 7.39˜7.62 (m, 5H), 7.70 (m, 2H), 7.94 (d, 2H), 8.12 (dd, 2H), 9.63 (s, 1H)

MS (APCI (+)): (M+H)⁺ 233

### (Synthesis of Compound E)

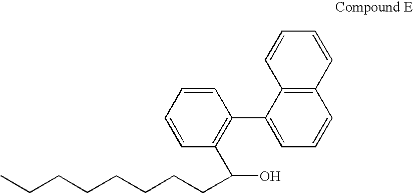

Under an inert atmosphere, 8.00 g (34.4 mmol) of compound D and 46 ml of dehydrated THF were charged in a 300 ml three-necked flask, and the mixture was cooled down to −78° C. Subsequently, 52 ml of n-octylmagnesium bromide (1.0 mol/l THF solution) was dropped over 30 minutes. After completion of dropping, the mixture was heated up to 0° C., stirred for 1 hour, then, heated up to room temperature and stirred for 45 minutes. In an ice bath, 20 ml of 1N hydrochloric acid was added to terminate the reaction, and the organic layer was extracted with ethyl acetate, and dried over sodium sulfate. The solvent was distilled off, then, the product was purified by silica gel column using toluene: hexane=10:1 mixed solvent as a developing solvent, to obtain 7.64 g (yield: 64%) of compound E as pale yellow oil. HPCL measurement showed two peaks, however, LC-MS measurement showed the same mass number, thus, the oil was judged to be a mixture of isomers.

### (Synthesis of Compound F)

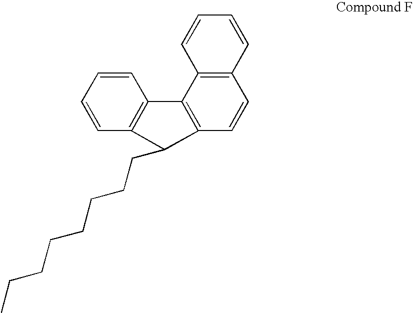

Under an inert atmosphere, 5.00 g (14.4 mmol) of compound E (mixture of isomers) and 74 ml of dehydrated dichloromethane were charged in a 500 ml three-necked flask, and the mixture was stirred and dissolved at room temperature. Subsequently, an etherate complex of boron trifluoride was dropped at room temperature over 1 hour, and after completion of dropping, the mixture was stirred for 4 hours at room temperature. 125 ml of ethanol was added slowly while stirring, and when heat generation was over, the organic layer was extracted with chloroform, washed twice with water, and dried over magnesium sulfate. The solvent was distilled off, then, the product was purified by silica gel column using hexane as a developing solvent, to obtain 3.22 g (yield: 68%) of compound F as colorless oil.

¹H-NMR (300 MHz/CDCl₃):

δ0.90 (t, 3H), 1.03˜1.26 (m, 14H), 2.13 (m, 2H), 4.05 (t, 1H), 7.35 (dd, 1H), 7.46˜7.50 (m, 2H), 7.59˜7.65 (m, 3H), 7.82 (d, 1H), 7.94 (d, 1H), 8.35 (d, 1H), 8.75 (d, 1H)

MS (APCI (+)): (M+H)⁺ 329

### (Synthesis of Compound G)

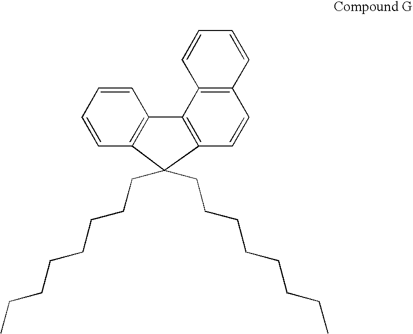

Under an inert atmosphere, 20 ml of ion exchanged water was charged in a 200 ml three-necked flask, and 18.9 g (0.47 mol) of sodium hydroxide was added portion-wise while stirring, to cause dissolution. The aqueous solution was cooled to room temperature, then, 20 ml of toluene, 5.17 g (15.7 mmol) of compound F and 1.52 g (4.72 mmol) of tributylammonium bromide were added, and the mixture was heated up to 50° C. n-octyl bromide was dropped, and after completion of dropping, the mixture was reacted at 50° C. for 9 hours. After completion of the reaction, the organic layer was extracted with toluene, washed twice with water, and dried over sodium sulfate. The product was purified by silica gel column using hexane as a developing solvent, to obtain 5.13 g (yield: 74%) of compound G as yellow oil.

¹H-NMR (300 MHz/CDCl₃):

δ 0.52 (m, 2H), 0.79 (t, 6H), 1.00˜1.20 (m, 22H), 2.05 (t, 4H), 7.34 (d, 1H), 7.40˜7.53 (m, 2H), 7.63 (m, 3H), 7.83 (d, 1H), 7.94 (d, 1H), 8.31 (d, 1H), 8.75 (d, 1H)

MS (APCI (+)): (M+H)⁺ 441

### EXAMPLE 1

### Synthesis of Compound H

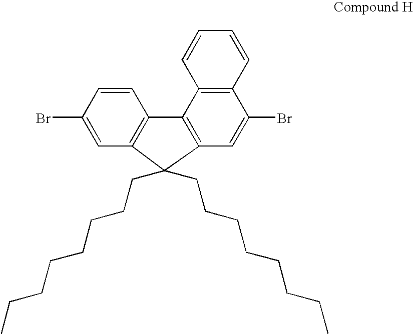

Under an air atmosphere, 4.00 g (9.08 mmol) of compound G and 57 ml of acetic acid: dichloromethane=1:1 mixed solvent were charged in a 50 ml three-necked flask, and the mixture was stirred at room temperature to cause dissolution. Subsequently, 7.79 g (20.0 mmol) of benzyltrimethylammonium tribromide was added, and zinc chloride was added until completion of dissolution of benzyltrimethylammonium tribromide while stirring. The mixture was stirred at room temperature for 20 hours, then, 10 ml of a 5% sodium hydrogen sulfite aqueous solution was added to terminate the reaction, the organic layer was extracted with chloroform, washed with a potassium carbonate aqueous solution twice, and dried over sodium sulfate. The product was purified twice by flush column using hexane as a developing solvent, then, re-crystallized from ethanol:hexane=1:1, subsequently, 10:1 mixed solvent, to obtain 4.13 g (yield: 76%) of compound H as white crystal.

¹H-NMR (300 MHz/CDCl₃):

δ 0.60 (m, 2H), 0.91 (t, 6H), 1.01˜1.38 (m, 22H), 2.09 (t, 4H), 7.62˜7.75 (m, 3H), 7.89 (s, 1H), 8.20 (d, 1H), 8.47 (d, 1H), 8.72 (d, 1H)

MS (APPI (+)): (M+H)⁺ 598

### SYNTHESIS EXAMPLE 5

A 100 ml four-necked round bottomed flask was purged with an argon gas, then, compound H (3.2 g, 5.3 mmol), bispinacolatedirobon (3.8 g, 14.8 mmol), PdCl₂ (dppf)(0.39 g, 0.45 mmol), bis(diphenylphosphino)ferrocene (0.27 g, 0.45 mmol) and potassium acetate (3.1 g, 32 mmol) were charged, and 45 ml of dehydrated dioxane was added. Under an argon atmosphere, the mixture was heated up to 100° C. and reacted for 36 hours. After allowing the product to cool, 2 g of cerite was pre-coated and filtration was carried out, and concentrated, to obtain a black solution. It was dissolved in 50 g of hexane and coloring components was removed by activated carbon to obtain 37 g of pale yellow liquid (in filtration, 5 g of radiolite (manufactured by Showa Kagaku Kogyo K.K.) was pre-coated).

6 g of ethyl acetate, 12 g of dehydrated methanol and 2 g of hexane were added, and immersed in a dry ice-methanol bath, to obtain 2.1 g of compound I in the form of colorless crystal.

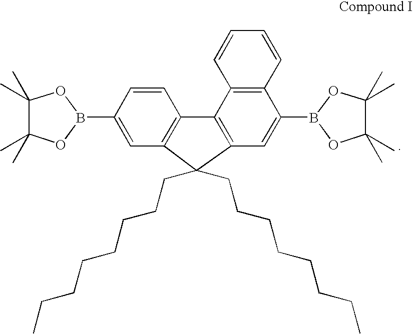

### SYNTHESIS EXAMPLE 6

### Synthesis of Compound J

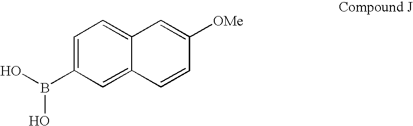

Under an argon atmosphere, magnesium chips (9.99 g, 0.411 mol) and tetrahydrofuran (dehydrated solvent) (30 mL) were charged in a 500 mL flask. 1,2-dibromoethane (5.94 g, 0.032 mol) was dropped, and after confirmation of bubbling, 2-bromo-6-methoxynaphthalene (75 g, 0.316 mol) dissolved in tetrahydrofuran (dehydrated solvent) (484 mL) was dropped over 40 minutes, then, refluxed for 30 minutes, to prepare a Grignard solution.

Under an argon atmosphere, trimethoxyborane (49.3 g, 0.476 mol), tetrahydrofuran (dehydrated solvent) (160 ml) were charged in a 500 mL flask, and the mixture was cooled to −78° C., into this was dropped the above-mentioned Grignard solution over 1.25 hours. The mixture was heated up to room temperature over 2 hours, then, 75 mL of ion exchanged water was added, and the mixture was stirred for about 30 minutes. Concentration under reduced pressure distilled the solvent off, then, ion exchanged water (200 mL), 1 N HCl (500 mL) and dichloromethane (80 mL) were added and the mixture was stirred vigorously for 30 minutes. Solid was filtrated, and washed with dichloromethane (100 mL), and dried under reduced pressure to obtain compound J (53.0 g, yield 75%) in the form of white solid.

¹H-NMR (300 MHz/CDCl₃):

δ 3.35 (s, 2H), 3.95 (s, 3H), 7.15 (d, 1H), 7.22 (s, 1H), 7.63-7.82 (m, 3H), 8.10-8.25 (bd, 1H)

### (Synthesis of Compound K)

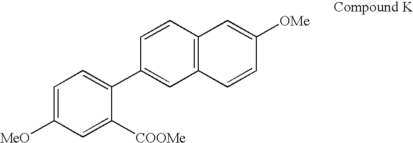

Under an argon atmosphere, methyl 2-bromo-5-methoxybenzoate (56.0 g, 0.229 mol), compound J (51.0 g, 0.240 mol) and toluene (268 mL) deaerated previously by bubbling with an argon gas were charged in a 1 L flask, and the mixture was heated up to 60° C. while bubbling with an argon gas. Separately, an aqueous solution of potassium carbonate (82.0 g, 0.593 mol) dissolved in ion exchanged water (273 mL) was deaerated by bubbling with an argon gas for 30 minutes, then, poured into the above-mentioned solution. When the mass reached 65° C., tetrakis(triphenylphosphine)palladium (0) (2,743 g, 0.0024 mol) was charged, and the mixture was heated and refluxed for 3 hours. Methyl 2-bromo-5-methoxybenzoate (2.17 g, 0.090 mol) was additionally charged, and the mixture was refluxed for 3 hours. The mixture was separated, and the aqueous layer was extracted with toluene, then, the oil layer was combined. After passing through a silica gel short column, the product was concentrated and crystallized, and filtrated and dried, to obtain compound K (71.9 g, yield 93%) in the form of white solid.

¹H-NMR (300 MHz/CDCl₃):

δ 3.59 (s, 3H), 3.86 (s, 3H), 3.94 (s, 3H), 7.07-7.19 (m, 2H), 7.34-7.42 (m, 2H), 7.69-7.76 (m, 2H)

LC/MS (APPI(+)): M⁺ 322

### (Synthesis of Compound L)

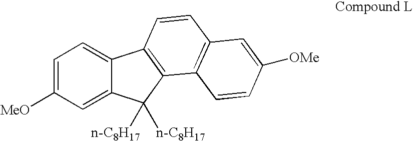

Under an argon atmosphere, compound K (40.00 g, 0.122 mol) was dissolved in tetrahydrofuran (dehydrated solvent) (220 g) with stirring in a 1 L flask, and cooled in an ice bath. Into this was dropped n-octylmagnesium bromide (22 wt %, tetrahydrofuran solution, 482 g, 0.487 mol), and the mixture was stirred at room temperature over night. After reaction, 1 N hydrochloric acid water (820 mL) was added and stirred, then, the mixture was separated. The aqueous layer was extracted with toluene, then, the organic layer was combined. The resulting organic layer was washed with water, then, dried over anhydrous sodium sulfate, and concentrated to distill off the solvent, to obtain an alkylated coarse product (64.5 g) in the form of oil.

Under an argon atmosphere, the above-mentioned alkylated coarse product (30 g) was dissolved in tetrahydrofuran (dehydrated solvent) (242 g) with stirring in a 500 mL flask, and cooled in an ice bath. Into this was charged sodium borohydride (1.269 g, 0.0335 mol), and the ice bath was removed, and the mixture was thermally insulated at room temperature for 15.5 hours. Sodium borohydride (1.3 g, 0.0344 mol) was additionally added, and the mixture was thermally insulated at 40° C. for 7 hours, then, ethanol (30 g) was additionally added, and the mixture was heated to 50° C. and thermally insulated for 7.5 hours. In 1 N hydrochloric acid water (400 g), a reaction mass was poured and the mixture was stirred, then, the organic layer was extracted with chloroform. The resultant organic layer was washed with water, then, dried over anhydrous sodium sulfate, and concentrated to distilled off the solvent, to obtain a reduced coarse produce (28.8 g) in the form of oil.

Under an argon atmosphere, boron trifluoride-diethyl ether complex (98.2 g, 0.692 mol) was mixed in methylene chloride (63.9 g) with stirring in a 500 mL flask, and the above-mentioned reduced coarse product (15.29 g) was diluted in methylene chloride (63.9 g), then, dropped into the above-mentioned mixture at room temperature over 14 minutes, then, the mixture was thermally insulated at room temperature for 3 hours. After the reaction, a reaction mass was poured into water (250 mL) and the mixture was stirred, and the organic layer was extracted with chloroform. The resultant organic layer was washed with water, then, dried over anhydrous sodium sulfate, and concentrated to distill off the solvent, to obtain a cyclized coarse product (14.8 g) in the form of oil.

Under an argon atmosphere, sodium hydroxide (30.8 g, 0.769 mol) was dissolved in water (32 g) with stirring in a 200 mL flask, and the mixture was cooled to room temperature, then, the above-mentioned cyclized coarse product (14.78 g) was diluted in toluene (37 g) and charged into this at room temperature. Subsequently, tetra-n-butylammonium bromide (2.48 g, 0.00769 mol) was charged and the mixture was heated to 50° C., then, 1-bromooctane (9.90 g, 0.0513 mol) was dropped over 6 minutes, and the mixture was thermally insulated at 50° C. for 5 hours and at 60° C. for 7 hours. After the reaction, a reaction mass was poured into water (200 mL), the mixture was stirred, then, separated. The aqueous layer was extracted with toluene, and the oil layer was combined. The resulting oil layer was washed with water, then, dried over anhydrous sodium sulfate, and concentrated to distill off the solvent, to obtain an oil (12.6 g). The resulting oil was purified by a silica gel column using a mixed solvent of hexane/toluene=4/1 as a developing solvent, to obtain compound L (7.59 g, yield 50%) in the form of oil.

¹H-NMR (300 MHz/CDCl₃):

δ 0.30-0.50 (m, 4H), 0.72-0.83 (t, 6H), 0.83-1.20 (m, 20H), 2.05-2.20 (m, 2H), 2.35-2.50 (m, 2H), 3.90 (s, 3H), 3.94 (s, 3H), 6.87-6.95 (m, 2H), 7.19-7.23 (m, 2H), 7.61 (d, 1H), 7.70-7.80 (m, 2H), 8.06 (d, 1H)

### (Synthesis of Compound L)

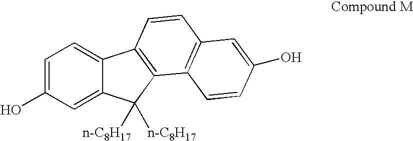

Under an argon atmosphere, into a 200 mL flask was charged compound L (4.07 g, 0.0080 mol) and methylene chloride (36.3 g) and the mixture was stirred and diluted, then, cooled down to −78° C., and a methylene chloride solution of trimethoxyborane (1 M, 20.1 mL, 0.0201 mol) was dropped into this mixture over 1 hour. The mixture was heated up to room temperature over 1 hour, then, thermally insulated at room temperature for 4 hours. A reaction mass was poured into ice-cooled water (15 g), and the mixture was stirred until the oil layer became clear. The mixture was separated, and the aqueous layer was extracted with methylene chloride, then, the oil layer was combined. The resulting oil layer was washed with water, and concentrated to obtain compound M (4.16 g, yield 96%) in the form of white yellow solid.

¹H-NMR (300 MHz/CDCl₃):

δ 0.30-0.50 (m, 4H), 0.78 (t, 6H, J=6.9 Hz), 0.85-1.21 (m, 20H), 2.22 (dt, 4H, J=11.4, 5.4 Hz), 4.83 (s, 1H), 4.98 (s, 1H), 6.83 (d, 1H), 6.90 (s, 1H), 7.15 (d, 1H), 7.25 (s, 1H), 7.57 (d, 1H), 7.60 (d, 1H), 7.63 (d, 1H), 8.06 (d, 1H)

LC/MS (APPI(+)): (M+H)⁺ 473

### EXAMPLE 2

### Synthesis of Compound N

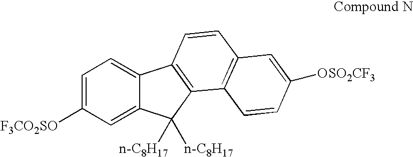

Under an argon atmosphere, into a 200 mL flask was charged compound M (4.00 g, 0.0082 mol), triethylamine (2.49 g, 0.0246 mol) and methylene chloride (55.8 g) and the mixture was stirred and dissolved, then, cooled down to −78° C., and trifluoromethanesulfonic anhydride (5.09 g, 0.0181 mol) was dropped into this over 30 minutes. The mixture was heated up to room temperature over 1.5 hours, then, thermally insulated at room temperature for 5 hours. A reaction mass was poured into ice-cooled 1N hydrochloric acid water (80 g), and extracted with n-hexane. The resultant oil layer was washed with a saturated sodium hydrogencarbonate aqueous solution, then, dried over anhydrous sodium sulfate. The resultant oil layer was passed through a silica gel short column, further, toluene was passed through this silica gel short column, and combined, then, concentrated and dried to solid. The resultant solid was re-crystallized from n-hexane, and filtrated and dried, to obtain compound N (5.13 g, yield 85%) in the form of white solid.

¹H-NMR (300 MHz/CDCl₃):

δ 0.28-0.43 (m, 4H), 0.77 (t, 6H, J=7.1 Hz), 0.83-1.26 (m, 20H), 2.17-2.30 (m, 2H), 2.35-2.49 (m, 2H), 7.33 (d, 1H), 7.35 (s, 1H), 7.48 (d, 1H, J=9.3 Hz), 7.81-7.95 (m, 4H), 8.26 (d, 1H, J=9.3 Hz)

LC/MS (APPI(+)): M⁺ 736

### EXAMPLE 3

### Synthesis of Compound O

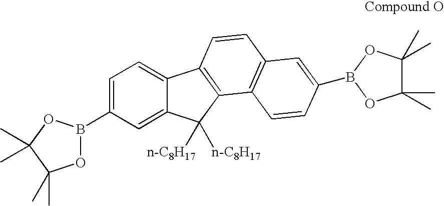

Under an argon atmosphere, into a 200 mL flask was charged compound N (3.88 g, 0.0053 mol), pinacoldiborane (2.94 g, 0.0116 mol), dichlorobisdiphenylphosphinoferrocenepalladium(II) (0.258 g, 0.00027 mol), diphenylphosphinoferrocene (0.175 g, 0.00027 mol) and potassium acetate (3.10 g, 0.0316 mol), and an atmosphere in the flask was purged with an argon gas, then, 1,4-dioxane (dehydrated solvent) (46.4 g) was charged, and the mixture was heated up to 100° C., and thermally insulated at 100° C. for 4 hors. After allowing the mixture to cool to room temperature, diluted with n-hexane (100 mL) and insoluble materials were filtrated off on a filter pre-coated with radiolite. The product was concentrated, and the solvent was substituted by toluene, then, passed through a silica gel short column. The produce was concentrated, and the solvent was substituted by n-hexane, then, activated carbon (5 g) was added and the mixture was stirred for 30 minutes, then, insoluble materials were filtrated off on a filter pre-coated with radiolite, to obtain colorless transparent liquid. It was concentrated and dried to solid, obtaining white solid. Ethyl acetate (5.1 g) was added, and the mixture was heated up to 60° C. to cause dissolution thereof, then, the mixture was allowed to cool to room temperature, and methanol (40 g) was dropped while stirring to cause crystallization, and the crystal was filtrated and dried to obtain compound O (2.04 g, yield 55%) in the form of white solid.

¹H-NMR (300 MHz/CDCl₃):

δ 0.22-0.43 (m, 4H), 0.77 (t, 3H), 0.83-1.22 (m, 20H), 1.40 (s, 24H), 2.20-2.40 (m, 2H), 2.40-2.55 (m, 2H), 7.76-7.95 (m, 6H), 8.19 (d, 1H), 8.47 (s, 1H)

LC/MS (APPI(+)): M⁺ 692

### SYNTHESIS EXAMPLE 7

### Synthesis of Compound P

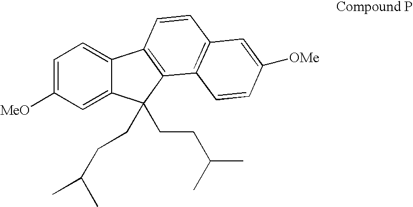

Compound P (18.2 g, yield 47%) in the form of white solid was synthesized from compound J (30.0 g, 0.0919 mol) using isoamylmagnesium bromide prepared by a usual method from magnesium and isoamyl bromide instead of n-octylmagnesium bromide, by the same method as for synthesis of compound L.

¹H-NMR (300 MHz/CDCl₃):

δ 0.20-0.40 (dt, 4H), 0.57 (d, 6H, J=7 Hz), 0.59 (d, 6H, J=7 Hz), 1.14-1.27 (qq, 2H), 2.10-2.20 (dt, 2H), 2.37-2.48 (dt, 2H), 3.88 (s, 3H), 3.93 (s, 3H), 6.89-6.92 (d, 1H), 6.95 (s, 1H), 7.15-7.24 (m, 2H), 7.60-7.63 (d, 1H), 7.71-7.78 (m, 2H), 8.05-8.08 (d, 1H)

LC/MS (APPI(+)): (M+H)⁺ 417

### (Synthesis of Compound Q)

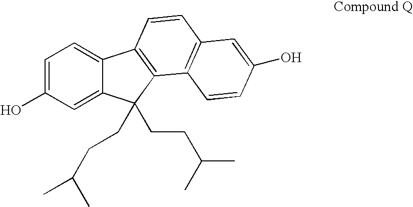

Compound Q (15.2 g, yield 90%) in the form of white solid was synthesized from compound P (18.0 g, 0.0430 mol), by the same method as for compound M.

¹H-NMR (300 MHz/THF-d₈):

δ 0.20-0.52 (m, 4H), 0.53-0.78 (m, 12H), 1.10-1.35 (m, 2H), 2.10-2.23 (m, 2H), 2.40-2.60 (m, 2H), 6.73 (d, 1H), 6.85 (s, 1H), 7.05-7.20 (m, 2H), 7.50-7.72 (m, 3H), 8.08 (d, 1H), 8.17 (s, 1H), 8.43 (s, 1H)

LC/MS (APPI(+)): (M+H)⁺ 389

### EXAMPLE 7

### Synthesis of Compound R

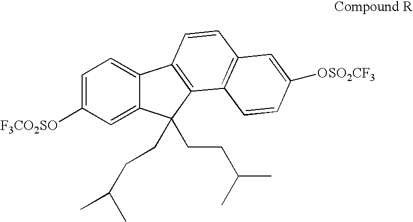

Compound R (21.6 g, yield 87%) in the form of white solid was synthesized from compound Q (15.0 g, 0.0380 mol), by the same method as for compound N.

¹H-NMR (300 MHz/CDCl₃):

δ 0.19-0.27 (m, 4H), 0.51-0.63 (m, 12H), 1.16-1.30 (m, 2H), 2.20-2.31 (m, 2H), 2.40-2.51 (m, 2H), 7.25-7.37 (m, 2H), 7.47-7.52 (d, 1H), 7.82-7.99 (m, 4H), 8.24-8.28 (d, 1H)

LC/MS (APPI(+)): M⁺ 652

### SYNTHESIS EXAMPLE 8

### Synthesis of Compound TA

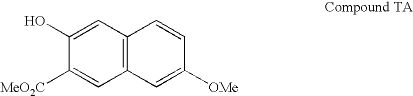

500 ml of methanol was added to 78.0 g of 2-hydroxy-7-methoxynaphtoic acid in a 1000 ml egg plant-shaped flask and the mixture was stirred vigorously, 10 ml of sulfuric acid was dropped, and the mixture was stirred for 6 hours while heating under reflux. The cooled reaction solution was slowly poured into 1 kg of ice to deposit a product. The resulting precipitate was filtrated and washed with 2000 ml of ice water, then, dried to obtain 81.6 g (yield 96.9%) of compound TA.

¹H-NMR (300 MHz/CDCl₃): δ 3.89 (s, 3H), 4.00 (s, 3H), 7.07 (d, 1H), 7.19 (dd, 1H), 7.26 (s, 1H), 7.59 (d, 1H), 8.37 (s, 1H), 10.28 (s, 1H)

LC-MS (APCI-+): 233.2

### (Synthesis of Compound TB)

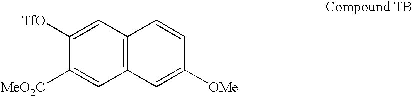

Into a nitrogen purged 2000 ml three-necked flask was added 81.6 g of compound TA, 1000 ml of methylene chloride and 70 ml of triethylamine, to prepare a solution. The solution was cooled to 0° C. in an ice bath, then, 60 ml of trifluoromethanesulfonic anhydride was dropped slowly. The mixture was heated up to room temperature over 1 hour, and stirred at room temperature for 1 hour. The reaction was stopped using 100 ml of 1 M hydrochloric acid, and the reaction solution was washed with 500 ml of water twice. Further, the reaction solution was washed with 500 ml of a saturated sodium hydrogencarbonate aqueous solution and 500 ml of water, and the resulting organic layer was filtrated by passing through a silica gel pad, then, the solvent was removed. Re-crystallization was carried out using a toluene-hexane mixed solvent, to obtain 83.2 g (yield 66.6%) of compound TB in the form of white solid.

¹H-NMR (300 MHz/CDCl₃): δ 3.95 (s, 3H), 4.02 (s, 3H), 7.24 (s, 1H), 7.34 (dd, 1H), 7.67 (s, 1H), 7.72 (d, 1H), 8.54 (s, 1H)

LC-MS (APCI(+)): 364.2

### (Synthesis of Compound TC)

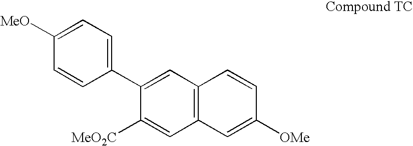

Into a 2000 ml three-necked flask was added compound TB, 35.5 g of 4-methoxyphenylboronic acid, tetrakistriphenylphosphinepalladium (0) and 77.0 g of potassium carbonate, then, 250 ml of toluene and 250 ml of water were added and the mixture was heated under reflux. The mixture was stirred for 6 hours, then, cooled to room temperature. The reaction solution was filtrated through a silica gel pad, and the resulting solution was concentrated. Re-crystallization was carried out using a toluene-hexane mixed solvent, to obtain 64.3 g (yield 86.4%) of compound TC in the form of white solid.

¹H-NMR (300 MHz/CDCl₃): δ 3.76 (s, 3H), 3.76 (s, 3H), 3.95 (s, 3H), 6.97 d, 2H), 7.26 (d, 1H), 7.29 (d, 1H), 7.34 (d, 2H), 7.72 (s, 1H), 7.74 (d, 1H), 8.24 (s, 1H)

LC-MS (APPI(+)): 323.2

### (Synthesis of Compound TD)

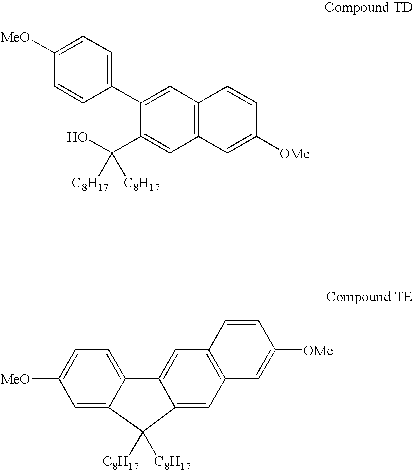

Under a nitrogen atmosphere, 32.2 g of magnesium and 20 ml of tetrahydrofuran were added to a reaction vessel and stirred, a tetrahydrofuran (1160 ml) solution of 232.5 g of n-octyl bromide was added, to prepared an octylmagnesium bromide solution. In a separate reaction vessel, 97 g of compound TC was dissolved in 291 g of tetrahydrofuran under a nitrogen atmosphere, and the mixture was cooled in an ice bath, into this was dropped n-octylmagnesium bromide prepared previously, and the mixture was stirred at room temperature over night. After the reaction, 3.5% hydrochloric acid water (2760 g) was added and the mixture was stirred, then, separated. The aqueous layer was extracted with 3000 ml of toluene, then, the organic layer was combined. The resulting organic layer was washed with water, then, dried over anhydrous sodium sulfate, and concentrated to distill off the solvent, to obtain a coarse product (136 g) containing compound TE in the form of oil.

Under an argon atmosphere, the above-mentioned coarse product (136 g) containing compound TE was dissolved in ethanol (1140 g) with stirring in a 500 mL flask, and the mixture was cooled in an ice bath. Into this was charged sodium borohydride (4.8 g), the ice bath was remove, and the mixture was stirred at room temperature for 3 hours. 1140 ml of water was added to terminate the reaction, extraction with 2000 ml of toluene was conducted, then, the resulting organic layer was washed with water, then, dried over anhydrous sodium sulfate, and concentrated to distill of the solvent, to obtain an oil (135.5 g) containing compound TD.

Under an argon atmosphere, boron trifluoride-diethyl ether complex (343 ml) was mixed in methylene chloride with stirring in a reaction vessel, and the above-mentioned reduced coarse product (135.5 g) was diluted in dichloromethane (1355 ml), then, dropped into the above-mentioned mixture at room temperature, then, the mixture was thermally insulated at room temperature for 6 hours. After the reaction, a reaction mass was poured into water (1355 mL) and the mixture was stirred, and the organic layer was extracted with chloroform. The resultant organic layer was washed with water, then, dried over anhydrous sodium sulfate, and concentrated to distill off the solvent, to obtain a cyclized coarse product (129 g) in the form of oil.

Under an argon atmosphere, sodium hydroxide (281 g) was dissolved in water (571 g) with stirring in a reaction vessel, and the mixture was cooled to room temperature, then, the above-mentioned cyclized coarse product (129 g) and tetra-n-butylammonium bromide (45 g) were diluted in toluene (476 ml) and charged into this, and the mixture was heated up to 50° C., then, 1-bromooctane (67.8 g) was dropped, and the mixture was stirred 50° C. for 5 hours. Thereafter, 33.9 g of 1-bromooctane was additionally added, and the mixture was stirred further over night and day, then, 67.8 g was additionally added. After the reaction, a reaction mass was poured into water (1850 mL), the mixture was stirred, then, separated. The aqueous layer was extracted with 440 ml of toluene, and the oil layer was combined. The resulting oil layer was washed with water, then, dried over anhydrous sodium sulfate, and concentrated to distill off the solvent, to obtain an oil (172 g). The resulting oil was purified by a silica gel column using a mixed solvent of chloroform/hexane=10/1 as a developing solvent, to obtain compound TD (61.4 g, yield 40.9%) in the form of oil.

¹H-NMR (300 MHz/CDCl₃): δ 0.68 (t, 4H), 0.80 (t, 6H), 0.91-1.56 (m, 20H), 2.05 (q, 4H), 3.93 (s, 3H), 3.96 (s, 3H), 6.87 (s, 1H), 6.90 (s, dH), 7.11 (d, 1H), 7.18 (s, 1H), 7.59 (s, 1H), 7.68 (s, 1H), 7.74 (s, 1H), 7.91 (s, 1H)

LC-MS (APPI (+)): 501.3

### (Synthesis of Compound TF)

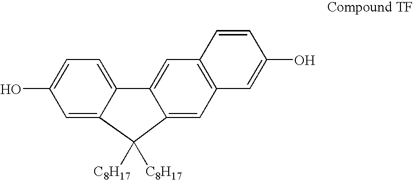

Into a nitrogen-purged 300 ml three-necked flask was added 15 g of compound TD and 100 mL of dichloromethane, then, the mixture was cooled down to −20° C. using a salt ice bath. 75 ml of born tribromide was weighed by a dropping funnel, and added drop-wise. Thereafter, the mixture was heated up to room temperature and stirred for 2 hours, and 100 mL of water was added to stop the reaction. Extraction with 300 mL of chloroform was performed, and the resulting organic layer was washed with a 10% sodium thiosulfate aqueous solution, and dried over sodium sulfate, then, passed through a silica gel column, to carry out bottom cut, obtaining 10.2 g (66.7%) of compound TF.

¹H-NMR (300 MHz/CDCl₃): δ 0.64 (t, 4H), 0.80 (t, 6H), 0.95-1.30 (m, 20H), 1.91 (q, 4H), 4.91 (s, 1H), 4.99 (s, 1H), 6.81 (s, 1H), 6.82 (d, 1H), 7.05 (dd, 1H), 7.17 (d, 1H), 7.52 (s, 1H), 7.65 (d, 1H), 7.78 (d, 1H), 7.90 (s, 1H)

LC/MS (APPI(+)): 473.3

### EXAMPLE 5

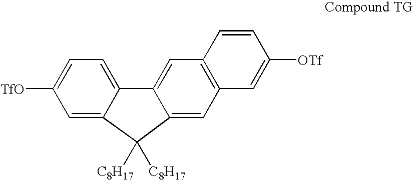

Into a three-necked flask (200 ml) was added 10.2 g of compound TF, 130 ml of dichloromethane and 8.5 ml of triethylamine Under a nitrogen atmosphere, 7.4 mL of trifluoromethanesulfonic anhydride was dropped slowly into the mixture which was being stirred at −78° C. in a dry ice-methanol bath so that the temperature in the system did not change. The cooling bath was removed, the mixture was stirred at room temperature for 3 hours, then, 1 M HCl was added to stop the reaction, and extraction was effected using chloroform. The organic layer was washed with a 10% sodium hydrogencarbonate aqueous solution, and dried over sodium sulfate, then, passed through a silica gel column. The resulting coarse product was re-crystallized from toluene to obtain 10.7 g (yield 67.4%) of compound TG.

¹H-NMR (300 MHz/CDCl₃): δ0.61 (t, 4H), 0.80 (t, 6H), 0.95-1.30 (m, 20H), 2.06 (q, 4H), 7.28 (d, 1H), 7.33 (s, 1H), 7.38 (dd, 1H), 7.78 (s, 1H), 7.79 (d, 1H), 7.90 (d, 1H), 7.96 (d, 1H), 8.16 (s, 1H)

LC/MS/APPI(+)): 736.1.

### EXAMPLE 6

### Synthesis of Polymer Compound 1

Compound H (0.30 g, 0.55 mmol), N,N′-bis(4-bromophenyl)-N,N′-bis(4-t-butyl-2,6-dimethylphenyl)-1,4-phenylenediamine (0.40 g, 0.55 mmol) and 2,2′-bipyridyl (0.34 g, 2.2 mmol) were dissolved in 50 mL of dehydrated tetrahydrofuran, then, an atmosphere in the system was purged with nitrogen by bubbling with nitrogen. Under a nitrogen atmosphere, bis(1,5-cyclooctadiene)nickel (0) (Ni(COD)₂)(0.60 g, 2.2 mmol) was added and the mixture was heated up to 60° C., and reacted for 3 hours while stirring. After the reaction, this reaction solution was cooled down to room temperature (about 25° C.), and dropped into a mixed solution of 25% ammonia water 5 mL/methanol 50 mL/ion exchanged water 50 mL and the mixture was stirred, then, the deposited precipitate was filtrated and dried under reduced pressure for 2 hours, then, dissolved in 50 mL of toluene before conducting filtration, and the filtrate was purified by passing through an alumina column, and the toluene layer was washed with about 50 mL of 4% ammonia water for 2 hours, further, with about 50 mL of ion exchanged water. The organic layer was dropped into about 100 mL of methanol and the mixture was stirred for 1 hour, and filtrated and dried under reduced pressure for 2 hours. The yield was 0.30 g. This polymer is called polymer compound 1. The number-average molecular weight and weight-average molecular weight in terms of polystyrene were Mn=1.3×10⁴ and Mw=6.4×10⁴, respectively. The glass transition temperature was measured to find a value of 257° C.

### EXAMPLE 7

### Synthesis of Polymer Compound 2

Under an inert atmosphere, compound I (0.10 g, 0.14 mmol) and N,N′-bis(4-bromophenyl)-N,N′-bis(4-t-butyl-2,6-dimethylphenyl)-1,4-phenylenediamine (0.10 g, 0.14 mmol) were dissolved in 2.9 ml of toluene, to this was added tetrakis(triphenylphosphine)palladium (0.003 g, 0.0028 mmol) and the mixture was stirred for 10 minutes at room temperature. Subsequently, 0.5 ml of a 20% tetraethylammonium hydroxide aqueous solution was added and the mixture was heated, and heated for 2 hours under reflux. Phenylboronic acid (0.017 g, 0.014 mmol) was added and the mixture was heated for 1 hour under reflux. After completion of heating, the mixture was cooled down to room temperature, a reaction mass was dropped into 30 ml of methanol, and the deposited precipitate was filtrated. The resulting precipitate was washed with methanol, dried under reduced pressure, to obtain solid. The resulting solid was dissolved in 3 ml of toluene, passed through an alumina column, then, dropped into 20 ml of methanol and the mixture was stirred for 1 hour, and the deposited precipitate was filtrated. The resulting precipitate was washed with methanol, and dried under reduced pressure. The yield was 0.070 g. This polymer is called polymer compound 2. The number-average molecular weight and weight-average molecular weight in terms of polystyrene were Mn=1.5×10⁴ and Mw=3.0×10⁴, respectively.

### EXAMPLE 8

### Preparation of Solution

Polymer compound 1 obtained above was dissolved in toluene, to produce a toluene solution having a polymer concentration of 1.3 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, Baytron P AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 1500 rpm to form a film. The thickness after film formation was about 70 nm. Further, this was dried under reduced pressure at 80° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 80 nm, to manufacture an EL element. After the degree of vacuum reached 1×10⁻⁴ Pa or less, vapor deposition of a metal was initiated. By applying voltage on the resulting element, EL light emission having a peak at 490 nm was obtained from this element. The intensity of EL light emission was approximately in proportion to the current density. This element showed initiation of light emission from 3.7 V, and had a maximum light emission efficiency of 0.18 cd/A.

### (Measurement of Increase of Voltage)

The EL element obtained above was driven for 100 hours at a constant current of 50 mA/cm², and change of luminance by time was measured to find an increase in voltage by 7.3% as compared with the initial voltage.

### (Measurement of Current Density at 4V)

When a voltage of 4 V was applied on an EL element produced by the same method as described above, a current of 10 mA/cm² flowed.

### EXAMPLE 9

### Preparation of Solution

Polymer compound 2 obtained above was dissolved in toluene, to produce a toluene solution having a polymer concentration of 1.3 wt %.

### (Production of EL Element)

An EL element was obtained by the same manner as in Example 8, using the toluene solution obtained above. By applying voltage on the resulting element, EL light emission having a peak at 490 nm was obtained from this element. The intensity of EL light emission was approximately in proportion to the current density. This element showed initiation of light emission from 4.2 V, and had a maximum light emission efficiency of 0.36 cd/A.

### (Measurement of Increase of Voltage)

The EL element obtained above was driven for 100 hours at a constant current of 50 mA/cm², and change of luminance by time was measured to find an increase in voltage by 15.6% as compared with the initial voltage.

### (Measurement of Current Density at 4V)

When a voltage of 4 V was applied on an EL element produced by the same method as described above, a current of 1 mA/cm² flowed.

TABLE 1

| | Light | | Maximum | |
|---|---|---|---|---|
| | emission | | light | |
| | initiation | Current | emission | Voltage |
| | voltage | density | efficiency | increase |
| Example 8 | 3.7 V | 10 mA/cm² | 0.18 cd/A | 7.3% |
| Example 9 | 4.2 V | 1 mA/cm² | 0.36 cd/A | 15.6% |

### EXAMPLE 10

### Synthesis of Polymer Compound 3

0.9 g of compound H and 0.50 g of 2,2′-bipyridyl were charged in a reaction vessel, then, an atmosphere in the system was purged with a nitrogen gas. To this was added 60 g of tetrahydrofuran (dehydrated solvent) previously deaerated by bubbling with an argon gas. Next, to this mixed solution was added 0.92 g of bis(1,5-cyclooctadiene)nickel (0), the mixture was stirred at room temperature for 10 minutes, then, reacted at 60° C. for 3 hours. The reaction was conducted in a nitrogen gas atmosphere. After the reaction, this solution was cooled, then, a mixed solution of 25% ammonia water 10 mL/methanol 150 mL/ion exchanged water 150 mL was poured, and the mixture was stirred for about 1 hour. Next, the produced precipitate was filtrated and recovered. This precipitate was dried, then, dissolved in toluene. This solution was filtrated to remove insoluble materials, then, this solution was passed through a column filled with alumina to purify the solution. Next, this toluene solution was washed with 1 N hydrochloric acid, then, allowed to stand still, separated, and a toluene solution was recovered, and this toluene solution was washed with about 3% ammonia water, then, allowed to stand still, separated, and a toluene solution was recovered, then, this toluene solution was washed with ion exchanged water, and allowed to stand still, separated, and a toluene solution was recovered. By adding methanol to this toluene solution under stirring, to cause re-precipitation and purification.

Next, the produced precipitate was recovered, and this precipitate was dried under reduced pressure, to obtain 0.08 g of a polymer. This polymer is called polymer compound 3. The resulting polymer compound 3 had a weight-average molecular weight in terms of polystyrene of 2.4×10⁵ and a number-average molecular weight of 7.3×10⁴.

### EXAMPLE 11

### Synthesis of Polymer Compound 4

1250 mg of compound N, 1107 mg of compound H and 1590 mg of 2,2′-bipyridyl were dissolved in 102 mL of tetrahydrofuran, then, under a nitrogen atmosphere, to this solution was added 2800 mg of bis(1,5-cyclooctadiene)nickel (0) {Ni(COD)₂}, the mixture was heated up to 60° C., and reacted for 3 hours. After the reaction, this solution was cooled to room temperature, and dropped into a mixed solution of 25% ammonia water 12 mL/methanol 102 mL/ion exchanged water 102 mL, and the mixture was stirred for 30 minutes, then, the deposited precipitate was filtrated and dried under reduced pressure for 2 hours, and dissolved in 102 ml of toluene. After dissolution, 0.41 g of radiolite was added and the mixture was stirred for 30 minutes, to filtrate insoluble materials off. The resulting filtrate was purified by passing through an alumina column (alumina amount, 10 g), and to the recovered toluene solution was added 200 mL of 5.2% hydrochloric acid and the mixture was stirred for 3 hours. After stirring, the aqueous layer was removed, then, to the organic layer was added 200 mL of 2.9% ammonia water and the mixture was stirred for 2 hours, and the aqueous layer was removed. Further, to the organic layer was added 200 mL of water and the mixture was stirred for 1 hour, and the aqueous layer was removed. Then, 100 mL of methanol was dropped into the organic layer and the mixture was stirred for 30 minutes, and the deposited precipitate was filtrated and dried under reduced pressure for 2 hours.

The resulting polymer showed a yield of 985 mg. This polymer is called polymer compound 4. The resulting polymer compound 4 had a weight-average molecular weight in terms of polystyrene of 2.5×10⁵ and a number-average molecular weight of 9.6×10⁴.

### EXAMPLE 12

Compound H (10.6 g, 17.6 mmol), N,N′-bis(4-bromophenyl)-N,N′-bis(4-t-butyl-2,6-dimethylphenyl)-1,4-phenylenediamine (0.27 g, 0.36 mmol) and 2,2′-bipyridyl (7.6 g, 48.6 mmol) were dissolved in 1200 mL of dehydrated tetrahydrofuran, then, an atmosphere in the system was purged with nitrogen by bubbling with nitrogen. Under a nitrogen atmosphere, this solution was heated up to 60° C., and bis(1,5-cyclooctadiene)nickel (0) {Ni(COD)₂} (13.4 g, 48.6 mmol) was added at 60° C., and the mixture was reacted for 3 hours while stirring. After the reaction, this solution was cooled to room temperature (about 25° C., and dropped into a mixed solution of 25% ammonia water 65 mL/methanol 1200 mL/ion exchanged water 1200 mL, and the mixture was stirred, then, the deposited precipitate was filtrated and dried under reduced pressure for 2 hours, then, dissolved in 540 mL of toluene before filtration, and the filtrate was purified by passing through an alumina column, and the toluene layer was washed with about 1000 mL of 5.2% hydrochloric acid water for 3 hours, with about 1000 mL of 4% ammonia water for 2 hours, further with about 1000 mL of ion exchanged water. The organic layer was dropped into about 1000 mL of methanol and the mixture was stirred for 30 minutes, and the deposited precipitate was filtrated and dried under reduced pressure for 2 hours. The resulting polymer showed a yield of 8.42 g. This polymer is called polymer compound 5. The resulting polymer compound 5 had a weight-average molecular weight in terms of polystyrene of 3.9×10⁵ and a number-average molecular weight of 5.4×10⁴.

### EXAMPLE 13

Compound H (7.1 g, 11.9 mmol), N,N′-bis(4-bromophenyl)-N,N′-bis(4-t-butyl-2,6-dimethylphenyl)-1,4-phenylenediamine (0.46 g, 0.63 mmol) and 2,2′-bipyridyl (5.3 g, 33.9 mmol) were dissolved in 720 mL of dehydrated tetrahydrofuran, then, an atmosphere in the system was purged with nitrogen by bubbling with nitrogen. Under a nitrogen atmosphere, this solution was heated up to 60° C., and bis(1,5-cyclooctadiene)nickel (0) {Ni(COD)₂} (9.3 g, 33.9 mmol) was added at 60° C., and the mixture was reacted for 3 hours while stirring. After the reaction, this solution was cooled to room temperature (about 25° C., and dropped into a mixed solution of 25% ammonia water 45 mL/methanol 700 mL/ion exchanged water 700 mL, and the mixture was stirred, then, the deposited precipitate was filtrated and dried under reduced pressure for 2 hours, then, dissolved in 540 mL of toluene before filtration, and the filtrate was purified by passing through an alumina column, and the toluene layer was washed with about 500 mL of 5.2% hydrochloric acid water for 3 hours, with about 500 mL of 4% ammonia water for 2 hours, further with about 500 mL of ion exchanged water. About 100 mL of methanol was dropped into the organic layer and the mixture was stirred for 1 hour, and the supernatant was removed by decantation. The resulting precipitate was dissolved in 300 mL of toluene, and dropped into about 600 mL of methanol and the mixture was stirred for 1 hour, and filtrated and dried under reduced pressure for 2 hours. The yield was 3.6 g. This polymer is called polymer compound 6. The number-average molecular weight and weight-average molecular weight in terms of polystyrene were Mn=2.1×10⁴ and Mw=4.5×10⁵, respectively.

### EXAMPLE 14

Compound H (17.8 g, 29.7 mmol), N,N′-bis(4-bromophenyl)-N,N′-bis(4-t-butyl-2,6-dimethylphenyl)-1,4-phenylenediamine (2.4 g, 3.3 mmol) and 2,2′-bipyridyl (13.9 g, 89.1 mmol) were dissolved in 1200 mL of dehydrated tetrahydrofuran, then, an atmosphere in the system was purged with nitrogen by bubbling with nitrogen. Under a nitrogen atmosphere, this solution was heated up to 60° C., and bis(1,5-cyclooctadiene)nickel (0) {Ni(COD)₂} (24.5 g, 89.1 mmol) was added at 60° C., and the mixture was reacted for 3 hours while stirring. After the reaction, this solution was cooled to room temperature (about 25° C., and dropped into a mixed solution of 25% ammonia water 120 mL/methanol 1200 mL/ion exchanged water 1200 mL, and the mixture was stirred, then, the deposited precipitate was filtrated and dried under reduced pressure for 2 hours, then, dissolved in 1000 mL of toluene before filtration, and the filtrate was purified by passing through an alumina column, and the toluene layer was washed with about 1000 mL of 5.2% hydrochloric acid water for 3 hours, with about 1000 mL of 4% ammonia water for 2 hours, further with about 1000 mL of ion exchanged water. About 400 mL of methanol was dropped into the organic layer and the mixture was stirred for 1 hour, and the supernatant was removed by decantation. The resulting precipitate was dissolved in 300 mL of toluene, and dropped into about 600 mL of methanol and the mixture was stirred for 1 hour, and filtrated and dried under reduced pressure for 2 hours. The yield was 10.5 g. This polymer is called polymer compound 7. The number-average molecular weight and weight-average molecular weight in terms of polystyrene were Mn=1.3×10⁵ and Mw=5.8×10⁵, respectively.

### EXAMPLE 15

Compound H (6.0 g, 10.0 mmol), N,N′-bis(4-bromophenyl)-N,N′-bis(4-t-butyl-2,6-dimethylphenyl)-1,4-phenylenediamine (1.8 g, 2.5 mmol) and 2,2′-bipyridyl (5.3 g, 33.9 mmol) were dissolved in 230 mL of dehydrated tetrahydrofuran, then, an atmosphere in the system was purged with nitrogen by bubbling with nitrogen. Under a nitrogen atmosphere, this solution was heated up to 60° C., and bis(1,5-cyclooctadiene)nickel (0) {Ni(COD)₂} (9.3 g, 33.9 mmol) was added at 60° C., and the mixture was reacted for 3 hours while stirring. After the reaction, this solution was cooled to room temperature (about 25° C., and dropped into a mixed solution of 25% ammonia water 45 mL/methanol 230 mL/ion exchanged water 230 mL, and the mixture was stirred, then, the deposited precipitate was filtrated and dried under reduced pressure for 2 hours, then, dissolved in 400 mL of toluene before filtration, and the filtrate was purified by passing through an alumina column, and the toluene layer was washed with about 400 mL of 4% ammonia water for 2 hours, further with about 400 mL of ion exchanged water. About 100 mL of methanol was dropped into the organic layer and the mixture was stirred for 1 hour, and the supernatant was removed by decantation. The resulting precipitate was dissolved in 200 mL of toluene, and dropped into about 400 mL of methanol and the mixture was stirred for 1 hour, and filtrated and dried under reduced pressure for 2 hours. The yield was 4.7 g. This polymer is called polymer compound 8. The number-average molecular weight and weight-average molecular weight in terms of polystyrene were Mn=1.6×10⁵ and Mw=3.9×10⁵, respectively.

### EXAMPLE 16

Compound H (5.2 g, 8.8 mmol), N,N′-bis(4-bromophenyl)-N,N′-bis(4-t-butyl-2,6-dimethylphenyl)-1,4-phenylenediamine (2.8 g, 3.8 mmol) and 2,2′-bipyridyl (5.3 g, 33.9 mmol) were dissolved in 230 mL of dehydrated tetrahydrofuran, then, an atmosphere in the system was purged with nitrogen by bubbling with nitrogen. Under a nitrogen atmosphere, this solution was heated up to 60° C., and bis(1,5-cyclooctadiene)nickel (0) {Ni(COD)₂} (9.3 g, 33.9 mmol) was added at 60° C., and the mixture was reacted for 3 hours while stirring. After the reaction, this solution was cooled to room temperature (about 25° C., and dropped into a mixed solution of 25% ammonia water 45 mL/methanol 230 mL/ion exchanged water 230 mL, and the mixture was stirred, then, the deposited precipitate was filtrated and dried under reduced pressure for 2 hours, then, dissolved in 200 mL of toluene before filtration, and the filtrate was purified by passing through an alumina column, and the toluene layer was washed with about 200 mL of 4% ammonia water for 2 hours, further with about 200 mL of ion exchanged water. About 200 mL of methanol was dropped into the organic layer and the mixture was stirred for 1 hour, and the supernatant was removed by decantation. The resulting precipitate was dissolved in 200 mL of toluene, and dropped into about 400 mL of methanol and the mixture was stirred for 1 hour, and filtrated and dried under reduced pressure for 2 hours. The yield was 4.7 g. This polymer is called polymer compound 9. The number-average molecular weight and weight-average molecular weight in terms of polystyrene were Mn=7.6×10⁴ and Mw=3.1×10⁵, respectively.

### EXAMPLE 17

Compound H (0.27 g), N,N′-bis(4-bromophenyl)-N,N′-bis(4-t-butyl-2,6-dimethylphenyl)-1,4-phenylenediamine (0.78 g) and 2,2′-bipyridyl (0.56 g) were dissolved in a reaction vessel, then, an atmosphere in the reaction system was purged with a nitrogen gas. To this was added 50 g of tetrahydrofuran (dehydrated solvent) deaerated previously by bubbling with an argon gas. Next, to this mixed solution was added 1.0 g of bis(1,5-cyclooctadiene)nickel (0), and the mixture was stirred at room temperature for 10 minutes, then, reacted at 60° C. for 3 hours. The reaction was conducted in a nitrogen gas atmosphere.

After the reaction, this solution was cooled, then, into this solution was poured a mixed solution of 25% ammonia water 10 mL/methanol 35 mL/ion exchanged water 35 mL, and the mixture was stirred for about 1 hour. Then, the produced precipitate was filtrated, and recovered. This precipitate was dried under reduced pressure, then, dissolved in toluene. This toluene solution was filtrated to remove insoluble materials, then, this toluene solution was purified by passing through a column filled with alumina. Next, this toluene solution was washed with about 5% ammonia water, then, allowed to stand still, separated, then, a toluene solution was recovered, next, this toluene solution was washed with water, then, allowed to stand still, separated, and a toluene solution was recovered. Next, this toluene solution was poured into methanol, and re-precipitated and purified.

Next, the produced precipitate was recovered, and this precipitate was dried under reduced pressure, to obtain 0.3 g of a polymer. This polymer is called polymer compound 10. The weight-average molecular weight in terms of polystyrene was 4.2×10⁴ and the number-average molecular weight was 7.8×10³.

### EXAMPLE 18

Compound H (10.6 g, 17.6 mmol), N,N′-bis(4-bromophenyl)-N,N′-bis(4-t-butyl-2,6-dimethylphenyl)-benzidine (0.29 g, 0.36 mmol) and 2,2′-bipyridyl (7.6 g, 48.6 mmol) were dissolved in 1100 mL of dehydrated tetrahydrofuran, then, an atmosphere in the system was purged with nitrogen by bubbling with nitrogen. Under a nitrogen atmosphere, this solution was heated up to 60° C., and bis(1,5-cyclooctadiene)nickel (0) {Ni(COD)₂} (13.4 g, 48.6 mmol) was added at 60° C., and the mixture was reacted for 3 hours while stirring. After the reaction, this solution was cooled to room temperature (about 25° C., and dropped into a mixed solution of 25% ammonia water 65 mL/methanol 1100 mL/ion exchanged water 1100 mL, and the mixture was stirred, then, the deposited precipitate was filtrated and dried under reduced pressure for 2 hours, then, dissolved in 550 mL of toluene before filtration, and the filtrate was purified by passing through an alumina column, and the toluene layer was washed with about 550 mL of 5.2% hydrochloric acid water for 3 hours, with about 550 mL of 4% ammonia water for 2 hours, further with about 550 mL of ion exchanged water. The organic layer was dropped in about 550 mL of methanol and the mixture was stirred for 30 minutes, and the deposited precipitate was filtrated and dried under reduced pressure for 2 hours. The resulting polymer had a yield of 6.3 g. This polymer is called polymer compound 11. The weight-average molecular weight in terms of polystyrene was 4.2×10⁵ and the number-average molecular weight was 6.6×10⁴.

### EXAMPLE 19

Compound H (4.85 g, 8.1 mmol), N,N′-bis(4-bromophenyl)-N,N′-bis(4-t-butyl-2,6-dimethylphenyl)-1,4-phenylenediamine (0.73 g, 0.9 mmol) and 2,2′-bipyridyl (3.80 g, 24.3 mmol) were dissolved in 420 mL of dehydrated tetrahydrofuran, then, an atmosphere in the system was purged with nitrogen by bubbling with nitrogen. Under a nitrogen atmosphere, this solution was heated up to 60° C., and bis(1,5-cyclooctadiene)nickel (0) {Ni(COD)₂} (6.68 g, 24.3 mmol) was added at 60° C., and the mixture was reacted for 3 hours while stirring. After the reaction, this solution was cooled to room temperature (about 25° C., and dropped into a mixed solution of 25% ammonia water 30 mL/methanol 420 mL/ion exchanged water 420 mL, and the mixture was stirred, then, the deposited precipitate was filtrated and dried under reduced pressure for 2 hours, then, dissolved in 550 mL of toluene before filtration, and the filtrate was purified by passing through an alumina column, and the toluene layer was washed with about 500 mL of 5.2% hydrochloric acid water for 3 hours, with about 500 mL of 4% ammonia water for 2 hours, further with about 500 mL of ion exchanged water. The organic layer was dropped in about 1000 mL of methanol and the mixture was stirred for 30 minutes, and the deposited precipitate was filtrated and dried under reduced pressure for 2 hours. The yield was 3.5 g. This polymer is called polymer compound 12. The number-average molecular weight and weight-average molecular weight in terms of polystyrene were Mn=3.9×10⁴ and Mw=3.7×10⁵, respectively.

### EXAMPLE 20

Compound H (1.0 g, 1.7 mmol), N,N′-bis(4-bromophenyl)-N,N′-bis(4-t-butyl-2,6-dimethylphenyl)-benzidine (0.34 g, 0.42 mmol) and 2,2′-bipyridyl (0.78 g, 5.0 mmol) were dissolved in 55 mL of dehydrated tetrahydrofuran, then, an atmosphere in the system was purged with nitrogen by bubbling with nitrogen. To this solution was added bis(1,5-cyclooctadiene)nickel (0) {Ni(COD)₂} (1.4 g, 5.0 mmol), the mixture was heated up to 60° C., and under a nitrogen atmosphere, reacted for 3 hours while stirring. After the reaction, this solution was cooled to room temperature (about 25° C., and dropped into a mixed solution of 25% ammonia water 5 mL/methanol 50 mL/ion exchanged water 50 mL, and the mixture was stirred, then, the deposited precipitate was filtrated and dried under reduced pressure for 2 hours, then, dissolved in 50 mL of toluene before filtration, and the filtrate was purified by passing through an alumina column, and the toluene layer was washed with about 50 mL of 5.2% hydrochloric acid water for 3 hours, with about 50 mL of 4% ammonia water for 2 hours, further with about 50 mL of ion exchanged water. The organic layer was dropped in about 150 mL of methanol and the mixture was stirred for 1 hour, and filtrated and dried under reduced pressure for 2 hours. The yield was 0.87 g. This polymer is called polymer compound 13. The number-average molecular weight and weight-average molecular weight in terms of polystyrene were Mn=3.8×10⁴ and Mw=1.2×10⁵, respectively.

### EXAMPLE 21

Compound H (5.2 g, 8.8 mmol), N,N′-bis(4-bromophenyl)-N,N′-bis(4-t-butyl-2,6-dimethylphenyl)-benzidine (3.1 g, 3.8 mmol) and 2,2′-bipyridyl (5.3 g, 33.9 mmol) were dissolved in 230 mL of dehydrated tetrahydrofuran, then, an atmosphere in the system was purged with nitrogen by bubbling with nitrogen. Under a nitrogen atmosphere, this solution was heated up to 60° C., and to this was added bis(1,5-cyclooctadiene)nickel (0) {Ni(COD)₂} (9.3 g, 33.9 mmol), and the mixture was reacted for 3 hours while stirring. After the reaction, this solution was cooled to room temperature (about 25° C., and dropped into a mixed solution of 25% ammonia water 45 mL/methanol 230 mL/ion exchanged water 230 mL, and the mixture was stirred, then, the deposited precipitate was filtrated and dried under reduced pressure for 2 hours, then, dissolved in 200 mL of toluene before filtration, and the filtrate was purified by passing through an alumina column, and the toluene layer was washed with about 200 mL of 5.2% hydrochloric acid water for 3 hours, with about 200 mL of 4% ammonia water for 2 hours, further with about 200 mL of ion exchanged water. About 200 mL of methanol was dropped into the organic layer and the mixture was stirred for 1 hour, and the supernatant was removed by decantation. The resulting precipitate was dissolved in 200 mL of toluene, and dropped into about 400 mL of methanol and the mixture was stirred for 1 hour, and filtrated and dried under reduced pressure for 2 hours. The yield was 4.7 g. This polymer is called polymer compound 14. The number-average molecular weight and weight-average molecular weight in terms of polystyrene were Mn=8.9×10⁴ and Mw=5.2×10⁵, respectively.

### EXAMPLE 22

0.58 g of compound H, 0.089 g of N,N′-bis(4-bromophenyl)-N,N′-bis(4-t-butyl-2,6-dimethylphenyl)-1,4-phenylenediamine, 0.053 g of TPA and 0.45 g of 2,2′-bipyridyl were charged in a reaction vessel, then, an atmosphere in the reaction system was purged with nitrogen.

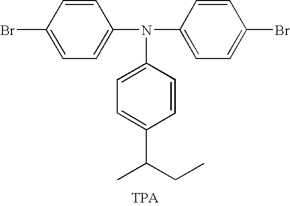

To this was added 40 g of tetrahydrofuran (dehydrated solvent) deaerated previously by bubbling with an argon gas. Next, to this mixed solution was added 0.8 g of bis(1,5-cyclooctadiene)nickel (0), and the mixture was stirred at room temperature for 10 minutes, then, reacted at 60° C. for 3 hours. The reaction was conducted in a nitrogen gas atmosphere.

After the reaction, this solution was cooled, then, into this solution was poured a mixed solution of methanol 50 mL/ion exchanged water 50 mL, and the mixture was stirred for about 1 hour. Then, the produced precipitate was filtrated and recovered. This precipitate was dried, then, dissolved in toluene. This solution was filtrated to remove insoluble materials, then, this solution was purified by passing through a column filled with alumina. Next, this toluene solution was washed with about 1 N hydrochloric acid, then, allowed to stand still, separated, then, a toluene solution was recovered, and this toluene solution was washed with about 3% ammonia water, then, allowed to stand still, separated, and a toluene solution was recovered, next, this toluene solution was washed with ion exchanged water, allowed to stand still, separated, and a toluene solution was recovered. Then, methanol was added to this toluene solution under stirring, to cause re-precipitation and purification.

Next, the produced precipitate was recovered, and this precipitate was dried under reduced pressure, to obtain 0.16 g of a polymer. This polymer is called polymer compound 15. The resulting polymer compound 15 had a weight-average molecular weight in terms of polystyrene of 1.5×10⁵ and a number-average molecular weight of 2.9×10⁴.

### EXAMPLE 23

0.50 g of compound H, 0.084 g of N,N′-bis(4-bromophenyl)-N,N′-bis(4-t-butyl-2,6-dimethylphenyl)-1,4-phenylenediamine, 0.11 g of TPA and 0.45 g of 2,2′-bipyridyl were charged in a reaction vessel, then, an atmosphere in the reaction system was purged with nitrogen.

To this was added 40 g of tetrahydrofuran (dehydrated solvent) deaerated previously by bubbling with an argon gas. Next, to this mixed solution was added 0.8 g of bis(1,5-cyclooctadiene)nickel (0), and the mixture was stirred at room temperature for 10 minutes, then, reacted at 60° C. for 3 hours. The reaction was conducted in a nitrogen gas atmosphere.

After the reaction, this solution was cooled, then, into this solution was poured a mixed solution of methanol 50 mL/ion exchanged water 50 mL, and the mixture was stirred for about 1 hour. Then, the produced precipitate was filtrated and recovered. This precipitate was dried, then, dissolved in toluene. This solution was filtrated to remove insoluble materials, then, this solution was purified by passing through a column filled with alumina. Next, this toluene solution was washed with about 3% ammonia water, then, allowed to stand still, separated, then, a toluene solution was recovered, next, this toluene solution was washed with ion exchanged water, then, allowed to stand still, separated, and a toluene solution was recovered. Then, methanol was added to this toluene solution under stirring, to cause re-precipitation and purification.

Next, the produced precipitate was recovered, and this precipitate was dried under reduced pressure, to obtain 0.16 g of a polymer. This polymer is called polymer compound 16. The resulting polymer compound 16 had a weight-average molecular weight in terms of polystyrene of 1.3×10⁵ and a number-average molecular weight of 2.1×10⁴.

### EXAMPLE 24

Under an inert atmosphere, compound I (0.10 g, 0.14 mmol) and N,N′-bis(4-bromophenyl)-N,N′-bis(4-t-butyl-2,6-dimethylphenyl)-1,4-phenylenediamine (0.10 g, 0.14 mmol) were dissolved in 2.9 ml of toluene, to this was added tetrakis(triphenylphosphine)palladium (0.003 g, 0.0028 mmol) and the mixture was stirred for 10 minutes at room temperature. Subsequently, 0.5 ml of a 20% tetraethylammonium hydroxide aqueous solution was added and the mixture was heated, and heated for 2 hours under reflux. Phenylboronic acid (0.017 g, 0.014 mmol) was added and the mixture was heated for 1 hour under reflux. After completion of heating, the mixture was cooled down to room temperature, a reaction mass was dropped into 30 ml of methanol, and the deposited precipitate was filtrated. The resulting precipitate was washed with methanol, dried under reduced pressure, to obtain solid. The resulting solid was dissolved in 3 ml of toluene, passed through an alumina column, then, dropped into 20 ml of methanol and the mixture was stirred for 1 hour, and the deposited precipitate was filtrated. The resulting precipitate was washed with methanol, and dried under reduced pressure. The yield was 0.060 g. This polymer is called polymer compound 17. The number-average molecular weight and weight-average molecular weight in terms of polystyrene were Mn=9.8×10³ and Mw=2.4×10⁴, respectively.

### COMPARATIVE EXAMPLE 1

### Synthesis of Polymer Compound 18

Under an inert atmosphere, 2,7-dibromo-9,9-dioctylfluorene (287 mg, 0.523 mmol), 2,7-(9,9-dioctyl)fluorene diboronic acid ethylene glycol cyclic ester (305 mg, 0.575 mmol) and aliquot 336 (15 mg) were dissolved in toluene (4.3 g), and to this was added potassium carbonate (231 mg, 1.67 mmol) as about 1 g of aqueous solution. Further, tetrakis(triphenylphosphine)palladium (0.39 mg, 0.00034 mmol) was added and the mixture was heated under reflux for 20 hours. Subsequently, bromobenzene (11.5 mg) was added and the mixture was further heated under reflux for 5 hours. After completion of heating, a reaction mass was dropped into mixed liquid of methanol (40 ml) and 1 N hydrochloric acid water (2.2 mol), and the mixture was dried under reduced pressure to obtain solid. Subsequently, the solid was dissolved in 50 ml of toluene, passed through a silica column, then, concentrated to 20 ml. The concentrate was dropped into methanol, the deposited precipitate was filtrated, and dried under reduced pressure to obtain polymer compound 18. The yield was 340 mg.

The resulting polymer compound 18 had Mn=1.2×10³ and Mw=3.2×10³ in terms of polystyrene.

### COMPARATIVE EXAMPLE 2

### Synthesis of Polymer Compound 19

307 mg of 2,7-dibromo-9,9-dioctylfluorene, 52 mg of N,N′-bis(4-bromophenyl)-N,N′-bis(4-t-butyl-2,6-dimethylphenyl)-1,4-phenylenediamine, 32 mg of TPA and 250 mg of 2,2′-bipyridyl were dissolved in 20 mL of dehydrated tetrahydrofuran, then, under a nitrogen atmosphere, to this solution was added 440 mg of bis(1,5-cyclooctadiene)nickel (0) {Ni(COD)₂}, and the mixture was warmed up to 60° C. and reacted for 3 hours. After the reaction, this solution was cooled to room temperature, and dropped into a mixed solution of 25% ammonia water 10 mL/methanol 120 mL/ion exchanged water 500 mL, and the mixture was stirred for 30 minutes, then, the deposited precipitate was filtrated and dried under reduced pressure for 2 hours, then, dissolved in 30 mL of toluene. 30 mL of 1 N hydrochloric acid was added and the mixture was stirred for 3 hours, then, the aqueous layer was removed. Next, to the organic layer was added 30 mL of 4% ammonia water and the mixture was stirred for 3 hours, then, the aqueous layer was removed. Subsequently, the organic layer was dropped into 150 mL of methanol and the mixture was stirred for 30 minutes, the deposited precipitate was filtrated and dried under reduced pressure for 2 hours, and dissolved in 90 mL of toluene. Thereafter, the mixture was purified by passing through an alumina column (alumina amount, 10 g), and the recovered toluene solution was dropped into 200 mL of methanol and the mixture was stirred for 30 minutes, the deposited precipitate was filtrated and dried under reduced pressure for 2 hours. The resulting polymer showed a yield of 170 mg. This polymer is called polymer compound 19.

The resulting polymer compound 19 had Mn=3.2×10⁴ and Mw=8.3×10⁴ in terms of polystyrene.

### EXAMPLE 25

The fluorescent spectra and glass transition temperatures of polymer compounds 1 to 17 were measured. The results are shown in the following Table 2.

TABLE 2

| | | Glass | Fluorescent | Fluorescent |
|---|---|---|---|---|
| | | transition | peak | intensity |
| | Compound | temperature | wavelength | (relative |
| Run | No. | (° C.) | (nm) | value) |
| 1 | polymer | 129 | 450 | 8.3 |
| | compound 3 | | | |
| 2 | polymer | 129 | 450 | 5.3 |
| | compound 4 | | | |
| Comparative | polymer | 73 | 428 | 3.6 |
| Example | compound | | | |
| | 18 | | | |
| 3 | polymer | 134 | 456 | 6.1 |
| | compound 5 | | | |
| 4 | polymer | 137 | 462 | 5.7 |
| | compound 6 | | | |
| 5 | polymer | 159 | 462 | 4.8 |
| | compound 7 | | | |
| 6 | polymer | 175 | 468 | 5.1 |
| | compound 8 | | | |
| 7 | polymer | 207 | 472 | 2.9 |
| | compound 9 | | | |
| 8 | polymer | 132 | 457 | 7.2 |
| | compound | | | |
| | 11 | | | |
| 9 | polymer | 161 | 454 | 6.9 |
| | compound | | | |
| | 12 | | | |
| 10 | polymer | 193 | 456 | 5.3 |
| | compound | | | |
| | 13 | | | |
| 11 | polymer | 213 | 458 | 4.0 |
| | compound | | | |
| | 14 | | | |
| 12 | polymer | 167 | 467 | 4.1 |
| | compound | | | |
| | 15 | | | |
| 13 | polymer | 175 | 467 | 4.9 |
| | compound | | | |
| | 16 | | | |
| 14 | polymer | 210 | 469 | 1.6 |
| | compound | | | |
| | 17 | | | |
| Comparative | polymer | 98 | 446 | — |
| Example | compound | | | |
| | 19 | | | |

### EXAMPLE 26

### Synthesis of Polymer Compound 20

Compound H (4.500 g), N,N′-bis(4-bromophenyl)-N,N′-bis(4-t-butyl-2,6-dimethylphenyl)-1,4-phenylenediamine (0.617 g) and 2,2′-bipyridyl (3.523 g) were dissolved in 211 mL of dehydrated tetrahydrofuran, then, an atmosphere in the system was purged with nitrogen by bubbling with nitrogen. The mixture was heated up to 60° C., then, under a nitrogen atmosphere, to this was added bis(1,5-cyclooctadiene)nickel (0) {Ni(COD)₂} (6.204 g), and the mixture was reacted for 3 hours while stirring. This reaction solution was cooled to room temperature, and dropped into a mixed solution of 25% ammonia water 30 mL/methanol 211 mL/ion exchanged water 211 mL, and the mixture was stirred for 1 hour, then, the deposited precipitate was filtrated and dried under reduced pressure for 2 hours. Thereafter, the mixture was dissolved in 251 mL of toluene before filtration, subsequently, purified by passing through an alumina column. Next, 493 mL of 5.2% hydrochloric acid water was added and the mixture was stirred for 3 hours, then, the aqueous layer was removed. Next, 493 mL of 4% ammonia water was added and the mixture was stirred for 2 hours, then, the aqueous layer was removed. To the organic layer was further added about 493 mL of ion exchanged water and the mixture was stirred for 1 hour, then, the aqueous layer was removed. 110 mL of methanol was dropped over about 30 minutes while stirring the organic layer. The supernatant was recovered, and this solvent was distilled off. To the remaining solid was added 14 mL of toluene and the mixture was stirred to attain completion dissolution, then, dropped into 220 mL of methanol and the mixture was stirred for 30 minute. The generated precipitate was recovered, and dried under reduced pressure for 2 hours to obtain 0.2 g of a polymer. This polymer is called polymer compound 20. The resulting polymer compound 20 had a number-average molecular weight of 7.6×10³, a weight-average molecular weight of 5.5×10⁴, and a dispersion of 7.2, and the molecular weight distribution thereof was unimodal.

### EXAMPLE 27

### Synthesis of Polymer Compound 21

Compound H (1.0 g), N,N′-bis(4-bromophenyl)-N,N′-bis(4-t-butyl-2,6-dimethylphenyl)-1,4-phenylenediamine (0.15 g) and 2,2′-bipyridyl (0.76 g) were dissolved in 50 mL of dehydrated tetrahydrofuran, then, an atmosphere in the system was purged with nitrogen by bubbling with nitrogen. Under a nitrogen atmosphere, to this solution was added bis(1,5-cyclooctadiene)nickel (0) {Ni(COD)₂} (1.3 g), and the mixture was heated up to 60° C. and reacted while stirring. This reaction solution was cooled to room temperature (about 25° C.), and dropped into a mixed solution of 25% ammonia water 5 mL/methanol about 50 mL/ion exchanged water about 50 mL, and the mixture was stirred for 1 hour, then, the deposited precipitate was filtrated and dried under reduced pressure for 2 hours, thereafter, the mixture was dissolved in 50 mL of toluene before filtration, and the filtrate was purified by passing through an alumina column, and about 50 mL of 4% ammonia water was added and stirred for 2 hours, then, the aqueous layer was removed. To the organic layer was further added about 50 mL of ion exchanged water and the mixture was stirred for 1 hour, then, the aqueous layer was removed. The organic layer was dropped into 100 mL of methanol and the mixture was stirred for 1 hour, and the deposited precipitate was filtrated and dried under reduced pressure for 2 hours. The resulting copolymer (hereinafter, referred to as polymer compound 21) showed a yield of 0.55 g. The number-average molecular weight and weight-average molecular weight in terms of polystyrene were Mn=3.3×10⁴ and Mw=9.7×10⁴, respectively, and the dispersion was 2.9 and the molecular weight distribution was unimodal.

### EXAMPLE 28

### Synthesis of Polymer Compound 22

Compound H (0.727 g), N,N′-bis(4-bromophenyl)-N,N′-bis(4-t-butyl-2,6-dimethylphenyl)-1,4-phenylenediamine (0.100 g), water (0.039 g) and 2,2′-bipyridyl (0.63 g) were dissolved in 81 mL of dehydrated tetrahydrofuran, then, an atmosphere in the system was purged with nitrogen by bubbling with nitrogen. The mixture was heated up to 60° C., then, under a nitrogen atmosphere, to this solution was added bis(1,5-cyclooctadiene)nickel (0) {Ni(COD)₂} (1.114 g), and the mixture was stirred and reacted for 3 hours. This reaction solution was cooled to room temperature, and dropped into a mixed solution of 25% ammonia water 5 mL/methanol about 81 mL/ion exchanged water about 81 mL, and the mixture was stirred for 1 hour, then, the deposited precipitate was filtrated and dried under reduced pressure for 2 hours. Thereafter, the mixture was dissolved in 41 mL of toluene before filtration, and the filtrate was subsequently purified by passing through an alumina column. Next, 80 mL of 5.2% hydrochloric acid water was added and the mixture was stirred for 3 hours, then, the aqueous layer was removed. Next, 80 mL of 4% ammonia water was added and the mixture was stirred for 2 hours, then, the aqueous layer was removed. To the organic layer was further added about 80 mL of ion exchanged water and the mixture was stirred for 1 hour, then, the aqueous layer was removed. The organic layer was poured into 127 mL of methanol and the mixture was stirred for 1 hour, and the deposited precipitate was filtrated and dried under reduced pressure for 2 hours. The resulting copolymer (hereinafter, referred to as polymer compound 22) showed a yield of 0.466 g. The number-average molecular weight and weight-average molecular weight in terms of polystyrene were Mn=3.9×10⁴ and Mw=1.7×10⁵, respectively, and the dispersion was 4.4 and the molecular weight distribution was unimodal.

### EXAMPLE 29

### Synthesis of Polymer Compound 23

Compound H (0.727 g), N,N′-bis(4-bromophenyl)-N,N′-bis(4-t-butyl-2,6-dimethylphenyl)-1,4-phenylenediamine (0.100 g) and 2,2′-bipyridyl (0.63 g) were dissolved in 81 mL of dehydrated tetrahydrofuran, then, an atmosphere in the system was purged with nitrogen by bubbling with nitrogen. The mixture was heated up to 60° C., then, under a nitrogen atmosphere, to this solution was added bis(1,5-cyclooctadiene)nickel (0) {Ni(COD)₂} (1.11 g), and the mixture was reacted for 5 hours. This reaction solution was cooled to room temperature, and dropped into a mixed solution of 25% ammonia water 5 mL/methanol about 41 mL/ion exchanged water about 41 mL, and the mixture was stirred for 1 hour, then, the deposited precipitate was filtrated and dried under reduced pressure for 2 hours. Thereafter, the mixture was dissolved in 41 mL of toluene before filtration, and the filtrate was subsequently purified by passing through an alumina column. Next, 80 mL of 5.2% hydrochloric acid water was added and the mixture was stirred for 3 hours, then, the aqueous layer was removed. Next, 80 mL of 4% ammonia water was added and the mixture was stirred for 2 hours, then, the aqueous layer was removed. To the organic layer was further added about 80 mL of ion exchanged water and the mixture was stirred for 1 hour, then, the aqueous layer was removed. The organic layer was poured into 127 mL of methanol and the mixture was stirred for 1 hour, and the deposited precipitate was filtrated and dried under reduced pressure for 2 hours. The resulting copolymer (hereinafter, referred to as polymer compound 23) showed a yield of 0.351 g. The number-average molecular weight and weight-average molecular weight in terms of polystyrene were Mn=2.9×10⁴ and Mw=2.6×10⁵, respectively, and the dispersion was 9.0 and the molecular weight distribution was unimodal.

### EXAMPLE 30

### Manufacturing of El Element

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution of polymer compounds 20 to 23 obtained above was spin-coated at a rotational speed of 1500 rpm to form a film. The thickness after film formation was about 70 nm. Further, this was dried under reduced pressure at 80° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 80 nm, to manufacture an EL element. After the degree of vacuum reached 1×10⁻⁴ Pa or less, vapor deposition of a metal was initiated.

### <Light Emission Efficiency>

By applying voltage on the resulting element, EL light emission was obtained from this element. The intensity of EL light emission was approximately in proportion to the current density. The maximum light emission efficiencies of the resulting polymer compounds are shown in Table 3.

TABLE 3

| | | maximum light |
|---|---|---|
| | weight-average | emission |
| | molecular weight (Mw) | efficiency (cd/A) |
| polymer compound 20 | 5.5 × 10⁴ | 2.24 |
| polymer compound 21 | 9.7 × 10⁴ | 2.26 |
| polymer compound 22 | 1.7 × 10⁵ | 3.05 |
| polymer compound 23 | 2.6 × 10⁵ | 3.02 |

### EXAMPLE 31

Compound H (5.9 g) and 2,2′-bipyridyl (3.1 g) were dissolved in 240 mL of dehydrated tetrahydrofuran, then, an atmosphere in the system was purged with nitrogen by bubbling with nitrogen. Under a nitrogen atmosphere, this solution was heated up to 60° C., then, to this was added bis(1,5-cyclooctadiene)nickel (0) {Ni(COD)₂} (5.4 g), and the mixture was reacted for 3 hours under thermal insulation and stirring. This reaction solution was cooled to room temperature (about 25° C.), and dropped into a mixed solution of 25% ammonia water 36 mL/methanol about 720 mL/ion exchanged water about 720 mL, and the mixture was stirred for 1 hour, then, the deposited precipitate was filtrated and dried under reduced pressure for 2 hours, thereafter, the mixture was dissolved in 300 mL of toluene before filtration, and the filtrate was purified by passing through an alumina column, and about 600 mL of 4% ammonia water was added and the mixture was stirred for 2 hours, then, the aqueous layer was removed. To the organic layer was further added about 600 mL of ion exchanged water and the mixture was stirred for 1 hour, then, the aqueous layer was removed. 60 mL of methanol was added to the organic layer and the precipitate was removed by filtration and the liquid portion was concentrated to 30 ml, then, this was dropped into about 100 mL of methanol and the mixture was stirred for 1 hour, and the deposited precipitate was filtrated and dried under reduced pressure for 2 hours. The resulting copolymer (hereinafter, referred to as polymer compound 25) showed a yield of 0.13 g. The number-average molecular weight and weight-average molecular weight in terms of polystyrene were Mn=1.1×10⁴ and Mw=2.0×10⁴, respectively. The dispersion was 1.8 and the molecular weight distribution was unimodal.

### EXAMPLE 32

Compound H (1.0 g) and 2,2′-bipyridyl (0.78 g) were dissolved in 15 mL of dehydrated tetrahydrofuran, then, an atmosphere in the system was purged with nitrogen by bubbling with nitrogen. Under a nitrogen atmosphere, to this was added bis(1,5-cyclooctadiene)nickel (0) {Ni(COD)₂} (1.4 g), and the mixture was heated up to 60° C. and reacted for 3 hours while stirring. This reaction solution was cooled to room temperature (about 25° C.), and dropped into a mixed solution of 25% ammonia water 3 mL/methanol about 20 mL/ion exchanged water about 20 mL, and the mixture was stirred for 1 hour, then, the deposited precipitate was filtrated and dried under reduced pressure for 2 hours, thereafter, the mixture was dissolved in 50 mL of toluene before filtration, and the filtrate was purified by passing through an alumina column, and stirred for 3 hours, then, the aqueous layer was removed. Next, about 200 mL of 4% ammonia water was added to this, and the mixture was stirred for 2 hours, then, the aqueous layer was removed. To the organic layer was further added about 200 mL of ion exchanged water and the mixture was stirred for 1 hour, then, the aqueous layer was removed. 10 mL of methanol was added to the organic layer and the deposited precipitate was collected by decantation and dissolved in 20 ml of toluene, then, this was dropped into about 60 mL of methanol and the mixture was stirred for 1 hour, and the deposited precipitate was filtrated and dried under reduced pressure for 2 hours. The resulting copolymer (hereinafter, referred to as polymer compound 26) showed a yield of 0.44 g. The number-average molecular weight and weight-average molecular weight in terms of polystyrene were Mn=4.8×10⁴ and Mw=8.9×10⁴, respectively, the dispersion was 1.9 and the molecular weight distribution was unimodal.

### EXAMPLE 33

Compound H (6.0 g) and 2,2′-bipyridyl (4.2 g) were dissolved in 540 mL of dehydrated tetrahydrofuran, then, an atmosphere in the system was purged with nitrogen by bubbling with nitrogen. The mixture was heated up to 60° C., then, under a nitrogen atmosphere, to this solution was added bis(1,5-cyclooctadiene)nickel (0) {Ni(COD)₂} (7.4 g), and the mixture was stirred and reacted for 3 hours. This reaction solution was cooled to room temperature, and dropped into a mixed solution of 25% ammonia water 36 mL/methanol 540 mL/ion exchanged water 540 mL, and the mixture was stirred for 1 hour, then, the deposited precipitate was filtrated and dried under reduced pressure for 2 hours. Thereafter, the mixture was dissolved in 300 mL of toluene before filtration, and the filtrate was purified by passing through an alumina column. Next, 590 mL of 5.2% hydrochloric acid water was added and the mixture was stirred for 3 hours, then, the aqueous layer was removed. Next, 590 mL of 4% ammonia water was added to this, and the mixture was stirred for 2 hours, then, the aqueous layer was removed. To the organic layer was further added about 590 mL of ion exchanged water and the mixture was stirred for 1 hour, then, the aqueous layer was removed. The organic layer was poured into 940 mL of methanol and the mixture was stirred for 1 hour, and the deposited precipitate was filtrated and dried under reduced pressure for 2 hours. The resulting copolymer (hereinafter, referred to as polymer compound 27) showed a yield of 3.6 g. The number-average molecular weight and weight-average molecular weight in terms of polystyrene were Mn=8.8×10⁴ and Mw=4.4×10⁵, respectively, the dispersion was 5.0 and the molecular weight distribution was unimodal.

### EXAMPLE 34

Compound H (5.2 g), N,N′-bis(4-bromophenyl)-N,N′-bis(4-t-butyl-2,6-dimethylphenyl)-1,4-phenylenediamine (2.8 g) and 2,2′-bipyridyl (5.3 g) were dissolved in 226 mL of dehydrated tetrahydrofuran, then, an atmosphere in the system was purged with nitrogen by bubbling with nitrogen. The mixture was heated up to 60° C., then, under a nitrogen atmosphere, to this solution was added bis(1,5-cyclooctadiene)nickel (0) {Ni(COD)₂} (9.3 g), and the mixture was stirred and reacted for 3 hours. This reaction solution was cooled to room temperature, and dropped into a mixed solution of 25% ammonia water 45 mL/methanol 226 mL/ion exchanged water 226 mL, and the mixture was stirred for 1 hour, then, the deposited precipitate was filtrated and dried under reduced pressure for 2 hours. Thereafter, the mixture was dissolved in 376 mL of toluene before filtration, subsequently, the filtrate was purified by passing through an alumina column. Next, 739 mL of 5.2% hydrochloric acid water was added and the mixture was stirred for 3 hours, then, the aqueous layer was removed. Next, 739 mL of 4% ammonia water was added to this, and the mixture was stirred for 2 hours, then, the aqueous layer was removed. To the organic layer was further added about 739 mL of ion exchanged water and the mixture was stirred for 1 hour, then, the aqueous layer was removed. To the organic layer was added 200 mL of methanol and the precipitate was removed by filtration and concentrated to 80 ml, then, this was dropped into about 200 mL of methanol and the mixture was stirred for 1 hour, the deposited precipitate was filtrated and dried under reduced pressure for 2 hours. The resulting copolymer (hereinafter, referred to as polymer compound 28) showed a yield of 2.3 g. The number-average molecular weight and weight-average molecular weight in terms of polystyrene were Mn=9.1×10³ and Mw=2.6×10⁴, respectively, the dispersion was 2.9 and the molecular weight distribution was bimodal.

### EXAMPLE 35

Compound H (0.42 g), N,N′-bis(4-bromophenyl)-N,N′-bis(4-t-butyl-2,6-dimethylphenyl)-1,4-phenylenediamine (0.22 g) and 2,2′-bipyridyl (0.38 g) were dissolved in 55 mL of dehydrated tetrahydrofuran, then, an atmosphere in the system was purged with nitrogen by bubbling with nitrogen. Under a nitrogen atmosphere, to this solution was added bis(1,5-cyclooctadiene)nickel (0) {Ni(COD)₂} (0.66 g), the mixture was heated up to 60° C., and reacted for 3 hours while stirring. This reaction solution was cooled to room temperature (about 25° C.), and dropped into a mixed solution of 25% ammonia water 4 mL/methanol about 55 mL/ion exchanged water about 55 mL, and the mixture was stirred for 1 hour, then, the deposited precipitate was filtrated and dried under reduced pressure for 2 hours. Thereafter, the mixture was dissolved in 30 mL of toluene before filtration, and the filtrate was purified by passing through an alumina column, to this was added about 60 mL of 4% ammonia water, and the mixture was stirred for 2 hours, then, the aqueous layer was removed. To the organic layer was further added about 60 mL of ion exchanged water and the mixture was stirred for 1 hour, then, the aqueous layer was removed. This was dropped into about 100 mL of methanol and the mixture was stirred for 1 hour, the deposited precipitate was filtrated and dried under reduced pressure for 2 hours. The resulting copolymer (hereinafter, referred to as polymer compound 29) showed a yield of 0.35 g. The number-average molecular weight and weight-average molecular weight in terms of polystyrene were Mn=1.2×10⁴ and Mw=8.6×10⁴, respectively, the dispersion was 7.2 and the molecular weight distribution was bimodal.

### EXAMPLE 36

Compound H (20.9 g), N,N′-bis(4-bromophenyl)-N,N′-bis(4-t-butyl-2,6-dimethylphenyl)-1,4-phenylenediamine (11.1 g) and 2,2′-bipyridyl (21.1 g) were dissolved in 900 mL of dehydrated tetrahydrofuran, then, an atmosphere in the system was purged with nitrogen by bubbling with nitrogen. Under a nitrogen atmosphere, this solution was heated up to 60° C., then, bis(1,5-cyclooctadiene)nickel (0) {Ni(COD)₂} (37.1 g) was added, and reacted for 3 hours under thermal insulation at 60° C. and stirring. This reaction solution was cooled to room temperature (about 25° C.), and dropped into a mixed solution of 25% ammonia water 90 mL/methanol about 450 mL/ion exchanged water about 450 mL, and the mixture was stirred for 1 hour, then, the deposited precipitate was filtrated and dried under reduced pressure for 2 hours. Thereafter, the mixture was dissolved in 750 mL of toluene before filtration, and the filtrate was purified by passing through an alumina column, to this was added about 1500 mL of 4% ammonia water, and the mixture was stirred for 2 hours, then, the aqueous layer was removed. To the organic layer was further added about 1500 mL of ion exchanged water and the mixture was stirred for 1 hour, then, the aqueous layer was removed. This was dropped into about 2000 mL of methanol and the mixture was stirred for 1 hour, the deposited precipitate was filtrated and dried under reduced pressure for 2 hours. The resulting copolymer (hereinafter, referred to as polymer compound 30) showed a yield of 19.5 g. The number-average molecular weight and weight-average molecular weight in terms of polystyrene were Mn=4.5×10⁴ and Mw=4.1×10⁵, respectively, the dispersion was 9.1 and the molecular weight distribution was bimodal.

### EXAMPLE 37

67 wt % of a polymer compound in the second column in the following Table 4 and 33 wt % of a polymer compound in the third column were dissolved in toluene in this ratio, to obtain a toluene solution having a polymer concentration of 1.3 wt %. The weight-average molecular weight in terms of polystyrene after mixing is shown in the fourth column.

Using this toluene solution, an EL element was manufactured by the same manner as in Example 30. The maximum light emission efficiency in this procedure is shown in the fifth column.

TABLE 4

| | Second | | Forth | |
|---|---|---|---|---|
| First column | column | Third column | column | Fifth column |
| 43-1 | polymer | polymer | 1.7 × 10⁴ | 2.56 cd/A |
| | compound 25 | compound 28 | | |
| 43-2 | polymer | polymer | 9.7 × 10⁴ | 2.81 cd/A |
| | compound 26 | compound 29 | | |
| 43-3 | polymer | polymer | 3.0 × 10⁵ | 3.07 cd/A |
| | compound 27 | compound 28 | | |
| 43-4 | polymer | polymer | 4.2 × 10⁵ | 3.26 cd/A |
| | compound 27 | compound 30 | | |

### EXAMPLE 38

### Synthesis of Polymer Compound 31

Compound H (22.0 g, 37 mmol) and 2,2′-bipyridyl (15.5 g, 100 mmol) were dissolved in 720 mL of dehydrated tetrahydrofuran, then, an atmosphere in the system was purged with nitrogen by bubbling with nitrogen. Under a nitrogen atmosphere, this solution was heated up to 60° C., and to this was added bis(1,5-cyclooctadiene)nickel (0) {Ni(COD)₂} (27.3 g, 100 mmol) at 60° C., and reacted for 3 hours while stirring. After the reaction, this reaction solution was cooled to room temperature (about 25° C.), and dropped into a mixed solution of 25% ammonia water 130 mL/methanol 2 L/ion exchanged water about 2 L, and the mixture was stirred, then, the deposited precipitate was filtrated and dried under reduced pressure for 2 hours, thereafter, the mixture was dissolved in 1.2 L of toluene before filtration, and the filtrate was purified by passing through an alumina column, and the toluene layer was washed with 2.5 L of 5.2% hydrochloric acid water for 3 hours, 2.5 L of 4% ammonia water for 2 hours, further, 2.5 L of ion exchanged water. 500 mL of methanol was dropped into the organic layer and the mixture was stirred for 1 hour, and the supernatant was removed by decantation. The resulting precipitate was dissolved in 1.2 L of toluene, and dropped into 3.5 L of methanol and the mixture was stirred for 1 hour, and filtrated and dried under reduced pressure for 2 hours. The yield was 11.45 g. This polymer is called polymer compound 31. The number-average molecular weight and weight-average molecular weight in terms of polystyrene were Mn=1.9×10⁵ and Mw=5.6×10⁵, respectively.

### EXAMPLE 39

### Synthesis of Polymer Compound 32

Compound H (7.35 g, 12.3 mmol), N,N′-bis(4-bromophenyl)-N,N′-bis(4-t-butyl-2,6-dimethylphenyl)-1,4-phenylenediamine (0.19 g, 0.25 mmol) and 2,2′-bipyridyl (5.28 g, 33.9 mmol) were dissolved in 450 mL of dehydrated tetrahydrofuran, then, an atmosphere in the system was purged with nitrogen by bubbling with nitrogen. Under a nitrogen atmosphere, this solution was heated up to 60° C., and to this was added bis(1,5-cyclooctadiene)nickel (0) {Ni(COD)₂} (9.3 g, 33.9 mmol) at 60° C., and reacted for 3 hours while stirring. After the reaction, this reaction solution was cooled to room temperature (about 25° C.), and dropped into a mixed solution of 25% ammonia water 90 mL/methanol 450 mL/ion exchanged water 450 mL, and the mixture was stirred, then, the deposited precipitate was filtrated and dried under reduced pressure for 2 hours, thereafter, the mixture was dissolved in 700 mL of toluene before filtration, and the filtrate was purified by passing through an alumina column, and the toluene layer was washed with 750 mL of 4% ammonia water for 2 hours, further, 750 mL of ion exchanged water. 150 mL of methanol was dropped into the organic layer and the mixture was stirred for 1 hour, and the supernatant was removed by decantation. The resulting precipitate was dissolved in 300 mL of toluene, and dropped into 600 mL of methanol and the mixture was stirred for 1 hour, and filtrated and dried under reduced pressure for 2 hours. The yield was 4.7 g. This polymer is called polymer compound 32. The number-average molecular weight and weight-average molecular weight in terms of polystyrene were Mn=7.6×10⁴ and Mw=6.6×10⁵, respectively.

### EXAMPLE 40

### Synthesis of Polymer Compound 33

Compound H (4.5 g, 7.5 mmol), N,N′-bis(4-bromophenyl)-N,N′-bis(4-t-butyl-2,6-dimethylphenyl)-1,4-phenylenediamine (0.62 g, 0.83 mmol) and 2,2′-bipyridyl (3.52 g, 22.6 mmol) were dissolved in 210 mL of dehydrated tetrahydrofuran, then, an atmosphere in the system was purged with nitrogen by bubbling with nitrogen. Under a nitrogen atmosphere, this solution was heated up to 60° C., and to this was added bis(1,5-cyclooctadiene)nickel (0) {Ni(COD)₂} (6.2 g, 22.6 mmol) at 60° C., and reacted for 3 hours while stirring. After the reaction, this reaction solution was cooled to room temperature (about 25° C.), and dropped into a mixed solution of 25% ammonia water 30 mL/methanol 600 mL/ion exchanged water 600 mL, and the mixture was stirred, then, the deposited precipitate was filtrated and dried under reduced pressure for 2 hours, thereafter, the mixture was dissolved in 450 mL of toluene before filtration, and the filtrate was purified by passing through an alumina column, and the toluene layer was washed with 500 mL of 5.2% hydrochloric acid water for 3 hours, 500 mL of 4% ammonia water for 2 hours, further, 500 mL of ion exchanged water. 100 mL of methanol was dropped into the organic layer and the mixture was stirred for 1 hour, and the supernatant was removed by decantation. The resulting precipitate was dissolved in 250 mL of toluene, and dropped into 750 mL of methanol and the mixture was stirred for 1 hour, and filtrated and dried under reduced pressure for 2 hours. The yield was 4.6 g. This polymer is called polymer compound 33. The number-average molecular weight and weight-average molecular weight in terms of polystyrene were Mn=1.2×10⁵ and Mw=3.9×10⁵, respectively.

### EXAMPLE 41

### Preparation of Solution

67 wt % of polymer compound 31 obtained above and 33 wt % of polymer compound 9 were dissolved in toluene in this ratio, to obtain a toluene solution having a polymer concentration of 1.3 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 1500 rpm to form a film. The thickness after film formation was about 70 nm. Further, this was dried under reduced pressure at 80° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 80 nm, to manufacture an EL element. After the degree of vacuum reached 1×10⁻⁴ Pa or less, vapor deposition of a metal was initiated. By applying voltage on the resulting element, EL light emission having a peak at 475 nm was obtained from this element. The intensity of EL light emission was approximately in proportion to the current density.

### (Measurement of Life)

The EL element obtained above was driven at a constant current of 100 mA/cm², and change in luminance by time was measured. As a result, this element had an initial luminance of 2620 cd/m² and showed a luminance half life of 41 hours. This was converted into a value at an initial luminance of 400 cd/m² hypothesizing that the acceleration coefficient of luminance-life is square, to find a half life of 1760 hours.

### EXAMPLE 42

### Preparation of Solution

71 wt % of polymer compound 32 obtained above and 29 wt % of polymer compound 9 were dissolved in toluene in this ratio, to obtain a toluene solution having a polymer concentration of 1.3 wt %.

### (Manufacturing of El Element)

Using the toluene solution obtained above, an EL element was obtained by the same manner as in Example 41. By applying voltage on the resulting element, EL light emission having a peak at 475 nm was obtained from this element. The intensity of EL light emission was approximately in proportion to the current density.

### (Measurement of Life)

The EL element obtained above was driven at a constant current of 100 mA/cm², and change in luminance by time was measured. As a result, this element had an initial luminance of 2930 cd/m² and showed a luminance half life of 30 hours. This was converted into a value at an initial luminance of 400 cd/m² hypothesizing that the acceleration coefficient of luminance-life is square, to find a half life of 1610 hours.

### EXAMPLE 43

### Preparation of Solution

Polymer compound 33 obtained above was dissolved in toluene, to obtain a toluene solution having a polymer concentration of 1.3 wt %.

### (Manufacturing of El Element)

Using the toluene solution obtained above, an EL element was obtained by the same manner as in Example 41. By applying voltage on the resulting element, EL light emission having a peak at 475 nm was obtained from this element. The intensity of EL light emission was approximately in proportion to the current density.

### (Measurement of Life)

The EL element obtained above was driven at a constant current of 100 mA/cm², and change in luminance by time was measured. As a result, this element had an initial luminance of 2750 cd/m² and showed a luminance half life of 19 hours. This was converted into a value at an initial luminance of 400 cd/m² hypothesizing that the acceleration coefficient of luminance-life is square, to find a half life of 900 hours.

TABLE 5

| | | | | Monomer | | | |
|---|---|---|---|---|---|---|---|
| | | | | composition | Initial | Luminance | 400 cd/m² |
| | | | Mixing | ratio in the | luminance | half life | convereted |
| | Polymer-1 | Polymer-2 | ratio | system X:Y | (cd/m²) | (h) | life (h) |
| Example | Polymer | Polymer | 67:33 | 90:10 | 2620 | 41 | 1752 |
| 41 | compound 31 | compound 9 | | | | | |
| Example | Polymer | Polymer | 71:29 | 90:10 | 2930 | 30 | 1610 |
| 42 | compound 32 | compound 9 | | | | | |
| Example | Polymer | | | 90:10 | 2750 | 19 | 914 |
| 43 | compound 33 | | | | | | |

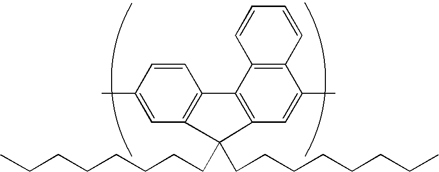

[symbol]

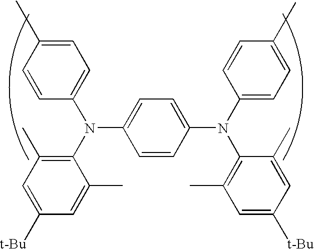

[symbol]

### EXAMPLE 44

### Synthesis of Polymer Compound 34

Compound H (10.7 g, 18 mmol) and 2,2′-bipyridyl (7.59 g, 48.6 mmol) were dissolved in 840 mL of dehydrated tetrahydrofuran, then, an atmosphere in the system was purged with nitrogen by bubbling with nitrogen. Under a nitrogen atmosphere, this solution was heated up to 60° C., and to this was added bis(1,5-cyclooctadiene)nickel (0) {Ni(COD)₂} (13.4 g, 48.6 mmol) at 60° C., and reacted for 3 hours while stirring. After the reaction, this reaction solution was cooled to room temperature (about 25° C.), and dropped into a mixed solution of 25% ammonia water 60 mL/methanol 1.3 L/ion exchanged water 1.3 L, and the mixture was stirred, then, the deposited precipitate was filtrated and dried under reduced pressure for 2 hours, thereafter, the mixture was dissolved in 1 L of toluene before filtration, and the filtrate was purified by passing through an alumina column, and the toluene layer was washed with 1 L of 5.2% hydrochloric acid water for 3 hours, 1 L of 4% ammonia water for 2 hours, further, 1 L of ion exchanged water. The organic layer was dropped into 2 L of methanol and the mixture was stirred for 30 minutes, and the deposited precipitate was filtrated and dried under reduced pressure for 2 hours. The yield was 17.35 g. This polymer is called polymer compound 34. The number-average molecular weight and weight-average molecular weight in terms of polystyrene were Mn=7.6×10⁴ and Mw=4.9×10⁵, respectively.

### EXAMPLE 45

### Synthesis of Polymer Compound 35

Compound H (15.5 g, 25.9 mmol), N,N′-diphenyl-N,N′-bis(4-t-butyl-2,6-dimethylphenyl)-benzidine (9.05 g, 11.1 mmol) synthesized above and 2,2′-bipyridyl (15.6 g, 100 mmol) were dissolved in 1.2 L of dehydrated tetrahydrofuran, then, an atmosphere in the system was purged with nitrogen by bubbling with nitrogen. Under a nitrogen atmosphere, this solution was heated up to 60° C., and to this was added bis(1,5-cyclooctadiene)nickel (0) {Ni(COD)₂} (27.5 g, 100 mmol) at 60° C., and reacted for 3 hours while stirring. After the reaction, this reaction solution was cooled to room temperature (about 25° C.), and dropped into a mixed solution of 25% ammonia water 70 mL/methanol 1.2 L/ion exchanged water 1.2 L, and the mixture was stirred, then, the deposited precipitate was filtrated and dried under reduced pressure for 2 hours, thereafter, the mixture was dissolved in 1 L of toluene before filtration, and the filtrate was purified by passing through an alumina column, and the toluene layer was washed with 1 L of 5.2% hydrochloric acid water for 3 hours, 1 L of 4% ammonia water for 2 hours, further, 1 L of ion exchanged water. The organic layer was dropped into 2 L of methanol and the mixture was stirred for 30 minutes, and the deposited precipitate was filtrated and dried under reduced pressure for 2 hours. The yield was 17.45 g. This polymer is called polymer compound 35. The number-average molecular weight and weight-average molecular weight in terms of polystyrene were Mn=3.0×10⁴ and Mw=3.5×10⁵, respectively.

### EXAMPLE 46

### Synthesis of Polymer Compound 36

Compound H (0.5 g, 0.84 mmol), N,N′-diphenyl-N,N′-bis(4-t-butyl-2,6-dimethylphenyl)-benzidine (0.076 g, 0.093 mmol) synthesized above and 2,2′-bipyridyl (0.35 g, 2.2 mmol) were dissolved in 70 mL of dehydrated tetrahydrofuran, then, an atmosphere in the system was purged with nitrogen by bubbling with nitrogen. Under a nitrogen atmosphere, this solution was heated up to 60° C., and to this was added bis(1,5-cyclooctadiene)nickel (0) {Ni(COD)₂} (0.61 g, 2.2 mmol) at 60° C., and reacted for 3 hours while stirring. After the reaction, this reaction solution was cooled to room temperature (about 25° C.), and dropped into a mixed solution of 25% ammonia water 3 mL/methanol 70 mL/ion exchanged water 70 mL, and the mixture was stirred, then, the deposited precipitate was filtrated and dried under reduced pressure for 2 hours, thereafter, the mixture was dissolved in 70 mL of toluene before filtration, and the filtrate was purified by passing through an alumina column, and the toluene layer was washed with 60 mL of 5.2% hydrochloric acid water for 3 hours, 60 mL of 4% ammonia water for 2 hours, further, 60 mL of ion exchanged water. The organic layer was dropped into 120 mL of methanol and the mixture was stirred for 30 minutes, and the deposited precipitate was filtrated and dried under reduced pressure for 2 hours. The yield was 0.87 g. The number-average molecular weight and weight-average molecular weight in terms of polystyrene were Mn=4.5×10⁴ and Mw=9.8×10⁴, respectively. This polymer is called polymer compound 36.

### EXAMPLE 47

### Preparation of Solution

67 wt % of polymer compound 34 obtained above and 33 wt % of polymer compound 35 were dissolved in toluene in this ratio, to obtain a toluene solution having a polymer concentration of 1.3 wt %.

### (Manufacturing of El Element)

Using the toluene solution obtained above, an EL element was obtained by the same manner as in Example 41. By applying voltage on the resulting element, EL light emission having a peak at 470 nm was obtained from this element. The intensity of EL light emission was approximately in proportion to the current density. This element manifested initiation of light emission from 2.9 V and had a maximum light emission efficiency of 3.12 cd/A.

### EXAMPLE 48

### Preparation of Solution

Polymer compound 36 obtained above was dissolved in toluene, to obtain a toluene solution having a polymer concentration of 1.3 wt %.

### (Manufacturing of El Element)

Using the toluene solution obtained above, an EL element was obtained by the same manner as in Example 41. By applying voltage on the resulting element, EL light emission having a peak at 460 nm was obtained from this element. The intensity of EL light emission was approximately in proportion to the current density. This element manifested initiation of light emission from 3.2 V and had a maximum light emission efficiency of 0.66 cd/A.

TABLE 6

| | | | | | Maximum |
|---|---|---|---|---|---|
| | | | | Monomer | light |
| | | | | composition | emission |
| | | | Mixing | ratio in the | efficiency |
| | Polymer-1 | Polymer-2 | ratio | system X:Z | (cd/A) |
| Example | Polymer | Polymer | 67:33 | 90:10 | 3.12 |
| 47 | compound | compound | | | |
| | 34 | 35 | | | |
| Example | Polymer | | | 90:10 | 0.66 |
| 48 | compound | | | | |
| | 36 | | | | |

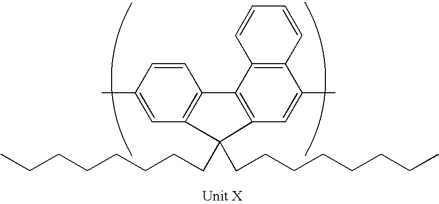

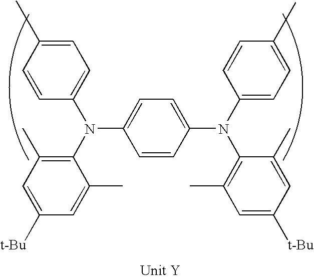

### EXAMPLE 49

### Synthesis of Polymer Compound 37

Compound H (10.6 g, 17.6 mmol), N,N′-bis(4-bromophenyl)-N,N′-bis(4-t-butyl-2,6-dimethylphenyl)-benzidine (0.29 g, 0.36 mmol) and 2,2′-bipyridyl (7.6 g, 48.6 mmol) were dissolved in 1100 mL of dehydrated tetrahydrofuran, then, an atmosphere in the system was purged with nitrogen by bubbling with nitrogen. Under a nitrogen atmosphere, this solution was heated up to 60° C., and to this was added bis(1,5-cyclooctadiene)nickel (0) {Ni(COD)₂} (13.4 g, 48.6 mmol) at 60° C., and reacted for 3 hours while stirring. After the reaction, this reaction solution was cooled to room temperature (about 25° C.), and dropped into a mixed solution of 25% ammonia water 65 mL/methanol 1100 mL/ion exchanged water 1100 mL, and the mixture was stirred, then, the deposited precipitate was filtrated and dried under reduced pressure for 2 hours, thereafter, the mixture was dissolved in 550 mL of toluene before filtration, and the filtrate was purified by passing through an alumina column, and the toluene layer was washed with about 550 mL of 5.2% hydrochloric acid water for 3 hours, about 550 mL of 4% ammonia water for 2 hours, further, about 550 mL of ion exchanged water. The organic layer was dropped into about 550 mL of methanol and the mixture was stirred for 30 minutes, and the deposited precipitate was filtrated and dried under reduced pressure for 2 hours. The yield of the resulting polymer was 6.3 g. This polymer is called polymer compound 37. The weight-average molecular weight in terms of polystyrene was 4.2×10⁵ and the number-average molecular weight was 6.6×10⁴.

### EXAMPLE 50

### Synthesis of Polymer Compound 38

Compound H (13.8 g, 23.1 mmol), N,N′-bis(4-bromophenyl)-N,N′-bis(4-t-butyl-2,6-dimethylphenyl)-benzidine (8.07 g, 9.9 mmol) and 2,2′-bipyridyl (13.9 g, 89.1 mmol) were dissolved in 1100 mL of dehydrated tetrahydrofuran, then, an atmosphere in the system was purged with nitrogen by bubbling with nitrogen. Under a nitrogen atmosphere, this solution was heated up to 60° C., and to this was added bis(1,5-cyclooctadiene)nickel (0) {Ni(COD)₂} (24.5 g, 89.1 mmol) at 60° C., and reacted for 3 hours while stirring. After the reaction, this reaction solution was cooled to room temperature (about 25° C.), and dropped into a mixed solution of 25% ammonia water 120 mL/methanol 2.4 L/ion exchanged water 2.4 L, and the mixture was stirred, then, the deposited precipitate was filtrated and dried under reduced pressure for 2 hours, thereafter, the mixture was dissolved in 1 L of toluene before filtration, and the filtrate was purified by passing through an alumina column, and the toluene layer was washed with 2 L of 5.2% hydrochloric acid water for 3 hours, 2 L of 4% ammonia water for 2 hours, further, 2 L of ion exchanged water. The organic layer was dropped into 3 L of methanol and the mixture was stirred for 30 minutes, and the deposited precipitate was filtrated and dried under reduced pressure for 2 hours. The yield of the resulting polymer was 13.36 g. This polymer is called polymer compound 38. The weight-average molecular weight in terms of polystyrene was 2.3×10⁴ and the number-average molecular weight was 3.6×10⁵.

### EXAMPLE 51

### Preparation of Solution

50 wt % of polymer compound 34 obtained above and 50 wt % of polymer compound 35 were dissolved in toluene in this ratio, to obtain a toluene solution having a polymer concentration of 1.3 wt %.

### (Manufacturing of El Element)

Using the toluene solution obtained above, an EL element was obtained by the same manner as in Example 41. By applying voltage on the resulting element, EL light emission having a peak at 460 nm was obtained from this element. The intensity of EL light emission was approximately in proportion to the current density. This element manifested initiation of light emission from 2.7 V and had a maximum light emission efficiency of 1.80 cd/A.

### EXAMPLE 52

### Preparation of Solution

53 wt % of polymer compound 37 obtained above and 47 wt % of polymer compound 38 were dissolved in toluene in this ratio, to obtain a toluene solution having a polymer concentration of 1.3 wt %.

### (Manufacturing of El Element)

Using the toluene solution obtained above, an EL element was obtained by the same manner as in Example 41. By applying voltage on the resulting element, EL light emission having a peak at 470 nm was obtained from this element. The intensity of EL light emission was approximately in proportion to the current density. This element manifested initiation of light emission from 3.8 V and had a maximum light emission efficiency of 1.02 cd/A.

TABLE 7

| | | | | | Maximum |
|---|---|---|---|---|---|
| | | | | Monomer | light |
| | | | | composition | emission |
| | | | Mixing | ratio in the | efficiency |
| | Polymer-1 | Polymer-2 | ratio | system X:Z | (cd/A) |
| Example | Polymer | Polymer | 50:50 | 85:15 | 1.81 |
| 51 | compound | compound | | | |
| | 34 | 35 | | | |
| Example | Polymer | Polymer | 53:47 | 85:15 | 1.02 |
| 52 | compound | compound | | | |
| | 37 | 38 | | | |

### EXAMPLE 53

Compound H (0.45 g), N,N′-bis(4-bromophenyl)-N,N′-bis(4-t-butyl-2,6-dimethylphenyl)-benzidine (0.61 g) and 2,2′-bipyridyl (0.56 g) were charged in a reaction vessel, then, an atmosphere in the reaction system was purged with a nitrogen gas. To this was added 50 g of tetrahydrofuran (dehydrated solvent) deaerated previously by bubbling with an argon gas. Next, to this mixed solution was added bis(1,5-cyclooctadiene)nickel (0) (1.0 g), and the mixture was stirred at room temperature for 10 minutes, then, reacted at 60° C. for 3 hours. The reaction was conducted in a nitrogen gas atmosphere.

After the reaction, this solution was cooled, then, into this solution was poured a mixed solution of 25% ammonia water 10 ml/methanol 35 mL/ion exchanged water 35 mL, and the mixture was stirred for about 1 hour. Then, the produced precipitate was filtrated and recovered. This precipitate was dried under reduced pressure, then, dissolved in toluene. This solution was filtrated to remove insoluble materials, then, this solution was purified by passing through a column filled with alumina. Next, this toluene solution was washed with about 5% ammonia water, then, allowed to standstill, separated, then, a toluene solution was recovered, next, this toluene solution was washed with water, then, allowed to stand still, separated, and a toluene solution was recovered. Next, this toluene solution was poured into methanol, to cause re-precipitation and purification.

Next, the produced precipitate was recovered, and this precipitate was dried under reduced pressure, to obtain 0.32 g of a polymer. This polymer is called polymer compound 39. The weight-average molecular weight in terms of polystyrene was 1.9×10⁵ and the number-average molecular weight was 2.0×10⁴.

### EXAMPLE 54

Compound H (0.27 g), N,N′-bis(4-bromophenyl)-N,N′-bis(4-t-butyl-2,6-dimethylphenyl)-benzidine (0.86 g) and 2,2′-bipyridyl (0.56 g) were charged in a reaction vessel, then, an atmosphere in the reaction system was purged with a nitrogen gas. To this was added 50 g of tetrahydrofuran (dehydrated solvent) deaerated previously by bubbling with an argon gas. Next, to this mixed solution was added bis(1,5-cyclooctadiene)nickel (0) (1.0 g), and the mixture was stirred at room temperature for 10 minutes, then, reacted at 60° C. for 3 hours. The reaction was conducted in a nitrogen gas atmosphere.

After the reaction, this solution was cooled, then, into this solution was poured a mixed solution of 25% ammonia water 10 ml/methanol 35 mL/ion exchanged water 35 mL, and the mixture was stirred for about 1 hour. Then, the produced precipitate was filtrated and recovered. This precipitate was dried under reduced pressure, then, dissolved in toluene. This solution was filtrated to remove insoluble materials, then, this solution was purified by passing through a column filled with alumina. Next, this toluene solution was washed with about 5% ammonia water, then, allowed to standstill, separated, then, a toluene solution was recovered, next, this toluene solution was washed with water, then, allowed to stand still, separated, and a toluene solution was recovered. Next, this toluene solution was poured into methanol, to cause re-precipitation and purification.

Next, the produced precipitate was recovered, and this precipitate was dried under reduced pressure, to obtain 0.35 g of a polymer. This polymer is called polymer compound 40. The weight-average molecular weight in terms of polystyrene was 1.9×10⁵ and the number-average molecular weight was 1.7×10⁴.

### EXAMPLE 55

### Preparation of Solution

25 wt % of polymer compound 34 obtained above and 75 wt % of polymer compound 12 were dissolved in toluene in this ratio, to obtain a toluene solution having a polymer concentration of 1.3 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 1500 rpm to form a film. The thickness after film formation was about 70 nm. Further, this was dried under reduced pressure at 80° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 80 nm, to manufacture an EL element. After the degree of vacuum reached 1×10⁻⁴ Pa or less, vapor deposition of a metal was initiated. By applying voltage on the resulting element, EL light emission having a peak at 460 nm was obtained from this element. The intensity of EL light emission was approximately in proportion to the current density. This element manifested initiation of light emission from 3.1 V and had a maximum light emission efficiency of 1.79 cd/A.

### (Measurement of Life)

The EL element obtained above was driven at a constant current of 100 mA/cm², and change in luminance by time was measured. As a result, this element had an initial luminance of 1519 cd/m² and showed a luminance half life of 14.3 hours. This was converted into a value at an initial luminance of 400 cd/m² hypothesizing that the acceleration coefficient of luminance-life is square, to find a half life of 207 hours.

### EXAMPLE 56

### Preparation of Solution

62.5 wt % of polymer compound 34 obtained above and 37.5 wt % of polymer compound 13 were dissolved in toluene in this ratio, to obtain a toluene solution having a polymer concentration of 1.3 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 1500 rpm to form a film. The thickness after film formation was about 70 nm. Further, this was dried under reduced pressure at 80° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 80 nm, to manufacture an EL element. After the degree of vacuum reached 1×10⁻⁴ Pa or less, vapor deposition of a metal was initiated. By applying voltage on the resulting element, EL light emission having a peak at 460 nm was obtained from this element. The intensity of EL light emission was approximately in proportion to the current density. This element manifested initiation of light emission from 3.0 V and had a maximum light emission efficiency of 2.06 cd/A.

### (Measurement of Life)

The EL element obtained above was driven at a constant current of 100 mA/cm², and change in luminance by time was measured. As a result, this element had an initial luminance of 1554 cd/m² and showed a luminance half life of 15.3 hours. This was converted into a value at an initial luminance of 400 cd/m² hypothesizing that the acceleration coefficient of luminance-life is square, to find a half life of 232 hours.

### EXAMPLE 57

### Preparation of Solution

75 wt % of polymer compound 34 obtained above and 25 wt % of polymer compound 14 were dissolved in toluene in this ratio, to obtain a toluene solution having a polymer concentration of 1.3 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 1500 rpm to form a film. The thickness after film formation was about 70 nm. Further, this was dried under reduced pressure at 80° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 80 nm, to manufacture an EL element. After the degree of vacuum reached 1×10⁻⁴ Pa or less, vapor deposition of a metal was initiated. By applying voltage on the resulting element, EL light emission having a peak at 455 nm was obtained from this element. The intensity of EL light emission was approximately in proportion to the current density. This element manifested initiation of light emission from 2.9 V and had a maximum light emission efficiency of 1.84 cd/A.

### (Measurement of Life)

The EL element obtained above was driven at a constant current of 100 mA/cm², and change in luminance by time was measured. As a result, this element had an initial luminance of 1349 cd/m² and showed a luminance half life of 14.8 hours. This was converted into a value at an initial luminance of 400 cd/m² hypothesizing that the acceleration coefficient of luminance-life is square, to find a half life of 169 hours.

### EXAMPLE 58

### Preparation of Solution

85 wt % of polymer compound 34 obtained above and 15 wt % of polymer compound 39 were dissolved in toluene in this ratio, to obtain a toluene solution having a polymer concentration of 1.3 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 1500 rpm to form a film. The thickness after film formation was about 70 nm. Further, this was dried under reduced pressure at 80° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 80 nm, to manufacture an EL element. After the degree of vacuum reached 1×10⁻⁴ Pa or less, vapor deposition of a metal was initiated. By applying voltage on the resulting element, EL light emission having a peak at 455 nm was obtained from this element. The intensity of EL light emission was approximately in proportion to the current density. This element manifested initiation of light emission from 3.1 V and had a maximum light emission efficiency of 1.66 cd/A.

### (Measurement of Life)

The EL element obtained above was driven at a constant current of 100 mA/cm², and change in luminance by time was measured. As a result, this element had an initial luminance of 1063 cd/m² and showed a luminance half life of 13.3 hours. This was converted into a value at an initial luminance of 400 cd/m² hypothesizing that the acceleration coefficient of luminance-life is square, to find a half life of 94 hours.

### EXAMPLE 59

### Preparation of Solution

89.3 wt % of polymer compound 34 obtained above and 10.7 wt % of polymer compound 40 were dissolved in toluene in this ratio, to obtain a toluene solution having a polymer concentration of 1.3 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 1500 rpm to form a film. The thickness after film formation was about 70 nm. Further, this was dried under reduced pressure at 80° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 80 nm, to manufacture an EL element. After the degree of vacuum reached 1×10⁻⁴ Pa or less, vapor deposition of a metal was initiated. By applying voltage on the resulting element, EL light emission having a peak at 455 nm was obtained from this element. The intensity of EL light emission was approximately in proportion to the current density. This element manifested initiation of light emission from 3.2 V and had a maximum light emission efficiency of 1.25 cd/A.

### (Measurement of Life)

The EL element obtained above was driven at a constant current of 100 mA/cm², and change in luminance by time was measured. As a result, this element had an initial luminance of 840 cd/m² and showed a luminance half life of 12.8 hours. This was converted into a value at an initial luminance of 400 cd/m² hypothesizing that the acceleration coefficient of luminance-life is square, to find a half life of 57 hours.

TABLE 8

| | | | | | Maximum | | | |
|---|---|---|---|---|---|---|---|---|
| | | | | Monomer | light | | | |
| | | | | composition | emission | Initial | Luminance | 400 cd/m² |
| | | | Mixing | ratio in the | efficiency | luminance | half life | convereted |
| Example | Polymer-1 | Polymer-2 | ratio | system X:Z | (cd/A) | (cd/m²) | (h) | life (h) |
| Example | Polymer | Polymer | 25/75 | 92.5:7.5 | 1.79 | 1519 | 14.3 | 207 |
| 55 | compound | compound | | | | | | |
| | 34 | 12 | | | | | | |
| Example | Polymer | Polymer | 62.5/37.5 | 92.5:7.5 | 2.06 | 1554 | 15.3 | 232 |
| 56 | compound | compound | | | | | | |
| | 34 | 13 | | | | | | |
| Example | Polymer | Polymer | 75/25 | 92.5:7.5 | 1.84 | 1349 | 14.8 | 169 |
| 57 | compound | compound | | | | | | |
| | 34 | 14 | | | | | | |
| Example | Polymer | Polymer | 85/15 | 92.5:7.5 | 1.66 | 1063 | 13.3 | 94 |
| 58 | compound | compound | | | | | | |
| | 34 | 39 | | | | | | |
| Example | Polymer | Polymer | 89.3/10.7 | 92.5:7.5 | 1.25 | 840 | 12.8 | 57 |
| 59 | compound | compound | | | | | | |
| | 34 | 40 | | | | | | |

### EXAMPLE 60

Compound H (1.8 g), N,N′-bis(4-bromophenyl)-N,N′-bis(4-t-butyl-2,6-dimethylphenyl)-1,4-phenylenediamine (2.23 g) and 2,2′-bipyridyl (2.25 g) were charged in a reaction vessel, then, an atmosphere in the reaction system was purged with a nitrogen gas. To this was added 200 g of tetrahydrofuran (dehydrated solvent) deaerated previously by bubbling with an argon gas. Next, to this mixed solution was added 4.0 g of bis(1,5-cyclooctadiene)nickel (0), and the mixture was stirred at room temperature for 10 minutes, then, reacted at 60° C. for 3 hours. The reaction was conducted in a nitrogen gas atmosphere.

After the reaction, this solution was cooled, then, into this solution was poured a mixed solution of 25% ammonia water 50 ml/methanol 150 mL/ion exchanged water 150 mL, and the mixture was stirred for about 1 hour. Then, the produced precipitate was filtrated and recovered. This precipitate was dried under reduced pressure, then, dissolved in toluene. This solution was filtrated to remove insoluble materials, then, this solution was purified by passing through a column filled with alumina. Next, this toluene solution was washed with about 5% ammonia water, then, allowed to stand still, separated, then, a toluene solution was recovered, next, this toluene solution was washed with water, then, allowed to stand still, separated, and a toluene solution was recovered. Next, this toluene solution was poured into methanol, to cause re-precipitation and purification.

Next, the produced precipitate was recovered, and this precipitate was dried under reduced pressure, to obtain 1.5 g of a polymer. This polymer is called polymer compound 41. The resulting polymer compound 41 had a weight-average molecular weight in terms of polystyrene of 6.7×10⁴ and a number-average molecular weight of 1.3×10⁴.

### EXAMPLE 61

Compound H (20.9 g), N,N′-bis(4-bromophenyl)-N,N′-bis(4-t-butyl-2,6-dimethylphenyl)-1,4-phenylenediamine (11.1 g) and 2,2′-bipyridyl (21.1 g) were dissolved in 1170 mL of dehydrated tetrahydrofuran, then, the mixture was heated up to 60° C. under a nitrogen atmosphere, and to this was added bis(1,5-cyclooctadiene)nickel (0) {Ni(COD)₂} (37.1 g), and reacted for 3 hours. After the reaction, this reaction solution was cooled to room temperature, and dropped into a mixed solution of 25% ammonia water 180 mL/methanol 1170 mL/ion exchanged water 1170 mL, and the mixture was stirred for 30 minutes, then, the deposited precipitate was filtrated and dried under reduced pressure for 2 hours, then, the mixture was dissolved in 1500 mL of toluene. After dissolution, 6.00 g of radiolite was added and the mixture was stirred for 30 minutes, and insoluble materials were filtrated. The resulting filtrate was purified by passing through an alumina column. Next, 2950 mL of 5.2% hydrochloric acid water was added and the mixture was stirred for 3 hours, then, the aqueous layer was removed. Subsequently, 2950 mL of 4% ammonia water was added and the mixture was stirred for 2 hours, then, the aqueous layer was removed. To the organic layer was further added about 2950 mL of ion exchanged water and the mixture was stirred for 1 hour, then, the aqueous layer was removed. Thereafter, the organic layer was poured into 4700 mL of methanol and the mixture was stirred for 1 hour, the deposited precipitate was filtrated and dried under reduced pressure. The resulting polymer (hereinafter, referred to as polymer compound 42) showed a yield of 22.7 g. The number-average molecular weight and weight-average molecular weight in terms of polystyrene were Mn=2.7×10⁴ and Mw=2.6×10⁵, respectively.

### EXAMPLE 62

### Preparation of Solution

90 wt % of polymer compound 34 obtained above and 10 wt % of polymer compound 41 were dissolved in toluene in this ratio, to obtain a toluene solution having a polymer concentration of 1.3 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 1500 rpm to form a film. The thickness after film formation was about 70 nm. Further, this was dried under reduced pressure at 80° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 80 nm, to manufacture an EL element. After the degree of vacuum reached 1×10⁻⁴ Pa or less, vapor deposition of a metal was initiated. By applying voltage on the resulting element, EL light emission having a peak at 470 nm was obtained from this element. The intensity of EL light emission was approximately in proportion to the current density. This element manifested initiation of light emission from 3.7 V and had a maximum light emission efficiency of 2.29 cd/A.

### EXAMPLE 63

### Preparation of Solution

80 wt % of polymer compound 34 obtained above and 20 wt % of polymer compound 41 were dissolved in toluene in this ratio, to obtain a toluene solution having a polymer concentration of 1.3 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 1500 rpm to form a film. The thickness after film formation was about 70 nm. Further, this was dried under reduced pressure at 80° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 80 nm, to manufacture an EL element. After the degree of vacuum reached 1×10⁻⁴ Pa or less, vapor deposition of a metal was initiated. By applying voltage on the resulting element, EL light emission having a peak at 470 nm was obtained from this element. The intensity of EL light emission was approximately in proportion to the current density. This element manifested initiation of light emission from 3.1 V and had a maximum light emission efficiency of 2.72 cd/A.

### EXAMPLE 64

### Preparation of Solution

50 wt % of polymer compound 34 obtained above and 50 wt % of polymer compound 41 were dissolved in toluene in this ratio, to obtain a toluene solution having a polymer concentration of 1.3 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 1500 rpm to form a film. The thickness after film formation was about 70 nm. Further, this was dried under reduced pressure at 80° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 80 nm, to manufacture an EL element. After the degree of vacuum reached 1×10⁻⁴ Pa or less, vapor deposition of a metal was initiated. By applying voltage on the resulting element, EL light emission having a peak at 475 nm was obtained from this element. The intensity of EL light emission was approximately in proportion to the current density. This element manifested initiation of light emission from 2.9 V and had a maximum light emission efficiency of 2.03 cd/A.

### EXAMPLE 65

### Preparation of Solution

80 wt % of polymer compound 34 obtained above and 20 wt % of polymer compound 41 were dissolved in toluene in this ratio, to obtain a toluene solution having a polymer concentration of 1.3 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 1500 rpm to form a film. The thickness after film formation was about 70 nm. Further, this was dried under reduced pressure at 80° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 80 nm, to manufacture an EL element. After the degree of vacuum reached 1×10⁻⁴ Pa or less, vapor deposition of a metal was initiated. By applying voltage on the resulting element, EL light emission having a peak at 475 nm was obtained from this element. The intensity of EL light emission was approximately in proportion to the current density. This element manifested initiation of light emission from 3.2 V and had a maximum light emission efficiency of 0.63 cd/A.

TABLE 9

| | Polymer | Monomer | Maximum light |
|---|---|---|---|
| | compound 34/ | composition | emission |
| | Polymer | ratio in the | efficiency |
| | compound 42 | system X:Y | (cd/A) |
| Example 62 | 90/10 | 95:5 | 2.29 |
| Example 63 | 80/20 | 90:10 | 2.72 |
| Example 64 | 50/50 | 75:25 | 2.03 |
| Example 65 | 30/70 | 65:35 | 0.67 |

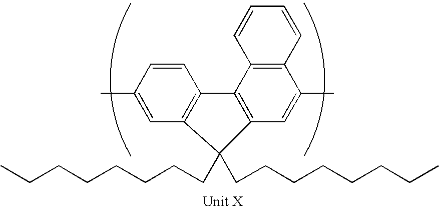

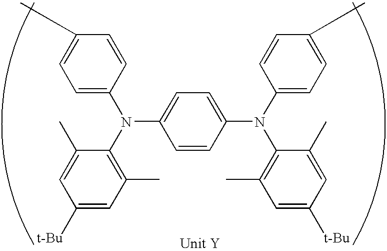

### EXAMPLE 66

### Preparation of Solution

83 wt % of polymer compound 34 obtained above and 17 wt % of polymer compound 42 were dissolved in toluene in this ratio, to obtain a toluene solution having a polymer concentration of 1.3 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 1500 rpm to form a film. The thickness after film formation was about 70 nm. Further, this was dried under reduced pressure at 80° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 80 nm, to manufacture an EL element. After the degree of vacuum reached 1×10⁻⁴ Pa or less, vapor deposition of a metal was initiated. By applying voltage on the resulting element, EL light emission having a peak at 470 nm was obtained from this element. The intensity of EL light emission was approximately in proportion to the current density. This element manifested initiation of light emission from 3.1 V and had a maximum light emission efficiency of 2.89 cd/A.

### EXAMPLE 67

### Preparation of Solution

67 wt % of polymer compound 34 obtained above and 33 wt % of polymer compound 42 were dissolved in toluene in this ratio, to obtain a toluene solution having a polymer concentration of 1.3 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 1500 rpm to form a film. The thickness after film formation was about 70 nm. Further, this was dried under reduced pressure at 80° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 80 nm, to manufacture an EL element. After the degree of vacuum reached 1×10⁻⁴ Pa or less, vapor deposition of a metal was initiated. By applying voltage on the resulting element, EL light emission having a peak at 470 nm was obtained from this element. The intensity of EL light emission was approximately in proportion to the current density. This element manifested initiation of light emission from 3.1 V and had a maximum light emission efficiency of 3.39 cd/A.

### EXAMPLE 68

### Preparation of Solution

17 wt % of polymer compound 34 obtained above and 83 wt % of polymer compound 42 were dissolved in toluene in this ratio, to obtain a toluene solution having a polymer concentration of 1.3 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 1500 rpm to form a film. The thickness after film formation was about 70 nm. Further, this was dried under reduced pressure at 80° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 80 nm, to manufacture an EL element. After the degree of vacuum reached 1×10⁻⁴ Pa or less, vapor deposition of a metal was initiated. By applying voltage on the resulting element, EL light emission having a peak at 470 nm was obtained from this element. The intensity of EL light emission was approximately in proportion to the current density. This element manifested initiation of light emission from 3.0 V and had a maximum light emission efficiency of 1.27 cd/A.

TABLE 10

| | Polymer | Monomer | Maximum light |
|---|---|---|---|
| | compound 34/ | composition | emission |
| | Polymer | ratio in the | efficiency |
| | compound 42 | system X:Y | (cd/A) |
| Example 66 | 83/17 | 95:5 | 2.89 |
| Example 67 | 67/33 | 90:10 | 3.39 |
| Example 68 | 17/83 | 75:25 | 1.27 |

### EXAMPLE 69

Compound H (0.90 g), N,N-bis(4-bromophenyl)-N-(4-t-butyl-2,6-dimethylphenyl)-amine (0.62 g) and 2,2′-bipyridyl (1.1 g) were dissolved in 110 mL of dehydrated tetrahydrofuran, then, an atmosphere in the system was purged with nitrogen by bubbling with nitrogen. Under a nitrogen atmosphere, to this solution was added bis(1,5-cyclooctadiene)nickel (0) {Ni(COD)₂} (2.0 g), and the mixture was heated up to 60° C., and reacted for 3 hours while stirring. After the reaction, this reaction solution was cooled to room temperature (about 25° C.), and dropped into a mixed solution of 25% ammonia water 30 mL/methanol 150 mL/ion exchanged water 150 mL, and the mixture was stirred for 1 hour, then, the deposited precipitate was filtrated and dried under reduced pressure for 2 hours, thereafter, the mixture was dissolved in 50 mL of toluene before filtration, and the filtrate was purified by passing through an alumina column, and about 50 mL of 4% ammonia water was added and the mixture was stirred for 2 hours, then, the aqueous layer was removed. To the organic layer was added about 50 mL of ion exchanged water and the mixture was stirred for 1 hour, then, the aqueous layer was removed. The organic layer was dropped into about 100 mL of methanol and the mixture was stirred for 1 hour, and the deposited precipitate was filtrated and dried under reduced pressure for 2 hours. The resulting polymer (hereinafter, referred to as polymer compound 43) showed a yield of 500 mg. The number-average molecular weight and weight-average molecular weight in terms of polystyrene were Mn=1.8×10⁴ and Mw=7.5×10⁴, respectively.

### EXAMPLE 70

On a glass base plate carrying an ITO film having a thickness of 150 nm formed by a sputtering method, a solution of poly(ethylenedioxythiophene)/polystyrenesulfonic acid (manufactured by Bayer, BaytronP) was spin-coated to form a film having a thickness of 70 nm, and dried on a hot plate at 200° C. for 10 minutes. Next, a toluene solution so prepared that the content of a 2:8 (by weight) mixture of polymer compound 43 and polymer compound 3 was 1.5 wt % was spin-coated at a rotational speed of 1200 rpm to form a film. Further, this was dried under reduced pressure at 90° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 70 nm, to manufacture an EL element. After the degree of vacuum reached 1×10⁻⁴ Pa or less, vapor deposition of a metal was initiated.

By applying voltage on the resulting element, EL light emission having a peak at 456 nm was obtained. Attenuation of luminance was measured setting the initial luminance at 956 cd/m², to find a luminance after 20 hours of 603 cd/m².

### EXAMPLE 71

### Synthesis of Compound XB

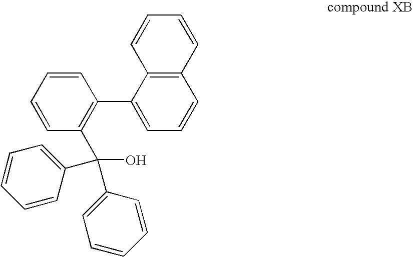

On a four-necked flask (2000 ml), a mechanical stirrer, condenser and thermometer were installed, and the flask was set on an ice bath under ventilation of nitrogen. 500 ml of phenyllithium was transferred from a reagent bottle into the flask quickly. 47 g of compound X was gradually added in 8 times each in about 5 g in solid condition. Thereafter, the ice bath was removed, the content was stirred at room temperature for 2 hours, and 500 mL of a saturated ammonium chloride aqueous solution was added slowly, to quench the reaction. Toluene (500 ml, twice) was used for extraction, and the organic layer was dried over sodium sulfate, then, the solvent was removed. After drying in a drying over (50° C.), 79.6 g (yield: 93.6%) of compound XB was obtained in the form of oil.

¹H-NMR (300 MHz/CDCl₃): δ 2.63 (s, —OH), 6.54 (d, 1H), 6.91 (d, 1H), 7.06-7.5 (m, 17H), 7.66 (d, 1H), 7.81 (d, 1H).

LC/MS (APPI(+)): 369.2

### (Synthesis of Compound XC)

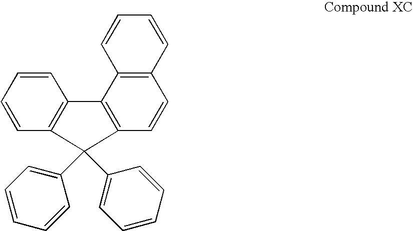

A three-necked flask equipped with a dropping funnel, mechanical stirrer and condenser was left immersed in an ice bath while ventilating nitrogen. 150 mL of trifluoroborate ether complex was transferred into the flask under sealed condition, then, 150 mL of anhydrous dichloromethane was added and the mixture was stirred. 79 g of compound XB obtained above was dissolved in 300 mL of dichloromethane, and placed in the dropping funnel and dropped (1 hour). The mixture was stirred for 3 hours without any other procedure, and water (500 mL) was added slowly to stop the reaction. The solution was separated using 500 mL of toluene, and further, extracted twice with 500 mL of toluene, and washed by water (500 mL) and saturated sodium hydrogencarbonate aqueous solution (500 mL). After passing through a short column of silica gel, the solvent was distilled off, to obtain 65.5 g of a coarse product containing compound XC. It was re-crystallized from toluene (50 mL) and washed with hexane (100 mL). 43.5 g (yield: 72.8%) of compound XC was obtained in the form of white solid.

¹H-NMR (300 MHz/CDCl₃): δ 7.16-7.33 (m, 11H), 7.44-7.58 (m, 4H), 7.62-7.70 (m, 1H), 7.78 (d, 1H), 7.91 (d, 1H), 8.39 (d, 1H), 8.80 (d, 1H).

LC/MS (APPI(+)): 368.2

### (Synthesis of Compound XD)

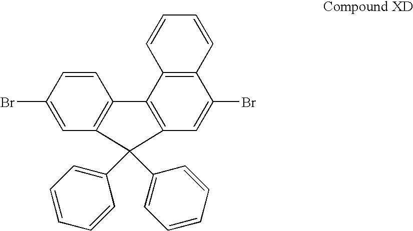

Into a three-necked flask (2000 ml) was added 75.0 g of compound XC, anhydrous dichloromethane (1000 ml), acetic acid (1350 ml) and zinc chloride (69.9 g), sequentially. The flask was heated to 50° C. in an oil bath and the content was stirred for 15 minutes. Benzyltrimethylammonium tribromide (222 g) was dissolved in anhydrous dichloromethane (500 ml) and, BTMA.Br₃ solution was dropped over 3 hours from a dropping funnel. After dropping, the mixture was further stirred at 50° C. for 3 hours, then, the mixture was allowed to cool to room temperature slowly. 500 ml of water was added for quenching, and the solution was separated. The aqueous layer was extracted by 200 ml of chloroform, and the combined organic layer was washed with 400 ml of 5% sodium thiosulfate aqueous solution. This was washed further using 400 ml of 5% potassium carbonate aqueous solution and 100 ml of water, then, dehydrated by sodium sulfate. The solvent was distilled off by concentration under reduced pressure, then, dissolved twice with 100 ml of hexane and the solvent was completely distilled off. For re-crystallization, 2-propanol was added during heating under reflux using 5-fold amount of toluene and the mixture was stirred for 10 minutes, then, allowed to cool to room temperature, and washed with 100 ml of hexane, to obtain 105 g (yield: 87.1%) of compound XD.

¹H-NMR (300 MHz/CDCl₃): δ 7.19-7.25 (M, 11H), 7.57-7.59 (M, 2H), 7.62-7.73 (M, 2H), 7.82 (s, 1H), 8.21 (d, 1H), 8.36 (d, 1H), 8.70 (d, 1H)

LC/MS (APPI(+)): 525.9

### EXAMPLE 72

### Synthesis of Compound XE

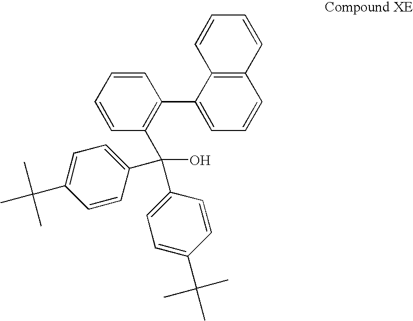

Into a 3 L three-necked flask was added 113 g of 4-t-butylphenyl bromide and 1500 ml of tetrahydrofuran, and the mixture was cooled down to −78° C. under a nitrogen atmosphere. 600 ml of n-butyllithium was placed in a dropping funnel and dropped slowly so that the temperature in the system did not change. After dropping, the mixture was stirred at room temperature for 2 hours, then, cooled down to −78° C. and, a solution prepared by dissolving 34.6 g of compound XA in 500 ml tetrahydrofuran was dropped over a period of 60 minutes. Further, the mixture was stirred for 2 hours at −78° C., then, the reaction was terminated using 500 ml of saturated ammonium chloride aqueous solution, and extracted with 1000 ml of toluene. This was washed with water, then, impurities were removed by passing through a silica gel short column, to obtain 61.5 g (yield: 88.2%) of compound XE.

¹H-NMR (300 MHz/CDCl₃): δ1.26 (s, 9H), 1.34 (s, 9H), 2.58 (s, 1H), 6.58 (d, 1H), 6.98-7.13 (m, 12H), 7.20 (d, 1H), 7.23 (d, 1H), 7.28-7.32 (m, 2H), 7.38-7.43 (m, 2H), 7.72 (d, 1H), 7.79 (d, 1H).

MS (ESI(+)): 537.3.

### (Synthesis of Compound XF)

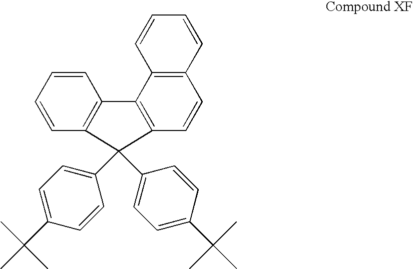

Into a 2000 ml three-necked flask containing 325 ml of boron trifluoride ether complex was added 1500 ml of dichloromethane, and the mixture as cooled sufficiently in an ice bath. 132 g of compound XE was dissolved in dichloromethane to give a solution, and this solution was dropped over a period of 1 hour using a non-isobaric dropping funnel. The ice bath was removed, and the mixture was stirred at room temperature for 2 hours, then, water was added to this to stop the reaction. Extraction was performed using chloroform, the organic layer was concentrated, then, an orange oil was obtained. Re-crystallization using 240 ml of toluene and 50 ml of 2-propanol gave 64 g (yield: 52.8%) of intended compound XF.

¹H-NMR (300 MHz/CDCl₃): δ 1.32 (s, 18H), 2.63 (s, 1H), 6.57 (d, 1H), 7.00-7.25 (m, 12H), 7.21 (d, 1H), 7.26 (d, 1H), 7.74 (d, 1H), 7.80-9.50 (m, 2H), 7.77 (d, 1H), 7.80 (d, 1H).

LC-MS (APPI-posi): m/z calcd for [C37H36+H]+, 480.68; found, 481.2.

### (Synthesis of Compound XG)

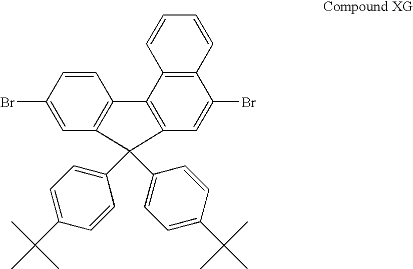

Into a three-necked flask (2000 ml) was added 64.0 g of compound XF, anhydrous dichloromethane (500 ml), acetic acid (830 ml) and zinc chloride (36 g), sequentially. The flask was heated to 50° C. in an oil bath and the content was stirred for 15 minutes. Benzyltrimethylammonium tribromide (103 g) was dissolved in anhydrous dichloromethane (300 ml) and, this solution was dropped over 3 hours from a dropping funnel. After dropping, the mixture was further stirred at 50° C. for 3 hours, then, the mixture was allowed to cool to room temperature slowly. 500 ml of water was added for quenching, and the solution was separated. The aqueous layer was extracted by 200 ml of chloroform, and the combined organic layer was washed with 400 ml of 5% sodium thiosulfate aqueous solution. This was washed further using 400 ml of 5% potassium carbonate aqueous solution and 100 ml of water, then, dehydrated by sodium sulfate. The solvent was distilled off by concentration under reduced pressure, then, dissolved twice with 100 ml of hexane and the solvent was completely distilled off. For re-crystallization, 2-propanol was added during heating under reflux using 5-fold amount of toluene and the mixture was stirred for 10 minutes, then, allowed to cool to room temperature, and washed with 100 ml of hexane, to obtain 46 g (yield: 72.0%) of compound XG.

¹H-NMR (300 MHz/CDCl₃): δ 1.28 (s, 18H), 7.10 (d, 4H), 7.25 (d, 4H), 7.55-7.71 (m, 4H), 7.85 (s, 1H), 8.19 (d, 1H), 8.36 (d, 1H), 8.69 (d, 1H).

LC-MS (APPI-posi): m/z calcd for [C37H34Br2]+, 638.47; found, 638.0.

### EXAMPLE 73

### Synthesis of Compound XH

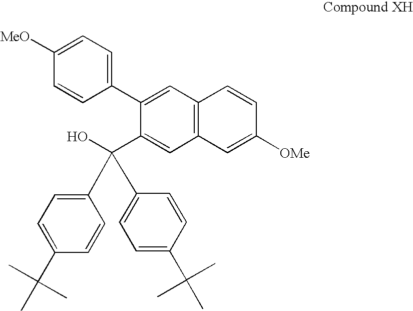

Into a 3 L three-necked flask was added 105.7 g of 4-t-butylphenyl bromide and 1500 ml of tetrahydrofuran, and the mixture was cooled down to −78° C. under a nitrogen atmosphere. 551 ml of n-butyllithium was placed in a dropping funnel and dropped slowly so that the temperature in the system did not change. After dropping, the mixture was stirred at room temperature for 2 hours, then, cooled down to −78° C. and, a solution prepared by dissolving 40 g of compound V in 500 ml tetrahydrofuran was dropped over a period of 60 minutes. Further, the mixture was stirred for 2 hours at −78° C., then, the reaction was terminated using 500 ml of saturated ammonium chloride aqueous solution, and extracted with 1000 ml of toluene. This was washed with water, then, impurities were removed by passing through a silica gel short column, to obtain 69.3 g (yield: 97.6%) of compound XH.

¹H-NMR (300 MHz/CDCl₃): δ 1.28 (s, 18H), 7.11 (d, 4H), 7.25-7.38 (m, 7H), 7.69 (s, 1H), 7.86 (s, 1H), 7.90 (d, 1H), 7.97 (d, 1H), 8.21 (s, 1H)

MS (APPI (+)): (M−OH)⁺ 541.4

### (Synthesis of Compound XI)

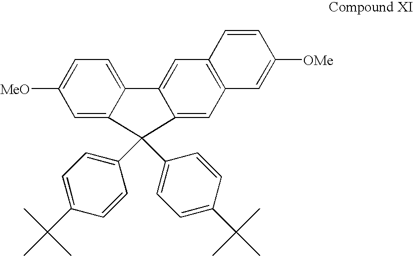

Into a 2000 ml three-necked flask containing boron trifluoride ether complex was added 400 ml of dichloromethane, and the mixture was cooled sufficiently in an ice bath. Compound XH was dissolved in dichloromethane to give a solution, and this solution was dropped over a period of 1 hour using a non-isobaric dropping funnel. The ice bath was removed, and the mixture was stirred at room temperature for 2 hours, then, water was added to this to stop the reaction. Extraction was performed using chloroform, the organic layer was concentrated, then, an orange oil was obtained. Re-crystallization using 120 ml of toluene and 30 ml of 2-propanol gave 54 g (yield: 82.5%) of intended compound XI.

¹H-NMR (300 MHz/CDCl₃): δ 1.27 (s, 18H), 3.80 (s, 3H), 3.87 (s, 3H), 6.90 (d, 1H), 7.09 (d, 1H), 7.15-7.26 (m, 9H), 7.67 (s, 1H), 7.76 (d, 1H), 7.98 (s, 1H)

MS (APPI (+)): (M+H)⁺ 541.3

### (Synthesis of Compound XJ)

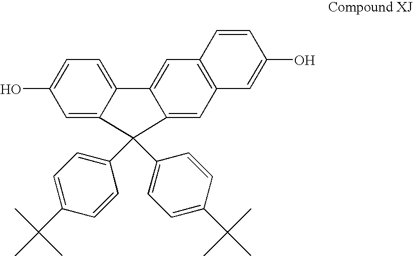

Into a three-necked flask (200 ml) was added 115 g of compound X and 100 ml of dichloromethane. A boron tribromide dichloromethane solution was placed in a dropping funnel and dropped over 1 hour into the mixture being stirred at 0° C. in an ice bath under a nitrogen atmosphere. Thereafter, the ice bath was removed, and the mixture was stirred for 3 hours at room temperature. 100 ml of water was added to stop the reaction, the solution was separated, then, extraction was performed using chloroform. The resulting organic layer was washed with a 10% sodium thiosulfate aqueous solution, and dried over sodium sulfate, then, filtrated through a silica gel pad (3 cm) pre-coated on a glass filter, to obtain 10.3 g (yield: 71.6%) of compound XJ as a mixture.

¹H-NMR (300 MHz/CDCl₃) CDCl₃): δ 1.25 (s, 18H), 4.77 (s, 3H), 4.88 (s, 1H), 6.82 (dd, 1H), 6.83 (s, 1H), 7.00 (s, 1H), 7.01 (dd, 1H), 7.15 (d, 4H), 7.21 (d, 4H), 7.58 (s, 1H), 7.69 (dd, 1H), 7.74 (d, 1H), 7.95 (s, 1H)

LC-MS (APPI-posi): m/z calcd for [C37H36O2+H]+, 513.69; found, 513.

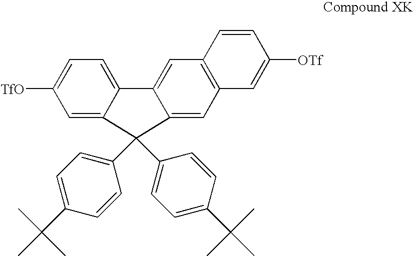

A 1000 ml flask was purged with argon, 43.2 g of compound XJ and 25.5 g of 4-N,N-dimethylaminopyridine were placed and dissolved in 402 ml of dichloromethane. After cooling with an ice bath, 51.7 g of trifluoromethanesulfonic anhydride was dropped. Thereafter, the mixture was stirred for 3 hours at room temperature. A reaction mass was poured into 1000 ml of water, and extracted twice with 500 ml of chloroform. The solvent was distilled off, to obtain 63.8 g of a coarse product. 20 g of the coarse product was purified by silica gel column chromatography, to obtain 11.5 g of compound XK.

¹H-NMR (300 MHz/CDCl₃): δ 1.28 (s, 18H), 7.11 (d, 4H), 7.25-7.38 (m, 7H), 7.69 (s, 1H), 7.86 (s, 1H), 7.95 (d, 1H), 7.97 (d, 1H), 8.21 (s, 1H)

### EXAMPLE 74

### Synthesis of Polymer Compound 44

1740 mg of compound XD and 1390 mg of 2,2′-bipyridyl were charged in a reaction vessel, then, an atmosphere in the reaction system was purged with a nitrogen gas. To this was added 298 mL of tetrahydrofuran (dehydrated solvent) deaerated previously by bubbling with an argon gas. Next, the mixture was heated up to 60° C. under a nitrogen atmosphere, and to this solution was added 2450 mg of bis(1,5-cyclooctadiene)nickel (0), and the mixture was stirred at 60° C. for 3 hours. The reaction was conducted in a nitrogen gas atmosphere.

After the reaction, this reaction solution was cooled to room temperature, and dropped into a mixed solution of 25% ammonia water 12 ml/methanol 297 mL/ion exchanged water 297 mL, and the mixture was stirred for about 1 hour. The deposited precipitate was filtrated and recovered. This precipitate was dried under reduced pressure for 2 hours, and dissolved in toluene. To this solution was added 0.4 g of radiolite and the mixture was stirred for 30 minutes, to filtrate insoluble materials off. The resulting filtrate was purified by passing through an alumina column (alumina amount, 10 g), and to the recovered toluene solution was added 200 mL of 5.2% hydrochloric acid and the mixture was stirred for 3 hours, then, allowed to stand still, separated, then, a toluene solution was recovered. To this toluene solution was added about 4% ammonia water and the mixture was stirred for 2 hours, and the aqueous layer was removed. Next, this toluene solution was washed with ion exchanged water, then, allowed to stand still, separated, then, a toluene solution was recovered. This toluene solution was added to 310 ml of methanol while stirring, to cause re-precipitation and purification.

Next, the produced precipitate was recovered, and this precipitate was dried under reduced pressure, to obtain 0.45 g of a polymer. This polymer is called polymer compound 44. The resulting polymer compound 44 had a weight-average molecular weight in terms of polystyrene of 1.8×10⁵ and a number-average molecular weight of 3.1×10⁴.

### EXAMPLE 75

### Synthesis of Polymer Compound 45

7.66 g of compound XG and 5.06 g of 2,2′-bipyridyl were charged in a reaction vessel, then, an atmosphere in the reaction system was purged with a nitrogen gas. To this was added 768 g of tetrahydrofuran (dehydrated solvent) deaerated previously by bubbling with an argon gas. Next, the mixture was heated up to 60° C. under a nitrogen atmosphere, and to this solution was added 8.91 g of bis(1,5-cyclooctadiene)nickel (0), and the mixture was stirred at 60° C. for 3 hours. The reaction was conducted in a nitrogen gas atmosphere.

After the reaction, this reaction solution was cooled, and dropped into a mixed solution of 25% ammonia water 43 ml/methanol 864 mL/ion exchanged water 864 mL, and the mixture was stirred for about 1 hour. The deposited precipitate was filtrated and recovered. This precipitate was dried, then, dissolved in toluene. To this solution was added 1.4 g of radiolite and the mixture was stirred for 30 minutes, to filtrate insoluble materials off. The resulting filtrate was purified by passing through an alumina column (alumina amount, 72 g), and to the recovered toluene solution was added 708 mL of 5.2% hydrochloric acid and the mixture was stirred for 3 hours. Then, the mixture was allowed to stand still, separated, then, a toluene solution was recovered, and this toluene solution was washed with 708 mL of about 4% ammonia water, then, allowed to stand still, separated, and a toluene solution was recovered, next, this toluene solution was washed with ion exchanged water, then, allowed to stand still, separated, and a toluene solution was recovered. This toluene solution was added to 1128 mL of methanol while stirring, to cause re-precipitation and purification.

Next, the produced precipitate was recovered, and this precipitate was dried under reduced pressure, to obtain 5.66 g of a polymer. This polymer is called polymer compound 45. The resulting polymer compound 45 had a weight-average molecular weight in terms of polystyrene of 1.4×10⁵ and a number-average molecular weight of 4.7×10⁴.

### EXAMPLE 76

### Synthesis of Polymer Compound 46

1660 mg of compound Z, 583 mg of XK and 1265 mg of 2,2′-bipyridyl were charged in a reaction vessel, then, 108 mL of tetrahydrofuran deaerated previously by bubbling with an argon gas was added. Next, the mixture was heated up to 60° C. under a nitrogen atmosphere, and to this solution was added 2228 mg of bis(1,5-cyclooctadiene)nickel (0), and the mixture was stirred at 60° C. for 3 hours. The reaction was conducted in a nitrogen gas atmosphere.

After the reaction, this reaction solution was cooled to room temperature, and dropped into a mixed solution of 25% ammonia water 11 ml/methanol 108 mL/ion exchanged water 108 mL, and the mixture was stirred for about 1 hour. The deposited precipitate was filtrated and recovered. This precipitate was dried under reduced pressure for 2 hours, and dissolved in 90 ml of toluene. After dissolution, to this solution was added 0.4 g of radiolite and the mixture was stirred for 30 minutes, to filtrate insoluble materials off. The resulting filtrate was purified by passing through an alumina column (alumina amount, 18 g), and to the recovered toluene solution was added 177 mL of 5.2% hydrochloric acid and the mixture was stirred for 3 hours, then, allowed to stand still, separated, then, a toluene solution was recovered. To this toluene solution was added 177 mL of about 4% ammonia water and the mixture was stirred for 2 hours, and the aqueous layer was removed. Further, 177 mL of water was added to the organic layer and the mixture was stirred for 1 hour, and the aqueous layer was removed. This toluene solution was dropped into 300 mL of methanol with stirring and the mixture was stirred for 30 minutes, to case re-precipitation and purification.

Next, the produced precipitate was recovered, and this precipitate was dried under reduced pressure, to obtain 1060 mg of a polymer. This polymer is called polymer compound 46. The resulting polymer compound 46 had a weight-average molecular weight in terms of polystyrene of 2.3×10⁴ and a number-average molecular weight of 8.1×10³.

### EXAMPLE 77

### Synthesis of Polymer Compound 47

1.47 g of compound Z and 0.843 g of 2,2′-bipyridyl were charged in a reaction vessel, then, an atmosphere in the reaction system was purged with a nitrogen gas. To this was added 128 g of tetrahydrofuran (dehydrated solvent) deaerated previously by bubbling with an argon gas. Next, the mixture was heated up to 60° C. under a nitrogen atmosphere, and to this solution was added 1.48 g of bis(1,5-cyclooctadiene)nickel (0), and the mixture was stirred at 60° C. for 3 hours. The reaction was conducted in a nitrogen gas atmosphere.

After the reaction, this reaction solution was cooled, then, dropped into a mixed solution of 25% ammonia water 144 ml/methanol 144 mL/ion exchanged water 7 mL, and the mixture was stirred for about 1 hour. The deposited precipitate was filtrated and recovered. This precipitate was dried, then, dissolved in toluene. To this solution was added 0.2 g of radiolite and the mixture was stirred for 30 minutes, to filtrate insoluble materials off. The resulting filtrate was purified by passing through an alumina column (alumina amount, 12 g), and to the recovered toluene solution was added 118 mL of 5.2% hydrochloric acid and the mixture was stirred for 3 hours, then, the mixture was allowed to stand still, separated, then, a toluene solution was recovered, and this toluene solution was washed with about 4% ammonia water, then, allowed to stand still, separated, and a toluene solution was recovered, next, this toluene solution was washed with ion exchanged water, then, allowed to stand still, separated, and a toluene solution was recovered. This toluene solution was added to 118 mL of methanol while stirring, to cause re-precipitation and purification.

Next, the produced precipitate was recovered, and this precipitate was dried under reduced pressure, to obtain 0.57 g of a polymer. This polymer is called polymer compound 47. The resulting polymer compound 47 had a weight-average molecular weight in terms of polystyrene of 1.7×10⁴ and a number-average molecular weight of 5.7×10³.

### EXAMPLE 78

### Synthesis of Polymer Compound 48

4531 mg of compound XD, 3006 mg of N,N′-bis(4-bromophenyl)-N,N′-bis(4-t-butyl-2,6-dimethylphenyl)-1,4-phenylenediamine and 5187 mg of 2,2′-bipyridyl were charged in a reaction vessel, then, 576 mL of tetrahydrofuran deaerated previously by bubbling with an argon gas was added. The mixture was heated up to 60° C. under a nitrogen atmosphere, and to this solution was added 9134 mg of bis(1,5-cyclooctadiene)nickel (0), and the mixture was reacted for 3 hours. The reaction was conducted in a nitrogen gas atmosphere.

After the reaction, this reaction solution was cooled to room temperature, and dropped into a mixed solution of 25% ammonia water 44 ml/methanol 576 mL/ion exchanged water 576 mL, and the mixture was stirred for about 1 hour. The deposited precipitate was filtrated and recovered. This precipitate was dried under reduced pressure for 2 hours, and dissolved in 369 ml of toluene. After dissolution, to this solution was added 1.5 g of radiolite and the mixture was stirred for 30 minutes, to filtrate insoluble materials off. The resulting filtrate was purified by passing through an alumina column (alumina amount, 74 g), and to the recovered toluene solution was added 726 mL of 5.2% hydrochloric acid and the mixture was stirred for 3 hours, then, allowed to stand still, separated, then, a toluene solution was recovered. This toluene solution was added to 726 mL of about 4% ammonia water and the mixture was stirred for 2 hours, and the aqueous layer was removed. Further, 726 mL of water was added to the organic layer and the mixture was stirred for 1 hour, and the aqueous layer was removed. This toluene solution was dropped into 1156 mL of methanol with stirring and the mixture was stirred for 30 minutes, to case re-precipitation and purification.

Next, the produced precipitate was recovered, and this precipitate was dried under reduced pressure, to obtain 4630 mg of a polymer. This polymer is called polymer compound 48. The resulting polymer compound 48 had a weight-average molecular weight in terms of polystyrene of 4.6×10⁵ and a number-average molecular weight of 3.6×10⁴.

### EXAMPLE 79

### Evaluation of Electron Injectability

The absolute values of LUMO obtained by measuring according to the above-mentioned conditions are shown in the following Table 11. It is understood that polymer compounds 44 to 46 all show very excellent electron injectability.

TABLE 11

| Polymer | Number-average | Weight-average | |
|---|---|---|---|
| compound | molecular weight | molecular weight | LUMO |
| Polymer | 74000 | 180000 | 2.5 eV |
| compound 3 | | | |
| Polymer | 31000 | 180000 | 2.8 eV |
| compound 44 | | | |
| Polymer | 47000 | 140000 | 3.0 eV |
| compound 45 | | | |
| Polymer | 8100 | 23000 | 2.9 eV |
| compound 46 | | | |
| Polymer | 5700 | 17000 | 2.6 eV |
| compound 47 | | | |
| Polymer | 27000 | 54000 | 2.4 eV |
| compound | | | |
| 18 (Comparative | | | |
| Example) | | | |
| Polymer | 36000 | 460000 | 2.9 eV |
| compound 48 | | | |

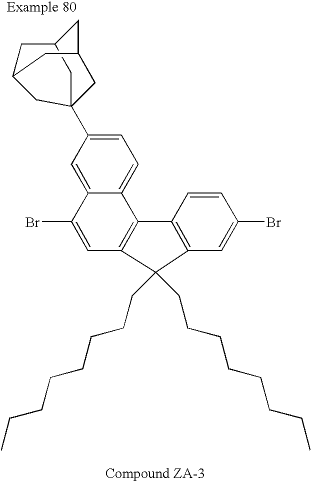

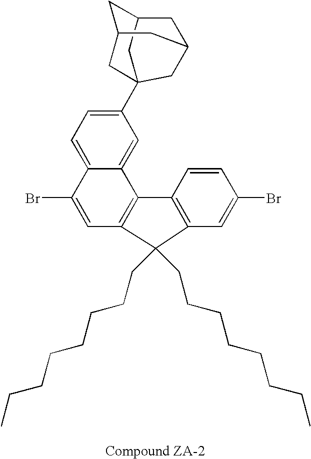

Into a 1000 mL two-necked flask was weighed ferric chloride (6.75 g, 42 mmol) and 1-bromoadamantane (21.6 g, 100.3 mmol), and a Dimroth cooling tube and a septum were installed, and an atmosphere in the system was purged with argon. Dehydrated dichloromethane (500 mL) was added. The flask was cooled to −10° C., a dehydrated dichloromethane solution (300 mL) of compound H (50.00 g, 83.5 mmol) was dropped using a dropping funnel over a period of 2.5 hours, and after completion of dropping, the mixture was stirred further for 4 hours remaining at low temperature. The reaction was stopped by water, and the organic layer was dried over sodium sulfate. The solvent was distilled off, and the resultant solid was purified by a silica gel column using hexane as a developing solvent, to obtain 27.2 g (yield: 44%) of a mixture of compound ZA-3 and compound ZA-2, in the form of white solid. The ratio of compound ZA-3 to compound ZA-2 was confirmed to be 5:1 by integral ratio of ¹H-NMR.

LC-MS: [M+H]: 731

### Compound ZA-3

NMR (CDCl₃): δ=0.51˜1.20 (m, 30H), 1.85 (s, 7H), 2.00 (t, 4H), 2.09 (s, 5H), 2.19 (s, 3H) 2.19, 7.53 (s, 1H), 7.54 (d, 1H), 7.76 (s, 1H), 7.78 (d, 1H), 8.12 (d, 1H), 8.28 (s, 1H), 8.60 (d, 1H)

### Compound ZA-2

NMR δ (CDCl₃): δ=0.51 (t, 6H) 0.78˜1.26 (m, 24H) 1.76˜2.22 (m, 19H), 7.52 (s, 1H), 7.59 (dd, 1H), 7.73 (dd, 2H), 8.11 (d, 1H), 8.30 (d, 1H), 8.51 (s, 1H)

### EXAMPLE 81

Into a 300 mL four-necked flask was weighed compound H (9.00 g, 15.0 mmol) and 1-bromoadamantane (8.09 g, 37.6 mmol), and an atmosphere in the system was purged with argon, then, dehydrated dichloromethane (144 mL) was added. Aluminum chloride (0.16 g, 1.20 mmol) was added and the mixture was stirred for 4 hours. The reaction was stopped by water, and chloroform was added and extraction was performed, and the aqueous layer was separated. To the separated aqueous layer was added chloroform and extraction and washing were carried out, and the aqueous layer was removed. The organic layer was mixed, washed with a 5% potassium carbonate aqueous solution and the aqueous layer was removed. The organic layer was dried over sodium sulfate, then, the solvent was distilled off to obtain solid, this solid was purified by a silica gel column using hexane as a developing solvent, to obtain 3.48 g (yield: 32%) of a mixture of compound ZA-3 and compound ZA-2, in the form of colorless oil. The ratio of compound ZA-3 to compound ZA-2 was confirmed to be 1:0.85 by integral ratio of ¹H-NMR.

### EXAMPLE 82

487 mg of the mixture of compound ZA-3 and compound ZA-2 (1:0.85) produced in Example 81, 211 mg of N,N′-bis(4-bromophenyl)-N,N′-bis(4-t-butyl-2,6-dimethylphenyl)-1,4-phenylenediamine and 360 mg of 2,2′-bipyridyl were dissolved in 57 mL of dehydrated tetrahydrofuran, then, under a nitrogen atmosphere, to this solution was added 630 mg of bis(1,5-cyclooctadiene)nickel (0) {Ni(COD)₂}, and the mixture was heated up to 60° C., and the mixture was reacted for 3 hours. After the reaction, this reaction solution was cooled to room temperature, and dropped into a mixed solution of 25% ammonia water 3 ml/methanol 57 mL/ion exchanged water 57 mL, and the mixture was stirred for 30 minutes, then, the deposited precipitate was filtrated and dried under reduced pressure for 2 hours, and dissolved in 29 ml of toluene. After dissolution, to this solution was added 0.11 g of radiolite and the mixture was stirred for 30 minutes, to filtrate insoluble materials off. The resulting filtrate was purified by passing through an alumina column (alumina amount, 6 g), and to the recovered toluene solution was added 56 mL of 2.9% ammonia water and the mixture was stirred for 2 hours, and the aqueous layer was removed. Further, 56 mL of water was added to the organic layer and the mixture was stirred for 1 hour, and the aqueous layer was removed. Thereafter, the organic layer was dropped into 89 mL of methanol and the mixture was stirred for 30 minutes, and the deposited precipitate was filtrated and dried under reduced pressure for 2 hours.

The resulting polymer showed a yield of 328 mg. This polymer is called polymer compound 49. The number-average molecular weight in terms of polystyrene Mn was 1.4×10⁴ and the weight-average molecular weight Mw was 6.4×10⁴. Fluorescent measurement was conducted to find a fluorescent peak of 478 nm and a fluorescent intensity of 3.8.

### EXAMPLE 83

The mixture (0.70 g) of compound ZA-3 and compound ZA-2 (1:0.85) produced in Example 81 and 2,2′-bipyridyl (0.40 g) were dissolved in 29 mL of dehydrated tetrahydrofuran, then, under a nitrogen atmosphere, to this solution was added bis(1,5-cyclooctadiene)nickel (0) {Ni(COD)₂} (0.71 g), and the mixture was heated up to 60° C., and reacted for 1.5 hours. After the reaction, this reaction solution was cooled to room temperature, and dropped into a mixed solution of 25% ammonia water 3 ml/methanol 29 mL/ion exchanged water 29 mL, and the mixture was stirred for 30 minutes, then, the deposited precipitate was filtrated and dried under reduced pressure for 2 hours, and dissolved in 29 ml of toluene. After dissolution, to this solution was added 0.11 g of radiolite and the mixture was stirred for 30 minutes, to filtrate insoluble materials off.

The resulting filtrate was purified by passing through an alumina column (alumina amount, 6 g), subsequently, the solvent was distilled off. After distilling the solvent off, methanol was charged into the residue, and the deposited precipitate was filtrated and dried under reduced pressure for 2 hours. The resulting polymer showed a yield of 0.04 g. This polymer is called polymer compound 50. The number-average molecular weight in terms of polystyrene Mn was 5.3×10⁴ and the weight-average molecular weight Mw was 2.6×10⁵. Fluorescent measurement was conducted to find a fluorescent peak of 478 nm and a fluorescent intensity of 4.1.

### EXAMPLE 84

The mixture (8.26 g) of compound ZA-3 and compound ZA-2 (5:1) produced in Example 80, N,N′-bis(4-bromophenyl)-N,N′-bis(4-t-butyl-2,6-dimethylphenyl)-1,4-phenylenediamine (0.93 g) and 5.28 g of 2,2′-bipyridyl were dissolved in 496 mL of dehydrated tetrahydrofuran, then, under a nitrogen atmosphere, the mixture was heated up to 60° C., to this solution was added bis(1,5-cyclooctadiene)nickel (0) {Ni(COD)₂} (9.31 g), and the mixture was reacted for 3 hours. After the reaction, this reaction solution was cooled to room temperature, and dropped into a mixed solution of 25% ammonia water 45 ml/methanol 496 mL/ion exchanged water 496 mL, and the mixture was stirred for 30 minutes, then, the deposited precipitate was filtrated and dried under reduced pressure for 2 hours, and dissolved in 376 ml of toluene. After dissolution, to this solution was added 1.5 g of radiolite and the mixture was stirred for 30 minutes, to filtrate insoluble materials off. The resulting filtrate was purified by passing through an alumina column (alumina amount, 75 g), and to the recovered toluene solution was added 739 mL of 2.9% ammonia water and the mixture was stirred for 2 hours, and the aqueous layer was removed. Further, 739 mL of water was added to the organic layer and the mixture was stirred for 1 hour, and the aqueous layer was removed. Thereafter, 225 mL of methanol was added to the organic layer, and the deposited precipitate was collected by decantation, and dissolved in 225 ml of toluene, then, this was dropped into about 900 mL of methanol and the mixture was stirred for 1 hour, and the deposited precipitate was filtrated and dried under reduced pressure for 2 hours. The resulting polymer showed a yield of 6.21 g. This polymer is called polymer compound 51. This polymer had a number-average molecular weight in terms of polystyrene Mn of 1.1×10⁵ and a weight-average molecular weight Mw of 3.1×10⁵.

### EXAMPLE 85

Compound H (1.98 g), the mixture (2.42 g) of compound ZA-3 and compound ZA-2 (1:5) produced in Example 81 and 2,2′-bipyridyl (2.78 g) were dissolved in 475 mL of dehydrated tetrahydrofuran, then, under a nitrogen atmosphere, the mixture was heated up to 60° C., to this solution was added bis(1,5-cyclooctadiene)nickel (0) {Ni(COD)₂} (4.90 g), and the mixture was reacted for 3 hours. After the reaction, this reaction solution was cooled to room temperature, and dropped into a mixed solution of 25% ammonia water 24 ml/methanol 475 mL/ion exchanged water 475 mL, and the mixture was stirred for 30 minutes, then, the deposited precipitate was filtrated and dried under reduced pressure for 2 hours, and dissolved in 198 ml of toluene. After dissolution, to this solution was added 0.8 g of radiolite and the mixture was stirred for 30 minutes, to filtrate insoluble materials off. The resulting filtrate was purified by passing through an alumina column (alumina amount, 40 g), and to the recovered toluene solution was added 389 mL of 5.2% hydrochloric acid water and the mixture was stirred for 3 hours, and the aqueous layer was removed. Subsequently, 389 mL of 2.9% ammonia water was added and the mixture was stirred for 2 hours, and the aqueous layer was removed. Further, 389 mL of water was added to the organic layer and the mixture was stirred for 1 hour, and the aqueous layer was removed. Thereafter, the organic layer was dropped into 620 mL of methanol and the mixture was stirred for 30 minutes, and the deposited precipitate was filtrated and dried under reduced pressure for 2 hours. This polymer is called polymer compound 52. The resulting polymer showed a yield of 1.82 g. This polymer had a number-average molecular weight in terms of polystyrene Mn of 5.5×10⁴ and a weight-average molecular weight Mw of 2.7×10⁵.

### EXAMPLE 86

### Synthesis of Compound AB

### (Synthesis of Compound X)

Into an argon-purged 10 L separable flask was added 619 g of methyl bromobenzoate, 904 g of potassium carbonate and 450 g of 1-naphthylboronic acid, and to the mixture was added 3600 ml of toluene and 4000 ml of water and the mixture was stirred. 30 g of tetrakistriphenylphosphinepalladium (0) was added and the mixture was heated under reflux, and stirred for 3 hours without any other procedure. The mixture was cooled to room temperature, then, separated, and washed with 2000 ml of water. The solvent was distilled off, then, purification was performed by a silica gel column using toluene. The resulting coarse product was concentrated and washed twice with 774 ml of hexane, and dried to obtain 596.9 g of compound X in the form of white solid.

¹H-NMR (300 MHz, CDCl₃)

δ 8.03 (1H, d), 7.88 (1H, d), 7.85 (1H, d), 7.62˜7.56 (1H, m), 7.53˜7.30 (7H, m), 3.36 (3H, s)

MS [APPI (+)] 263 ([M+H]⁺)

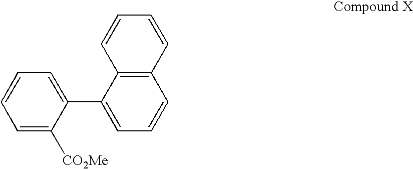

### (Synthesis of Compound Y)

A 2 L flask was purged with argon, and into this was added 340 g of polyphosphoric acid and 290 ml of methanesulfonic acid and the mixture was stirred until uniformity. To this solution was added 50.0 g (0.19 mol) of compound X synthesized above. The mixture was stirred at 50° C. for 8 hours, then, cooled to room temperature, and dropped into 2 L of ice water. The crystal was filtrated, washed with water and dried under reduced pressure, to obtain 56.43 g of a coarse product of compound Y. This was a mixture with benzanthrone, however, used in the subsequent process without purification.

¹H-NMR (300 MHz, CDCl₃)

δ 8.47 (1H, d) 8.01 (1H, d), 7.87 (1H, d), 7.77˜7.49 (6H, m), 7.32 (1H, d)

MS [APCI (+)] 231.1 ([M+H]⁺)

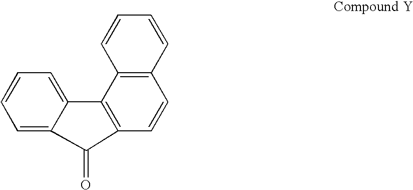

### (Synthesis of Compound Z)

A 1 L three-necked flask was purged with nitrogen, and into this was added 12.0 g of compound Y synthesized above, 250 ml of diethylene glycol and 15 ml of hydrazine mono-hydrate, and the mixture was stirred at 180° C. for 4.5 hours. The mixture was cooled to room temperature, then, 1 L of water was added to this and the mixture was extracted with 500 ml of toluene three times. The toluene phase was combined and washed with hydrochloric acid, water and saturated saline, and the solution was passed through 20 g of silica gel, then, the solvent was distilled off, to obtain 6.66 g of a coarse product of compound Z. This was a mixture with benzanthrone, however, used in the subsequent process without purification.

¹H-NMR (300 MHz, CDCl₃)

δ 8.78 (1H, d), 8.41 (1H, d) 7.97 (1H, d), 7.83 (1H, d), 7.72˜7.63 (3H, m), 7.57˜7.47 (2H, m), 7.39˜7.33 (1H, m), 4.03 (2H, s)

MS [APCI (+)] 217.1 ([M+H]⁺)

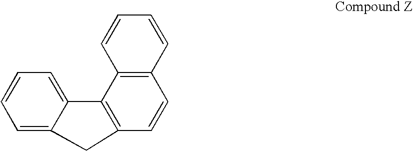

### (Synthesis of Compound Aa)

A 50 ml two-necked flask was purged with nitrogen and into this was added 6.50 g of compound Z synthesized above, 6.5 ml of water, 20 ml of dimethyl sulfoxide, 8.80 g of 1,5-dibromo-3-methylpentane, 5.01 g of sodium hydroxide and 0.98 g of tetra(n-butyl)ammonium bromide, and the mixture was stirred for 1 hour at 100° C. 50 ml of water was added, and the mixture was extracted twice with 50 ml of toluene. The toluene phase was filtrated by passing through 10 g of silica gel, and the solvent was distilled off to obtain 10.18 g of a coarse product. This was purified by silica gel column chromatography (silica gel 300 g, hexane only is used as a developing solvent) to obtain 6.64 g of compound AA (mixture of diastereomer).

MS[APPI(+)] 298 ([M]⁺)

¹H-NMR (300 MHz/CDCl₃) mixture of two diastereomer (about 1:1)

δ 8.81 (1H, d), 8.78 (1H, d), 8.41 (1H, d), 8.37 (1H, s), 8.03 (1H, d), 7.96˜7.93 (1H×2, m), 7.85 (1H, d), 7.81 (1H, d), 7.66˜7.30 (5H+6H, m), 2.21˜2.07 (2H×2, m), 1.85˜1.77 (5H×2, m), 1.64˜1.43 (2H×2, m), 1.20˜1.16 (3H×2, m)

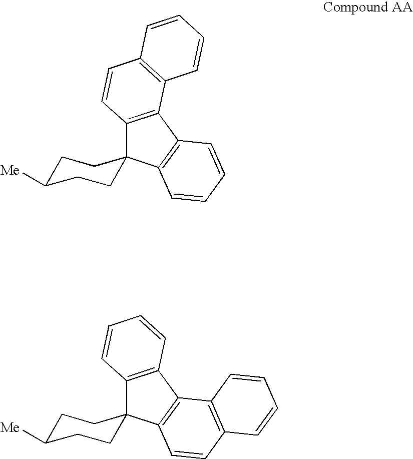

### (Synthesis of Compound Ab)

A 500 ml three-necked flask was purged with nitrogen and into this was added 6.60 g of compound AA, 6.92 g of zinc chloride, 140 ml of acetic acid and 70 ml of dichloromethane, and the mixture was heated up to 50° C. Into this solution, a solution prepared by dissolving 18.07 g of benzyltrimethylammonium bromide in 70 ml of dichloromethane was dropped over a period of 1 hour, and the mixture was further thermally insulated for 2 hours. The mixture was cooled to room temperature, and 200 ml of water was added to stop the reaction. 50 ml of chloroform was added, and the mixture was washed with 100 ml of water twice. Further, the mixture was washed with 200 mL of a saturated sodium thiosulfate aqueous solution, 200 mL of a saturated sodium hydrogencarbonate, and 100 mL of water. The resulting organic layer was filtrated by passing through a pre-coated silica gel, and the solution was concentrated to obtain 13 g of a coarse product containing the intended compound. This was purified by silica gel column chromatography (hexane only is used as a developing solvent), to obtain 5.58 g of a mixture of diastereomers of compound AB.

MS[APPI(+)] 454, 456, 458 ([M]⁺)

¹H-NMR (300 MHz/CDCl₃) mixture of two diastereomer (about 1:1)

δ 8.70 (1H, d), 8.67 (1H, d), 8.38 (1H×2, d), 8.30 (1H, s), 8.21 (1H, d), 8.19 (1H, d), 8.00 (1H, s), 7.90 (1H, s), 7.71˜7.53 (4H+5H, m), 2.17˜1.49 (9H×2, m), 1.22˜1.17 (3H×2, m)

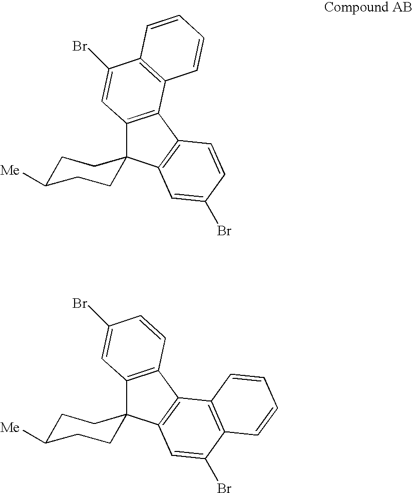

### EXAMPLE 87

Compound AB (1.1 g), N,N′-bis(4-bromophenyl)-N,N′-bis(4-t-butyl-2,6-dimethylphenyl)-benzidine (0.86 g) and 2,2′-bipyridyl (1.5 g) were dissolved in 285 mL of dehydrated tetrahydrofuran, then, an atmosphere in the system was purged with nitrogen by bubbling with nitrogen. The mixture was heated up to 60° C., then, under a nitrogen atmosphere, to this solution was added bis(1,5-cyclooctadiene)nickel (0) {Ni(COD)₂} (2.616 g), and the mixture was stirred and reacted for 3 hours. This reaction solution was cooled to room temperature, and dropped into a mixed solution of 25% ammonia water 13 mL/methanol 285 mL/ion exchanged water 285 mL, and the mixture was stirred for 1 hour, then, the deposited precipitate was filtrated and dried under reduced pressure, and dissolved in 106 ml of toluene. After dissolution, to this solution was added 0.42 g of radiolite and the mixture was stirred for 30 minutes, to filtrate insoluble materials off. The resulting filtrate was purified by passing through an alumina column. Next, 208 mL of 5.2% hydrochloric acid water was added and the mixture was stirred for 3 hours, then, the aqueous layer was removed. Subsequently, 208 mL of 4% ammonia water was added, and the mixture was stirred for 2 hours, then, the aqueous layer was removed. Further, about 208 mL of ion exchanged water was added to the organic layer and the mixture was stirred for 1 hour, then, the aqueous layer was removed. Thereafter, the organic layer was dropped into 331 mL of methanol and the mixture was stirred for 1 hour, and the deposited precipitate was filtrated and dried under reduced pressure. The resulting polymer (hereinafter, referred to as polymer compound 53) showed a yield of 1.07 g. The number-average molecular weight and weight-average molecular weight in terms of polystyrene were Mn=1.3×10⁴ and Mw=1.1×10⁵, respectively.

### EXAMPLE 88

Compound AB (2.0 g) and 2,2′-bipyridyl (1.8 g) were dissolved in 316 mL of dehydrated tetrahydrofuran, then, an atmosphere in the system was purged with nitrogen by bubbling with nitrogen. The mixture was heated up to 60° C., then, under a nitrogen atmosphere, to this solution was added bis(1,5-cyclooctadiene)nickel (0) {Ni(COD)₂} (3.3 g), and the mixture was stirred and reacted for 3 hours. This reaction solution was cooled to room temperature, and dropped into a mixed solution of 25% ammonia water 16 mL/methanol 316 mL/ion exchanged water 316 mL, and the mixture was stirred for 1 hour, then, the deposited precipitate was filtrated and dried under reduced pressure, and dissolved in 132 ml of toluene. After dissolution, to this solution was added 0.53 g of radiolite and the mixture was stirred for 30 minutes, to filtrate insoluble materials off. The resulting filtrate was purified by passing through an alumina column. Next, 259 mL of 5.2% hydrochloric acid water was added and the mixture was stirred for 3 hours, then, the aqueous layer was removed. Subsequently, 259 mL of 4% ammonia water was added, and the mixture was stirred for 2 hours, then, the aqueous layer was removed. Further, about 259 mL of ion exchanged water was added to the organic layer and the mixture was stirred for 1 hour, then, the aqueous layer was removed. Thereafter, the organic layer was dropped into 412 mL of methanol and the mixture was stirred for 1 hour, and the deposited precipitate was filtrated and dried under reduced pressure. The resulting polymer (hereinafter, referred to as polymer compound 54) showed a yield of 0.41 g. The number-average molecular weight and weight-average molecular weight in terms of polystyrene were Mn=1.8×10⁴ and Mw=9.9×10⁴, respectively. The glass transition temperature was measured to find a value of 165° C.

### EXAMPLE 89

Compound AB (1.0 g), N,N′-bis(4-bromophenyl)-N,N′-bis(4-t-butyl-2,6-dimethylphenyl)-1,4-phenylenediamine (0.18 g) and 2,2′-bipyridyl (1.03 g) were dissolved in 88 mL of dehydrated tetrahydrofuran, then, an atmosphere in the system was purged with nitrogen by bubbling with nitrogen. The mixture was heated up to 60° C., then, under a nitrogen atmosphere, to this solution was added bis(1,5-cyclooctadiene)nickel (0) {Ni(COD)₂} (1.81 g), and the mixture was stirred and reacted for 3 hours. This reaction solution was cooled to room temperature, and dropped into a mixed solution of 25% ammonia water 9 mL/methanol 88 mL/ion exchanged water 88 mL, and the mixture was stirred for 1 hour, then, the deposited precipitate was filtrated and dried under reduced pressure, and dissolved in 50 ml of toluene. After dissolution, to this solution was added 5.84 g of radiolite and the mixture was stirred for 30 minutes, to filtrate insoluble materials off. The resulting filtrate was purified by passing through an alumina column. Next, 49 mL of 5.2% hydrochloric acid water was added and the mixture was stirred for 3 hours, then, the aqueous layer was removed. Subsequently, 49 mL of 4% ammonia water was added, and the mixture was stirred for 2 hours, then, the aqueous layer was removed. Further, about 49 mL of ion exchanged water was added to the organic layer and the mixture was stirred for 1 hour, then, the aqueous layer was removed. Thereafter, the organic layer was dropped into 287 mL of methanol and the mixture was stirred for 1 hour, and the deposited precipitate was filtrated and dried under reduced pressure. The resulting polymer compound hereinafter, referred to as polymer compound 55) showed a yield of 0.55 g. The number-average molecular weight and weight-average molecular weight in terms of polystyrene were Mn=2.9×10⁴ and Mw=1.9×10⁵, respectively.

### (Preparation of Solution)

Polymer compound 55 obtained above was used to manufacture a toluene solution having a concentration of 1.3 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 4000 rpm to form a film. The thickness after film formation was about 80 nm. Further, this was dried under reduced pressure at 80° C. for 1 hour, then, lithium fluoride was vapor-deposited at a thickness of about 4 nm, and calcium was vapor-deposited at a thickness of about 5 nm as a cathode, then, aluminum was vapor-deposited at a thickness of about 80 nm, to manufacture an EL element. After the degree of vacuum reached 1×10⁻⁴ Pa or less, vapor deposition of a metal was initiated. By applying voltage on the resulting element, EL light emission having a peak at 490 nm was obtained from this element. The intensity of EL light emission was approximately in proportion to the current density. This element manifested initiation of light emission from 3.0 V and had a maximum light emission efficiency of 3.97 cd/m².

### (Measurement of Life)

The EL element obtained above was driven at a constant current of 75 mA/cm², and change in luminance by time was measured. As a result, this element had an initial luminance of 2780 cd/m² and showed a luminance half life of 6.3 hours. This was converted into a value at an initial luminance of 400 cd/m² hypothesizing that the acceleration coefficient of luminance-life is square, to find a half life of 304 hours.

### EXAMPLE 94

### Synthesis of Compound AJ

### (Synthesis of Compound AH)

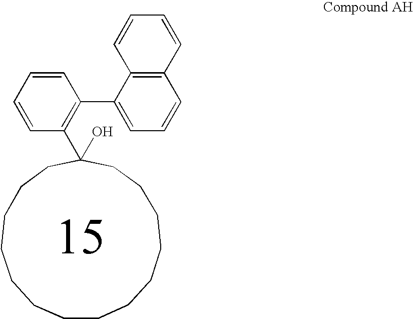

A 300 mL three-necked flask was purged with nitrogen, and into this was added 5.00 g (17.7 mmol) compound AC and the mixture was dissolved in 100 ml of THF. The mixture was cooled down to −78° C., then, 12.6 ml of n-butyllithium (1.54 M hexane solution, 19.4 mmol) was dropped. The mixture was thermally insulated for 30 minutes, then, a solution prepared by dissolving 4.75 g (21.2 mmol) of cyclopentadecanone in 25 ml of THF was dropped. The mixture was thermally insulated for 5 minutes, then, the ice bath was removed, and the mixture was heated up to room temperature and thermally insulated for 8 hours. 1 ml of water and 100 ml of toluene were added, and filtrated by passing through a glass filter carrying dispersed silica gel. The solvent was distilled off, to obtain 8.99 g of a coarse product. This was purified by silica gel column chromatography (developing solvent, hexane:ethyl acetate=40:1), to obtain 5.18 g of compound AH.

¹H-NMR (300 MHz/CDCl₃)

δ 7.88˜7.84 (2H, m), 7.57˜7.26 (8H, m), 7.09 (1H, d), 1.75˜1.63 (2H, m), 1.35˜1.17 (26H, m)

MS (APPI (positive))

m/z: 428 ([M]⁺)

### (Synthesis of Compound AI)

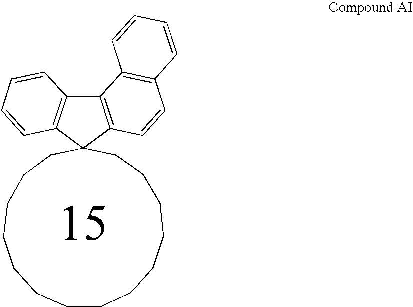

Under a nitrogen atmosphere, into a 200 ml two-necked flask was charged boron trifluoride ether complex, and 25 ml of dichloromethane was added and the mixture was stirred. While cooling in an ice bath, a solution prepared by dissolving 5 g of compound AH in 50 ml of dichloromethane was added. The mixture was stirred for 1 hour, then, 100 ml of water was added to stop the reaction, and the mixture was extracted with 50 ml of chloroform twice. The resulting organic layer was filtrated by passing through pre-coated silica gel, to obtain 4.1 g of compound AI. This mixture was used in the subsequent reaction without further purification.

¹H-NMR (300 MHz/CDCl₃)

δ 1.30-1.52 (m, 24H), 1.85 (q, 4H), 7.33 (t, 1H), 7.43 (d, 1H), 7.50 (t, 1H), 7.58˜7.65 (m, 2H), 7.68 (d, 1 H), 7.82 (d, 1H), 7.94 (d, 1H), 8.36 (d, 1H), 8.76 (d, 1H)

### (Synthesis of Compound AJ)

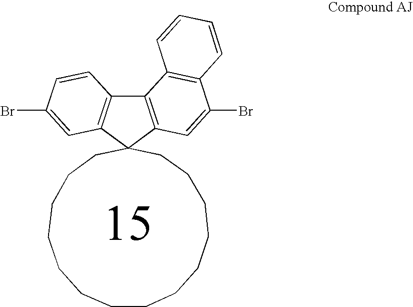

Under a nitrogen atmosphere, into a 300 ml three-necked flask was charged 4.6 g of compound AI, and 50 ml of dichloromethane was added and dissolved, to this was added 70 ml of acetic acid and the mixture was heated up to 50° C. in an oil bath. While heating, 3.35 g of zinc chloride was added and the mixture was stirred, and a solution prepared by dissolving 9.61 g of benzyltrimethylammonium tribromide in 21 ml of dichloromethane was added over 30 minutes while heating under reflux. The mixture was stirred at 50° C. further for 1 hour, and cooled to room temperature, then, 100 ml of water was added to stop the reaction. The reaction solution was separated, the aqueous layer was extracted with 50 ml of chloroform and the organic layer was combined. The organic layer was washed with 100 ml of a saturated sodium thiosulfate aqueous solution, then, washed with 150 ml of a saturated sodium hydrogencarbonate aqueous solution and 100 ml of water. The resulting organic layer was filtrated by passing through pre-coated silica gel, to obtain 6.8 g of a coarse product. This mixture was purified by silica gel column chromatography, to obtain 1.98 g of compound AJ.

¹H-NMR (300 MHz/CDCl₃): δ 1.26-1.6 (m, 24H), 1.76 (q, 4H), 7.55 (dd, 1H), 7.58-7.71 (m, 2H), 7.68 (S, 1 h), 7.96 (S, 1 h), 8.17 (d, 1H), 8.38 (dd, 1H), 8.67 (d, 1H)

### EXAMPLE 96

### Synthesis of Polymer Compound 59

Compound H (1.6 g), N,N′-bis(4-bromophenyl)-N,N′-bis(4-t-butyl-2,6-dimethylphenyl)-1,4-phenylenediamine (0.2 g) and 2,2′-bipyridyl (1.4 g) were dissolved in 83 mL of dehydrated tetrahydrofuran, then, an atmosphere in the system was purged with nitrogen by bubbling with nitrogen. Under a nitrogen atmosphere, to this solution was added bis(1,5-cyclooctadiene)nickel (0) {Ni(COD)₂} (2.5 g), and the mixture was heated up to 60° C., and reacted while stirring. 0.5 hours. 1-bromopyrene (0.08 g) was added and the mixture was further reacted for 2.5 hours. This reaction solution was cooled to room temperature (about 25° C.), and dropped into a mixed solution of 25% ammonia water 12 ml/methanol about 80 mL/ion exchanged water about 80 mL, and the mixture was stirred for 1 hour, then, the deposited precipitate was filtrated and dried under reduced pressure for 2 hours, then, dissolved in 100 ml of toluene before filtration, and the filtrate was purified by passing through an alumina column, and the mixture was stirred for 3 hours, then, the aqueous layer was removed. Next, about 200 mL of 4% ammonia water was added and the mixture was stirred for 2 hours, then, the aqueous layer was removed. Further, about 200 mL of ion exchanged water was added to the organic layer and the mixture was stirred for 1 hour, then, the aqueous layer was removed. 50 mL of methanol was added to the organic layer, and the deposited precipitate was collected by decantation, and dissolved in 50 ml of toluene, then, this was dropped into about 200 mL of methanol and the mixture was stirred for 1 hour, and the deposited precipitate was filtrated and dried under reduced pressure for 2 hours. The resulting polymer compound (hereinafter, referred to as polymer compound 59) showed a yield of 1.0 g. The number-average molecular weight and weight-average molecular weight in terms of polystyrene were Mn=1.5×10⁵ and Mw=4.1×10⁵, respectively.

### EXAMPLE 97

### Synthesis of Polymer Compound 60

Compound H (1.65 g) and 2,2′-bipyridyl (1.1 g) were dissolved in 83 mL of dehydrated tetrahydrofuran, then, an atmosphere in the system was purged with nitrogen by bubbling with nitrogen. Under a nitrogen atmosphere, this solution was heated up to 60° C., and bis(1,5-cyclooctadiene)nickel (0) {Ni(COD)₂} (2.0 g) was added, further, after 0.5 hours, 4-tert-butylbromobenzene (0.05 g) was added, and further, the mixture was reacted for 3 hours while thermally insulating. After reaction, the mixture was cooled to room temperature (about 25° C.), and dropped into a mixed solution of 25% ammonia water 11 ml/methanol about 110 mL/ion exchanged water about 110 mL, and the mixture was stirred for 1 hour, then, the deposited precipitate was filtrated and dried under reduced pressure for 2 hours, then, dissolved in 100 ml of toluene before filtration, and the filtrate was purified by passing through an alumina column, 200 mL of 5.2% hydrochloric acid water was added and the mixture was stirred for 3 hours, then, the aqueous layer was removed. Next, 200 mL of 4% ammonia water was added, and the mixture was stirred for 2 hours, then, the aqueous layer was removed. Further, about 200 mL of ion exchanged water was added to the organic layer and the mixture was stirred for 1 hour, then, the aqueous layer was removed. The organic layer was dropped into 500 mL of methanol and the mixture was stirred for 1 hour, and the deposited precipitate was filtrated and dried under reduced pressure for 2 hours. The resulting polymer compound (hereinafter, referred to as polymer compound 60) showed a yield of 1.0 g. The number-average molecular weight and weight-average molecular weight in terms of polystyrene were Mn=4.5×10⁴ and Mw=4.3×10⁵, respectively.

### EXAMPLE 98

### Synthesis of Polymer Compound 61

Compound H (4.897 g) and 2,2′-bipyridyl (3.795 g) were dissolved in 324 mL of dehydrated tetrahydrofuran, then, an atmosphere in the system was purged with nitrogen by bubbling with nitrogen. The mixture was heated up to 60° C., then, under a nitrogen atmosphere, to this solution was added bis(1,5-cyclooctadiene)nickel (0) {Ni(COD)₂} (6.684 g) and the mixture was stirred. 20 minutes after stirring, trifluoromethylbenzene (0.184 g) was added and the mixture was reacted further for 3 hours. This reaction solution was cooled to room temperature, and dropped into a mixed solution of 25% ammonia water 32 ml/methanol 324 mL/ion exchanged water 324 mL, and the mixture was stirred for 1 hour, then, the deposited precipitate was filtrated and dried under reduced pressure for 2 hours. The resulting polymer compound (hereinafter, referred to as polymer compound 61) showed a yield of 4.79 g. The number-average molecular weight and weight-average molecular weight in terms of polystyrene were Mn=8.4×10⁴ and Mw=3.6×10⁵, respectively.

### EXAMPLE 99

### Synthesis of Polymer Compound 62

Compound H (4.897 g) and 2,2′-bipyridyl (3.795 g) were dissolved in 324 mL of dehydrated tetrahydrofuran, then, an atmosphere in the system was purged with nitrogen by bubbling with nitrogen. The mixture was heated up to 60° C., then, under a nitrogen atmosphere, to this solution was added bis(1,5-cyclooctadiene)nickel (0) {Ni(COD)₂} (6.684 g) and the mixture was stirred. 20 minutes after stirring, pentafluorobenzene (0.202 g) was added and the mixture was reacted further for 3 hours. This reaction solution was cooled to room temperature, and dropped into a mixed solution of 25% ammonia water 32 ml/methanol 324 mL/ion exchanged water 324 mL, and the mixture was stirred for 1 hour, then, the deposited precipitate was filtrated and dried under reduced pressure for 2 hours. The resulting polymer compound (hereinafter, referred to as polymer compound 62) showed a yield of 4.74 g. The number-average molecular weight and weight-average molecular weight in terms of polystyrene were Mn=6.4×10⁴ and Mw=2.1×10⁵, respectively.

### EXAMPLE 100

### Synthesis of Polymer Compound 63

Compound H (1.8 g). N,N′-bis(4-bromophenyl)-N,N′-bis(4-t-butyl-2,6-dimethylphenyl)-1,4-phenylenediamine (0.1 g) and 2,2′-bipyridyl (1.4 g) were dissolved in 180 mL of dehydrated tetrahydrofuran, then, an atmosphere in the system was purged with nitrogen by bubbling with nitrogen. Under a nitrogen atmosphere, this solution was heated up to 60° C., and bis(1,5-cyclooctadiene)nickel (0) {(Ni(COD)₂} (2.5 g) was added, further, after 0.5 hours, 4-bromo-N,N-diphenylaniline (0.1 g) was added, and further, the mixture was reacted for 3 hours while thermally insulating. After reaction, the mixture was cooled to room temperature (about 25° C.), and dropped into a mixed solution of 25% ammonia water 12 ml/methanol about 180 mL/ion exchanged water about 180 mL, and the mixture was stirred for 1 hour, then, the deposited precipitate was filtrated and dried under reduced pressure for 2 hours, then, dissolved in 100 ml of toluene before filtration, and the filtrate was purified by passing through an alumina column, about 200 mL of 5.2% hydrochloric acid water was added and the mixture was stirred for 3 hours, then, the aqueous layer was removed. Next, about 200 mL of 4% ammonia water was added, and the mixture was stirred for 2 hours, then, the aqueous layer was removed. Further, about 200 mL of ion exchanged water was added to the organic layer and the mixture was stirred for 1 hour, then, the aqueous layer was removed. 40 mL of methanol was added to the organic layer, and the deposited precipitate was collected by decantation, and dissolved in 50 ml of toluene, then, this was dropped into about 200 mL of methanol and the mixture was stirred for 1 hour, and the deposited precipitate was filtrated and dried under reduced pressure for 2 hours. The resulting polymer compound (hereinafter, referred to as polymer compound 63) showed a yield of 1.0 g. The number-average molecular weight and weight-average molecular weight in terms of polystyrene were Mn=6.2×10⁴ and Mw=1.4×10⁵, respectively.

### EXAMPLE 101

### Synthesis of Polymer Compound 64

2.15 g of compound H, 1.71 g of N,N′-bis(4-bromophenyl)-N,N′-bis(4-t-butyl-2,6-dimethylphenyl)-1,4-phenylenediamine, 0.125 g of 5-chlorophenanthroline and 2.9 g of 2,2′-bipyridyl were charged in a reaction vessel, then, an atmosphere in the reaction system was purged with a nitrogen gas. To this was added 200 g of tetrahydrofuran (dehydrated solvent) deaerated previously by bubbling with an argon gas. Next, to this solution was added 4.2 g of bis(1,5-cyclooctadiene)nickel (0), and the mixture was stirred at room temperature for 10 minutes, then, reacted at 60° C. for 3 hours. The reaction was conducted in a nitrogen gas atmosphere.

After the reaction, this reaction solution was cooled, then, dropped into a mixed solution of methanol 150 mL/ion exchanged water 150 mL, and the mixture was stirred for about 1 hour. Next, the produced precipitate was filtrated and recovered. This precipitate was dried under reduced pressure, then, dissolved in toluene. This toluene solution was filtrated to remove insoluble materials, then, this toluene solution was purified by passing through a column filled with alumina. Next, this toluene solution was washed with about 1 N hydrochloric acid, and allowed to stand still, separated, then, a toluene solution was recovered. Next, this toluene solution was washed with about 3% ammonia water, and allowed to stand still, separated, then, a toluene solution was recovered. Next, this toluene solution was washed with water, and allowed to stand still, separated, then, a toluene solution was recovered. Next, this toluene solution was poured into methanol to cause re-precipitation and purification. The produced precipitate was recovered by filtration. Next, this precipitate was dried under reduced pressure, to obtain 0.8 g of a polymer. This polymer is called polymer compound 64. The resultant polymer compound 64 had a weight-average molecular weight in terms of polystyrene of 2.7×10⁴ and a number-average molecular weight of 7.6×10³.

### EXAMPLE 102

### Synthesis of Polymer Compound 65

Compound H (2.9 g), N,N′-bis(4-bromophenyl)-N,N′-bis(4-t-butyl-2,6-dimethylphenyl)-1,4-phenylenediamine (0.4 g) and 2,2′-bipyridyl (2.5 g) were dissolved in 150 mL of dehydrated tetrahydrofuran, then, an atmosphere in the system was purged with nitrogen by bubbling with nitrogen. Under a nitrogen atmosphere, this solution was heated up to 60° C., and bis(1,5-cyclooctadiene)nickel (0) {Ni(COD)₂} (4.5 g) was added, further, after 0.5 hours, 3-bromoquinoline (0.1 g) was added, and further, the mixture was reacted for 3 hours while thermally insulating. After reaction, the mixture was cooled to room temperature (about 25° C.), and dropped into a mixed solution of 25% ammonia water 22 ml/methanol about 150 mL/ion exchanged water about 150 mL, and the mixture was stirred for 1 hour, then, the deposited precipitate was filtrated and dried under reduced pressure for 2 hours, then, dissolved in 180 ml of toluene before filtration, and the filtrate was purified by passing through an alumina column, about 350 mL of 5.2% hydrochloric acid water was added and the mixture was stirred for 3 hours, then, the aqueous layer was removed. Next, about 350 mL of 4% ammonia water was added, and the mixture was stirred for 2 hours, then, the aqueous layer was removed. Further, about 350 mL of ion exchanged water was added to the organic layer and the mixture was stirred for 1 hour, then, the aqueous layer was removed. 70 mL of methanol was added to the organic layer, and the deposited precipitate was collected by decantation, and dissolved in 200 ml of toluene, then, this was dropped into about 600 mL of methanol and the mixture was stirred for 1 hour, and the deposited precipitate was filtrated and dried under reduced pressure for 2 hours. The resulting polymer compound (hereinafter, referred to as polymer compound 65) showed a yield of 2.0 g. The number-average molecular weight and weight-average molecular weight in terms of polystyrene were Mn=8.6×10⁴ and Mw=2.6×10⁵, respectively.

### EXAMPLE 103

### Synthesis of Polymer Compound 66

1.88 g of compound H, 1.1 g of N,N′-diphenyl-N,N′-bis(4-t-butyl-2,6-dimethylphenyl)-benzidine and 1.68 g of 2,2′-bipyridyl were charged in a reaction vessel, then, an atmosphere in the reaction system was purged with a nitrogen gas. To this was added 150 g of tetrahydrofuran (dehydrated solvent) deaerated previously by bubbling with an argon gas. Next, to this solution was added 3.0 g of bis(1,5-cyclooctadiene)nickel (0), and the mixture was stirred at room temperature for 10 minutes, then, reacted at 60° C. for 3 hours. The reaction was conducted in a nitrogen gas atmosphere.

After the reaction, this reaction solution was cooled, then, a mixed solution of 25% ammonia water 20 ml/methanol 150 mL/ion exchanged water 150 mL was poured into this solution, and the mixture was stirred for about 1 hour. Next, the produced precipitate was filtrated and recovered. This precipitate was dried under reduced pressure, then, dissolved in toluene. This toluene solution was filtrated to remove insoluble materials, then, this toluene solution was purified by passing through a column filled with alumina. Next, this toluene solution was washed with about 3% ammonia water, and allowed to stand still, separated, then, a toluene solution was recovered, next, this toluene solution was washed with water, and allowed to stand still, separated, then, a toluene solution was recovered. Next, this toluene solution was poured into methanol to cause re-precipitation and purification.

Next, the produced precipitate was recovered, this precipitate was dried under reduced pressure, to obtain 1.1 g of a polymer. This polymer is called polymer compound 66. The resultant polymer compound 66 had a weight-average molecular weight in terms of polystyrene of 1.1×10⁵ and a number-average molecular weight of 2.2×10⁴.

### EXAMPLE 104 DRIVING VOLTAGE

### Preparation of Solution

Polymer compound 59 obtained above was dissolved in toluene, to manufacture a toluene solution having a polymer concentration of 1.5 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 1500 rpm to form a film. The thickness after film formation was about 70 nm. Further, this was dried under reduced pressure at 80° C. for 1 hour, then, barium was vapor-deposited at a thickness of about 5 nm as a cathode, then, aluminum was vapor-deposited at a thickness of about 80 nm. After the degree of vacuum reached 1×10⁻⁴ Pa or less, vapor deposition of a metal was initiated. After vapor-deposition, sealing was carried out under a nitrogen atmosphere using a UV-hardening type sealer and a glass plate.

### (Measurement of Current-Voltage-Luminance Property)

Current (I)-voltage (V)-luminance (L) property was measured by allowing current which increases step by step at an interval of 5 mA per 4 mm² of emission part area until 100 mA to flow in the element obtained above. Measurement of luminance used a luminance meter BM-8 manufactured by Topcon K.K. From a V-L curve obtained by measurement, voltages at 30000 cd/m² were read and compared. As a result, the element showed 17.0 V.

### EXAMPLE 105 DRIVING VOLTAGE

### Preparation of Solution

Polymer compound 7 obtained above was dissolved in toluene, to manufacture a toluene solution having a polymer concentration of 1.5 wt %.

### (Manufacturing of EL Element)

On a glass base plate carrying an ITO film having a thickness of 150 nm formed by a sputtering method, liquid obtained by filtrating a suspension of poly(3,4)ethylenedioxythiophene/polystyrenesulfonic acid (manufactured by Bayer, BaytronP AI4083) through a 0.2 μm film filter was spin-coated to form a film having a thickness of 70 nm, and dried on a hot plate at 200° C. for 10 minutes. Next, the toluene solution obtained above was spin-coated at a rotational speed of 1500 rpm to form a film. The thickness after film formation was about 70 nm. Further, this was dried under reduced pressure at 80° C. for 1 hour, then, barium was vapor-deposited at a thickness of about 5 nm as a cathode, then, aluminum was vapor-deposited at a thickness of about 80 nm. After the degree of vacuum reached 1×10⁻⁴ Pa or less, vapor deposition of a metal was initiated. After vapor-deposition, sealing was carried out under a nitrogen atmosphere using a UV-hardening type sealer and a glass plate.

### (Measurement of Current-Voltage-Luminance Property)

Current (I)-voltage (V)-luminance (L) property was measured by allowing current which increases step by step at an interval of 5 mA per 4 mm² of emission part area until 100 mA to flow in the element obtained above. Measurement of luminance used a luminance meter BM-8 manufactured by Topcon K.K. From a V-L curve obtained by measurement, voltages at 30000 cd/m² were read and compared. As a result, the element showed 18.6 V.

TABLE 12

| | | | | Driving voltage |
|---|---|---|---|---|
| | | Mn | Mw | (30000 cd/m²) |
| Example 104 | polymer | 1.5E+05 | 4.1E+05 | 17.00 |
| | compound 59 | | | |
| Example 105 | polymer | 1.3E+05 | 5.8E+05 | 18.60 |
| | compound 7 | | | |

### EXAMPLE 106 MEASUREMENT OF LIFE

### Preparation of Solution

75 wt % of polymer compound 60 obtained above and 25 wt % of polymer compound 66 were dissolved in toluene in this ratio, to obtain a toluene solution having a polymer concentration of 1.3 wt %.

### (Manufacturing of EL Element)

Using the toluene solution obtained above, an EL element was made by the same method as in Example 104. By applying voltage on the resulting element, EL light emission having a peak at 460 nm was obtained from this element. The intensity of EL light emission was approximately in proportion to the current density.

### (Measurement of Life)

The EL element obtained above was driven at a constant current of 100 mA/cm², and change in luminance by time was measured. As a result, this element had an initial luminance of 2000 cd/m² and showed a luminance half life of 21.8 hours. This was converted into a value at an initial luminance of 400 cd/m² hypothesizing that the acceleration coefficient of luminance-life is square, to find a half life of 545 hours.

### EXAMPLE 107 MEASUREMENT OF LIFE

### Preparation of Solution

75 wt % of polymer compound 34 obtained above and 25 wt % of polymer compound 66 were dissolved in toluene in this ratio, to obtain a toluene solution having a polymer concentration of 1.3 wt %.

### (Manufacturing of EL Element)

Using the toluene solution obtained above, an EL element was made by the same method as in Example 104. By applying voltage on the resulting element, EL light emission having a peak at 460 nm was obtained from this element. The intensity of EL light emission was approximately in proportion to the current density.

### (Measurement of Life)

The EL element obtained above was driven at a constant current of 100 mA/cm², and change in luminance by time was measured. As a result, this element had an initial luminance of 1295 cd/m² and showed a luminance half life of 48.0 hours. This was converted into a value at an initial luminance of 400 cd/m² hypothesizing that the acceleration coefficient of luminance-life is square, to find a half life of 503 hours.

TABLE 13

| | | | | Luminance |
|---|---|---|---|---|
| | | | | half life |
| | | Mn | Mw | (400 cd/m2) |
| Example 106 | polymer | 7.7E+04 | 4.4E+05 | 545 |
| | compound 60 | | | |
| | polymer | 2.2E+04 | 1.1E+05 | |
| | compound 66 | | | |
| Example 107 | polymer | 7.6E+04 | 4.9E+05 | 503 |
| | compound 34 | | | |
| | polymer | 2.2E+04 | 1.1E+05 | |
| | compound 66 | | | |

### EXAMPLE 108

### Synthesis of Polymer Compound 67

Compound H (4.75 g), N,N′-bis(4-bromophenyl)-N,N′-bis(4-t-butyl-2,6-dimethylphenyl)-1,4-phenylenediamine (0.309 g) and 2,2′-bipyridyl (3.523 g) were dissolved in 601 mL of dehydrated tetrahydrofuran, then, an atmosphere in the system was purged with nitrogen by bubbling with nitrogen. The mixture was heated up to 60° C., then, under a nitrogen atmosphere, to this solution was added bis(1,5-cyclooctadiene)nickel (0) {Ni(COD)₂} (6.204 g), and the mixture was reacted for 3 hours while stirring. This solution was cooled to room temperature, and dropped into a mixed solution of 25% ammonia water 30 ml/methanol 601 mL/ion exchanged water 601 mL, and the mixture was stirred for 1 hour, then, the deposited precipitate was filtrated and dried under reduced pressure for 2 hours. Thereafter, this was dissolved in 251 ml of toluene before filtration, subsequently, the filtrate was purified by passing through an alumina column. Next, 493 mL of 5.2% hydrochloric acid water was added and the mixture was stirred for 3 hours, then, the aqueous layer was removed. Next, 493 mL of 4% ammonia water was added, and the mixture was stirred for 2 hours, then, the aqueous layer was removed. Further, 493 mL of ion exchanged water was added to the organic layer and the mixture was stirred for 1 hour, then, the aqueous layer was removed. 150 mL of methanol was added to the organic layer, and the deposited precipitate was collected by decantation, and dissolved in 150 ml of toluene, then, this was dropped into about 600 mL of methanol and the mixture was stirred for 1 hour, and the deposited precipitate was filtrated and dried under reduced pressure for 2 hours. The resulting polymer compound (hereinafter, referred to as polymer compound 67) showed a yield of 2.8 g. The number-average molecular weight and weight-average molecular weight in terms of polystyrene were Mn=7.3×10⁴ and Mw=2.2×10⁵, respectively.

### EXAMPLE 109

### Synthesis of Polymer Compound 68

12.6 g of compound H, 6.68 g of N,N′-bis(4-bromophenyl)-N,N′-bis(4-t-butyl-2,6-dimethylphenyl)-1,4-phenylenediamine and 11.7 g of 2,2′-bipyridyl were charged in a reaction vessel, then, an atmosphere in the reaction system was purged with a nitrogen gas. To this was added 1100 g of tetrahydrofuran (dehydrated solvent) deaerated previously by bubbling with an argon gas. Next, to this solution was added 20.6 g of bis(1,5-cyclooctadiene)nickel (0), and the mixture was stirred at room temperature for 10 minutes, then, reacted at 60° C. for 3 hours. The reaction was conducted in a nitrogen gas atmosphere.

After the reaction, this reaction solution was cooled, then, a mixed solution of 25% ammonia water 150 ml/methanol 500 mL/ion exchanged water 500 mL was poured into this solution, and the mixture was stirred for about 1 hour. Next, the produced precipitate was filtrated and recovered. This precipitate was dried under reduced pressure, then, dissolved in toluene. This toluene solution was filtrated to remove insoluble materials, then, this toluene solution was purified by passing through a column filled with alumina. Next, this toluene solution was washed with about 3% ammonia water, and allowed to stand still, separated, then, a toluene solution was recovered, next, this toluene solution was washed with water, and allowed to stand still, separated, then, a toluene solution was recovered. Next, this toluene solution was poured into methanol to cause re-precipitation and purification.

Next, the produced precipitate was recovered and this precipitate was dried under reduced pressure, to obtain 8.5 g of a polymer. This polymer is called polymer compound 68. The resultant polymer compound 68 had a weight-average molecular weight in terms of polystyrene of 7.7×10⁴ and a number-average molecular weight of 2.0×10⁴.

### EXAMPLE 110

Polymer compound 67 and polymer compound 68 were mixed at a weight ratio of 67:33 and dissolved in a solvent obtained by mixing xylene and bicyclohexyl at a weight ratio of 1:1 so as to give a concentration of 1.5 wt %, producing a solution.

### EXAMPLE 111

### Synthesis of Polymer Compound 69

Compound H (24.1 g) and 2,2′-bipyridyl (11.3 g) were dissolved in 1500 mL of dehydrated tetrahydrofuran, then, an atmosphere in the system was purged with nitrogen by bubbling with nitrogen. Under a nitrogen atmosphere, this solution was heated up to 60° C., then, bis(1,5-cyclooctadiene)nickel (0) {Ni(COD)₂} (20.0 g) was added, and the mixture was reacted for 3 hours while thermally insulating. After reaction, the mixture was cooled to room temperature (about 25° C.), and dropped into a mixed solution of 25% ammonia water about 150 ml/methanol about 1500 mL/ion exchanged water about 1500 mL, and the mixture was stirred for 1 hour, then, the deposited precipitate was filtrated and dried under reduced pressure for 2 hours, thereafter, this was dissolved in about 1200 ml of toluene before filtration, and the filtrate was purified by passing through an alumina column, and about 1200 mL of 5.2% hydrochloric acid water was added and the mixture was stirred for 3 hours, then, the aqueous layer was removed. Next, 1200 mL of 4% ammonia water was added, and the mixture was stirred for 2 hours, then, the aqueous layer was removed. Further, about 1200 mL of ion exchanged water was added to the organic layer and the mixture was stirred for 1 hour, then, the aqueous layer was removed. 300 mL of methanol was added to the organic layer, and the deposited precipitate was collected by decantation, and dissolved in 600 ml of toluene, then, this was dropped into about 1200 mL of methanol and the mixture was stirred for 1 hour, and the deposited precipitate was filtrated and dried under reduced pressure for 2 hours. The resulting polymer compound is called polymer compound 69. The yield was 10.8 g. The number-average molecular weight and weight-average molecular weight in terms of polystyrene were Mn=1.1×10⁵ and Mw=4.0×10⁵, respectively.

### EXAMPLE 112

### Synthesis of Polymer Compound 70

Compound H (4.75 g), N,N′-bis(4-bromophenyl)-N,N′-bis(4-t-butyl-2,6-dimethylphenyl)-1,4-phenylenediamine (0.309 g) and 2,2′-bipyridyl (3.523 g) were dissolved in 211 mL of dehydrated tetrahydrofuran, then, an atmosphere in the system was purged with nitrogen by bubbling with nitrogen. The mixture was heated up to 60° C., then, under a nitrogen atmosphere, to this solution was added bis(1,5-cyclooctadiene)nickel (0) {Ni(COD)₂} (6.204 g), and the mixture was reacted for 3 hours while stirring. This reaction solution was cooled to room temperature, and dropped into a mixed solution of 25% ammonia water 30 ml/methanol 601 mL/ion exchanged water 601 mL, and the mixture was stirred for 1 hour, then, the deposited precipitate was filtrated and dried under reduced pressure for 2 hours, thereafter, this was dissolved in 251 ml of toluene before filtration, subsequently, purification was effected through an alumina column. Next, 493 mL of 5.2% hydrochloric acid water was added and the mixture was stirred for 3 hours, then, the aqueous layer was removed. Next, 493 mL of 4% ammonia water was added, and the mixture was stirred for 2 hours, then, the aqueous layer was removed. Further, 493 mL of ion exchanged water was added to the organic layer and the mixture was stirred for 1 hour, then, the aqueous layer was removed. 150 mL of methanol was added to the organic layer, and the deposited precipitate was collected by decantation, and dissolved in 150 ml of toluene, then, this was dropped into about 600 mL of methanol and the mixture was stirred for 1 hour, and the deposited precipitate was filtrated and dried under reduced pressure for 2 hours. The resulting copolymer (hereinafter, referred to as polymer compound 70) showed a yield of 3.1 g. The number-average molecular weight and weight-average molecular weight in terms of polystyrene were Mn=1.3×10⁵ and Mw=4.6×10⁵, respectively.

### EXAMPLE 113

### Ink Solution 1

Polymer compound 69 and polymer compound 68 were mixed at a weight ratio of 2:1 and dissolved in a mixed solution of xylene and bicyclohexyl at a weight ratio of 1:1 so as to give a concentration of a polymer composition of 1.2 wt %, producing a solution 1. The viscosity of solution 1 was measured at 25° C., to find a value of 8.5 mPa·s.

### EXAMPLE 114

### Ink Solution 2

Polymer compound 70 and polymer compound 68 were mixed at a weight ratio of 4:1 and dissolved in a mixed solution of xylene and bicyclohexyl at a weight ratio of 3:7 so as to give a concentration of a polymer composition of 1.2 wt %, producing a solution 2. The viscosity of solution 2 was measured at room temperature, to find a value of 10.9 mPa·s.

### EXAMPLE 115

### Synthesis of Mixture W

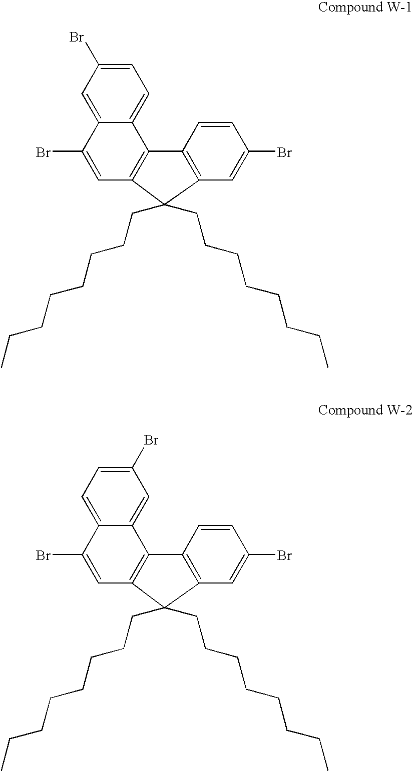

Into a 200 mL two-necked flask was weighed compound H (5.00 g, 8.35 mmol), and a Dimroth cooling tube and a septum were installed, and an atmosphere in the system was purged with argon. 60 ml of a mixed solution (1:1) of dehydrated dichloromethane and acetic acid was placed, and bromine (1.60 g, 10.0 mmol) was dropped. After completion of dropping, the mixture was heated at 50 to 55° C., and the mixture was stirred for 7.5 hours while dropping bromine (6.24 g, 40 mmol). The mixture was cooled to room temperature, then, a sodium thiosulfate aqueous solution was added to stop the reaction, and the organic layer was extracted with chloroform. After washing with a sodium carbonate aqueous solution, the solution was dried over sodium sulfate. The solvent was distilled off, then, the resulting solid was purified coarsely by a silica gel column, to obtain white solid (2.1 g). From the result of measurement of ¹H-NMR spectrum of this compound, it was confirmed that the produced tribromo body was a mixture of isomers having different bromine substitution positions, and the isomer ratio was 51:18. Purification of this solid by a silica gel column using hexane as a developing solvent isolated 0.65 g of white solid.

MS (APCI (+)): 678

### Compound W-1

NMR (CDCl₃): δ=0.492 (t, 6H), 0.78˜1.26 (m, 24H), 2.00 (t, 4H), 7.53 (s, 1H), 7.50 (d, 1H), 7.75 (d, 1H), 7.81 (s, 1H), 8.06 (d, 1H), 8.51 (d, 1H), 8.56 (s, 1H)

### Compound W-2

δ=0.49 (t, 6H), 0.79˜1.26 (m, 24H), 2.01 (t, 4H), 7.53 (s, 1H), 7.57 (d, 1H), 7.75 (d, 1H), 7.80 (s, 1H), 8.06 (d, 1H), 8.25 (d, 1H), 8.79 (s, 1H)

### EXAMPLE 116

### Synthesis of Compound X

Into an argon-purged 10 L separable flask was added 732 g of methyl bromobenzoate, 1067 g of potassium carbonate and 552 g of 1-naphthylboronic acid, and to this was added 4439 ml of toluene and 4528 ml of water and the mixture was stirred. 35.8 g of tetrakistriphenylphosphinepalladium (0) was added and the mixture was heated, and stirred for 2 hours at 85 to 90° C. After cooling to 35° C., the solution was separated and washed with 3900 ml of water. The toluene solution was filtrated using 950 g of silica gel, and washed with 10000 ml of toluene. The toluene solution was concentrated to about 900 g, and 950 ml of hexane was added. The deposited crystal was filtrated, and washed with 950 ml of hexane, and dried under reduced pressure to obtain white solid. The above-mentioned operation was repeated twice to obtain 1501 g of compound X.

¹H-NMR (300 MHz, CDCl₃)

δ 8.03 (1H, d), 7.88 (1H, d), 7.85 (1H, d), 7.62˜7.56 (1H, m), 7.53˜7.30 (7H, m), 3.36 (3H, s)

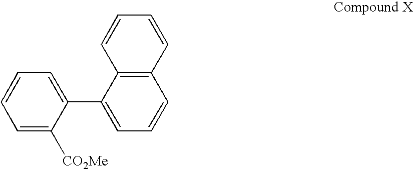

### (Synthesis of Compound AG)

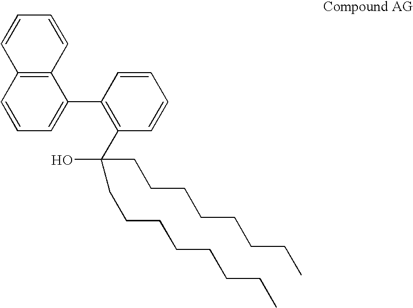

A dried reaction vessel was purged with nitrogen, and into this was added 297 g of magnesium, 150 ml of THF and 105 g of 1-bromooctane, and the mixture was stirred while controlling the inner temperature at 60° C., 1-bromooctane 1993 g/THF 10000 ml was dropped over 2.5 hours while keeping the inner temperature at 60 to 70° C., then, the mixture was stirred at 70° C. for 1 hour, and cooled down to 30° C. to prepare a Grignard reagent. Into another vessel purged with nitrogen, 750 g of compound X and 2300 ml of THF were added and into this mixture was dropped a Grignard reagent at 20 to 25° C. while stirring. After completion of dropping, the mixture was stirred at 23 to 25° C. for 2 hours, and allowed to stand at 20° C. over night and day. After cooling to 5° C., 18.8 mL of 1 N hydrochloric acid was dropped at 10° C. or lower to stop the reaction, and the solution was separated into toluene and water, the organic layer was extracted, further washed with water. The solution was dried over magnesium sulfate, then, the solvent was distilled off, to obtain a coarse product. The above-mentioned operation was repeated twice, to obtain 2262 g of a coarse product. From the result of HPLC measurement, it was found that the above-mentioned coarse product was a mixture (AG=18.5%, E=55.2%, AG-1=18.8%, in LC percentage) of compound AG and the following two impurities (compound E, AG-1).

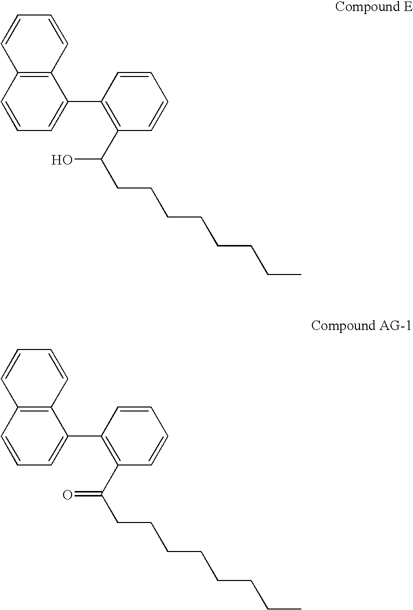

### (Reduction Reaction of Compound Ag-1)

1120 g of the above-mentioned compound was dissolved in 9400 ml of ethanol, the inner temperature was controlled at 20° C., then, 24.9 g of sodium tetrahydroborate was added and the mixture was heated up to 40° C., and reacted for 4 hours. The mixture was cooled to 20 to 25° C., then, stirred over night and day. Its reaction mass was poured into 1700 mL of water, and extracted with 2500 ml of chloroform, and washed with 1200 ml of water twice. The solution was dried over magnesium sulfate, then, the solvent was distilled off, and dried in vacuum to obtain a mixture (AG=20.6%, E=70.9%, in LC percentage) of compound AG and compound E. The above-described operation was repeated twice to obtain 2190 g of a mixture of compound AG and compound E.

### (Synthesis of Compound G, Compound F)

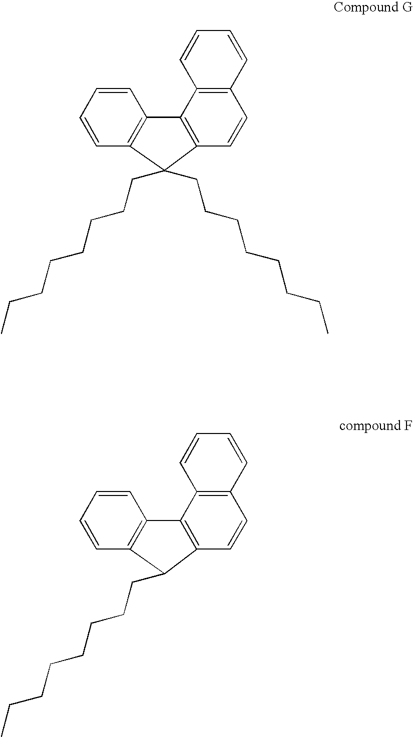

Into a reaction vessel was placed 1090 g of the above-mentioned mixture of compound AG and compound E, and 11400 mL of dehydrated dichloromethane, and 2630 ml of boron trifluoride etherate complex was dropped over 1 hour while stirring at 20 to 25° C. After completion of dropping, the mixture was stirred at 20 to 25° C. for 5 hours, then, the mixture was poured into 19000 mL of water to stop the reaction. 7500 ml of chloroform was added and extraction was performed, and washed with 14000 ml of water. After drying over magnesium sulfate, the solvent was distilled off, to obtain a mixture (G=29.0%, F=52.6%, in LC percentage) of compound G and compound F. The above-described operation was repeated twice to obtain 2082 g of a mixture of compound G and compound F.

### (Re-Alkylation Reaction of Compound F)

To 3.94 kg of ice-cooled water was added portion-wise 3747 g of sodium hydroxide while stirring, to prepare an aqueous solution. To this was added 1025 g of the above-mentioned mixture of compound G and compound F, and to this was added 4000 mL of toluene and 302 g of tetrabutylammonium bromide and the mixture was heated up to 50° C. 1206 g of 1-bromooctane was dropped, and the mixture was stirred at 50 to 55° C. for 2 hours, then, cooled down to 25° C. 3500 mL of toluene and 7000 mL of water were added and the organic layer was extracted, and the aqueous layer was extracted with 3500 ml of toluene twice, then, the organic layer was washed with 3500 ml of water twice. The organic layer was dried over magnesium sulfate, then, the solvent was distilled off, and dried in vacuum to obtain compound G. The above-described operation was repeated twice to obtain 2690 g of compound G.

### (Synthesis of Mixture H-1)

Into thoroughly dried reaction vessel was added 1320 g of compound G, 8300 ml of dehydrated dichloromethane and 8200 ml of acetic acid and the mixture was stirred at 25° C. Into this solution was added 816 g of zinc chloride, and the mixture was heated up to 50° C. 2.23 kg of benzyltrimethylammonium tribromide was added and reacted at 50° C. for 1 hour. The reaction mixture was cooled to room temperature, then, the reaction solution was poured into 32000 mL of water, then, separated, and the organic layer was extracted and the aqueous layer was extracted with 20000 ml of chloroform, then, the organic layer was washed with 23000 ml of a 5% sodium hydrogensulfite aqueous solution. Thereafter, the solution was washed with 23000 ml of water, 23000 ml of a 5% potassium carbonate aqueous solution and 23000 ml of water, sequentially. After drying over magnesium sulfate, the solvent was distilled off to obtain a coarse product. The coarse product was re-crystallized from 2000 ml of hexane, then, dried under reduced pressure to obtain a coarse product. The above-described operation was repeated twice to obtain 1797 g of a coarse product (LC percentage: 95%). The coarse product was purified by column chromatography, then, re-crystallization from hexane was conducted twice, to obtain 1224 g of white solid. 99.52% of compound H and 0.15% of total of compound W-1 and compound W-2 were detected, in LC percentage. This is called mixture H-1.

### EXAMPLE 117

### Synthesis of Polymer Compound 71

Compound H-1 (1.98 g) and 2,2′-bipyridyl (1.39 g) were dissolved in 180 mL of dehydrated tetrahydrofuran, then, an atmosphere in the system was purged with nitrogen by bubbling with nitrogen. Under a nitrogen atmosphere, this solution was heated up to 60° C., then, bis(1,5-cyclooctadiene)nickel (0) {Ni(COD)₂} (2.45 g) was added at 60° C., and the mixture was reacted for 3 hours while stirring. After reaction, the mixture was cooled to room temperature (about 25° C.), and dropped into a mixed solution of 25% ammonia water 12 ml/methanol 180 mL/ion exchanged water 180 mL, and the mixture was stirred, then, the deposited precipitate was filtrated and dried under reduced pressure for 2 hours, to obtain polymer compound 71. The number-average molecular weight and weight-average molecular weight in terms of polystyrene were Mn=9.4×10⁴ and Mw=4.8×10, respectively.

### EXAMPLE 118

### Synthesis of Polymer Compound 72

Compound H (1.98 g) and 2,2′-bipyridyl (1.39 g) were dissolved in 180 mL of dehydrated tetrahydrofuran, then, an atmosphere in the system was purged with nitrogen by bubbling with nitrogen. Under a nitrogen atmosphere, this solution was heated up to 60° C., then, bis(1,5-cyclooctadiene)nickel (0) {Ni(COD)₂} (2.45 g) was added at 60° C., and the mixture was reacted for 3 hours while stirring. After reaction, this reaction solution was cooled to room temperature (about 25° C.), and dropped into a mixed solution of 25% ammonia water 12 ml/methanol 180 mL/ion exchanged water 180 mL, and the mixture was stirred, then, the deposited precipitate was filtrated and dried under reduced pressure for 2 hours, to obtain polymer compound 72. The number-average molecular weight and weight-average molecular weight in terms of polystyrene were Mn=5.9×10⁴ and Mw=2.1×10⁵, respectively.

Compound H used in this example was analyzed by HPLC, to detect 99.86% of compound H, and 0.06% of a total of compound W-1 and compound W-2, in LC percentage.

### EXAMPLE 119

9.875 g of compound H and 6.958 g of 2,2′-bipyridyl were dissolved in 1188 mL of dehydrated tetrahydrofuran, then, the mixture was heated up to 60° C. under a nitrogen atmosphere, and to this solution was added 12.253 g of bis(1,5-cyclooctadiene)nickel (0) {Ni(COD)₂}, and the mixture was reacted for 3 hours. After reaction, this reaction solution was cooled to room temperature, and dropped into a mixed solution of 25% ammonia water 59 ml/methanol 1188 mL/ion exchanged water 1188 mL, and the mixture was stirred for 30 minutes, then, the deposited precipitate was filtrated and dried under reduced pressure for 2 hours, subsequently, two bathes synthesized in the same manner (scale is 1.09-fold) were mixed, and the mixture was dissolved in 1575 ml of toluene. After dissolution, 6.30 g of radiolite was added and the mixture was stirred for 30 minute, and insoluble materials were filtrated. The resulting filtrate was purified by passing through an alumina column. Next, 3098 mL of 5.2% hydrochloric acid water was added and the mixture was stirred for 3 hours, then, the aqueous layer was removed. Subsequently, 3098 mL of 4% ammonia water was added and the mixture was stirred for 2 hours, then, the aqueous layer was removed. Further, about 3098 mL of ion exchanged water was added to the organic layer, the mixture was stirred for 1 hour, then, the aqueous layer was removed. Thereafter, the organic layer was poured into 4935 ml of methanol and the mixture was stirred for 1 hour, the deposited precipitate was filtrated and dried under reduced pressure. The resulting polymer (hereinafter, referred to as polymer compound 73) showed a yield of 15.460 g. The number-average molecular weight and weight-average molecular weight in terms of polystyrene were Mn=7.8×10⁴ and Mw=4.1×10⁵, respectively.

### <Assignment of Diad Peak>

By measurement of NMR spectrum, cleavages depending on sequence and bonding mode were observed at proton and carbon 13 NMR peaks represented by H_{B1} and C_{B1}, and H_{B2} and C_{B2}, in formula (N1) and formula (N2), respectively. By analysis by tow-dimensional NMR method, a correlation NMR peak of a proton represented by H_{B1} and a carbon 13 represented by C_{B1} in the formula of diad

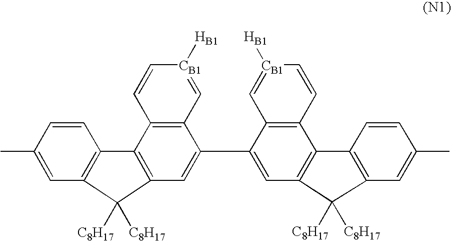

was observed at an intersection point of 7.37 ppm (¹H axis) and 125.3 ppm (¹³C axis) and a correlation NMR peak of a proton represented by H_{B2} and a carbon 13 represented by C_{B2} in the formula of diad

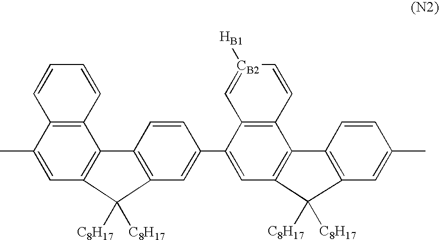

was observed at an intersection point of 7.54 ppm (¹H axis) and 125.3 ppm (¹³C axis).

From an integral value of a peak of H_{B1} and a peak of H_{B2} in a proton NMR spectrum, the ratio of a structure of the formula (N1) to a structure of the formula (N2) was calculated to find a numerical ratio of 26:74. On the other hand, in ¹H detection ¹H-¹³C two-dimensional correlation spectrum (HMQC spectrum), the ratio of a structure of the formula (N1) to a structure of the formula (N2) was calculated from an integral strength of a correlation peak of proton H_{B1} and carbon C_{B1} and an integral strength of a correlation peak of proton H_{B2} and carbon C_{B2}, to find a numerical ratio of 26:74 like the result obtained in proton NMR spectrum. Naphthalene ring-naphthalene ring chain was 0.26 based on all chains including a naphthalene ring in polymer compound 73.

### EXAMPLE 120

Compound H (5.0 g), N,N′-bis(4-bromophenyl)-N,N′-bis(4-t-butyl-2,6-dimethylphenyl)-1,4-phenylenediamine (2.6 g) and 2,2′-bipyridyl (4.5 g) were dissolved in 700 mL of dehydrated tetrahydrofuran, then, an atmosphere in the system was purged with nitrogen by bubbling with nitrogen. Under a nitrogen atmosphere, this solution was heated up to 60° C., then, bis(1,5-cyclooctadiene)nickel (0) {Ni(COD)₂} (7.9 g) was added, and the mixture was reacted for 3 hours while thermally insulating. After reaction, this solution was cooled to room temperature (about 25° C.), and dropped into a mixed solution of 25% ammonia water 30 ml/methanol about 300 mL/ion exchanged water about 300 mL, and the mixture was stirred for 1 hour, then, the deposited precipitate was filtrated and dried under reduced pressure for 2 hours, thereafter, this was dissolved in 350 ml of toluene before filtration, the filtrate was purified by passing through an alumina column, about 350 mL of 4% ammonia water was added, and the mixture was stirred for 2 hours, then, the aqueous layer was removed. Further, about 350 mL of ion exchanged water was added to the organic layer and the mixture was stirred for 1 hour, then, the aqueous layer was removed. The organic layer was dropped into 700 mL of methanol, the mixture was stirred for 1 hour, and the deposited precipitate was filtrated and dried under reduced pressure for 2 hours. The resulting polymer is called polymer compound 74. The yield was 4.7 g. The number-average molecular weight and weight-average molecular weight in terms of polystyrene were Mn=1.4×10⁴ and Mw=5.4×10⁵, respectively.

### <Assignment of Diad Peak>

By measurement of NMR spectrum, cleavages depending on sequence and bonding mode were observed at proton and carbon 13 NMR peaks represented by H_{B1} and C_{B1}, H_{B2} and C_{B2} and H_{B3} and C_{B3}, in formulae (N1), (N2) and (N3), respectively. By analysis by tow-dimensional NMR method, a correlation NMR peak of a proton represented by H_{B1} and a carbon 13 represented by C_{B1} in the formula of diad

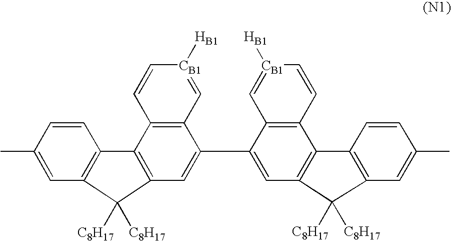

was observed at an intersection point of 7.37 ppm (¹H axis) and 125.3 ppm (¹³C axis) and a correlation NMR peak of a proton represented by H_{B2} and a carbon 13 represented by C_{B2} in the formula of diad

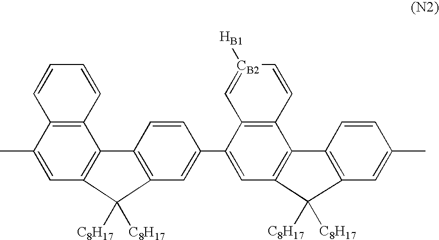

and a correlation NMR peak of a proton represented by H_{B3} and a carbon 13 represented by C_{B3} in the formula of diad

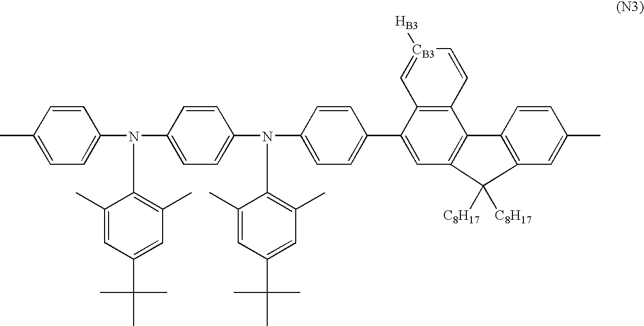

were both observed at an intersection point of 7.50 ppm (¹H axis) and 125.0 ppm (¹³C axis).

In ¹H detection ¹H-¹³C two-dimensional correlation spectrum (HMQC spectrum), the ratio of a structure of the formula (N1) to the sum of structures of the formula (N2) and formula (N3) was calculated from an integral strength of a correlation peak of proton H_{B1} and carbon C_{B1}, and an integral strength of a correlation peak of proton H_{B2} and carbon C_{B2} and proton H_{B3} and carbon C_{B3}, to find a numerical ratio of 15:85. Naphthalene ring-naphthalene ring chain was 0.15 based on all chains including a naphthalene ring in polymer compound 74.

### EXAMPLE 121

The NMR spectrum of the above-mentioned polymer compound 33 was measured by the method described above.

### <Assignment of Diad Peak>

By measurement of NMR spectrum, cleavages depending on sequence and bonding mode were observed at proton and carbon 13 NMR peaks represented by H_{B1} and C_{B1}, H_{B2} and C_{B2} and H_{B3} and C_{B3}, in formulae (N1), (N2) and (N3), respectively. By analysis by tow-dimensional NMR method, a correlation NMR peak of a proton represented by H_{B1} and a carbon 13 represented by C_{B1} in the formula of diad

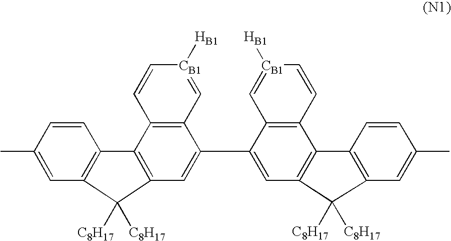

was observed at an intersection point of 7.37 ppm (¹H axis) and 125.3 ppm (¹³C axis) and a correlation NMR peak of a proton represented by H_{B2} and a carbon 13 represented by C_{B2} in the formula of diad

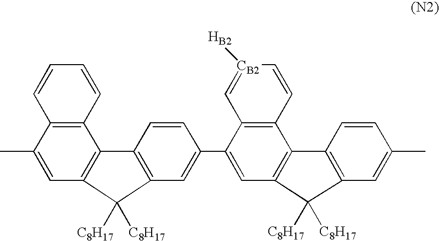

and a correlation NMR peak of a proton represented by H_{B3} and a carbon 13 represented by C_{B3} in the formula of diad

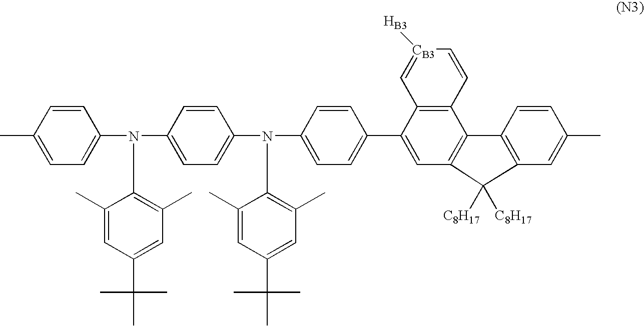

were both observed at an intersection point of 7.50 ppm (¹H axis) and 125.0 ppm (¹³C axis).

In ¹H detection ¹H-¹³C two-dimensional correlation spectrum (HMQC spectrum), the ratio of a structure of the formula (N1) to the sum of structures of the formula (N2) and formula (N3) was calculated from an integral strength of a correlation peak of proton H_{B1} and carbon C_{B1}, and an integral strength of a correlation peak of proton H_{B2} and carbon C_{B2} and proton H_{B3} and carbon C_{B3}, to find a numerical ratio of 17:83. Naphthalene ring-naphthalene ring chain was 0.17 based on all chains including a naphthalene ring in polymer compound 33.

### EXAMPLE 122

The NMR spectrum of the above-mentioned polymer compound 38 was measured by the method described above.

### <Assignment of Diad Peak>

By measurement of NMR spectrum, cleavages depending on sequence and bonding mode were observed at proton and carbon 13 NMR peaks represented by H_{B1} and C_{B1}, H_{B2} and C_{B2} and H_{B4} and C_{B4}, in formulae (N1), (N2) and (N4), respectively. By analysis by tow-dimensional NMR method, a correlation NMR peak of a proton represented by H_{B1} and a carbon 13 represented by C_{B1} in the formula of diad

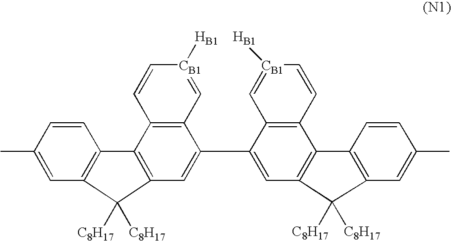

was observed at an intersection point of 7.37 ppm (¹H axis) and 125.3 ppm (¹³C axis) and a correlation NMR peak of a proton represented by H_{B2} and a carbon 13 represented by C_{B2} in the formula of diad

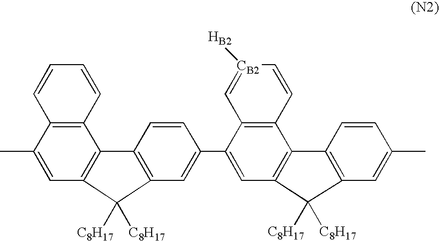

and a correlation NMR peak of a proton represented by H_{B4} and a carbon 13 represented by C_{B4} in the formula of diad

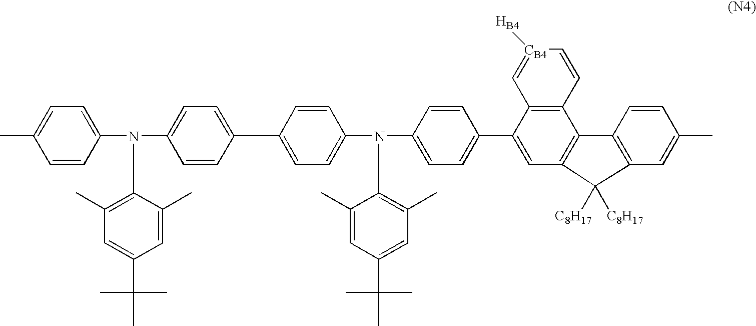

were both observed at an intersection point of 7.51 ppm (¹H axis) and 125.2 ppm (¹³C axis).

In ¹H detection ¹H-¹³C two-dimensional correlation spectrum (HMQC spectrum), the ratio of a structure of the formula (N1) to the sum of structures of the formula (N2) and formula (N4) was calculated from an integral strength of a correlation peak of proton H_{B1} and carbon C_{B1}, and an integral strength of a correlation peak of proton H_{B2} and carbon C_{B2} and proton H_{B4} and carbon C_{B4}, to find a numerical ratio of 14:86. Naphthalene ring-naphthalene ring chain was 0.14 based on all chains including a naphthalene ring in polymer compound 38.

### EXAMPLE 125

### Manufacturing of Polymer Electric Field Effect Transistor and Evaluation of Physical Property

An n-type silicon base plate doped at high concentration (specific resistance: 0.1 Ocm or less) was used as a gate electrode, and a silicon oxide film was formed thereon at a thickness of 200 nm by thermal oxidation, and the film was used as a gate insulation film. This silicon base plate with oxide film was subjected to ultrasonic wave washing with a weak alkaline detergent for 10 minutes, then, rinsed by flow of extra-pure water for 5 minutes, further, ultrasonic wave washing with extra-pure water was conducted for 10 minutes and ultrasonic wave washing with acetone was conducted for 10 minutes. The surface of the base plate lifted from acetone and dried was treated by ozone UV, then, immersed in an octane solution of perfluorooctyltrichlorosilane 8 mM in a glove box for 16 hours, to form a single molecule film on the surface of the silicon oxide film. Polymer compound 34 synthesized in Example 44 was dissolved in toluene at a concentration of 1.0 wt %, and filtrated through a 0.2 μm film filter to give an application solution. Using this application solution, a polymer active layer was formed at a thickness of 53 nm on the silicon base plate with oxide film on which the single molecule film had been formed, by a spin coat method in atmosphere. On this polymer active layer, platinum was vapor-deposited at a thickness of 0.5 nm, and gold was vapor-deposited thereon at a thickness of 40 nm, by a vacuum deposition method, to form a source electrode and a drain electrode, manufacturing a polymer electric field effect transistor (FIG. 5). In this case, the channel width of the electrode was 2000 μm and the channel length was 20 μm.

Using the manufactured polymer electric field effect transistor, the gate voltage V_{G} was changed from 0 to −80V and the source-drain voltage V_{DS} was changed from 0 to −80V in a nitrogen atmosphere, and a transistor property was measured. As a result, an excellent I_{D}−V_{DS} property (FIG. 6) was obtained, and when V_{G}=−80V and V_{DS}=−60V, a drain current of −79 nA flowed. Further, the electric field effect mobility obtained from the I_{D}−V_{GS} property was 1.7×10⁻⁴, and the threshold voltage was −40V and the current on-off ratio was 1×10³.

### INDUSTRIAL APPLICABILITY

The polymer compound of the present invention is useful as a light emitting material and an charge transporting material, and excellent in heat resistance, fluorescent intensity and the like. Therefore, the polymer LED containing the polymer compound of the present invention can be used for a curved or flat light source for illumination or back light of a liquid crystal display, a display of segment type, a flat panel display of dot matrix, and the like.

1. A polymer compound comprising a repeating unit of the following formula (1): 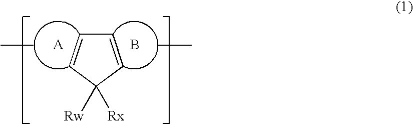
wherein, ring A and ring B represent each independently an aromatic hydrocarbon ring optionally having a substituent, at least one of ring A and ring B is an aromatic hydrocarbon ring composed of a plurality of condensed benzene rings, two connecting bonds are present on ring A and/or ring B, R_{w} and Rₓ represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, and R_{w} and Rₓ may mutually bond to form a ring.

2. The polymer compound according to claim 1, wherein the repeating unit of the formula (1) is a repeating unit of the following formula (2): 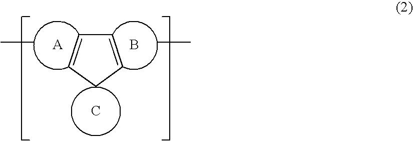
wherein, ring A and ring B represent each independently an aromatic hydrocarbon ring optionally having a substituent, at least one of ring A and ring B is an aromatic hydrocarbon ring composed of a plurality of condensed benzene rings, two connecting bonds are present on ring A and/or ring B, and ring C represent a hydrocarbon ring or heterocyclic ring.

3. The polymer compound according to claim 1, wherein the aromatic hydrocarbon ring in ring A and the aromatic hydrocarbon ring in ring B have mutually different ring structures.

4. The polymer compound according to claim 1, wherein the number-average molecular weight in terms of polystyrene is 10³ to 10⁸.

5. The polymer compound according to claim 1, wherein the weight-average molecular weight in terms of polystyrene is 5×10⁴ or more.

6. The polymer compound according to claim 5, wherein the weight-average molecular weight in terms of polystyrene is 10⁵ or more.

7. The polymer compound according to claim 1, wherein when the aromatic hydrocarbon ring has a substituent, the substituent is selected from the group consisting of an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group.

8. The polymer compound according to claim 1, wherein the combination of ring A and ring B is a combination selected from a benzene ring, naphthalene ring, anthracene ring, tetracene ring, pentacene ring, pyrene ring, and phenanthrene ring.

9. The polymer compound according to claim 8, wherein the combination of ring A and ring B is a combination selected from any combinations of benzene ring and naphthalene ring, benzene ring and anthracene ring, benzene ring and phenanthrene ring, naphthalene ring and anthracene ring, naphthalene ring and phenanthrene ring, anthracene ring and phenanthrene ring.

10. The polymer compound according to claim 9, wherein the ring A is a benzene ring and the ring B is a naphthalene ring.

11. The polymer compound according to claim 10, wherein the repeating unit of said formula (1) is a structure of the following formula (1-1), (1-2), (1-3) or (1-4): 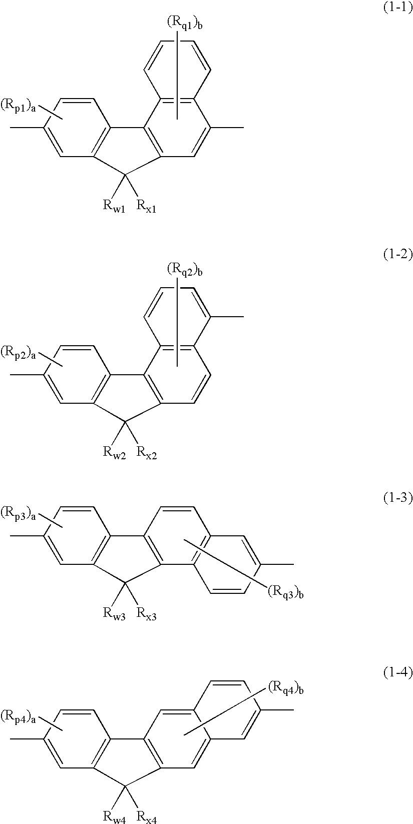
wherein, Rₚ₁, R_{q1}, Rₚ₂, R_{q2}, Rₚ₃, R_{q3}, Rₚ₄ and R_{q4} represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, a represents an integer of 0 to 3, and b represents an integer of 0 to 5, when a plurality of Rₚ₁s, R_{q1}s, Rₚ₂s, R_{q2}s, Rₚ₃s, R_{q3}s, Rₚ₄s and R_{q4}s are present, these may be the same or different, R_{w1}, Rₓ₁, R_{w2}, Rₓ₂, R_{w3}, Rₓ₃, R_{w4} and Rₓ₄ represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, and R_{w1} and Rₓ₁, R_{w2} and Rₓ₂, R_{w3} and Rₓ₃, R_{w4} and Rₓ₄ mutually bond to form a ring).

12. The polymer compound according to claim 11, wherein the repeating unit of said formula (1) is a structure of said formula (1-1), and a=b=0.

13. The polymer compound according to claim 11, composed only of any one of the repeating units of said formulae (1-1), (1-2), (1-3) and (1-4).

14. The polymer compound according to claim 11, comprising two or, more of the repeating units of said formulae (1-1), (1-2), (1-3) and (1-4).

15. The polymer compound according to claim 11, wherein in the repeating units of said formulae (1-1), (1-2), (1-3) and (1-4), R_{w1} and Rₓ₁, R_{w2} and Rₓ₂, R_{w3} and Rₓ₃, R_{w4} and Rₓ₄ are respectively the same.

16. The polymer compound according to claim 11, wherein R_{w1}, Rₓ₁, R_{w2}, Rₓ₂, R_{w3}, Rₓ₃, R_{w4} and Rₓ₄ represent each independently an aryl group or arylalkyl group.

17. The polymer compound according to claim 11, wherein in said formulae (1-1), (1-2), (1-3) and (1-4), a=0 and b=1.

18. The polymer compound according to claim 17, wherein said formulae (1-1) is the following formula (1-1-4) or (1-1-5): 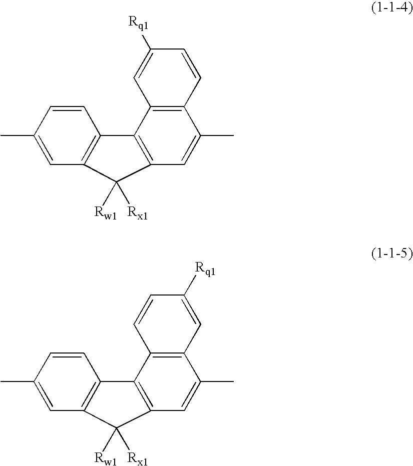
wherein, R_{w1}, Rₓ₁, and R_{q1} have the same meanings as described above.

19. The polymer compound according to claim 18, wherein in said formulae (1-1-4) and (1-1-5), R_{q1} represents an alkyl group having a branched structure or cyclic structure.

20. The polymer compound according to claim 1, comprising one or more of structures of the following formulae (31), (32) and (33): 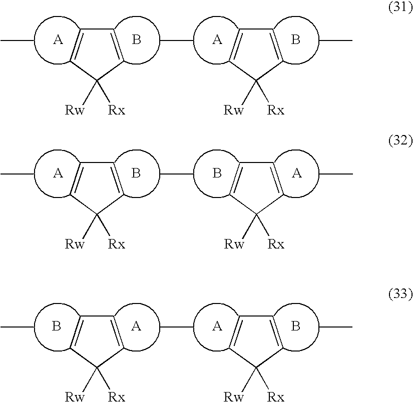
wherein, ring A and ring B represent each independently an aromatic hydrocarbon ring optionally having a substituent, the aromatic hydrocarbon ring in ring A and the aromatic hydrocarbon ring in ring B have mutually different ring structures, a connecting bond is present on both ring A and ring B, R_{w}, and Rₓ represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, and R_{w} and Rₓ may mutually bond to form a ring.

21. The polymer compound according to claim 20, wherein ring B represents an aromatic hydrocarbon ring composed of a plurality of condensed benzene rings, the aromatic hydrocarbon ring in ring A and the aromatic hydrocarbon ring composed of a plurality of condensed benzene rings in ring B have mutually different ring structures, a structure of said formula (31) is contained, and the proportion of a B ring-B ring chain shown in said formula (32) is 0.4 or less based on all chains containing ring B in the polymer compound.

22. The polymer compound according to claim 20, wherein it is a copolymer containing the repeating unit of said formula (1) in a ratio of 50 mol % or more based on all repeating units, and when the proportion that the repeating unit of the formula (1) is adjacent to the repeating unit of the formula (1) is represented by Q₁₁, Q₁₁ is 25% or more.

23. The polymer compound according to claim 1, further comprising a repeating unit of the following formula (3), (4), (5) or (6):
—Ar₁— (3)
Ar₂—X₁_{ff}Ar₃— (4)
—Ar₄—X₂— (5)
—X₃—(6)
wherein, Ar₁, Ar₂, Ar₃ and Ar₄ represent each independently an arylene group, divalent heterocyclic group or divalent group having a metal complex structure, X₁, X₂ and X₃ represent each independently —CR₉═CR₁₀—, —C≡C—, —N(R₁₁)— or —(SiR₁₂R₁₃)ₘ—, R₉ and R₁₀ represent each independently a hydrogen atom, alkyl group, aryl group, mono-valent heterocyclic group, carboxyl group, substituted carboxyl group or cyano group, R₁₁, R₁₂ and R₁₃ represent each independently a hydrogen atom, alkyl group, aryl group, mono-valent heterocyclic group, arylalkyl group or substituted amino group, ff represents 1 or 2, m represents an integer of 1 to 12, when a plurality of R₉s, R₁₀s, R₁₁s, R₁₂s and R₁₃s are present, these may be the same or different.

24. The polymer compound according to claim 23, wherein the repeating unit of said formula (3) is a repeating unit of the following formula (7), (8), (9), (10), (11) or (12): 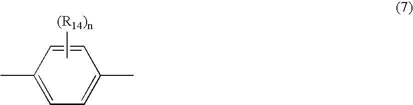
wherein, R₁₄ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, n represents an integer of 0 to 4, when a plurality of R₁₄s are present, these may be the same or different: 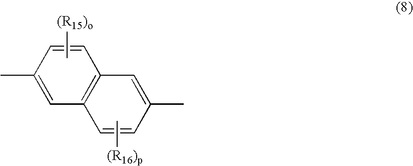
wherein, R₁₅ and R₁₆ represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, o and p represent each independently an integer of 0 to 3, when a plurality of R₁₅s and R₁₆s are present, these may be the same or different: 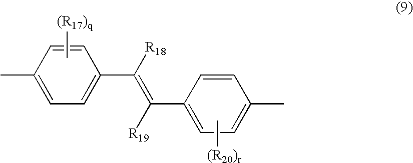
wherein, R₁₇ and R₂₀ represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, q and r represent each independently an integer of 0 to 4, R₁₈ and R₁₉ represent each independently a hydrogen atom, alkyl group, aryl group, mono-valent heterocyclic group, carboxyl group, substituted carboxyl group or cyano group, when a plurality of R₁₇s and R₂₀s are present, these may be the same or different: 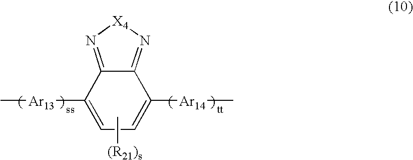
wherein, R₂₁ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, s represents an integer of 0 to 2, Ar₁₃ and Ar₁₄ represent each independently an arylene group, divalent heterocyclic group or divalent group having a metal complex structure, ss and tt represent each independently 0 or 1, X₄ represents O, S, SO, SO₂, Se or Te, when a plurality of R₂₁s are present, these may be the same or different: 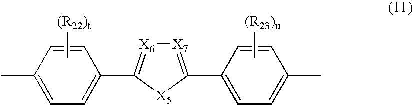
wherein, R₂₂ and R₂₃ represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, t and u represent each independently an integer of 0 to 4, X₅ represents O, S, SO₂, Se, Te, N—R₂₄ or SiR₂₅R₂₆, X₆ and X₇ represent each independently N or C—R₂₇, R₂₄, R₂₅, R₂₆ and R₂₇ represent each independently a hydrogen atom, alkyl group, aryl group, arylalkyl group or mono-valent heterocyclic group, when a plurality of R₂₂s, R₂₃s and R₂₇s are present, these may be the same or different: 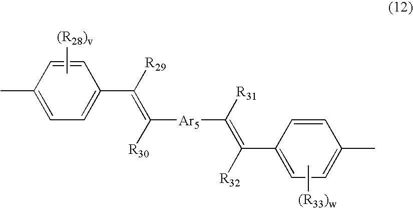
wherein, R₂₈ and R₃₃ represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, v and w represent each independently an integer of 0 to 4, R₂₉, R₃₀, R₃₁ and R₃₂ represent each independently a hydrogen atom, alkyl group, aryl group, mono-valent heterocyclic group, carboxyl group, substituted carboxyl group or cyano group, Ar₅ represents an arylene group, divalent heterocyclic group or divalent group having a metal complex structure, when a plurality of R₂₈s and R₃₃s are present, these may be the same or different).

25. The polymer compound according to claim 23, wherein the repeating unit of said formula (4) is a repeating unit of the following formula (13): 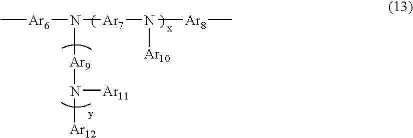
wherein, Ar₆, Ar₇, Ar₈ and Ar₉ represent each independently an arylene group or divalent heterocyclic group, Ar₁₀, Ar₁₁ and Ar₁₂ represent each independently an aryl group or mono-valent heterocyclic group, Ar₆, Ar₇, Ar₈, Ar₉ and Ar₁₀ may have a substituent, x and y represent each independently 0 or a positive integer.

26. The polymer compound according to claim 25, wherein in the repeating unit of said formula (13), Ar₁₀, Ar₁₁ and Ar₁₂ are each independently selected from groups of the following formula (13-1): 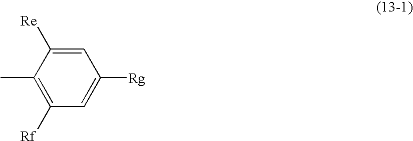
wherein, Re, Rf and Rg represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, mono-valent heterocyclic group or halogen atom.

27. The polymer compound according to claim 25, wherein in the repeating unit of said formula (13), x+y=1.

28. The polymer compound according to claim 25, wherein the compound comprises each one or more of repeating units of said formula (1) and repeating units of said formula (13), the sum of these repeating units is 50 mol % or more based on all repeating units, and the molar ratio of the sum of repeating units of the formula (1) to the sum of repeating units of the formula (13) is 98:2 to 60:40.

29. The polymer compound according to claim 28, wherein the compound comprises 1 to 3 repeating units of said formula (13).

30. The polymer compound according to claim 29, wherein the compound comprises one repeating unit of said formula (1) and 1 or 2 repeating units of said formula (13).

31. The polymer compound according to claim 28, wherein the sum of repeating units of said formula (1) and repeating units of said formula (13) is 90 mol % or more based on all repeating units.

32. The polymer compound according to claim 28, wherein the repeating unit of said formula (1) is a repeating unit of said formula (1-1), (1-2), (1-3) or (1-4).

33. The polymer compound according to claim 32, wherein the repeating unit of said formula (1) is a repeating unit of said formula (1-1) or (1-2).

34. The polymer compound according to claim 32, wherein the repeating unit of said formula (1) is a repeating unit of said formula (1-1) and a=b=0.

35. The polymer compound according to claim 25, wherein in the repeating unit of said formula (13), y=0 and x=1.

36. The polymer compound according to claim 25, wherein in the repeating unit of said formula (13), y=1 and x=0.

37. The polymer compound according to claim 25, wherein in the repeating unit of said formula (13), y=0 and x=0.

38. The polymer compound according to claim 25, wherein in the repeating unit of said formula (13), Ar₇ is represented by the following formula (19-1) or (19-2): 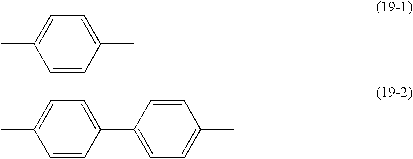
wherein, benzene rings contained in structures of (19-1) and (19-2) may have each independently 1 to 4 substituents, the substituents may be mutually the same or different, a plurality of substituents may be connected to form a ring, and another aromatic hydrocarbon ring or heterocyclic ring may be condensed next to the benzene ring.

39. The polymer compound according to claim 25, wherein it is a copolymer containing the repeating unit of said formula (13) in a ratio of 15 to 50 mol % based on all repeating units, and when the proportion that the repeating unit of the formula (13) is adjacent to the repeating unit of the formula (13) is represented by Q₂₂, Q₂₂ is 15 to 50% or more.

40. The polymer compound according to claim 25, wherein it comprises said formula (13) and the following formula (1-1) or (1-2), and when the proportion that the formula (13) is bonded further to the formula (13) is represented by Q₂₂ and the proportion that the formula (13) is bonded to a mark * of the formula (1-1) or the formula (1-2) is represented by Q_{21N}, Q₂₂ is in a range of 15 to 50% and Q_{21N} is in a range of 20 to 40%: 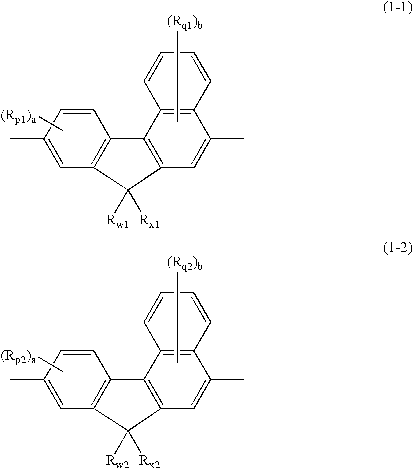
wherein, Rₚ₁, R_{q1}, Rₚ₂, R_{q2}, a, b, R_{w1}, Rₓ₁, R_{w2} and Rₓ₂ represent the same meanings as described above.

41. The polymer compound according to claim 13, wherein the compound is composed only of a repeating unit of said formula (1-1).

42. The polymer compound according to claim 41, wherein the repeating unit of said formula (1-1) is a repeating unit of the following formula (16):

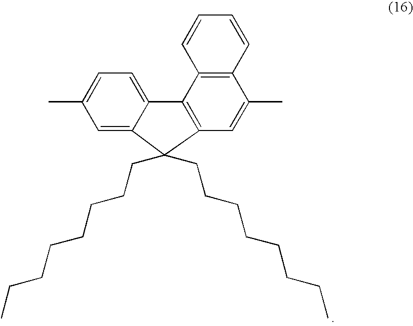

43. The polymer compound according to claim 41, wherein the solution curve of GPC is single-peaked and the degree of dispersion (weight-average molecular weight/number-average molecular weight) is 1.5 or more and 12 or less.

44. The polymer compound according to claim 38, wherein the compound is composed only of a repeating unit of said formula (16) and a repeating unit of the following formula (17):

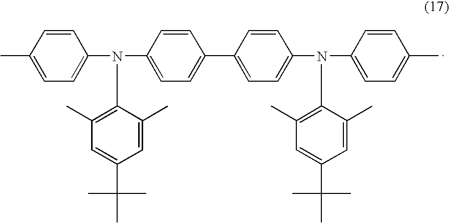

45. The polymer compound according to claim 25, wherein the solution curve of GPC is double-peaked.

46. The polymer compound according to claim 25, wherein when the ratio of the repeating unit of said formula (1) 100 mol %, a branched structure of the following formula (41) is contained in a ratio of 0.1 mol % or more: 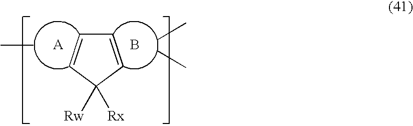
wherein, ring A, ring B, R_{w} and Rₓ represent the same meanings as described above, and three connecting bonds are present on ring A and/or ring B.

47. The polymer compound according to claim 46, wherein the compound contains a repeating unit of the following formula (41-1) in a ratio of 0.1 mol % or more based on the repeating unit of said formula (1): 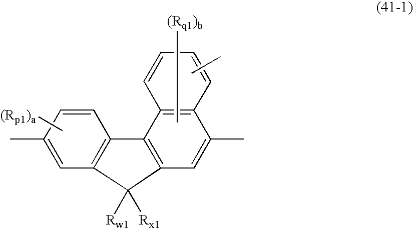
wherein, Rₚ₁, R_{q1}, R_{w1}, Rₓ₁, a and b represent the same meanings as described above.

48. The polymer compound according to claim 1, wherein one or more molecular chain ends of the polymer compound have an end group selected from the group consisting of a mono-valent heterocyclic group, mono-valent aromatic amine group, mono-valent group derived from a heterocyclic coordinated metal complex and aryl group having a formula weight of 90 or more.

49. The polymer compound according to claim 48, wherein the end group is a condensed ring compound group.

50. The polymer compound according to claim 48, wherein the end group is an aryl group having a substituent.

51. A method of producing the polymer compound according to claim 1, comprising using a compound of the formula (14): 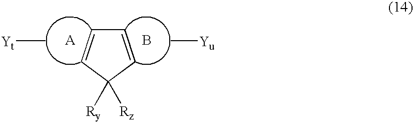
wherein, R_{y} and R_{z} represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, R_{y} and R_{z} may mutually bond to form a ring, Yₜ and Yᵤ represent each independently a substituent correlated with polymerization, and are bonded to ring A and/or ring B, as one raw material and polymerizing this.

52. The production method according to claim 51, wherein the formula (14) is a formula (14-1), (14-2), (14-3) or (14-4): 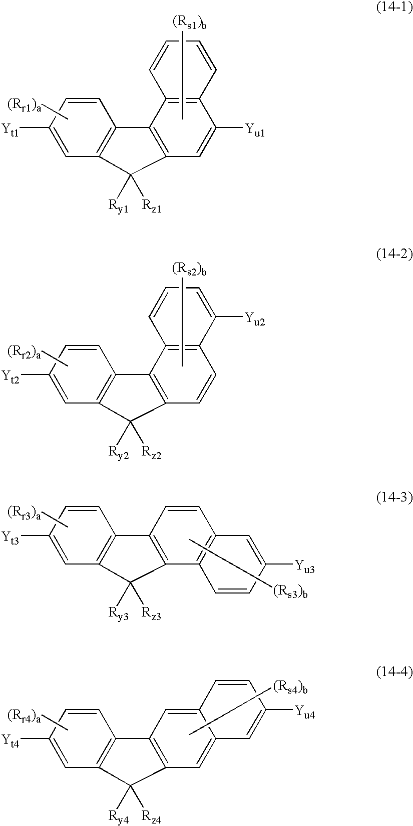
wherein, Rᵣ₁, Rₛ₁, Rᵣ₂, Rₛ₂, Rᵣ₃, Rₛ₃, Rᵣ₄ and Rₛ₄ represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group. a represents an integer of 0 to 3, and b represents an integer of 0 to 5, and when a plurality of Rᵣ₁s, Rₛ₁s, Rᵣ₂s, Rₛ₂s, Rᵣ₃s, Rₛ₃s, Rᵣ₄s and Rₛ₄s are present, these may be the same or different, R_{y1}, R_{z1}, R_{y2}, R_{z2}, R_{y3}, R_{z3}, R_{y4} and R_{z4} represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, and R_{y1} and R_{z1}, R_{y2} and R_{z2}, R_{y3} and R_{z3}, R_{y4} and R_{z4} may mutually bond to form a ring, Yₜ₁, Yᵤ₁, Yₜ₂, Yᵤ₂, Yₜ₃, Yᵤ₃, Yₜ₄ and Yᵤ₄ represent each independently a substituent correlated with polymerization.

53. The production method according to claim 51, wherein a compound of any of the following formulae (21) to (24) is used as a raw material and polymerized, in addition to the compound of said formula (14):
Y₅—Ar₁—Y₆ (21)
Y₇Ar₂—X₁_{ff}Ar₃—Y₈ (22)
Y₉—Ar₄—X₂—Y₁₀ (23)
Y₁₁—X₃—Y₁₂ (24)
wherein, Ar₁, Ar₂, Ar₃, Ar₄, ff, X₁, X₂ and X₃ represent the same meanings as described above, Y₅, Y₆, Y₇, Y₈, Y₉, Y₁₀, Y₁₁ and Y₁₂ represent each independently a substituent correlated with polymerization.

54. The production method according to claim 51, wherein compounds of the following formulae (25) and (27) are used as a raw material and polymerized, in addition to the compounds of said formula (14), said formula (15-1) and said formulae (21) to (24):
E₁-Y₁₃ (25)
E₂-Y₁₄ (27)
wherein, E1 and E2 represent a mono-valent heterocyclic group, aryl group having a substituent or mono-valent aromatic amine group, and Y₁₃ and Y₁₄ represent each independently a substituent correlated with polymerization.

55. The production method according to claim 51, wherein the substituent correlated with polymerization is selected each independently from a halogen atom, alkylsulfonate group, arylsulfonate group and arylalkylsulfonate group, and polymerized in the presence of a nickel 0-valent complex.

56. The production method according to claim 51, wherein the substituent correlated with polymerization is selected each independently from a halogen atom, alkylsulfonate group, arylsulfonate group, arylalkylsulfonate group, —B(OH)₂ or borate group, the ratio of the sum of mol numbers of a halogen atom, alkylsulfonate group, arylsulfonate group and arylalkylsulfonate group carried on all raw material compounds to the sum of mol numbers of —B(OH)₂ and borate group is substantially 1, and polymerization is carried out using a nickel or palladium catalyst.

57. A method of producing the polymer compound according to claim 1, comprising using a compound of the following formula (14B): 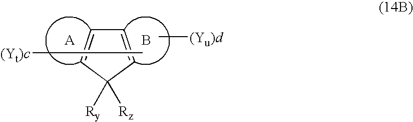
wherein, R_{y}, R_{z}, Yₜ and Yᵤ represent the same meanings as described above, c represents 0 or a positive integer, d represents 0 or a positive integer, and 3≦c+d≦6, as one raw material and polymerizing this.

58. The production method according to claim 57, wherein the compound of said formula (14B) is a compound of the following formula (14-5), (14-6) or (14-7): 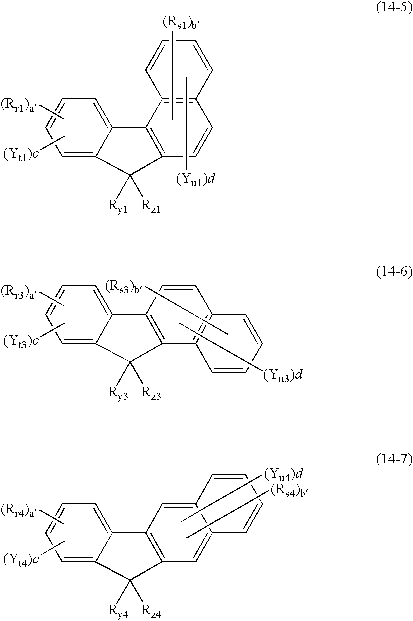
wherein, Rᵣ₁, Rₛ₁, Rᵣ₂, Rₛ₂, Rᵣ₃, Rₛ₃, Rᵣ₄, Rₛ₄, R_{y1}, R_{z1}, R_{y2}, R_{z2}, R_{y3}, R_{z3}, R_{y4}, R_{z4}, Yₜ₁, Yᵤ₁, Yₜ₃, Yᵤ₃, Yₜ₄ and Yᵤ₄ represent the same meanings as described above, a′ represents an integer of 0 to 4, b′ represents an integer of 0 to 5, c represents an integer of 0 to 3, d represents an integer of 0 to 5, a′+c≦4, b′+d≦6, and 3≦c+d≦6, when a plurality of Rᵣ₁s, Rₛ₁, Rᵣ₂s, Rₛ₂s, Rᵣ₃s, Rₛ₃s, Rᵣ₄s, Rₛ₄s, R_{y1}s, R_{z1}s, Yₜ₁s, Yᵤ₁s, Yₜ₃s, Yᵤ₃s, Yₜ₄s and Yᵤ₄s are present, these may be the same or different.

59. A compound of said formula (14B).

60. A compound of the following formula (14C): 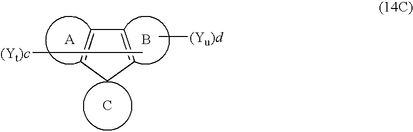
wherein, ring A, ring B and ring C represent the same meanings as described above, Yₜ and Yᵤ represent the same meanings as described above, c represents 0 or a positive integer, d represents 0 or a positive integer, and 2≦c+d≦6.

61. A compound of the following formula (14-1), (14-2), (14-3) or (14-4): 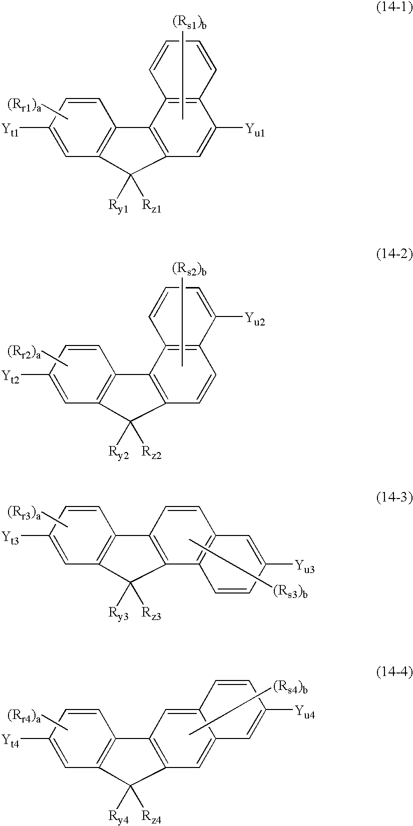
wherein, Rᵣ₁, Rₛ₁, Rᵣ₂, Rₛ₂, Rᵣ₃, Rₛ₃, Rᵣ₄ and Rₛ₄ represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, a represents an integer of 0 to 3, and b represents an integer of 0 to 5, and when a plurality of Rᵣ₁s, Rₛ₁s, Rᵣ₂s, Rₛ₂s, Rᵣ₃s, Rₛ₃s, Rᵣ₄s and Rₛ₄s are present, these may be the same or different, R_{y1}, R_{z1}, R_{y2}, R_{z2}, R_{y3}, R_{z3}, R_{y4} and R_{z4} represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, and R_{y1} and R_{z1}, R_{y2} and R_{z2}, R_{y3} and R_{z3}, R_{y4} and R_{z4} may mutually bond to form a ring, Yₜ₁, Yᵤ₁, Yₜ₂, Yᵤ₂, Yₜ₃, Yᵤ₃, Yₜ₄ and Yᵤ₄ represent each independently a substituent correlated with polymerization.

62. A compound of the following formula (14-5), (14-6) or (14-7): 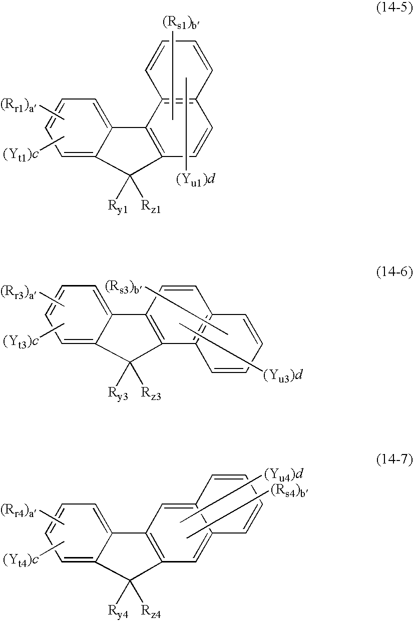
wherein, Rᵣ₁, Rₛ₁, Rᵣ₂, Rₛ₂, Rᵣ₃, Rₛ₃, Rᵣ₄, Rₛ₄, R_{y1}, R_{z1}, R_{y2}, R_{z2}, R_{y3}, R_{z3}, R_{y4}, R_{z4}, Yₜ₁, Yᵤ₁, Yₜ₃, Yᵤ₃, Yₜ₄ and Yᵤ₄ represent the same meanings as described above, a′ represents an integer of 0 to 4, b′ represents an integer of 0 to 5, c represents an integer of 0 to 3, d represents an integer of 0 to 5, a′+c≦4, b′+d≦6, and 3≦+d≦6, when a plurality of Rᵣ₁s, Rₛ₁, Rᵣ₂s, Rₛ₂s, Rᵣ₃s, Rₛ₃s, Rᵣ₄, Rₛ₄s, R_{y1}s, R_{z1}s, Yₜ₁s, Yᵤ₁s, Yₜ₃s, Yᵤ₃s, Yₜ₄s and Yᵤ₄s are present, these may be the same or different.

63. The compound according to claim 59, wherein the substituent correlated with polymerization is selected each independently from a halogen atom, alkylsulfonate group, arylsulfonate group and arylalkylsulfonate group.

64. A compound of said formula (14-1), (14-3) or (14-4) wherein Yₜ₁, Yᵤ₁, Yₜ₃, Yᵤ₃, Yₜ₄ and Yᵤ₄ represent a bromine atom.

65. The compound according to claim 64, wherein a and b in said formula (14-1), (14-3) or (14-4) is 0.

66. A compound of the following formula (14-8): 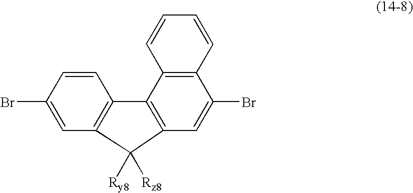
wherein, R_{y8} and R_{z8} represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, and R_{y8} and R_{z8} may mutually bond to form a ring.

67. A method of producing the compound according to claim 64, comprising brominating a compound of the following formula (14-9), (14-10) or (14-11) with a brominating agent: 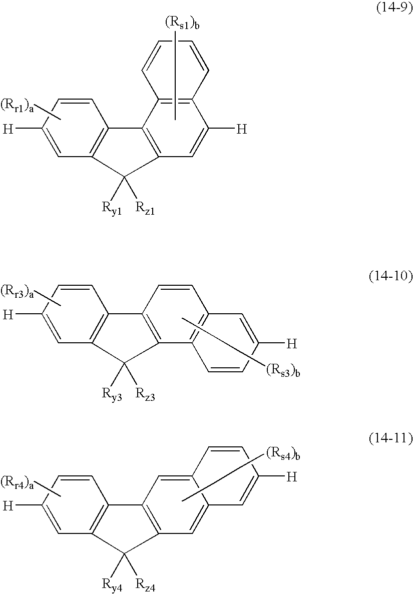
wherein, Rᵣ₁, Rₛ₁, Rᵣ₃, Rₛ₃, Rᵣ₄, Rₛ₄, R_{y1}, R_{z1}, R_{y3}, R_{z3}, R_{y4}, R_{z4}, and a and b have the same meanings as described above, H represents a hydrogen atom.

68. A method of producing a compound of the following formula (2-1), comprising reacting a compound of the following formula (2-2) with a metallizing agent to convert X_{L} into M_{L}, then, reacting this with a compound of the following formula (2-3): 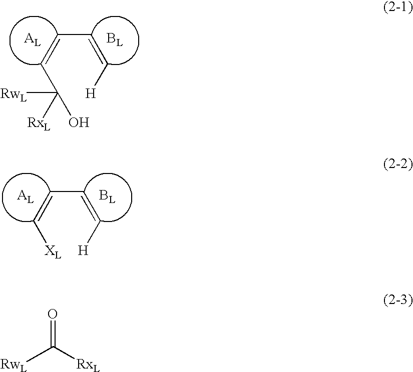
wherein, ring A_{L} and ring B_{L} represent each independently an aromatic hydrocarbon ring optionally having a substituent, at least one of ring A_{L} and ring B_{L} is an aromatic hydrocarbon ring composed of a plurality of condensed benzene rings, R_{wL} and R_{xL} represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, and R_{wL} and R_{xL} may mutually bond to form a ring, X_{L} represents a bromine atom or iodine atom, M_{L} represents a metal atom or its salt.

69. The compound according to claim 57, wherein the substituents correlated with polymerization are selected each independently from —B(OH)₂ or borate groups.

70. A method of producing the polymer compound according to claim 25 comprising using compounds of said formula (14) and the following formula (15-1): 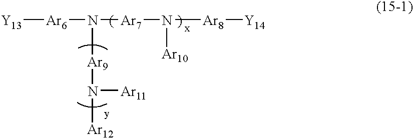
wherein, Ar₆, Ar₇, Ar₈ and Ar₉ represent each independently an arylene group or divalent heterocyclic group, Ar₁₀, Ar₁₁ and Ar₁₂ represent each independently an aryl group or mono-valent heterocyclic group, Ar₆, Ar₇, Ar₈, Ar₉ and Ar₁₀ may have a substituent, x and y represent each independently 0 or 1, x and y represent each independently 0 or a positive integer, and Y₁₃ and Y₁₄ represent each independently a substituent correlated with polymerization, as a raw material and polymerizing them.

71. A composition comprising at least one material selected from hole transporting materials, electron transporting materials and light emitting materials and the polymer compound according to claim 1.

72. A polymer composition comprising two or more polymer compounds containing a repeating unit of said formula (1), wherein the sum of the polymer compounds is 50 wt % or more based on the total amount.

73. The polymer composition according to claim 72, comprising at least one polymer compound composed only of a repeating unit of said formula (1) and at least one copolymer containing a repeating unit of said formula (1) in a ratio of 50 mol % or more.

74. The polymer composition according to claim 72, comprising two or more copolymers containing a repeating unit of said formula (1) in a ratio of 50 mol % or more, wherein the copolymers contain also mutually different repeating units.

75. The polymer composition according to claim 72, comprising two or more copolymers containing a repeating unit of said formula (1) in a ratio of 50 mol % or more, wherein the copolymers are composed of the same combination of repeating units though the copolymerization ratios thereof are mutually different.

76. The polymer composition according to claim 72, comprising two or more polymer compounds composed only of a repeating unit of said formula (1).

77. The polymer composition according to claim 72, wherein at least one polymer compound contained in the polymer composition is a copolymer containing a repeating unit of said formula (1) in a ratio of 50 mol % or more, this copolymer contains also a repeating unit of said formula (13), and the molar ratio of the repeating unit of said formula (1) to the repeating unit of said formula (13) is 99:1 to 50:50.

78. The polymer composition according to claim 72, comprising at least one polymer compound composed only of a repeating unit of said formula (1) and at least one copolymer containing a repeating unit of said formula (1) in a ratio of 50 mol % or more, wherein this copolymer contains a repeating unit of said formula (1) and a repeating unit of said formula (13), and the molar ratio of the repeating unit of said formula (1) to the repeating unit of said formula (13) is 90:10 to 50:50.

79. The polymer composition according to claim 72, comprising a copolymer containing a repeating unit of said formula (1) and a repeating unit of said formula (13) wherein the molar ratio of the repeating unit of said formula (1) to the repeating unit of said formula (13) is 99:1 to 90:10, and a copolymer containing a repeating unit of said formula (1) and a repeating unit of said formula (13) wherein the molar ratio of the repeating unit of said formula (1) to the repeating unit of said formula (13) is 80:20 to 50:50.

80. A solution comprising the polymer compound according to claim 1.

81. A solution comprising the polymer composition according to claim 71.

82. The solution according to claim 80, comprising two or more organic solvents.

83. The solution according to claim 80, comprising an organic solvent having a structure containing at least one benzene ring and having a melting point of 0° C. or less and a boiling point of 100° C. or more.

84. The solution according to claim 80, comprising at least one organic solvent selected from anisole, xylene, cyclohexylbenzene and bicyclohexyl.

85. The solution according to claim 80, wherein the ratio of a solvent having highest boiling point is 40 to 90 wt %.

86. The solution according to claim 80, wherein the concentration of polymer compounds in the solution is 0.5 to 2.0 wt %.

87. The solution according to claim 80, comprising a polymer compound composed only of a repeating unit of said formula (16) and a polymer compound composed of a repeating unit of said formula (16) and a repeating unit of said formula (17).

88. The solution according to claim 80, wherein the viscosity at 25° C. is 1 to 20 mPa·s.

89. The solution according to claim 80, further comprising an additive for controlling viscosity and/or surface tension.

90. The solution according to claim 80, further comprising an antioxidant.

91. The solution according to claim 80, wherein a difference between the solubility parameter of the solvent and the solubility parameter of the polymer compound is 10 or less.

92. A light emitting film comprising the polymer compound according to claim 1.

93. The light emitting film according to claim 92, wherein quantum yield of emission is 50% or more.

94. An electrically conductive film comprising the polymer compound according to claim 1.

95. The electrically conductive film according to claim 94, wherein the surface resistance is 1 KΩ/□ or less.

96. An organic semiconductor film comprising the polymer compound according to claim 1.

97. The organic semiconductor film according to claim 96, wherein a larger value of electron mobility or hole mobility is 10⁻⁵ cm²/V/s or more.

98. An organic transistor comprising the organic semiconductor film according to claim 96.

99. A method of producing the film according to claim 92, comprising using an inkjet method.

100. A polymer light emitting device comprising an organic layer between an anode and a cathode wherein the organic layer comprises the polymer compound according to claim 1.

101. The polymer light emitting device according to claim 100, wherein the organic layer is a light emitting layer.

102. The polymer light emitting device according to claim 101, wherein the light emitting layer further contains a hole transporting material, electron transporting material or light emitting material.

103. The polymer light emitting device according to claim 100, wherein the device comprises a light emitting layer and a charge transporting layer between an anode and a cathode wherein the charge transporting layer comprises a polymer compound comprising a repeating unit of the following formula (1): 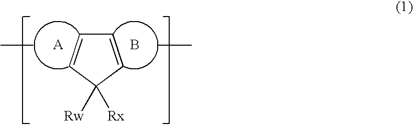
wherein, ring A and ring B represent each independently an aromatic hydrocarbon ring optionally having a substituent, at least one of ring A and ring B is an aromatic hydrocarbon ring composed of a plurality of condensed benzene rings, two connecting bonds are present on ring A and/or ring B, R_{w} and Rₓ represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, and R_{w} and Rₓ may mutually bond to form a ring.

104. The polymer light emitting device according to claim 100, wherein the device comprises a light emitting layer and a charge transporting layer between an anode and a cathode and comprises a charge injection layer between the charge transporting layer and the electrode wherein the charge injection layer comprises a polymer compound comprising a repeating unit of the following formula (1): 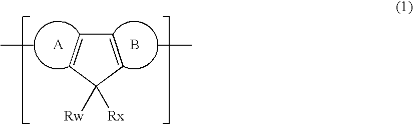
wherein, ring A and ring B represent each independently an aromatic hydrocarbon ring optionally having a substituent, at least one of ring A and ring B is an aromatic hydrocarbon ring composed of a plurality of condensed benzene rings, two connecting bonds are present on ring A and/or ring B, R_{w} and Rₓ represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, mono-valent heterocyclic group, carboxyl group, substituted carboxyl group or cyano group, and R_{w} and Rₓ may mutually bond to form a ring.

105. The polymer light emitting device according to claim 100, wherein the maximum external quantum yield when a voltage of 3.5 V or more is applied between an anode and a cathode is 1% or more.

106. A sheet light source, comprising the polymer light emitting device according to claim 100.

107. A segment display, comprising the polymer light emitting device according to claim 100.

108. A dot matrix display, comprising the polymer light emitting device according to claim 100.

109. A liquid crystal display, comprising as a back light the polymer light emitting device according to claim 100.
